(19) United States
(12) Patent Application Publication
(10) Pub. No.: US 2025/0126964 A1
(43) Pub. Date: Apr. 17, 2025

(54) LIGHT EMITTING ELEMENT, ORGANOMETALLIC COMPOUND FOR THE SAME, AND DISPLAY DEVICE INCLUDING THE SAME

(71) Applicant: Samsung Display Co., LTD., Yongin-si (KR)

(72) Inventors: EUNYOUNG LEE, Yongin-si (KR); SOO-BYUNG KO, Yongin-si (KR); SUJIN SHIN, Yongin-si (KR); SEIHWAN AHN, Yongin-si (KR); HYUNJUNG LEE, Yongin-si (KR); JUNGHOON HAN, Yongin-si (KR)

(21) Appl. No.: 18/656,593

(22) Filed: May 6, 2024

(30) Foreign Application Priority Data
Jul. 19, 2023 (KR) 10-2023-0093757

(51) Int. Cl. H10K 50/12; H10K 85/30; H10K 85/40; H10K 85/60

(52) U.S. Cl. CPC H10K 50/121; H10K 85/342; H10K 85/346; H10K 85/40; H10K 85/615; H10K 85/633; H10K 85/636; H10K 85/654; H10K 85/6572; H10K 85/6574; H10K 85/6576; H10K 85/658

(57) ABSTRACT

Provided is a light emitting element that may include a first electrode, a second electrode on the first electrode, and an emission layer between the first electrode and the second electrode. The emission layer may include a first compound represented by Formula 1 and exhibit low driving voltage and improved luminous efficiency characteristics.

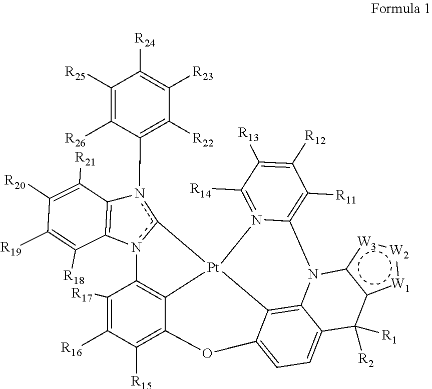

### CROSS-REFERENCE TO RELATED APPLICATIONS

The present application claims priority to and the benefit of Korean Patent Application No. 10-2023-0093757, filed on Jul. 19, 2023, in the Korean Intellectual Property Office, the entire content of which is hereby incorporated by reference.

### BACKGROUND

### 1. Field

Embodiments of the present disclosure herein relate to a light emitting element, an organometallic compound used therein, and a display device including the light emitting element.

### 2. Description of the Related Art

As image display devices, organic electroluminescence display devices and the like have been actively developed lately. The organic electroluminescence display devices and the like are display devices including so-called self-luminescent light emitting elements in which holes and electrons injected from a first electrode and a second electrode recombine in an emission layer, and thus a luminescent material in the emission layer emits light to provide display.

For application of light emitting elements to display devices, there is an interest in greater light efficiency and service life, and development of materials, for light emitting elements, capable of stably attaining such characteristics is being continuously researched.

### SUMMARY

Embodiments of the present disclosure provide a light emitting element having low voltage driving properties and improved luminous efficiency.

Embodiments of the present disclosure also provide an organometallic compound designed to improve light efficiency of a light emitting element.

Embodiments of the present disclosure also provide a display device having excellent display quality, including a light emitting element having improved luminous efficiency.

An embodiment of the present disclosure provides an organometallic compound represented by Formula 1 below.

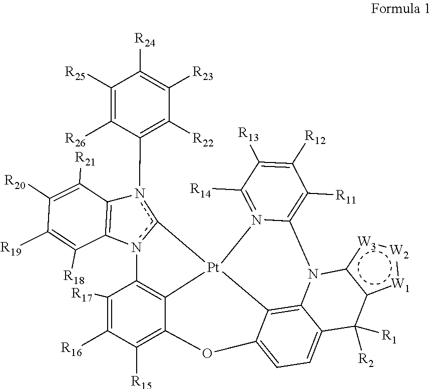

In Formula 1 above, at least one of W₁ to W₃ is O or S and the others are CRa, Ra is a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms, or bonded to an adjacent group to form a ring, and R₁, R₂, and R₁₁ to R₂₆ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms.

In an embodiment, Formula 1 above may be represented by Formula 1-1 below.

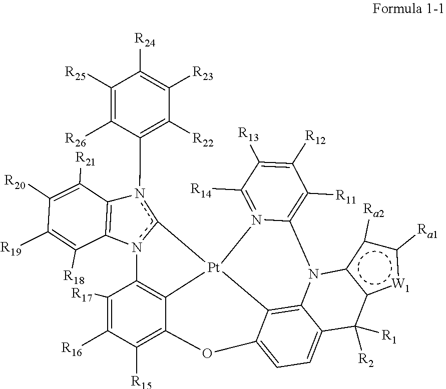

In Formula 1-1 above, W₁₁ is O or S, Rₐ₁ and Rₐ₂ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to ring-forming carbon atoms, and R₁, R₂, and R₁₁ to R₂₆ are the same as defined with respect to Formula 1 above.

In an embodiment, Rₐ₁ and Rₐ₂ may be hydrogen atoms.

In an embodiment, Formula 1 above may be represented by Formula 1-2 below.

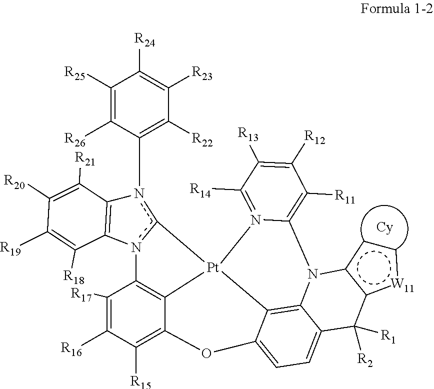

In Formula 1-2 above, W₁₁ is O or S, Cy is a substituted or unsubstituted hydrocarbon ring having 5 to 30 ring-forming carbon atoms, or a substituted or unsubstituted heterocycle having 3 to 30 ring-forming carbon atoms, and R₁, R₂, and R₁₁ to R₂₆ are the same as defined with respect to Formula 1 above.

In an embodiment, Cy above may be a substituted or unsubstituted benzene ring.

In an embodiment, the compound of Formula 1 above may emit light of phosphorescence (e.g., may emit light by way of phosphorescence).

In an embodiment of the present disclosure, a light emitting element includes a first electrode, a second electrode on the first electrode, and an emission layer between the first electrode and the second electrode and including a first compound, which is an organometallic compound of an embodiment.

In an embodiment, the light emitting element may further include at least one of a second compound represented by Formula HT-1 or a third compound represented by Formula ET-1 below.

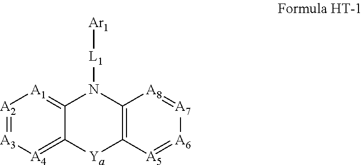

In Formula HT-1 above, A₁ to A₈ are each independently N or CR₅₁, L₁ is a direct linkage, a substituted or unsubstituted arylene group having 6 to 30 ring-forming carbon atoms, or a substituted or unsubstituted heteroarylene group having 2 to 30 ring-forming carbon atoms, Yₐ is a direct linkage, CR₅₂R₅₃, or SiR₅₄R₅₅, and Ar₁ is a substituted or unsubstituted aryl group having 6 to 30 ring-forming carbon atoms, or a substituted or unsubstituted heteroaryl group having 2 to 30 ring-forming carbon atoms. R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

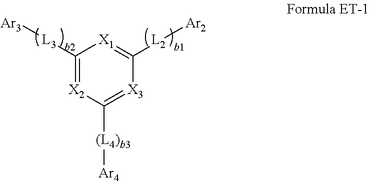

In Formula ET-1 above, at least one of X₁ to X₃ is N and the others are CR₅₆, R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and b1 to b3 are each independently an integer of 0 to 10. Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms.

In an embodiment, the emission layer may further include a fourth compound represented by Formula F-1 below.

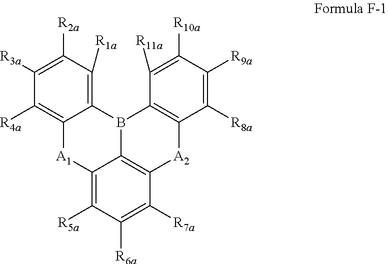

In Formula F-1 above, A₁ and A₂ are each independently O, S, Se, or NRₘ, Rₘ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and R₁ₐ to R₁₁ₐ are each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In an embodiment, the emission layer may include the first compound, the second compound, the third compound, and the fourth compound.

In an embodiment, the emission layer may include a host and a phosphorescent dopant, and the phosphorescent dopant may be the first compound.

In an embodiment, the emission layer may emit blue light having a maximum central wavelength of about 470 nm or less.

In an embodiment of the present disclosure, a display device includes a base layer, a circuit layer on the base layer, and a display element layer on the circuit layer and including a light emitting element, wherein the light emitting element includes a first electrode, a second electrode facing the first electrode, and an emission layer between the first electrode and the second electrode and containing an organometallic compound.

In an embodiment, the light emitting element may emit blue light.

In an embodiment, the display device may include a light control layer containing quantum dots.

### BRIEF DESCRIPTION OF DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view showing a portion corresponding to line I-I′ of FIG. 1;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 is a cross-sectional view schematically showing a light emitting element according to an embodiment;

FIG. 8 is a cross-sectional view showing a display device according to an embodiment;

FIG. 9 is a cross-sectional view showing a display device according to an embodiment;

FIG. 10 is a cross-sectional view showing a display device according to an embodiment;

FIG. 11 is a cross-sectional view showing a display device according to an embodiment; and

FIG. 12 is a view showing the inside of a vehicle in which a display device of an embodiment is disposed.

### DETAILED DESCRIPTION

The subject matter of the present disclosure may be modified in various manners and have many forms, and thus example embodiments will be exemplified in the drawings and described in more detail in the detailed description of the present disclosure. It should be understood, however, that it is not intended to limit the subject matter of the present disclosure to the particular forms disclosed, but rather, is intended to cover all modifications, equivalents, and alternatives falling within the spirit and scope of the present disclosure.

When explaining each of the drawings, like reference numbers are used for referring to like elements. In the accompanying drawings, the dimensions of each structure may be exaggeratingly illustrated for clarity of the present disclosure. It will be understood that, although the terms “first,” “second,” etc., may be used herein to describe various components, these components should not be limited by these terms.

These terms are only used to distinguish one component from another. For example, a first component could be termed a second component, and, similarly, a second component could be termed a first component, without departing from the scope of example embodiments of the present disclosure. As used herein, the singular forms, “a,” “an,” and “the” are intended to include the plural forms as well, unless the context clearly indicates otherwise.

In the present disclosure, it will be understood that the terms “include,” “have” or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present disclosure, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In addition, it will be understood that when a part is referred to as being “on” another part, it can be above the other part, or under the other part as well.

In the specification, the term “substituted or unsubstituted” may mean substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may mean that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle.

The hydrocarbon ring and the heterocycle may be monocyclic or polycyclic. In addition, the rings formed by being bonded to each other may be connected to another ring to form a spiro structure.

In the specification, the term “adjacent group” may mean a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group may be 1 to 50, 1 to 30, 1 to 20, 1 to 10, or 1 to 6.

Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the specification, a cycloalkyl group may mean a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments of the present disclosure are not limited thereto.

In the specification, an alkenyl group means a hydrocarbon group including at least one carbon double bond at a main chain (e.g., in the middle) or a terminal end of an alkyl group having 2 or more carbon atoms. The alkenyl group may be linear or branched. The number of carbon atoms in the alkenyl group is not specifically limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but embodiments of the present disclosure are not limited thereto.

In the specification, an alkynyl group means a hydrocarbon group including at least one carbon triple bond at a main chain (e.g., in the middle) or a terminal end of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, etc., but are not limited thereto.

In the specification, the hydrocarbon ring group means any suitable functional group or substituent derived from an aliphatic hydrocarbon ring. The hydrocarbon ring group may be a saturated hydrocarbon ring group having 5 to 20 ring-forming carbon atoms.

In the specification, an aryl group means any suitable functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the specification, the fluorenyl group may be substituted, and two substituents may be bonded to each other to form a spiro structure. Examples of the substituted fluorenyl group are as follows. However, embodiments of the present disclosure are not limited thereto.

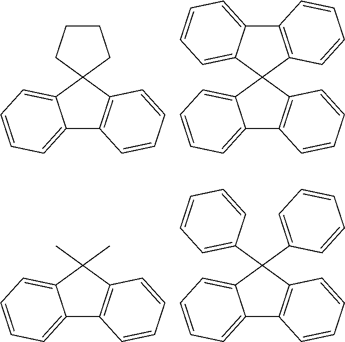

The heterocyclic group herein means any suitable functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited thereto.

In the specification, the heteroaryl group may contain at least one of B, O, N, P, Si, or S as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments of the present disclosure are not limited thereto.

In the specification, the number of ring-forming carbon atoms in the carbonyl group is not specifically limited, but may be 1 to 40, 1 to 30, or 1 to 20. For example, the carbonyl group may have the following structures, but embodiments of the present disclosure are not limited thereto.

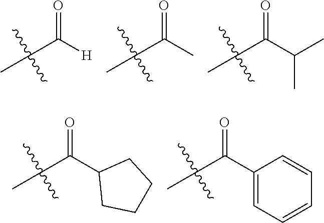

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the specification, an oxy group may mean that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

The boron group herein may mean that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but embodiments of the present disclosure are not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but embodiments of the present disclosure are not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the specification, the aryl group among an aryloxy group, an arylthio group, an arylsulfoxy group, an arylamino group, an arylboron group, an arylsilyl group, an arylamine group is the same as the examples of the aryl group described above.

In the specification, a direct linkage may mean a single bond.

In the specification, “

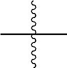

” and “*-” mean a position to be connected.

Hereinafter, embodiments of the present disclosure will be described with reference to the accompanying drawings.

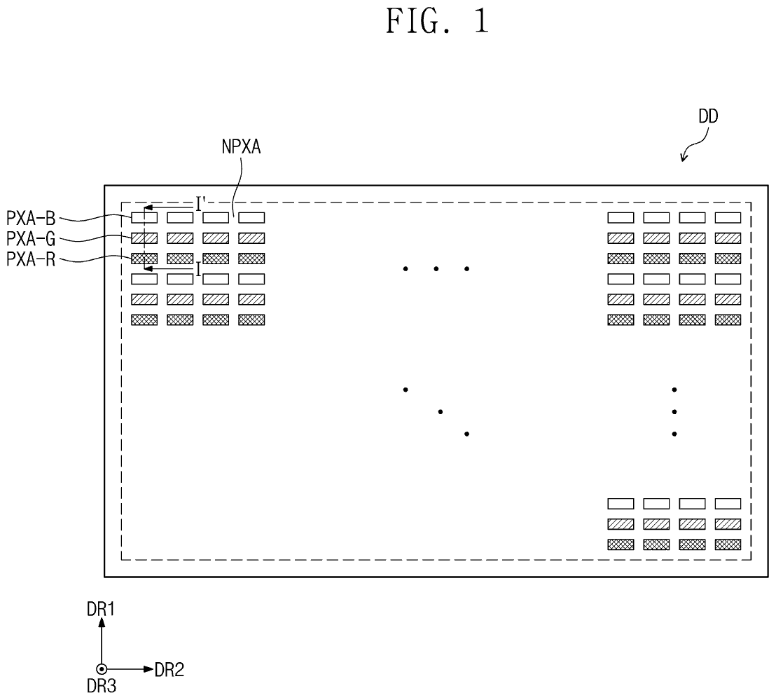

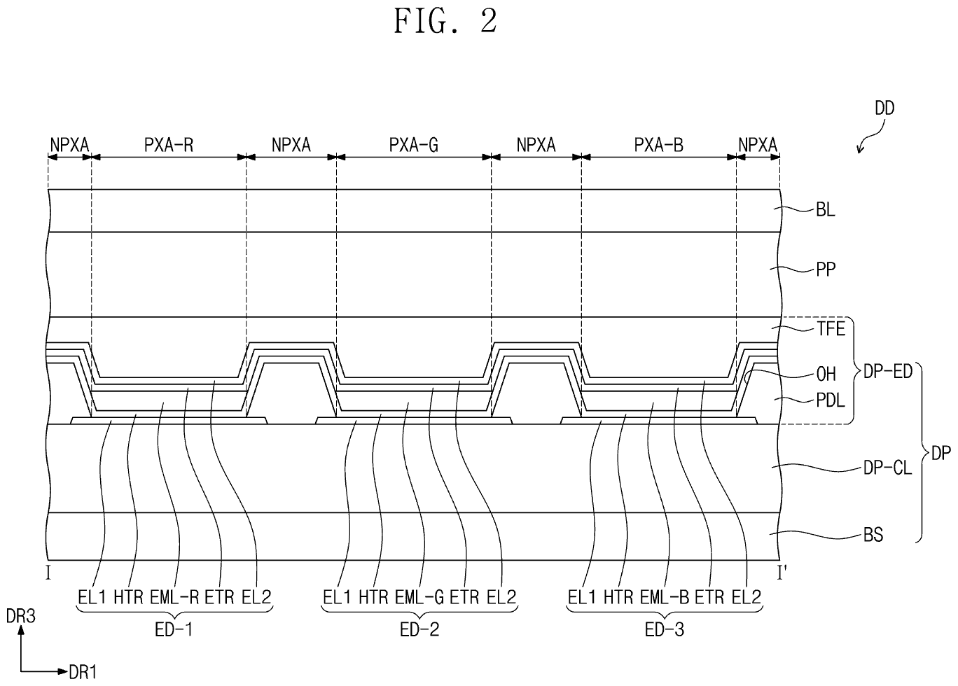

FIG. 1 is a plan view illustrating an embodiment of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP on the display panel DP. The display panel DP includes light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarization layer and/or a color filter layer. In some embodiments, the optical layer PP may be omitted from the display device DD of an embodiment.

A base substrate BL may be on the optical layer PP. The base substrate BL may be a member which provides a base surface on which the optical layer PP is provided. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may be omitted.

The display device DD according to an embodiment may further include a filling layer. The filling layer may be between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining layer PDL, the light emitting elements ED-1, ED-2, and ED-3 between portions of the pixel defining layer PDL, and an encapsulation layer TFE on the light emitting elements ED-1, ED-2, and ED-3.

The base layer BS may be a member which provides a base surface on which the display element layer DP-ED is provided. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

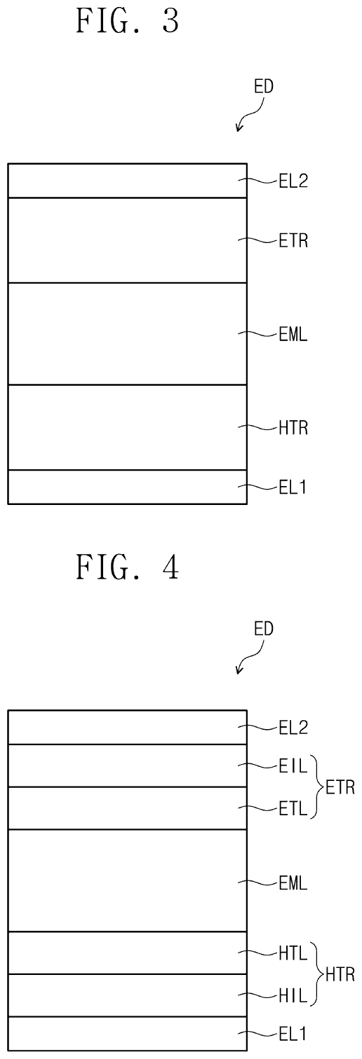

Each of the light emitting elements ED-1, ED-2, and ED-3 may have a structure of each light emitting element ED of embodiments according to FIGS. 3 to 7, which will be further described below. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are in openings OH defined in the pixel defining layer PDL, and the hole transport region HTR, the electron transport region ETR, and the second electrode EL2 are provided as a common layer in the entire light emitting elements ED-1, ED-2, and ED-3. However, embodiments of the present disclosure are not limited thereto, and in some embodiments, the hole transport region HTR and the electron transport region ETR in an embodiment may be provided by being patterned inside the openings OH defined in the pixel defining layer PDL. For example, the hole transport region HTR, the emission layers EML-R, EML-G, and EML-B, and the electron transport region ETR of the light emitting elements ED-1, ED-2, and ED-3 in an embodiment may be provided by being patterned utilizing an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE includes at least one insulation layer (e.g., electrical insulation layer). The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. The encapsulation-organic film may include a photopolymerizable organic material, but embodiments of the present disclosure are not particularly limited thereto.

The encapsulation layer TFE may be on the second electrode EL2 and may fill the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining layer PDL. The non-light emitting areas NPXA may be areas between the adjacent light emitting areas PXA-R, PXA-G, and PXA-B, which correspond to the pixel defining layer PDL. In some embodiments, the light emitting regions PXA-R, PXA-G, and PXA-B may respectively correspond to pixels. The pixel defining layer PDL may divide the light emitting elements ED-1, ED-2, and ED-3. The emission layers EML-R, EML-G, and EML-B of the light emitting elements ED-1, ED-2, and ED-3 may be in openings OH defined in the pixel defining layer PDL and separated from each other.

The light emitting regions PXA-R, PXA-G, and PXA-B may be divided into a plurality of groups according to the color of light generated from the light emitting elements ED-1, ED-2, and ED-3. In the display device DD of an embodiment illustrated in FIGS. 1 and 2, three light emitting regions PXA-R, PXA-G, and PXA-B, which emit red light, green light, and blue light, respectively, are illustrated as examples. For example, the display device DD of an embodiment may include the red light emitting region PXA-R, the green light emitting region PXA-G, and the blue light emitting region PXA-B that are separated from each other.

In the display device DD according to an embodiment, the plurality of light emitting elements ED-1, ED-2 and ED-3 may emit light beams having wavelengths different from each other. For example, in an embodiment, the display device DD may include a first light emitting element ED-1 that emits red light, a second light emitting element ED-2 that emits green light, and a third light emitting element ED-3 that emits blue light. In some embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may emit light beams in the same wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In addition, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light.

In this case, the areas of the light emitting regions PXA-R, PXA-G, and PXA-B may mean areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various suitable combinations according to the characteristics of display quality required or desired for the display device DD. For example, the arrangement form of the light emitting regions PXA-R, PXA-G, and PXA-B may be a PENTILE® arrangement structure (e.g., an RGBG matrix, RGBG structure, or RGBG matrix structure) or a DIAMOND PIXEL™ arrangement structure. PENTILE® is a duly registered trademark of Samsung Display Co., Ltd.

In addition, the areas of the light emitting regions PXA-R, PXA-G, and PXA-B may be different from each other. For example, in an embodiment, the area of the green light emitting region PXA-G may be smaller than that of the blue light emitting region PXA-B, but embodiments of the present disclosure are not limited thereto.

Hereinafter, FIGS. 3 to 7 are cross-sectional views schematically illustrating light emitting elements according to embodiments. Each of the light emitting elements ED according to embodiments may include a first electrode EL1, a hole transport region HTR, an emission layer EML, an electron transport region ETR, and a second electrode EL2 that are sequentially stacked.

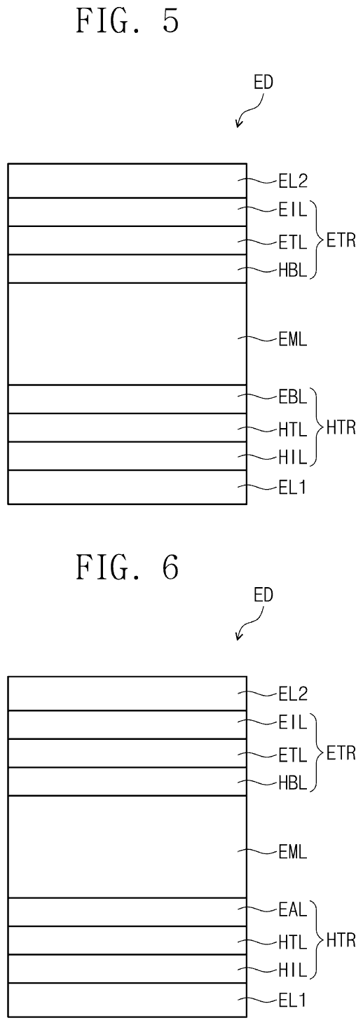

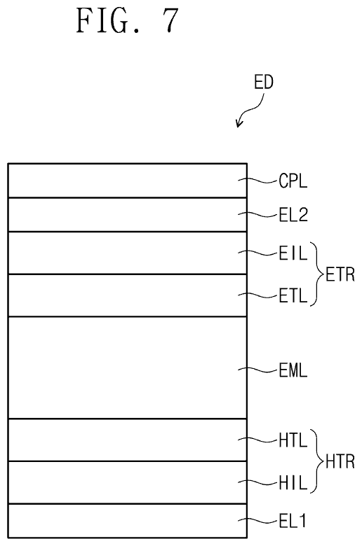

Compared with FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. As compared with FIG. 3, FIG. 6 illustrates a cross-sectional view of a light emitting element ED of an embodiment, in which a hole transport region HTR includes a hole injection layer HIL, a hole transport layer HTL, and an emission-auxiliary layer EAL, and an electron transport region ETR includes an electron injection layer EIL, an electron transport layer ETL, and a hole blocking layer HBL. Compared with FIG. 4, FIG. 7 illustrates a cross-sectional view of a light emitting element ED of an embodiment including a capping layer CPL on a second electrode EL2.

The first electrode EL1 has conductivity (e.g., electrical conductivity). The first electrode EL1 may be formed of a metal material, a metal alloy, and/or a conductive compound (e.g., an electrically conductive compound). The first electrode EL1 may be an anode or a cathode. However, embodiments of the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments of the present disclosure are not limited thereto. In addition, embodiments of the present disclosure are not limited thereto, and the first electrode EL1 may include the above-described metal materials, combinations of at least two metal materials of the above-described metal materials, oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is on the first electrode EL1. The hole transport region HTR may include at least one of a hole injection layer HIL, a hole transport layer HTL, an emission-auxiliary layer EAL, or an electron blocking layer EBL. The thickness of the hole transport region HTR may be, for example, from about 50 Å to about 15,000 Å. The emission-auxiliary layer EAL may be referred to as a buffer layer.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In addition, the hole transport region HTR may have a single layer structure formed of a plurality of different materials, or a structure in which a hole injection layer HIL/hole transport layer HTL, a hole injection layer HIL/hole transport layer HTL/emission-auxiliary layer EAL, a hole injection layer HIL/emission-auxiliary layer EAL, a hole transport layer HTL/emission-auxiliary layer EAL, or a hole injection layer HIL/hole transport layer HTL/electron blocking layer EBL are stacked in order from the first electrode EL1, but embodiments of the present disclosure are not limited thereto.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below.

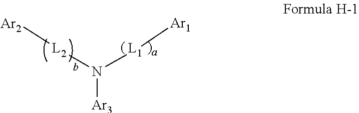

In Formula H-1 above, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. a and b may be each independently an integer of 0 to 10. In some embodiments, when a or b is an integer of 2 or greater, a plurality of L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 above may be a monoamine compound. In some embodiments, the compound represented by Formula H-2 above may be a diamine compound in which at least one among Ar₁ to Ar₃ includes the amine group as a substituent. In addition, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among the compounds in Compound Group H below. However, the compounds listed in Compound Group H below are examples, and the compounds represented by Formula H-1 are not limited to those represented by Compound Group H below.

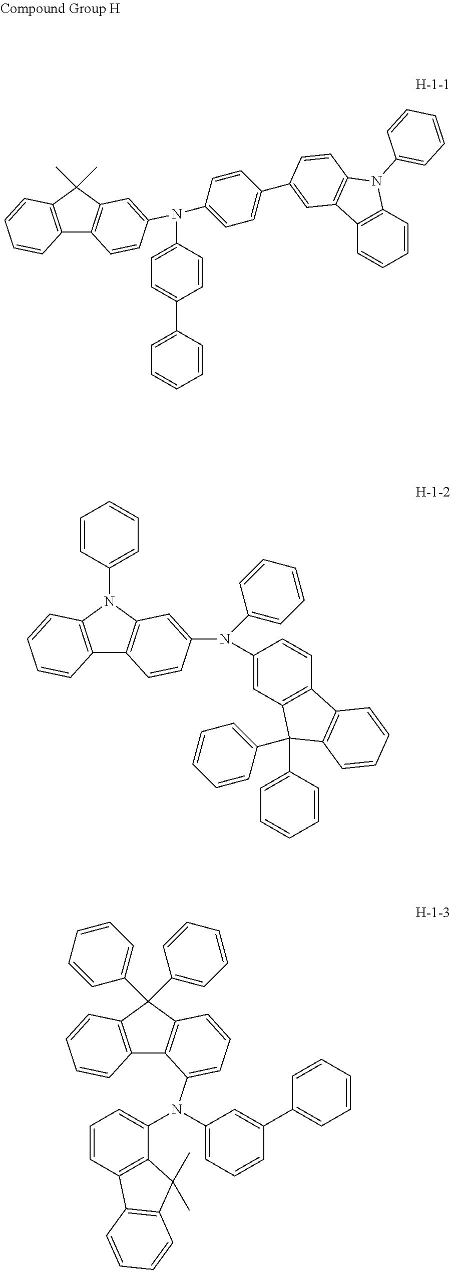 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

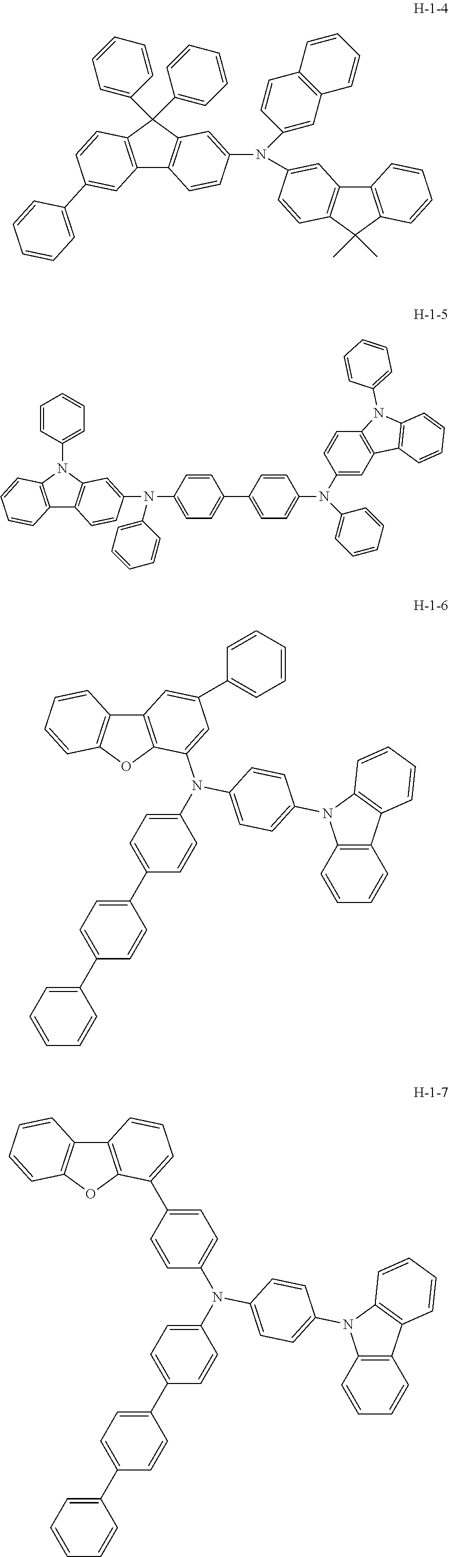 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

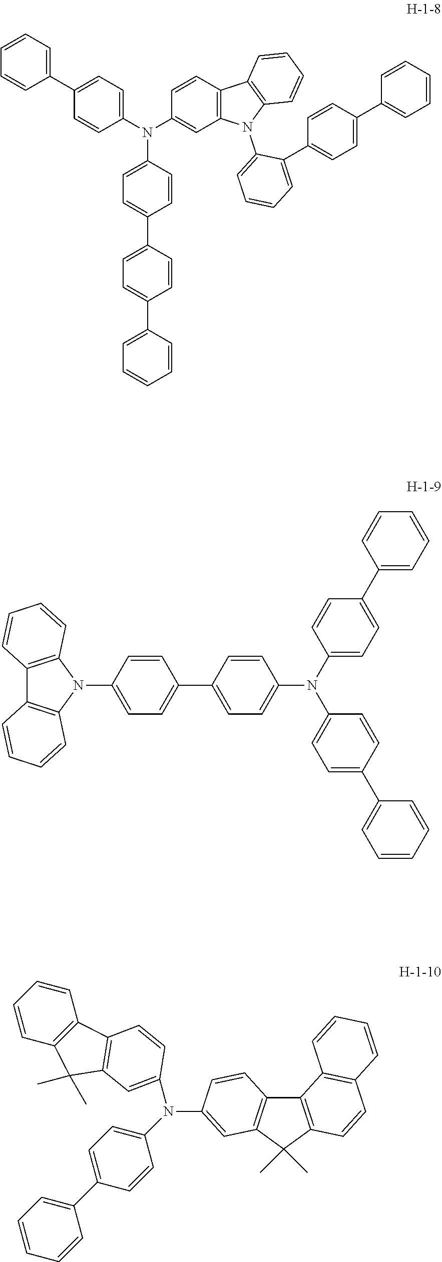 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

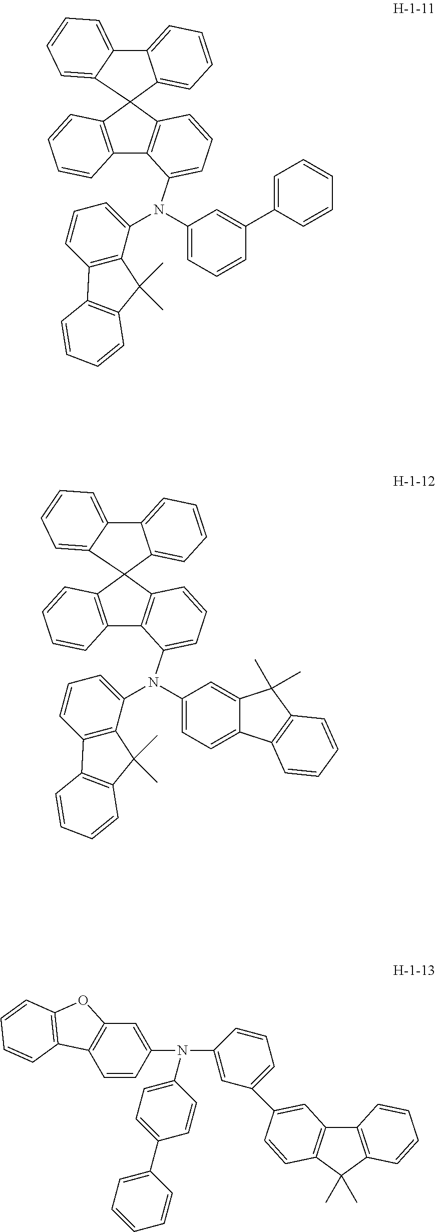 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

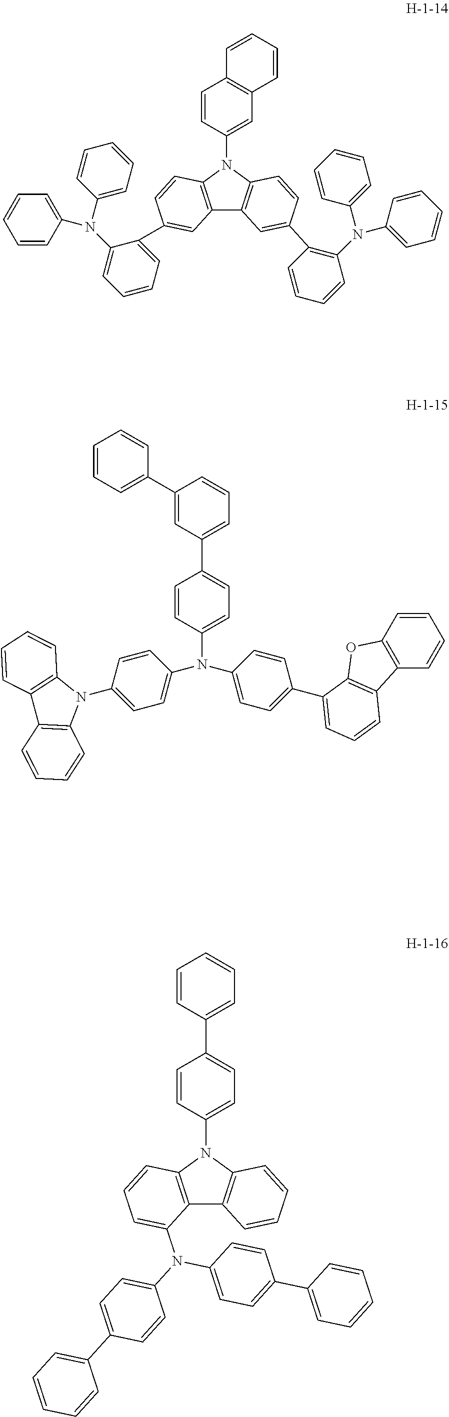

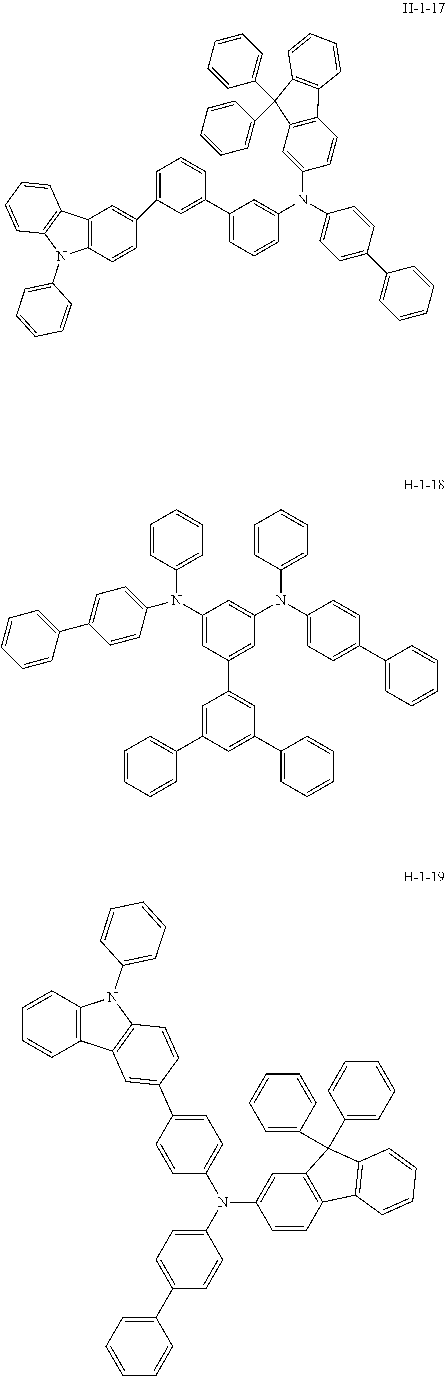 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an emission-auxiliary layer EAL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without a substantial increase in driving voltage.

The hole transport region HTR may further include a charge generating material to increase conductivity (e.g., electrical conductivity) in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, the p-dopant may include a metal halide compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the auxiliary emission layer EAL or the electron blocking layer EBL, in addition to the hole injection layer HIL and the hole transport layer HTL. The auxiliary emission layer EAL may compensate a resonance distance according to the wavelength of light emitted from the emission layer EML and regulate a hole charge balance to increase light emitting efficiency. In addition, the auxiliary emission layer EAL may serve to prevent electrons from being injected into the hole transport region HTR. Materials which may be included in the hole transport region HTR may be included in the auxiliary emission layer EAL. The electron blocking layer EBL is a layer that serves to prevent or reduce injection of electrons from the electron transport region ETR to the hole transport region HTR.

In the light emitting element ED of an embodiment, the emission layer EML may include a first compound, which is the organometallic compound according to an embodiment. In addition, in the light emitting element ED of an embodiment, the emission layer EML may further include a second compound and a third compound as host materials, in addition to the first compound. In an embodiment, the second compound may include a fused ring of three rings, which contains a nitrogen atom as a ring-forming atom. The third compound may include a C6-ring group containing at least one nitrogen atom as a ring-forming atom. In the light emitting element ED of an embodiment, the emission layer EML may further include a fourth compound, which is a thermally activated delayed fluorescent dopant, in addition to the first compound, which is the organometallic compound according to an embodiment. The second to fourth compounds will be described in more detail herein below.

Herein, the first compound may be referred to as an organometallic compound of an embodiment. The organometallic compound of an embodiment may include Pt as a central metal atom, and one of the ligands bonded to the central metal atom may include a heteropolycyclic ring structure of Formula A below. In Formula A, “

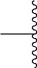

” is a portion that is bonded to the central metal atom, and “*-” is a portion that is connected to each neighboring ligand. The heteropolycyclic ring structure represented by Formula A may include a C5-ring containing O or S as a hetero atom, in addition to the C6-ring containing an N atom. In Formula A below, at least one of W₁ to W₃ may be O or S.

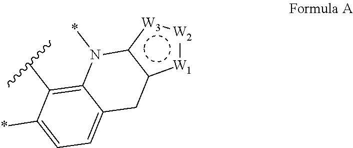

The organometallic compound of an embodiment may include a carbene derivative ligand and a pyridine derivative ligand, in addition to the heteropolycyclic ring structure of Formula A above.

The organometallic compound of an embodiment includes the heteropolycyclic ring structure represented by Formula A, and may thus have a deep HOMO energy level, thereby obtaining low driving voltage and a deep blue emission color. In addition, the organometallic compound of an embodiment may exhibit excellent luminous efficiency in the deep blue emission wavelength range.

The organometallic compound of an embodiment may be represented by Formula 1 below.

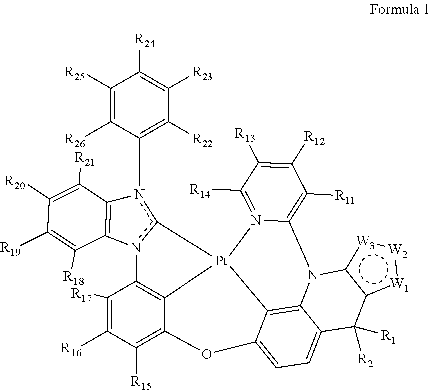

In Formula 1, at least one of W₁ to W₃ is O or S and the others are CRa. Ra may be a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms, or bonded to an adjacent group to form a ring.

In an embodiment, one selected from W₁ to W₃ may be O or S, or two or more selected from W₁ to W₃ may each independently be O or S. When two or more selected from W₁ to W₃ are O or S, which is a heteroatom, the plurality of heteroatoms may all be the same or at least one may be different from the others.

For example, in the organic metal compound represented by Formula 1, W₁ may be O or S, and W₂ and W₃ may each independently be CRa. In some embodiments, when Ra is bonded to an adjacent group to form a ring, the formed ring may be a hydrocarbon ring or a hetero ring. For example, the ring formed through the binding with an adjacent group may be an aryl ring or a heteroaryl ring.

In Formula 1, R₁, R₂, and R₁₁ to R₂₆ are each independently a hydrogen atom, a deuterium atom, a halogen atom, a substituted or unsubstituted alkyl group having 1 to 10 carbon atoms, a substituted or unsubstituted alkenyl group having 2 to carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to ring-forming carbon atoms.

For example, in an embodiment, R₁₁ to R₂₆ may each independently be a hydrogen atom, a deuterium atom, a substituted or unsubstituted alkyl group having 1 to 10 carbon atoms, or a substituted or unsubstituted aryl group having 6 to 30 ring-forming carbon atoms. In an embodiment, R₁ and R₂ may each independently be a hydrogen atom, a deuterium atom, a substituted or unsubstituted alkyl group having 1 to 10 carbon atoms, or a substituted or unsubstituted aryl group having 6 to 30 ring-forming carbon atoms.

The organometallic compound of an embodiment is bonded to the central metal atom, Pt, and includes a 3- or 4-ring fused polycyclic heteropolycyclic ring as a ligand, and may thus exhibit a deep HOMO (highest occupied molecular orbital) energy level. In addition, the inclusion of the heteropolycyclic ring may provide excellent luminous efficiency and blue luminescent characteristics together. In addition, the organometallic compound of an embodiment may exhibit deep blue light emission having a relatively short wavelength.

The organometallic compound of an embodiment may emit light of phosphorescence (e.g., may emit light by way of phosphorescence). The organometallic compound of an embodiment may be used as a phosphorescent dopant.

The organometallic compound of an embodiment represented by Formula 1 may be represented by Formula 1-1 below.

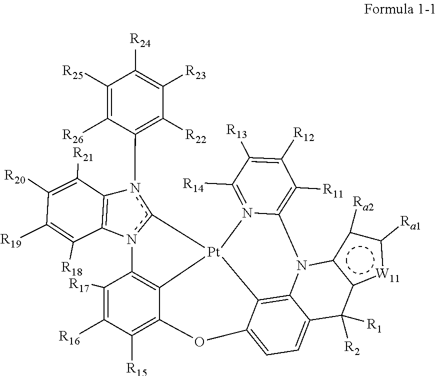

In Formula 1-1, W₁₁ may be O or S. In addition, Rₐ₁ and Rₐ₂ may each independently be a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms.

In one embodiment, Rₐ₁ and Rₐ₂ may be the same or different. For example, in Formula 1-1, both Rₐ₁ and Rₐ₂ may be hydrogen atoms.

In some embodiments, in Formula 1-1, the description of Formula 1 above may also apply to R₁, R₂, and R₁₁ to R₂₆.

The organometallic compound of an embodiment represented by Formula 1 may be represented by Formula 1-2 below.

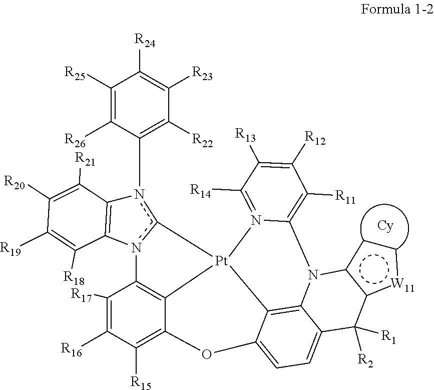

In Formula 1-2, W₁₁ may be O or S, and Cy may be a substituted or unsubstituted hydrocarbon ring having 5 to 30 ring-forming carbon atoms, or a substituted or unsubstituted heterocycle having 3 to 30 ring-forming carbon atoms.

In an embodiment, Cy may be a substituted or unsubstituted hexagonal hydrocarbon ring, or a substituted or unsubstituted hexagonal heterocycle. For example, Cy may be a substituted or unsubstituted benzene ring.

In some embodiments, in Formula 1-2, the description of Formula 1 above may also apply to R₁, R₂, and R₁₁ to R₂₆.

An organometallic compound according to an embodiment may be represented by any one among compounds of Compound Group 1 below. The light emitting element ED according to an embodiment may include at least one of the compounds from Compound Group 1 below. In Compound Group 1 below, D is a deuterium atom, and Ph is an unsubstituted phenyl group.

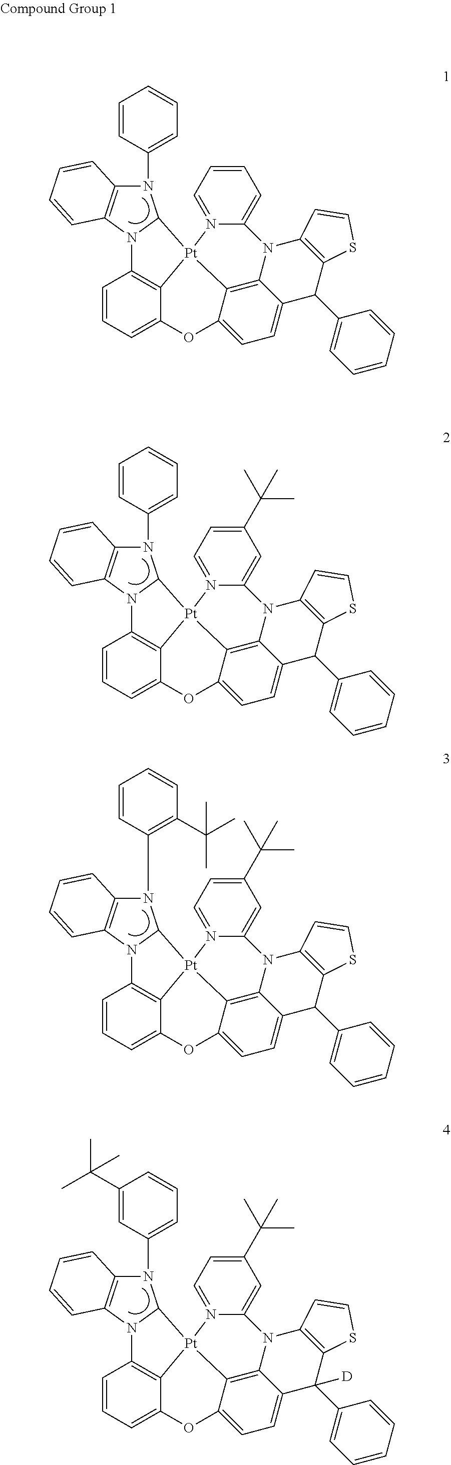

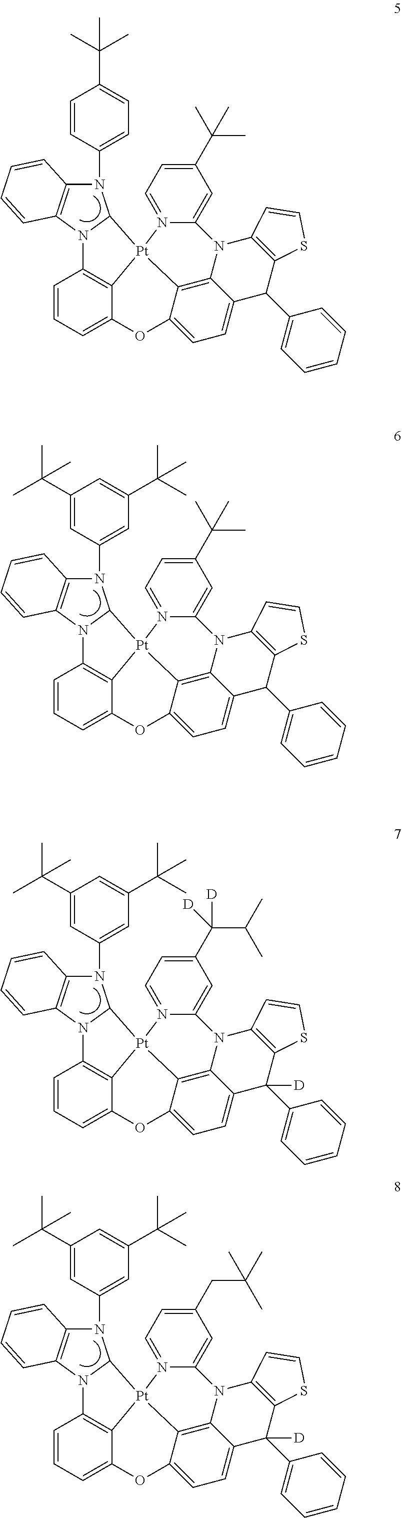

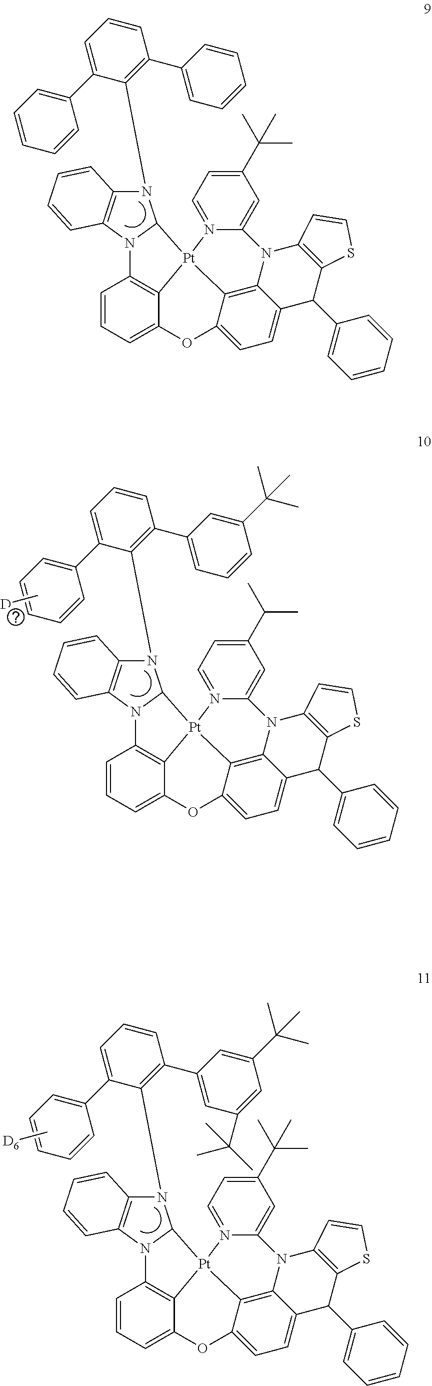

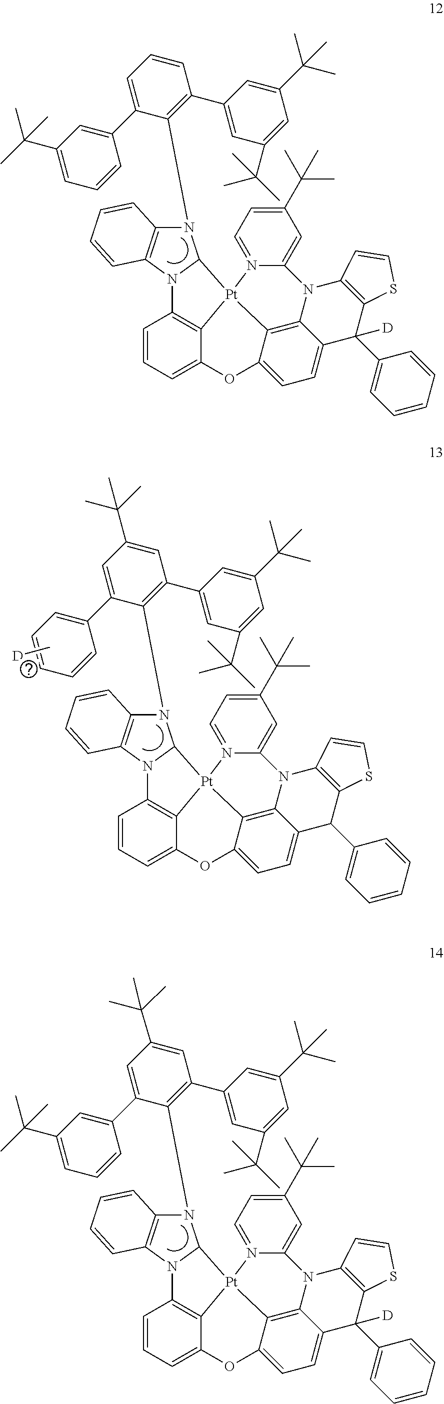

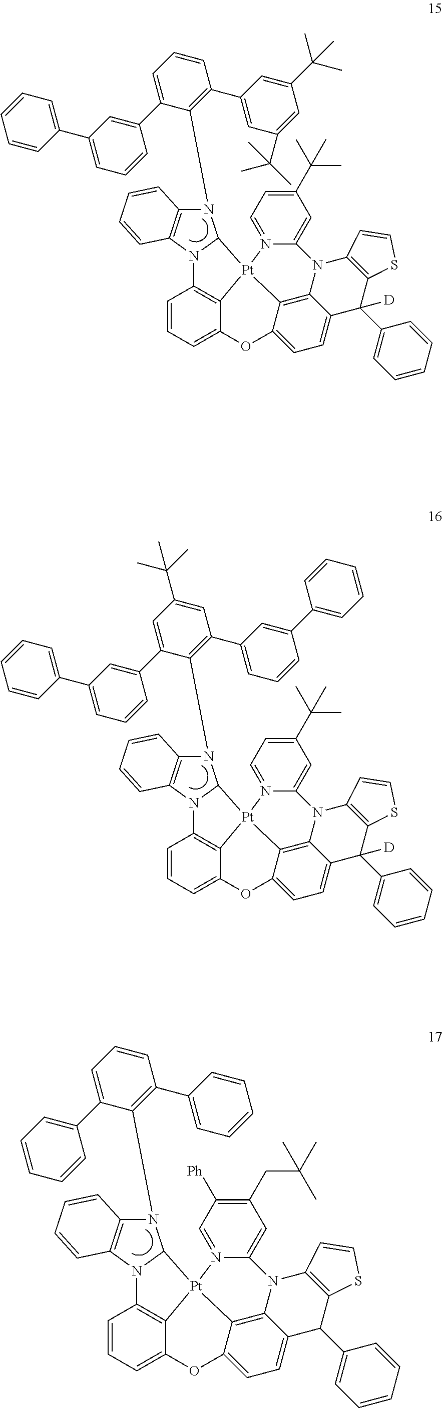

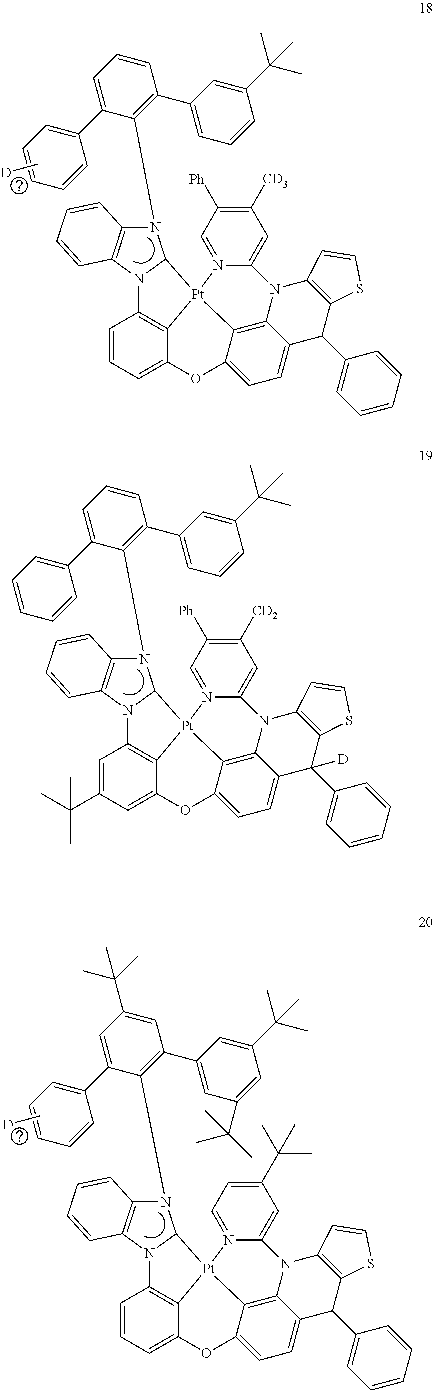

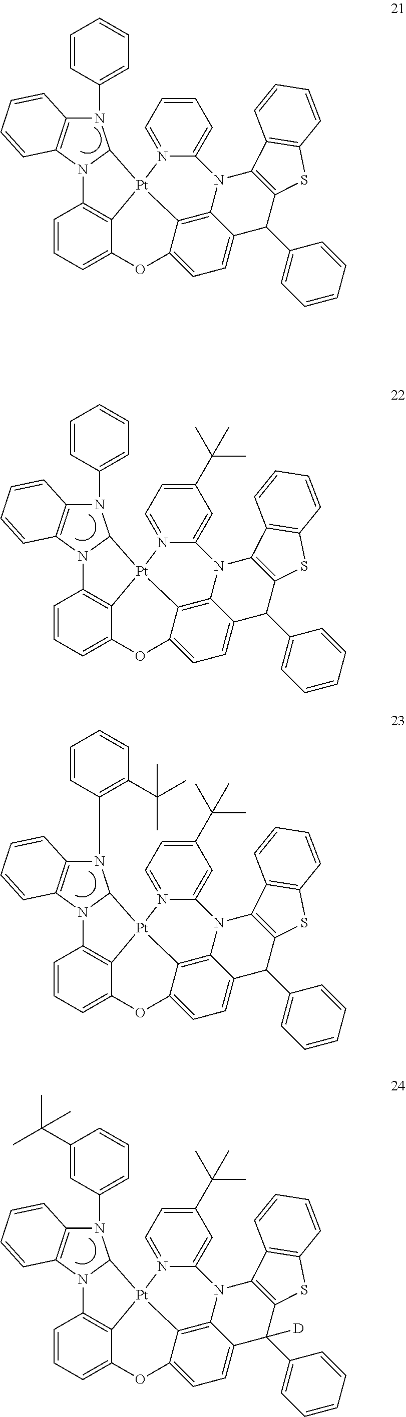

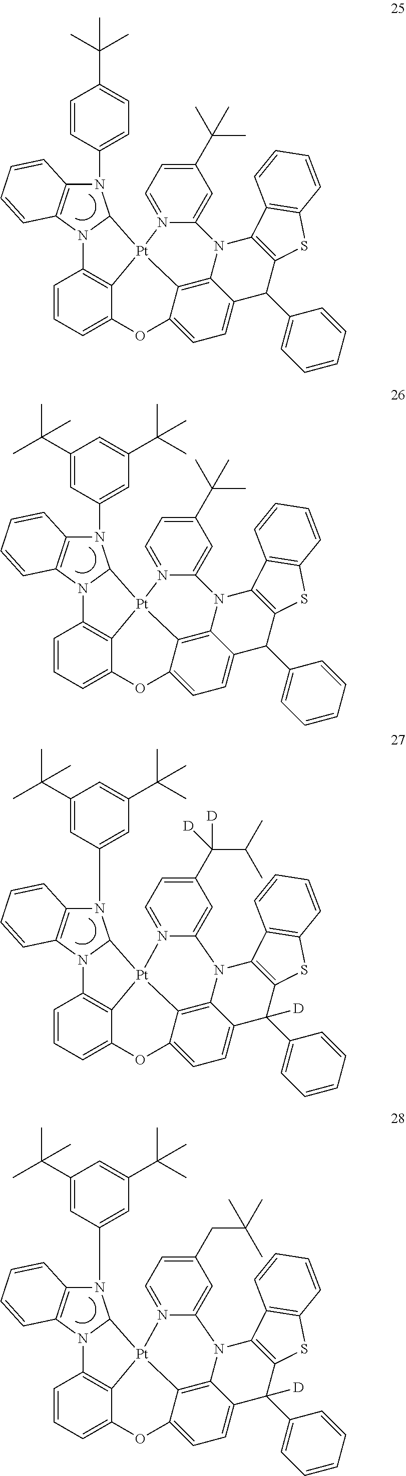

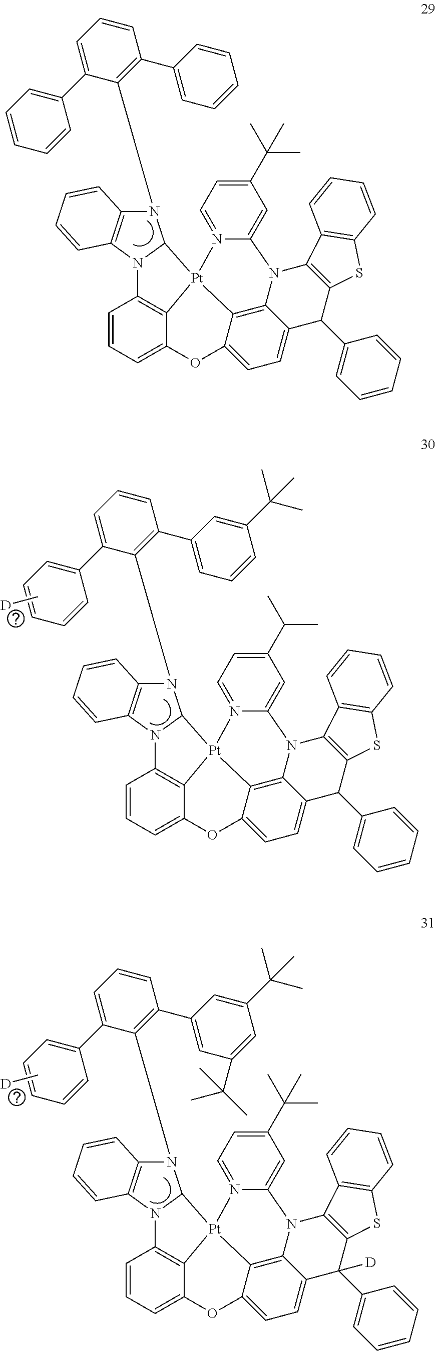

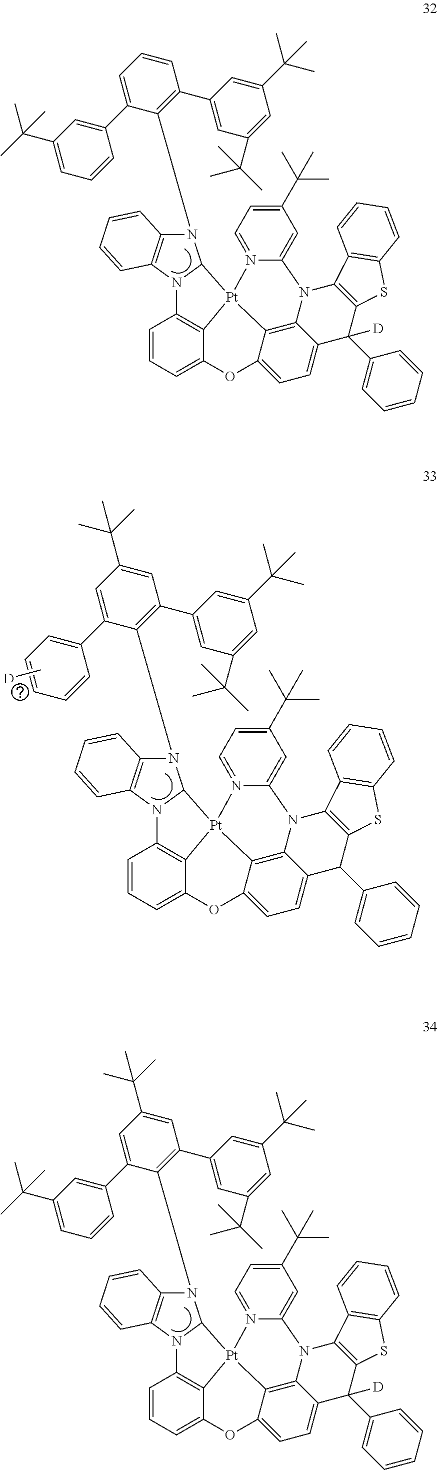

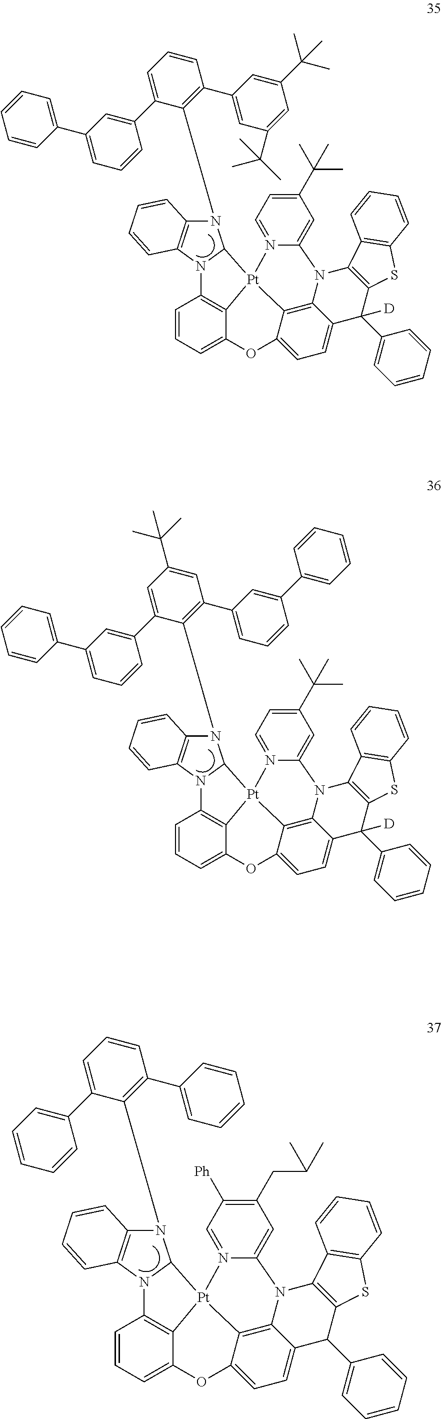

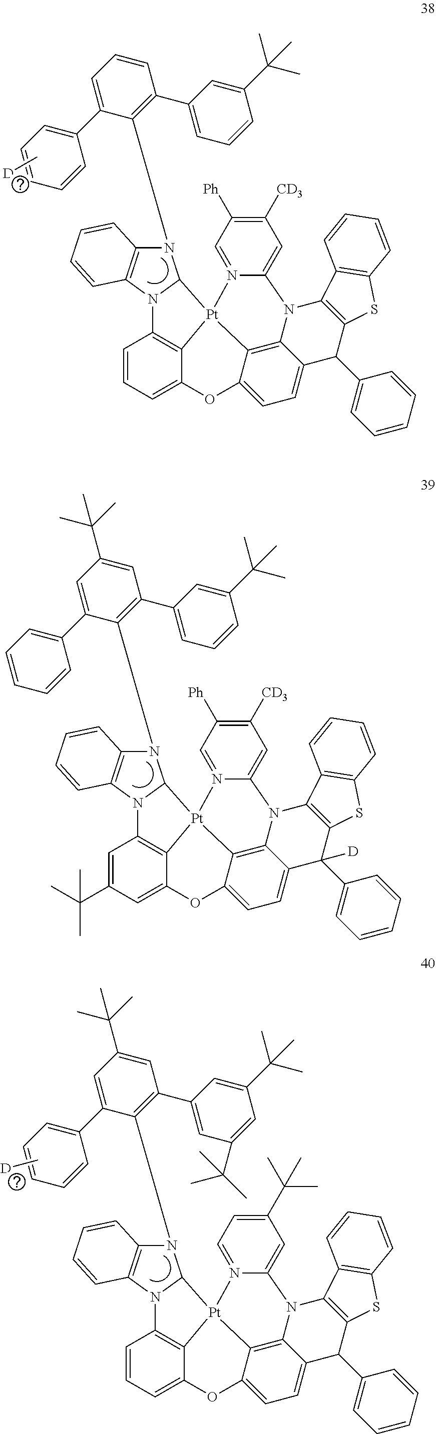

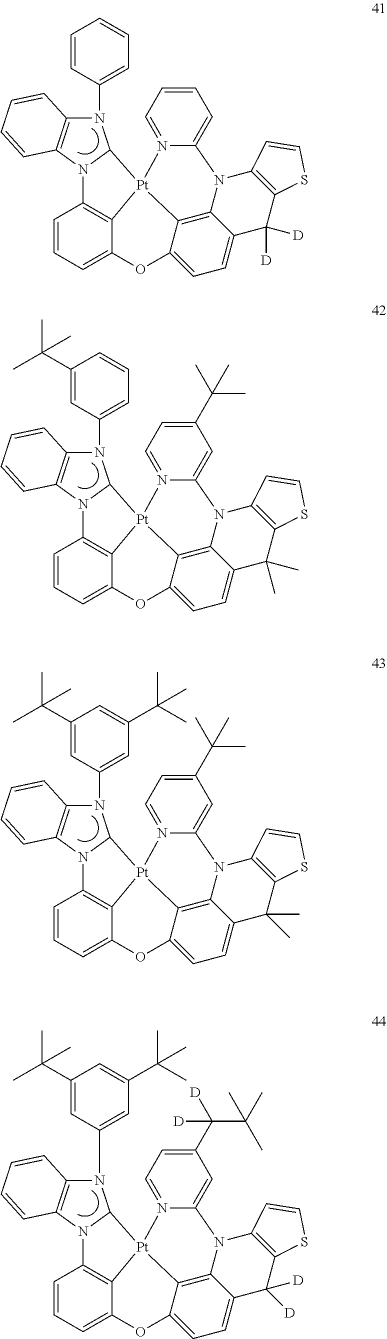

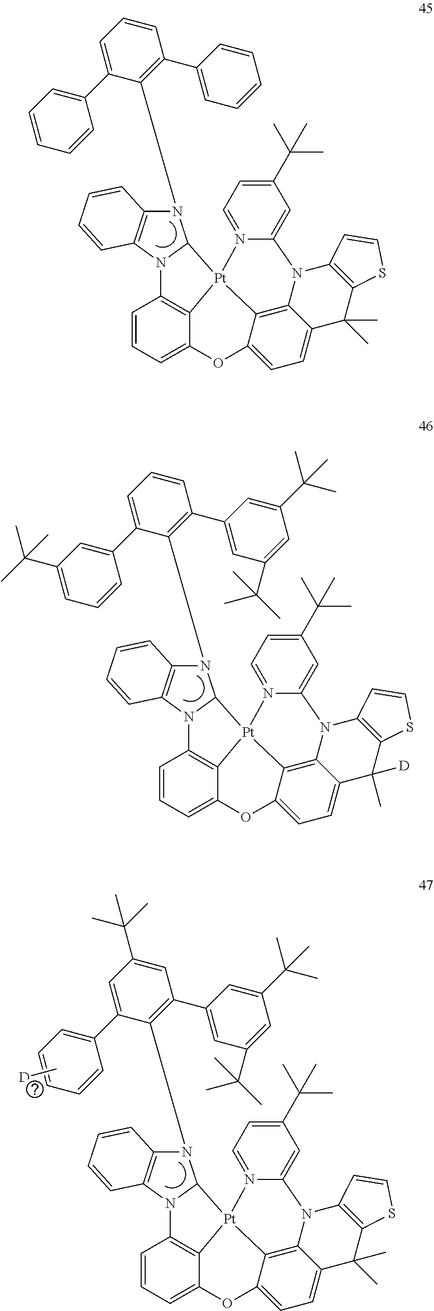

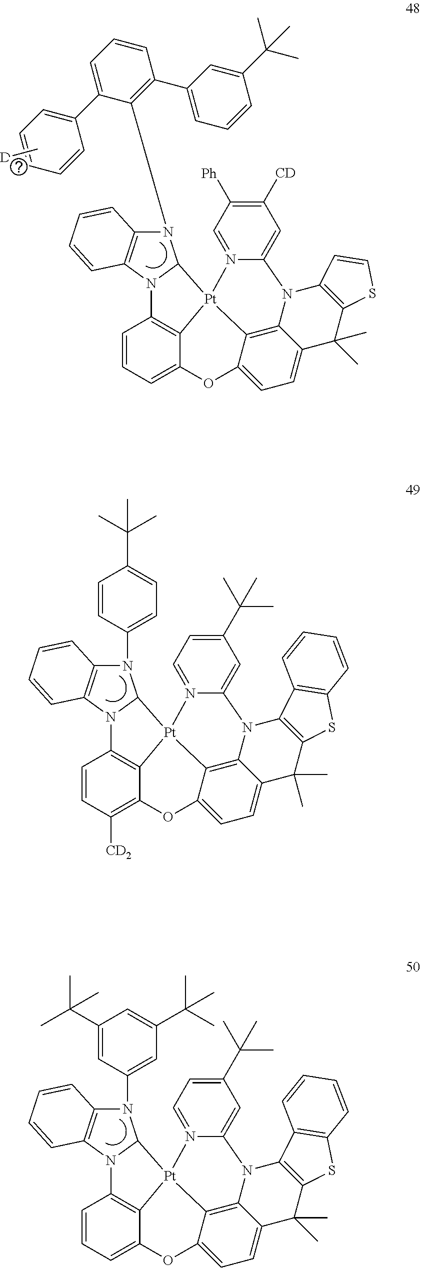

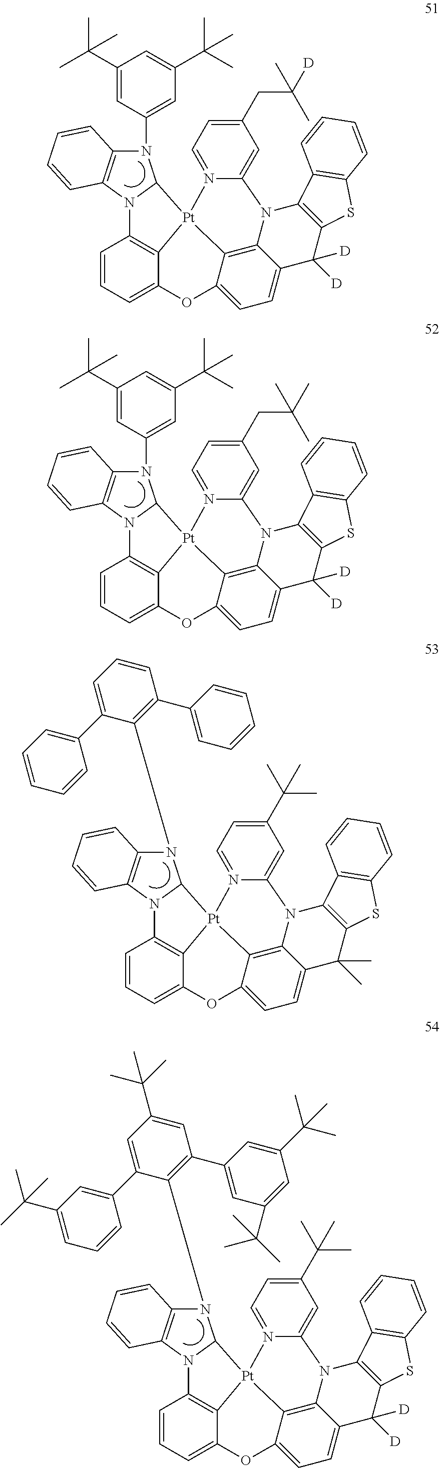

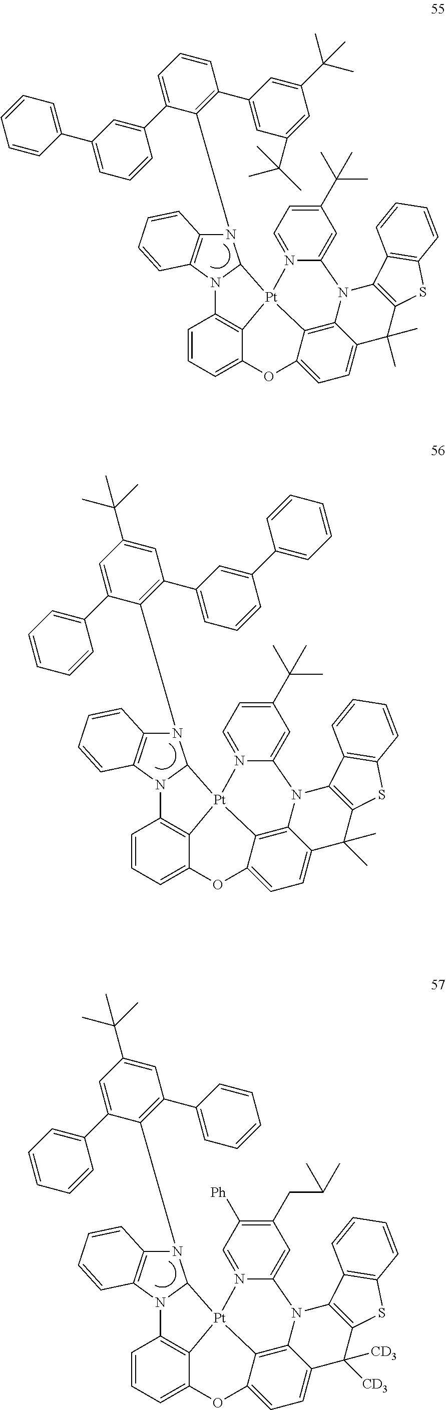

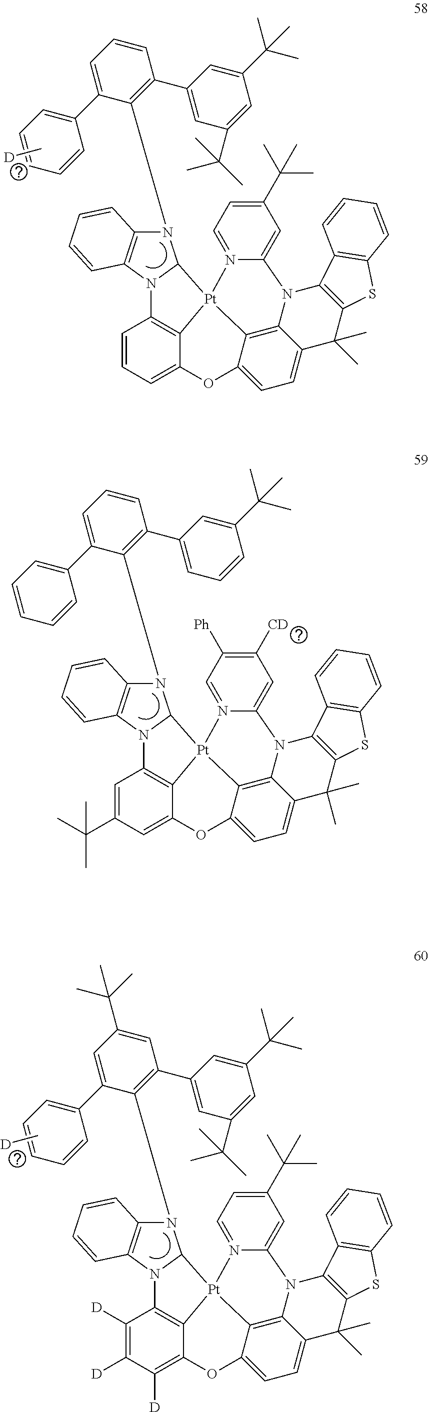

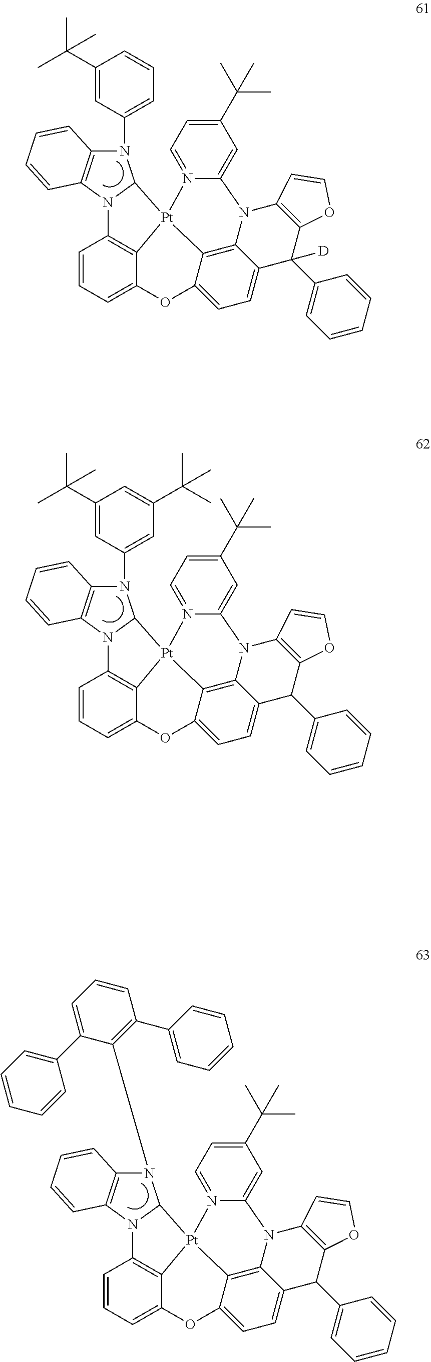

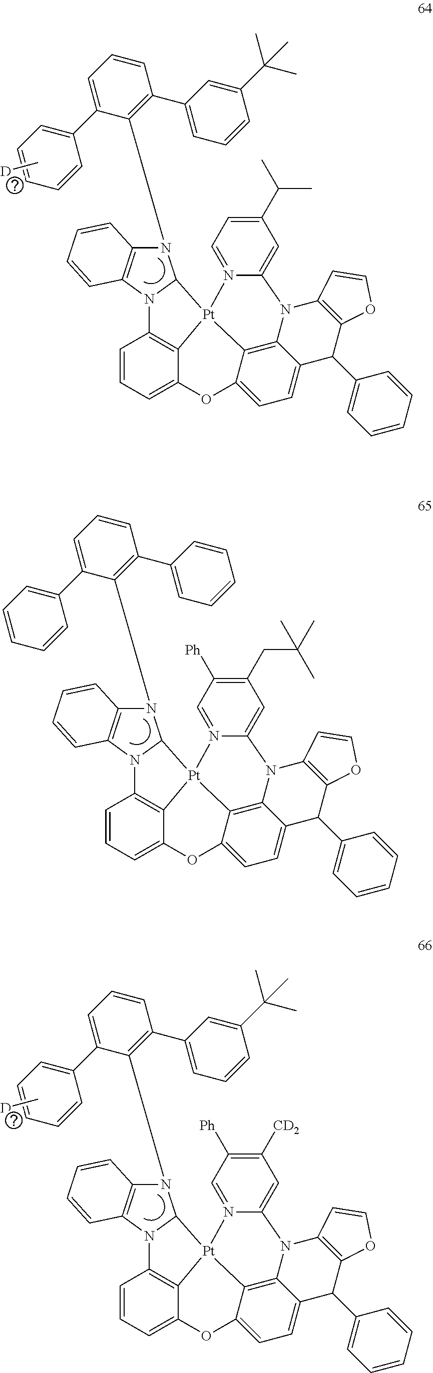

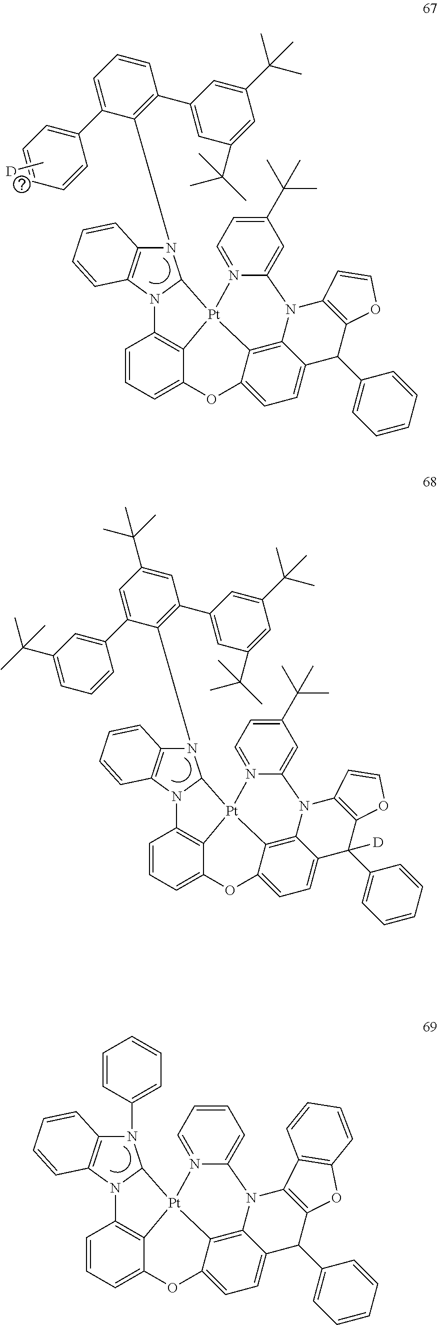

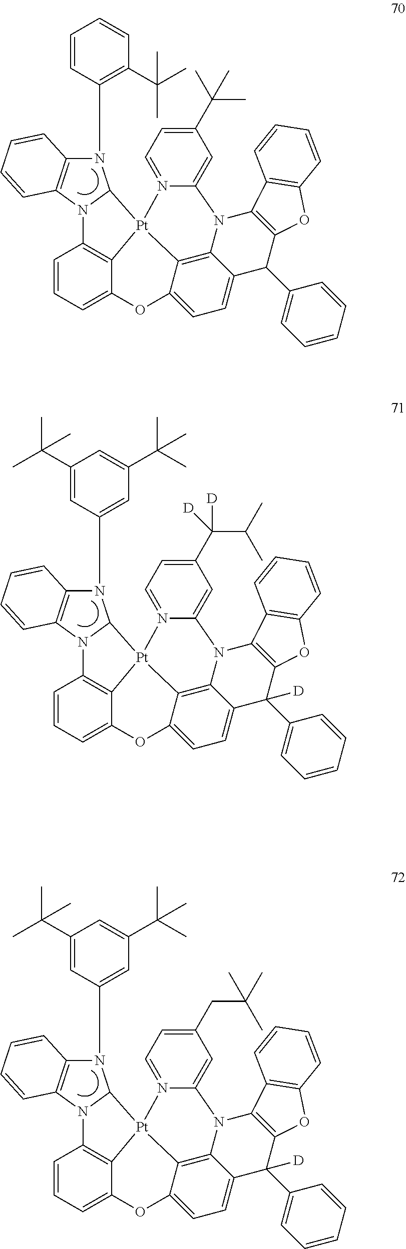

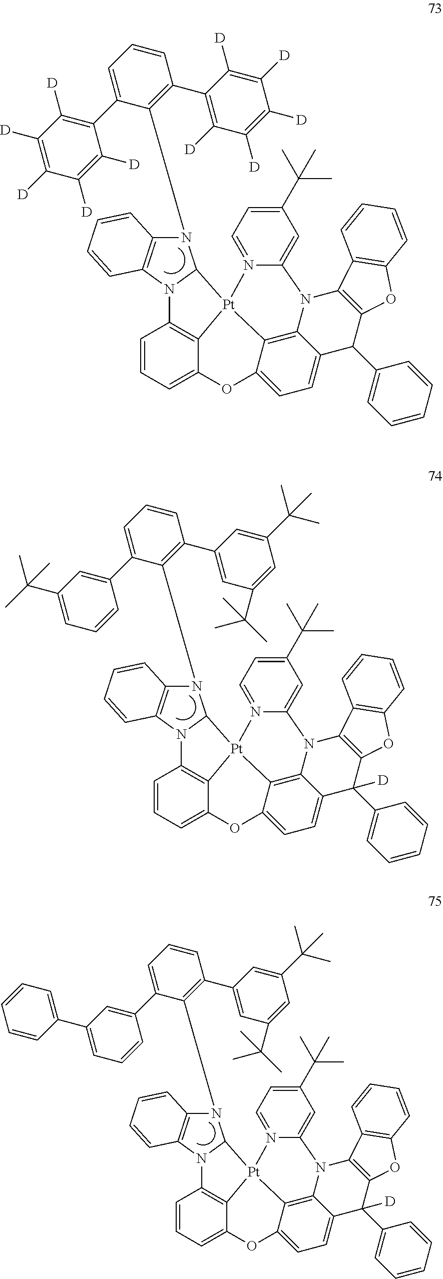

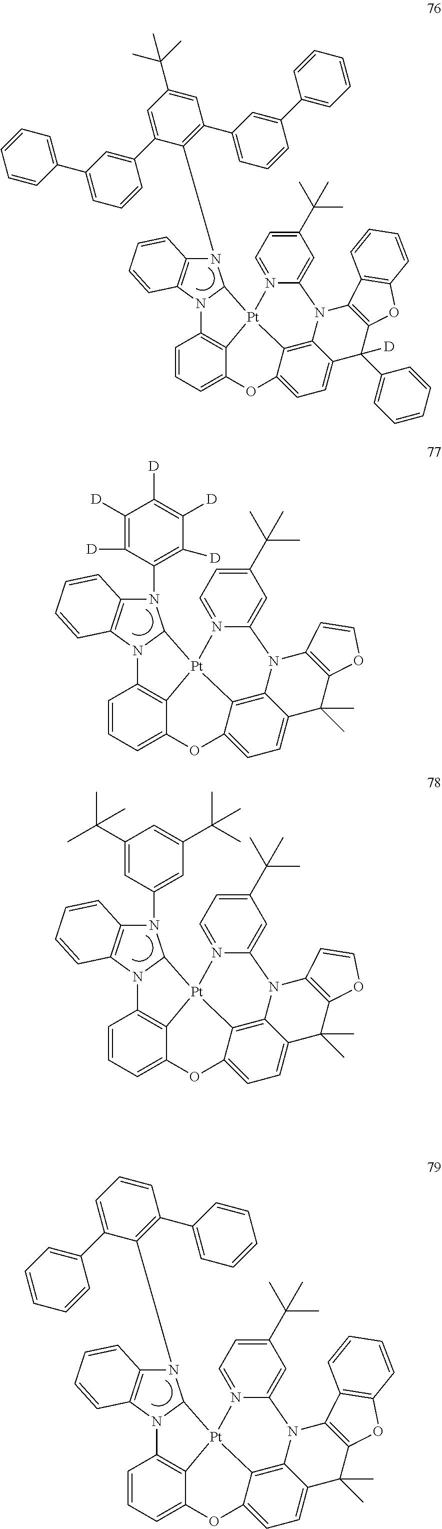

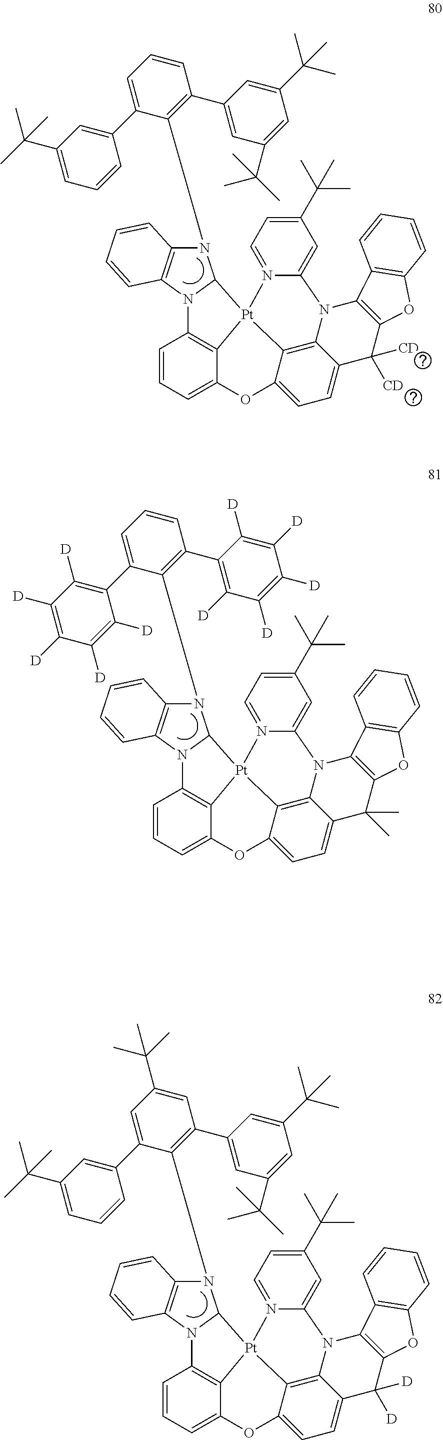

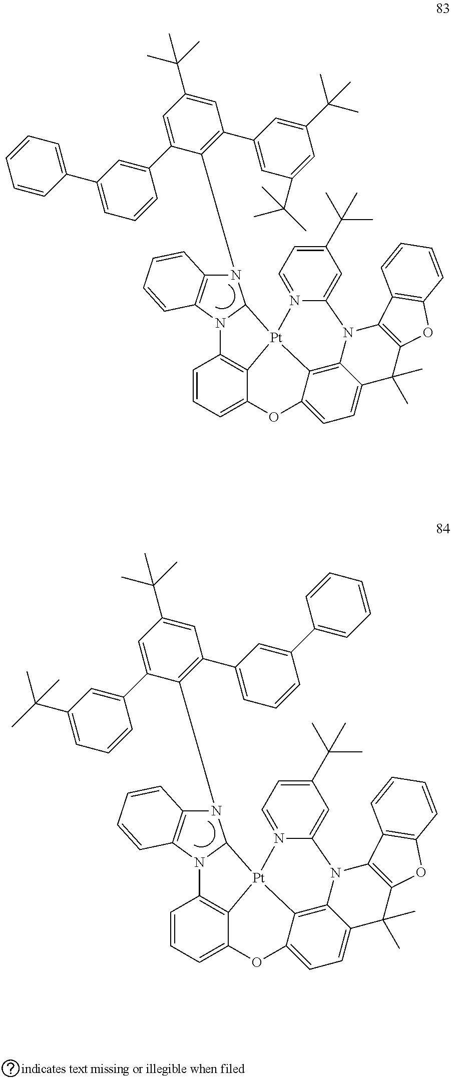

The organometallic compound of an embodiment includes a heteropolycyclic ring forming a 3- or 4-ring fused ring, and the heteropolycyclic ring has the structure of Formula A described above, may thus exhibit a deep HOMO energy level. For example, the organometallic compound of an embodiment may have a relatively lower HOMO energy level value than compounds having a polycyclic ring of a type (or kind) different from the heteropolycyclic ring having the structure of Formula A. For example, the organometallic compound in an embodiment may have a HOMO energy level of less than about −5.0 eV.

In addition, a light emitting element including the organometallic compound according to an embodiment may exhibit low driving voltage and high efficiency characteristics. In some embodiments, the light emitting element including the organometallic compound in an emission layer may emit blue light and also exhibit excellent light efficiency.

In the light emitting element according to an embodiment, the emission layer EML may include a host and a dopant, and the organometallic compound of an embodiment may be included in the emission layer EML as a dopant. In an embodiment, the emission layer EML may include a phosphorescent dopant, and the phosphorescent dopant may include the organometallic compound of an embodiment.

In some embodiments, the organometallic compound of an embodiment may emit light of phosphorescence (e.g., may emit light by way of phosphorescence).

The organometallic compound of an embodiment may emit blue light. For example, the organometallic compound of an embodiment may be a light emitting material having a central emission wavelength in a wavelength range of about 440 nm to about 470 nm. In some embodiments, the organometallic compound of an embodiment may be a light emitting material having a central emission wavelength in a wavelength range of about 445 nm to about 465 nm.

In an embodiment, the emission layer EML may include the organometallic compound of an embodiment, and include at least one of the second to fourth compounds.

In an embodiment, the emission layer EML may further include a second compound represented by Formula HT-1 below. For example, the second compound may be used as a hole transporting host material of the emission layer EML.

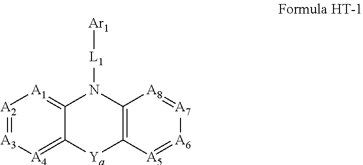

In Formula HT-1, A₁ to A₈ may each independently be N or CR₅₁. For example, A₁ to A₈ may all be CR₅₁. In some embodiments, any one of A₁ to A₈ may be N, and the others may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments of the present disclosure are not limited thereto.

In Formula HT-1, Yₐ may be a direct linkage, CR₅₂R₅₃, or SiR₅₄R₅₅. That is, two benzene rings connected to nitrogen atoms of Formula HT-1 may be connected through a direct linkage,

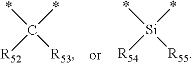

In Formula HT-1, when Yₐ is a direct linkage, the second compound represented by Formula HT-1 may include a carbazole moiety.

In Formula HT-1, Ar₁ is a substituted or unsubstituted aryl group having 6 to ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, or a substituted or unsubstituted biphenyl group, but embodiments of the present disclosure are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms. In some embodiments, R₅₁ to R₅₅ may each be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In an embodiment, the second compound represented by Formula HT-1 may be represented by any one among the compounds shown in Compound Group 2 below. The emission layer EML may include at least one of the compounds shown in Compound Group 2 below, as an electron transporting host material.

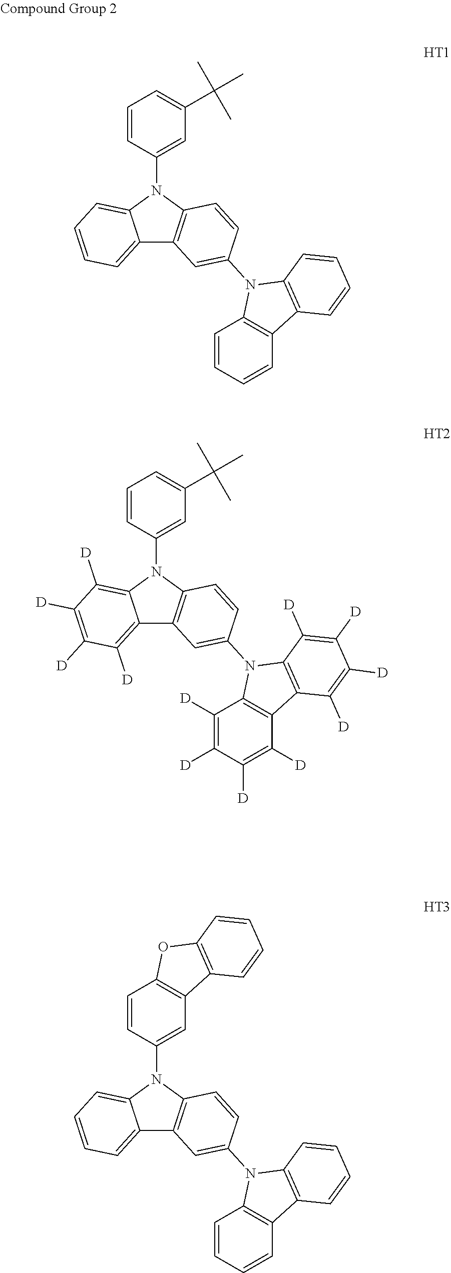 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

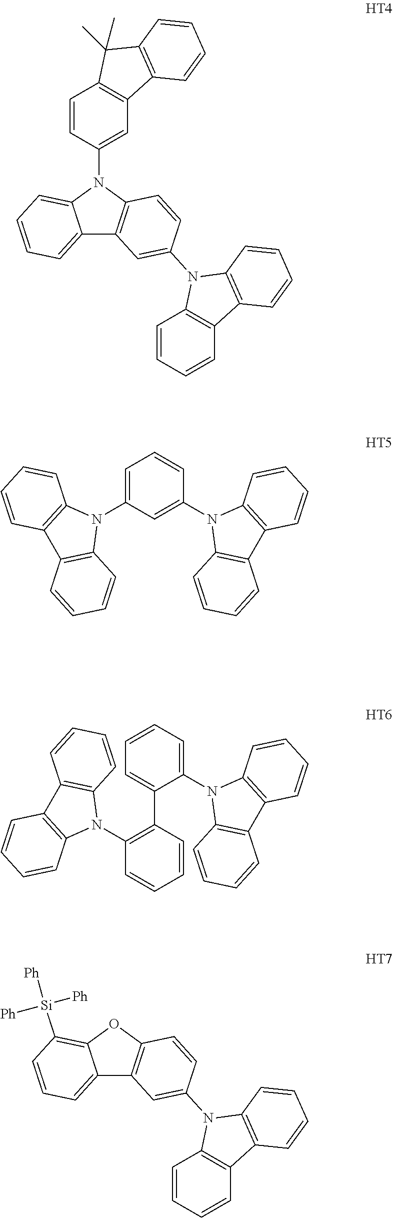 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

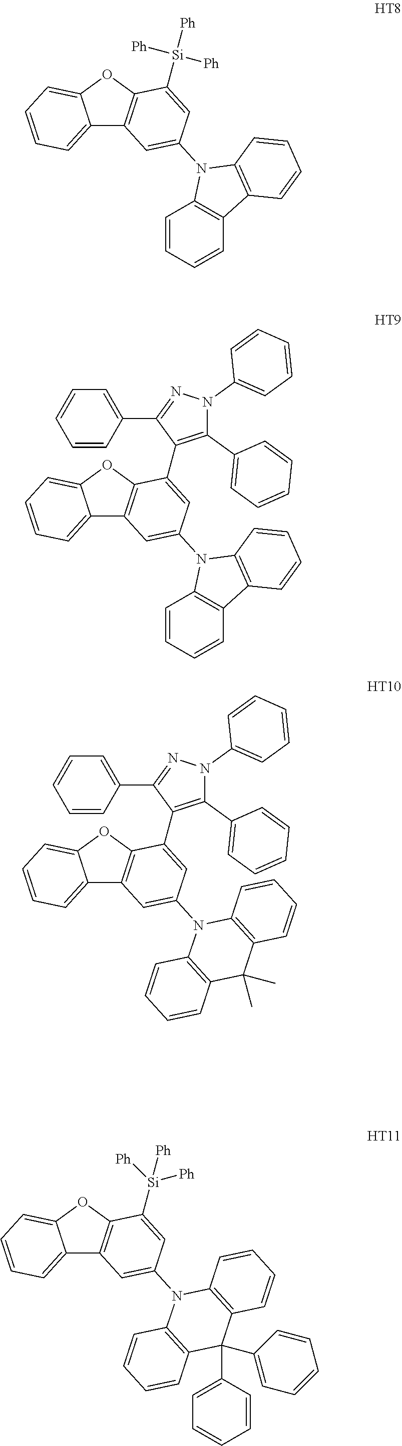 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

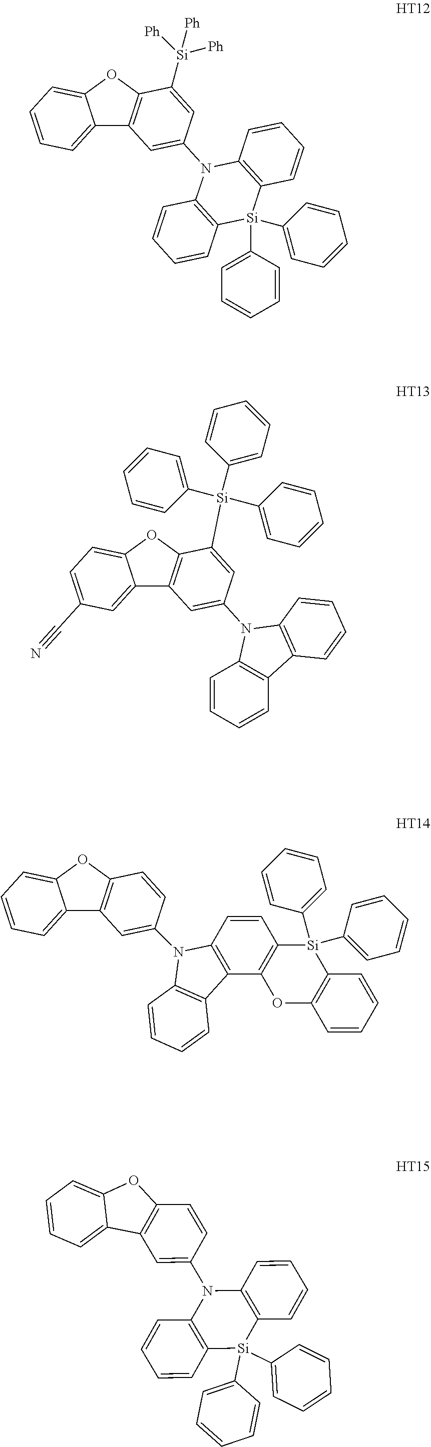 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

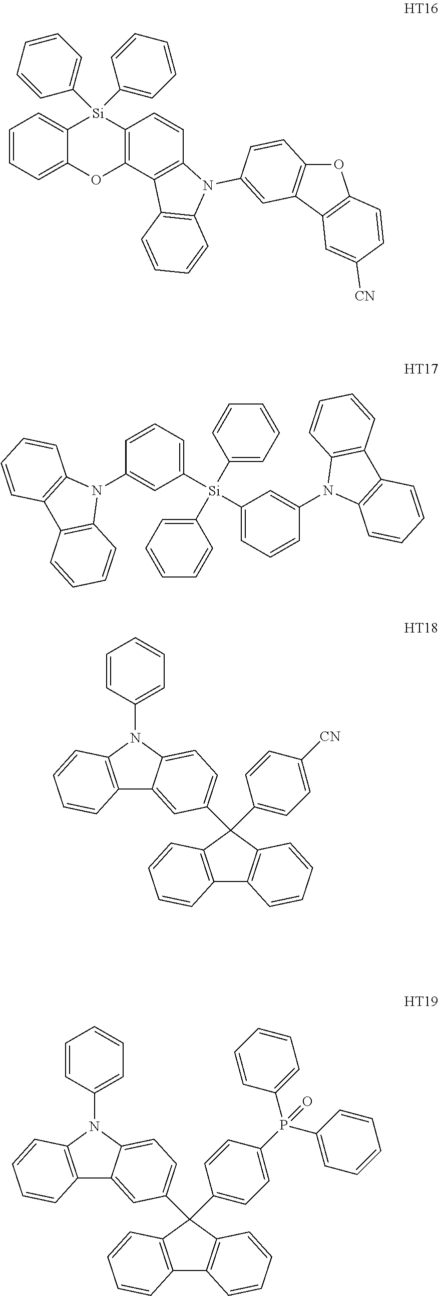 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

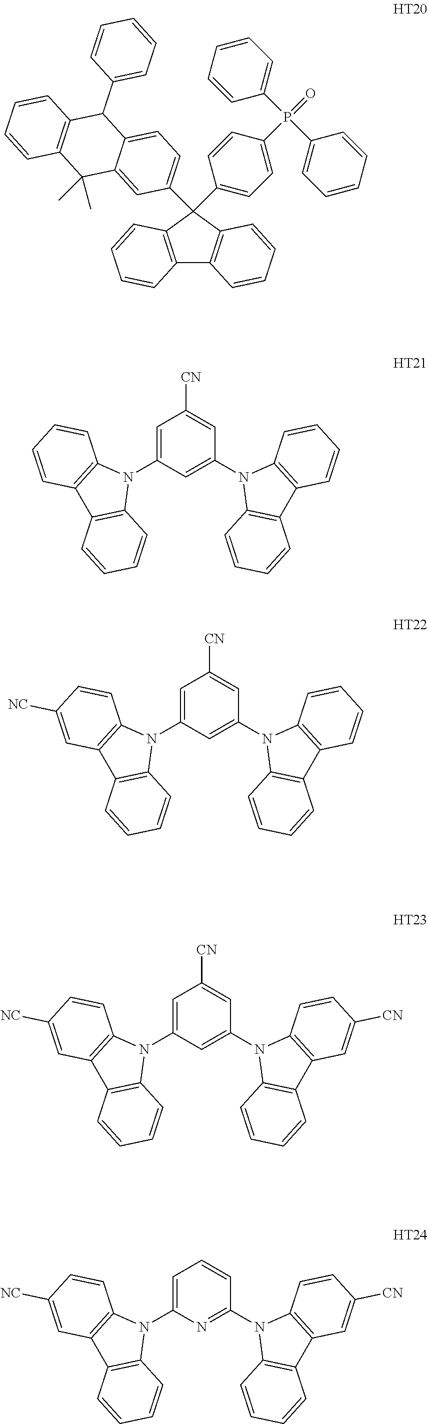 [SMILES: CC1(C)c2ccccc2C(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

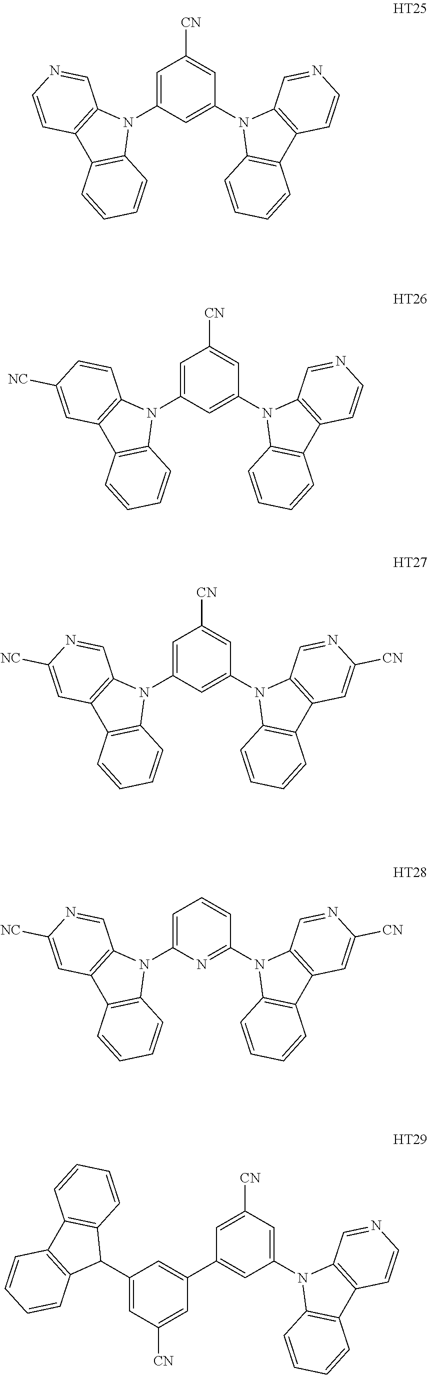

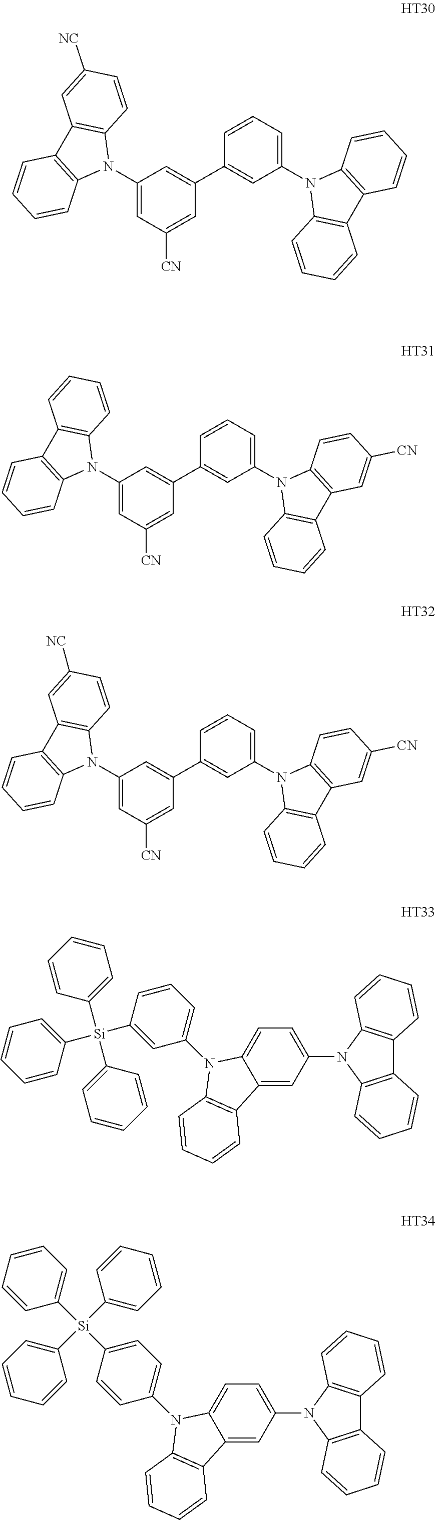

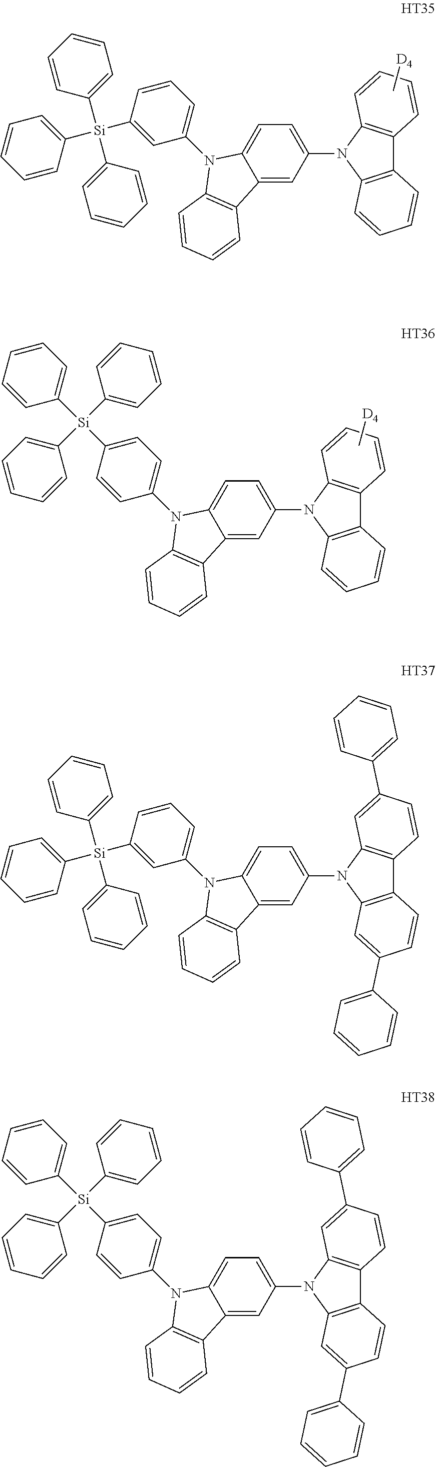

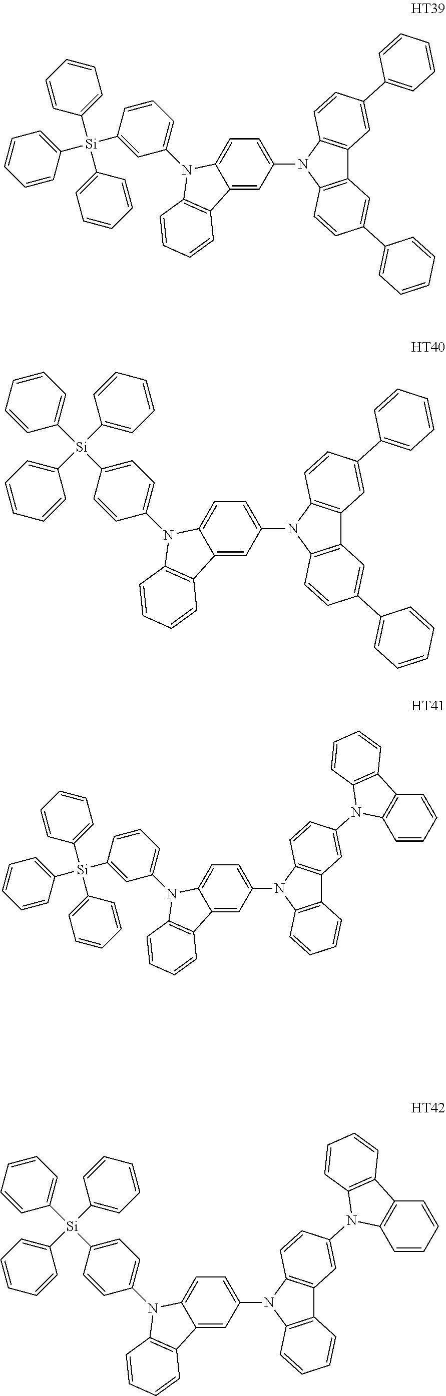 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

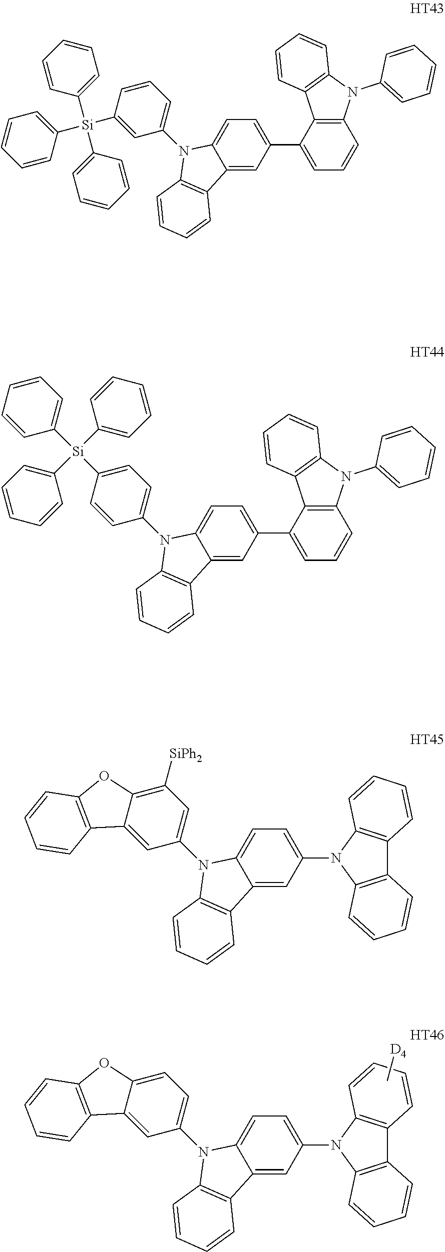

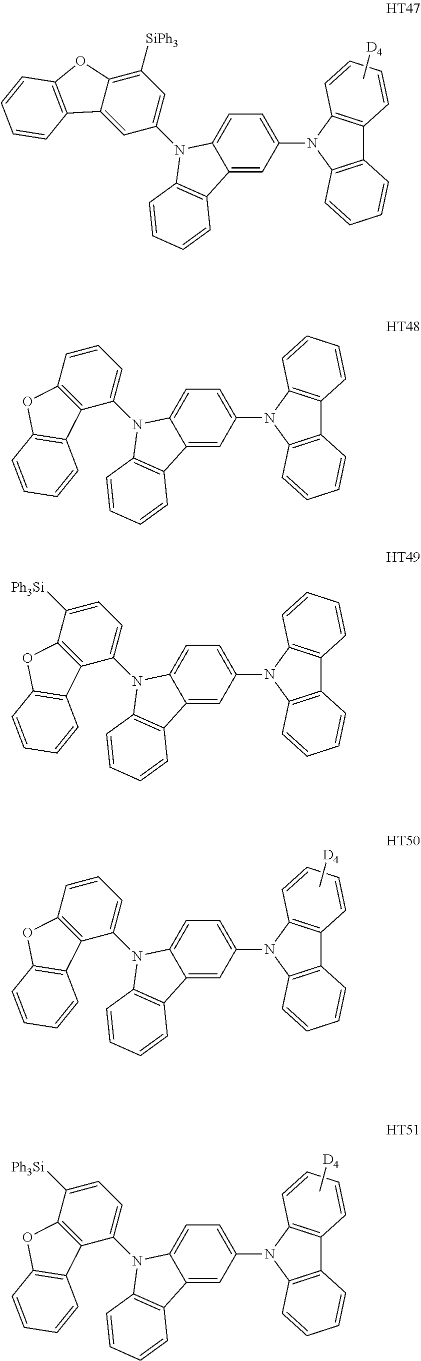

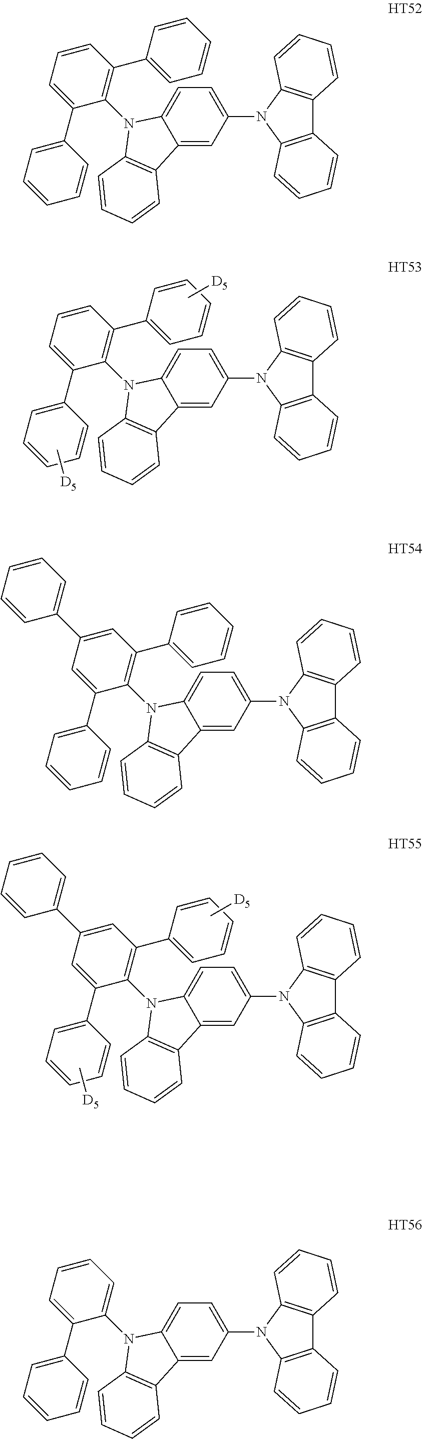

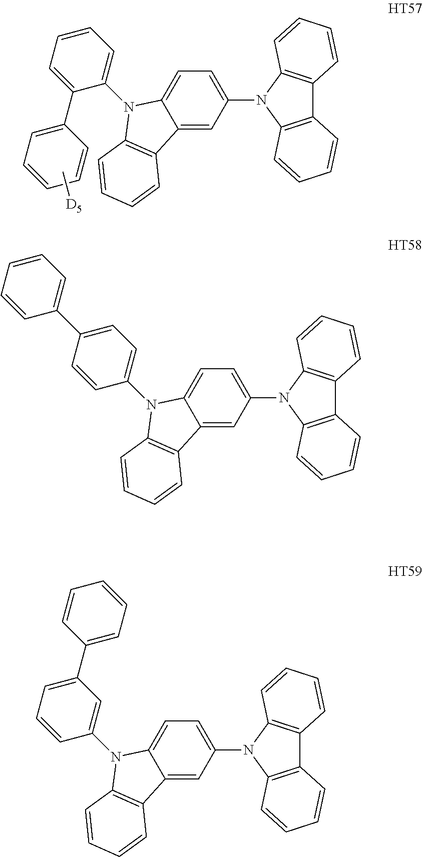

In the example compounds presented in Compound Group 2, “D” may indicate a deuterium atom, and “Ph” may indicate a substituted or unsubstituted phenyl group. For example, in the example compounds presented in Compound Group 2, “Ph” may be an unsubstituted phenyl group.

In an embodiment, the emission layer EML may further include a third compound represented by Formula ET-1 below. For example, the third compound may be used as an electron transporting host material of the emission layer EML.

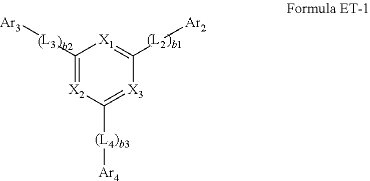

In Formula ET-1, at least one of X₁ to X₃ may be N and the others may be CR₅₆. For example, any one of X₁ to X₃ may be N, and the other two may each independently be CR₅₆. In this case, the third compound represented by Formula ET-1 may include a pyridine moiety. In some embodiments, two of X₁ to X₃ may be N and the other one may be CR₅₆. In this case, the third compound represented by Formula ET-1 may include a pyrimidine moiety. In some embodiments, X₁ to X₃ may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are an integer of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In an embodiment, the third compound may be represented by any one among the compounds of Compound Group 3 below. The light emitting element ED according to an embodiment may include any one among compounds of Compound Group 3 below.

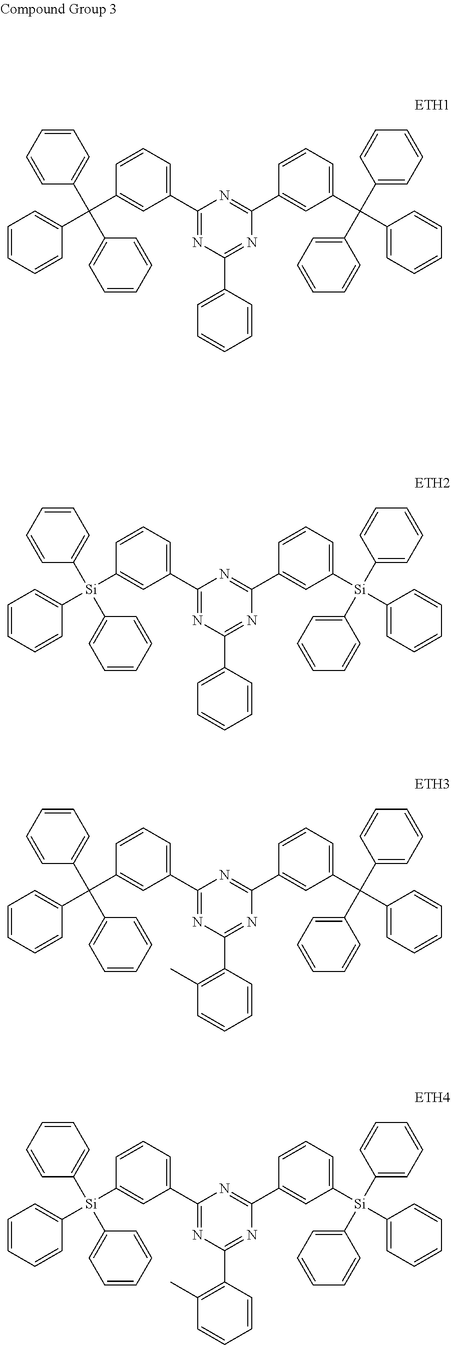 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

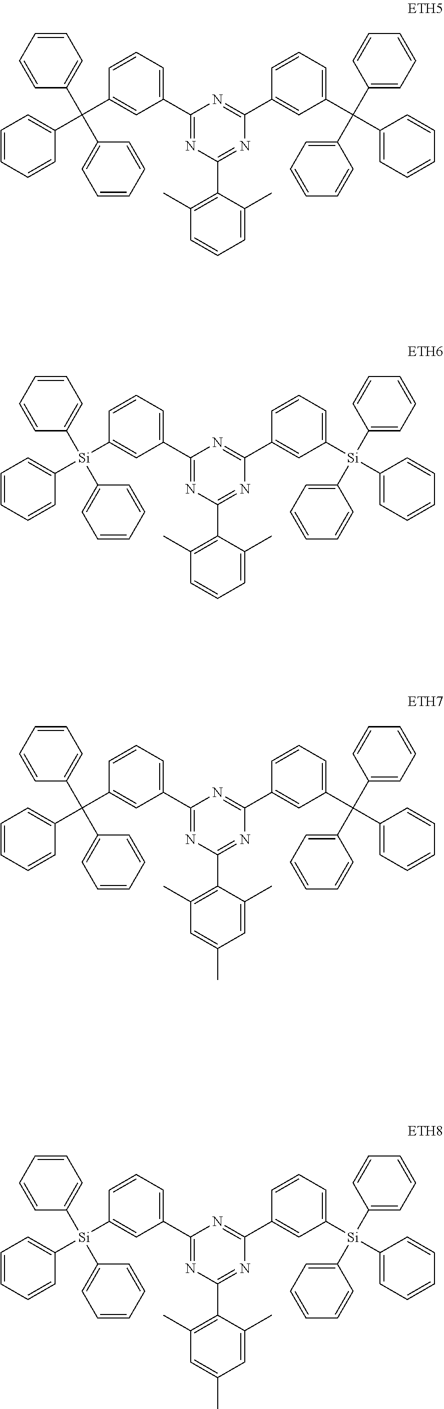 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

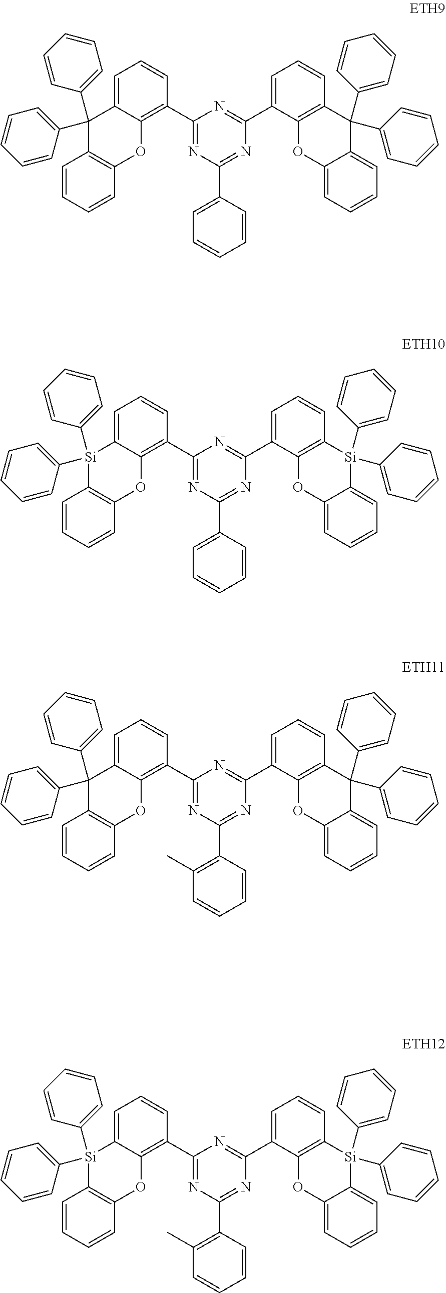 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

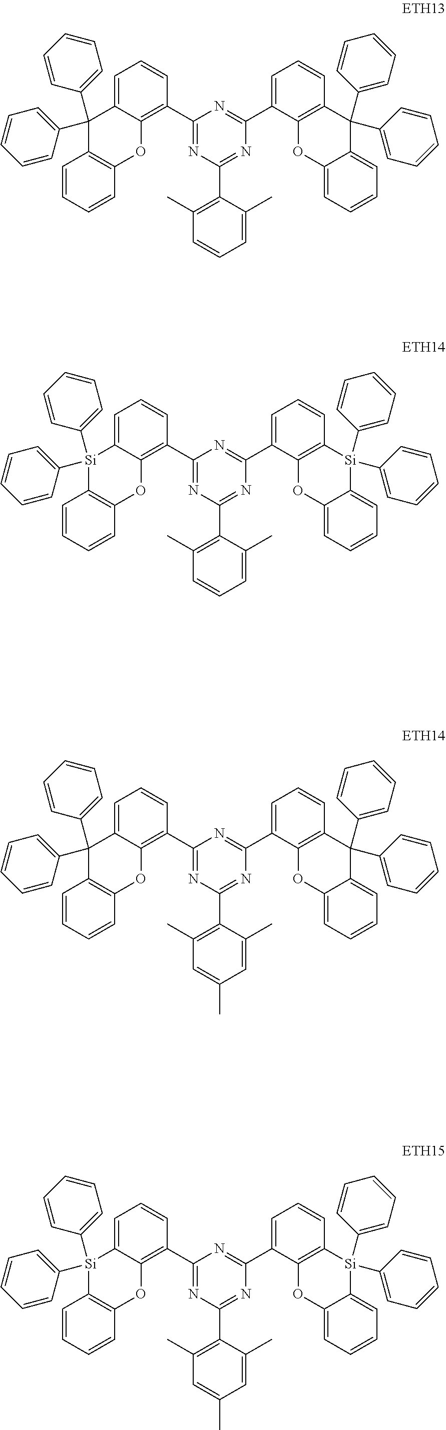 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

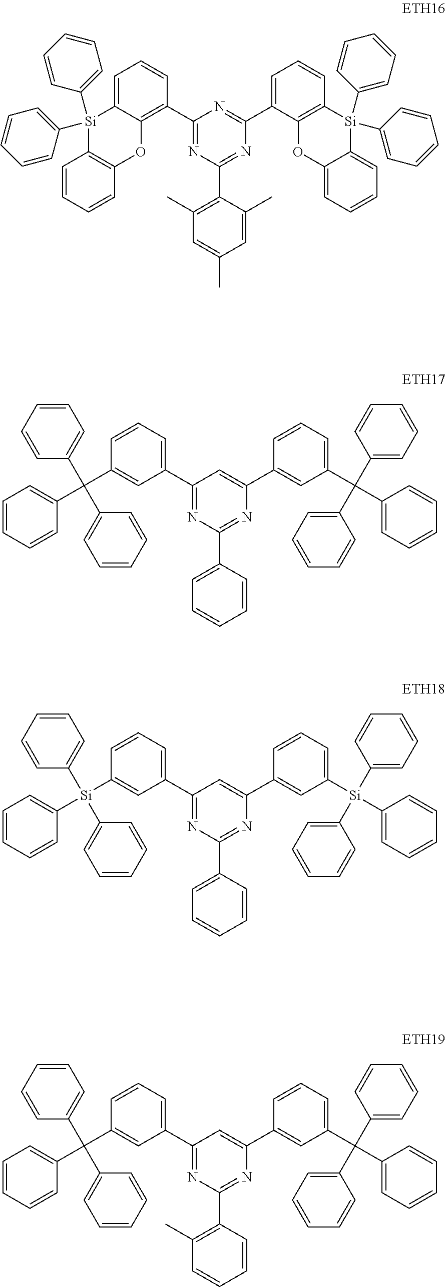 [SMILES: Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1]

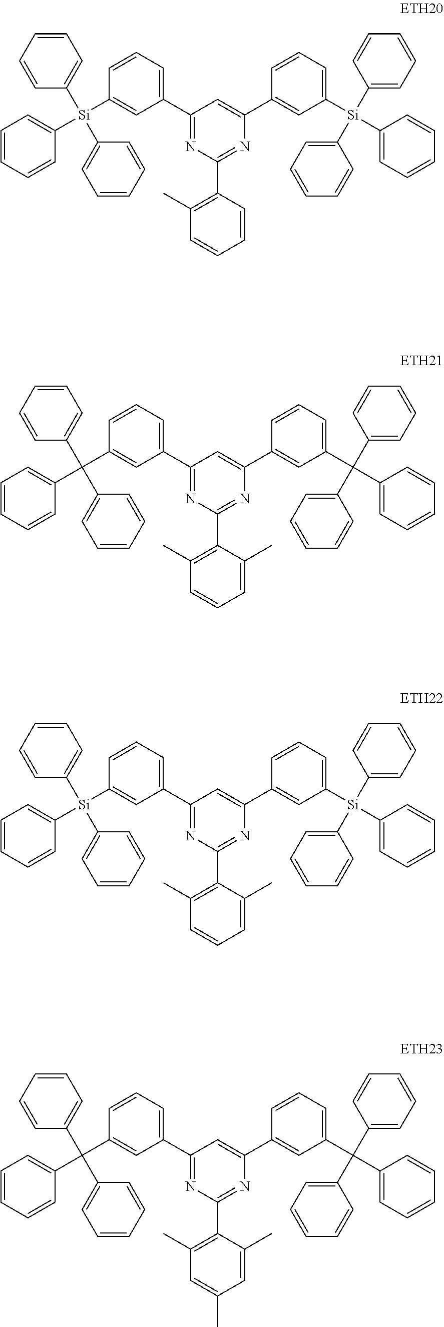 [SMILES: Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1]

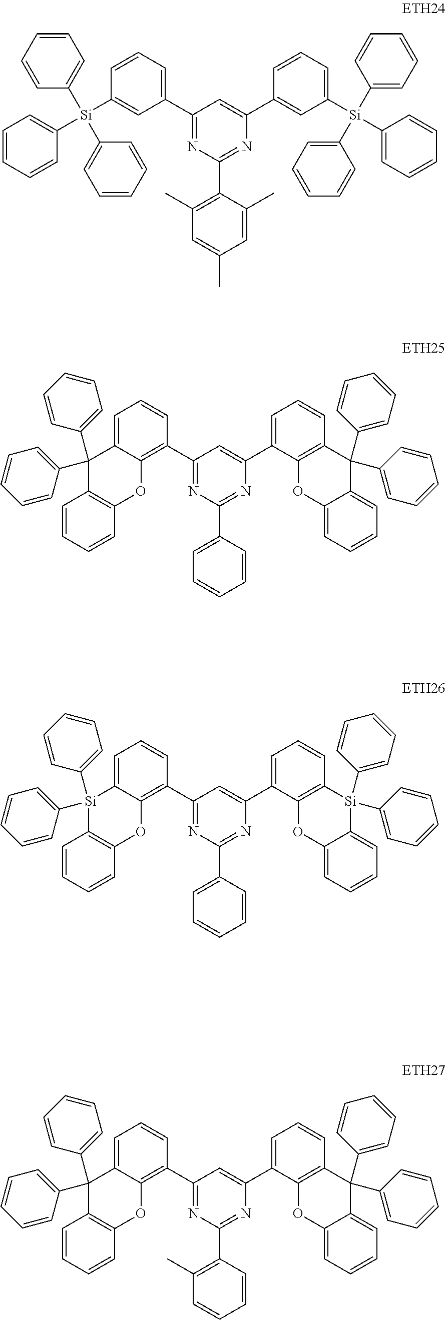 [SMILES: Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1]

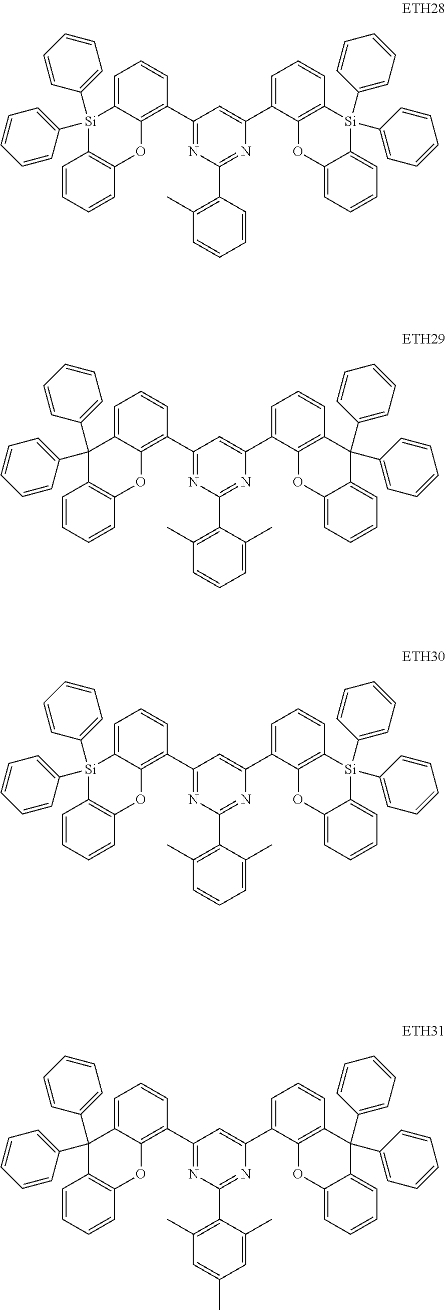 [SMILES: Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1]

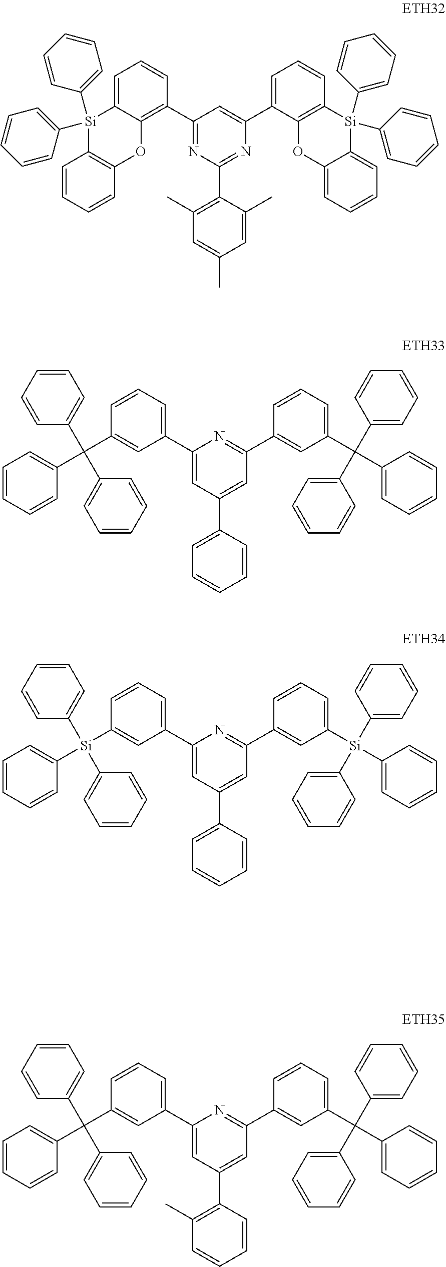 [SMILES: Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1 ; c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1]

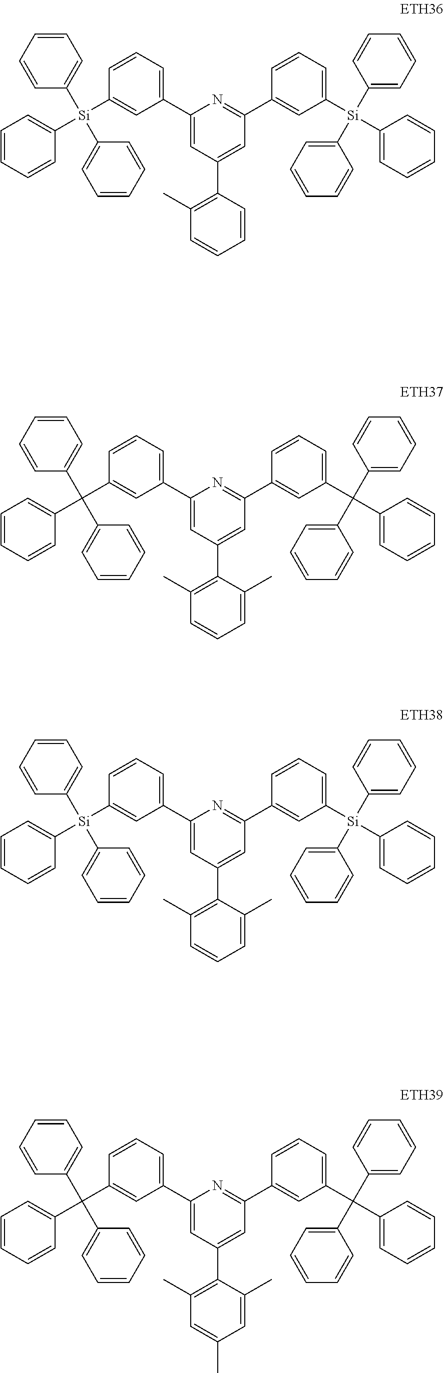 [SMILES: Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1]

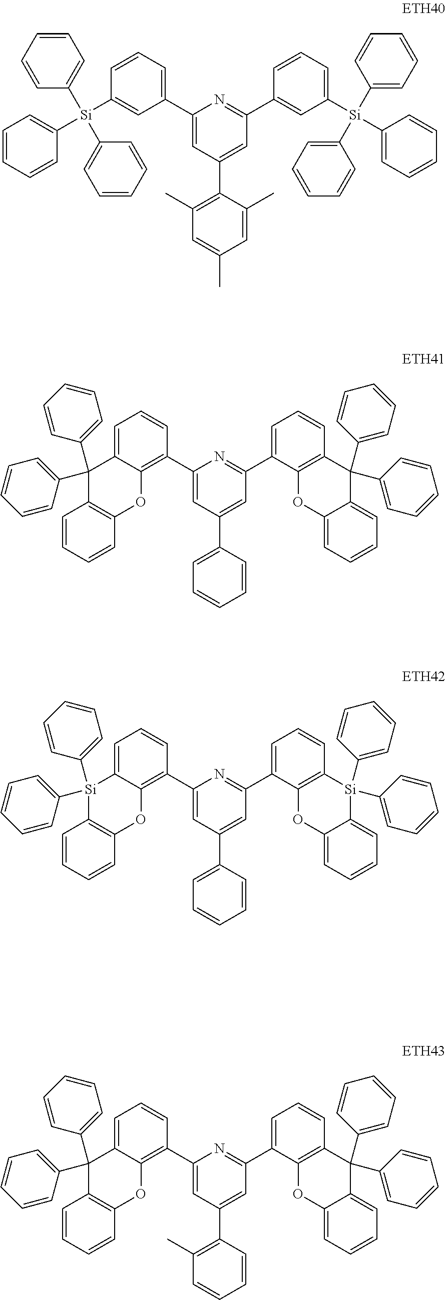 [SMILES: Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1]

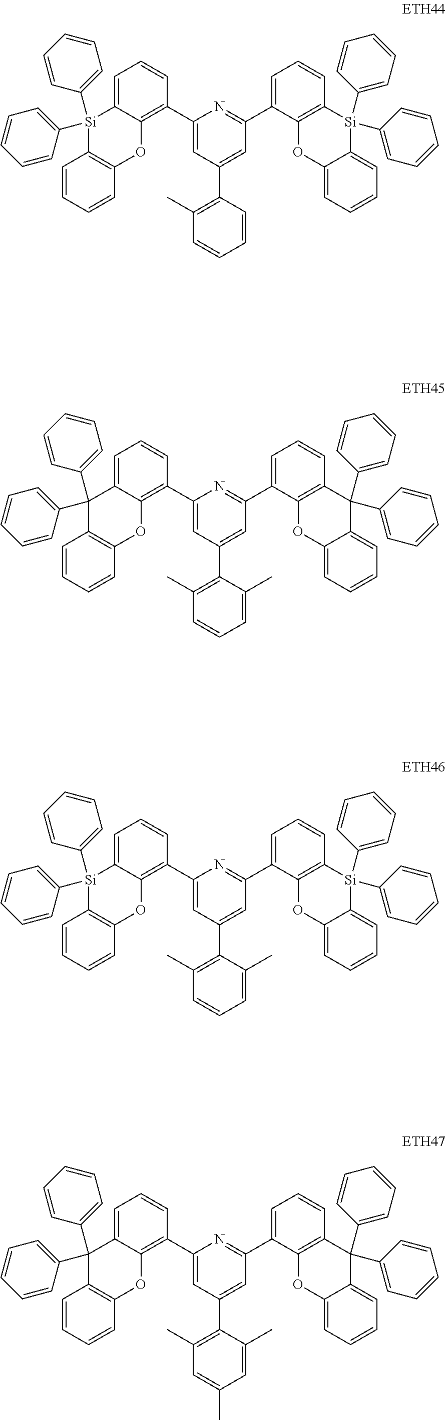 [SMILES: Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1]

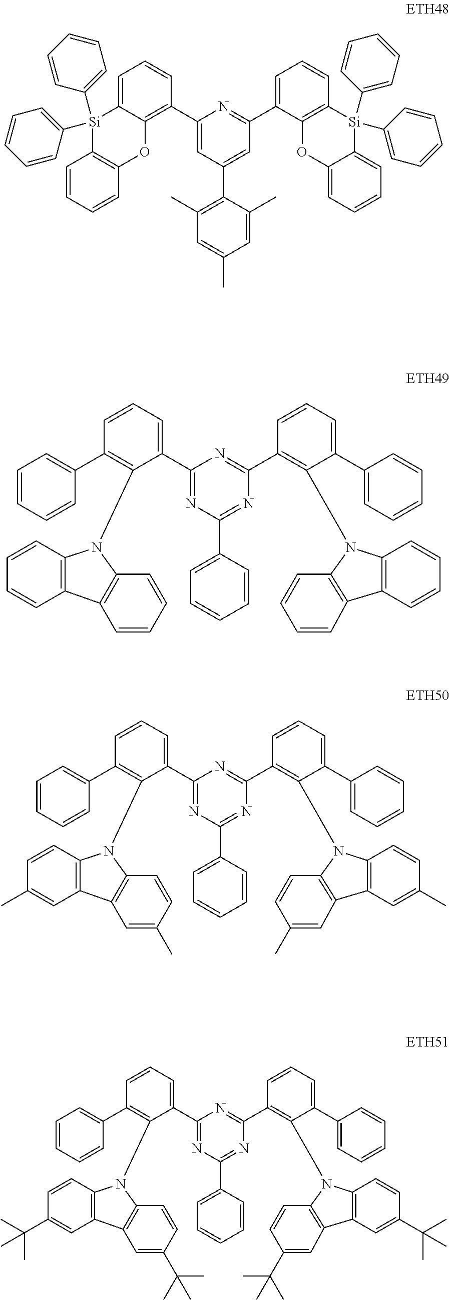

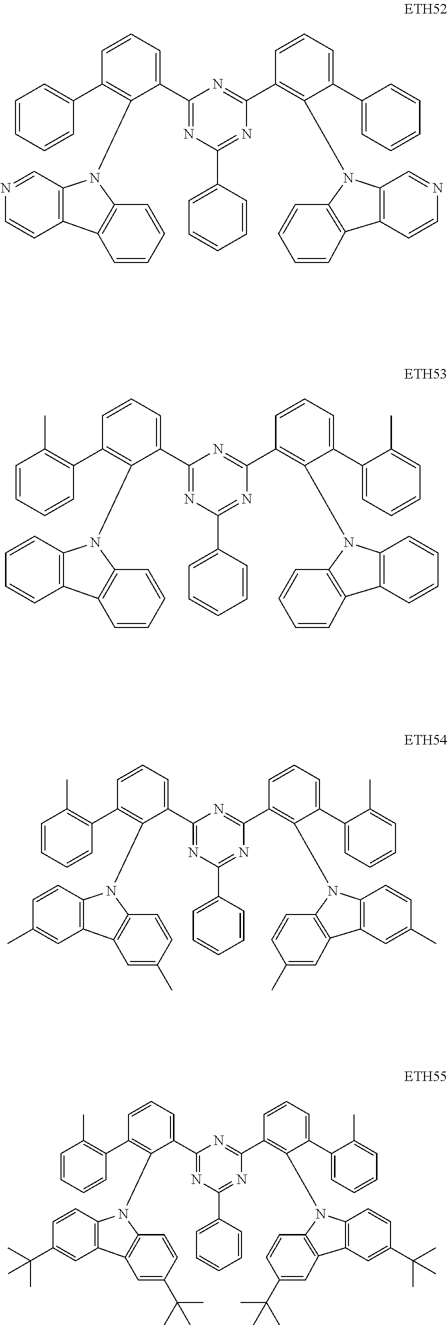

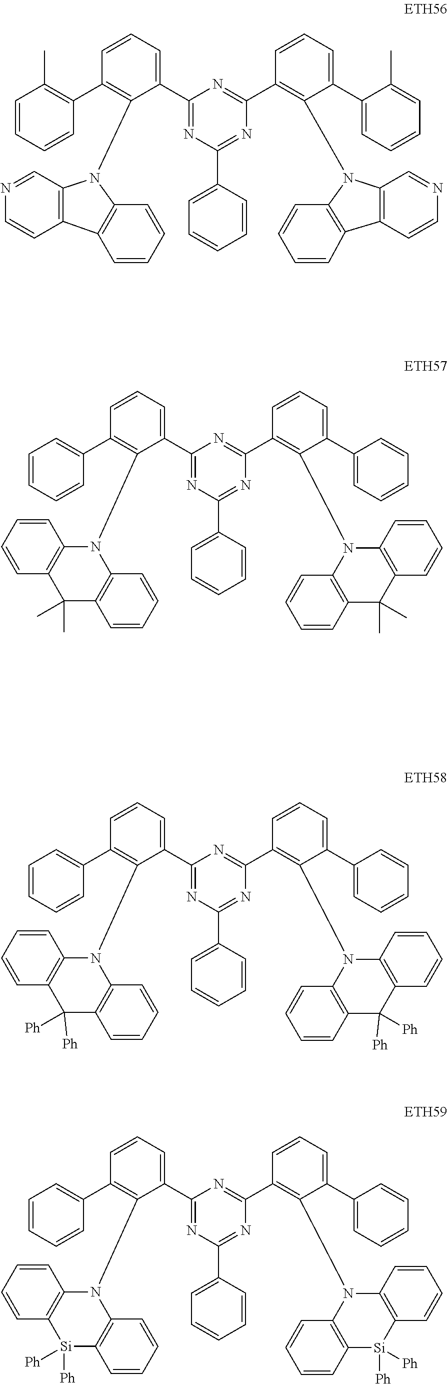

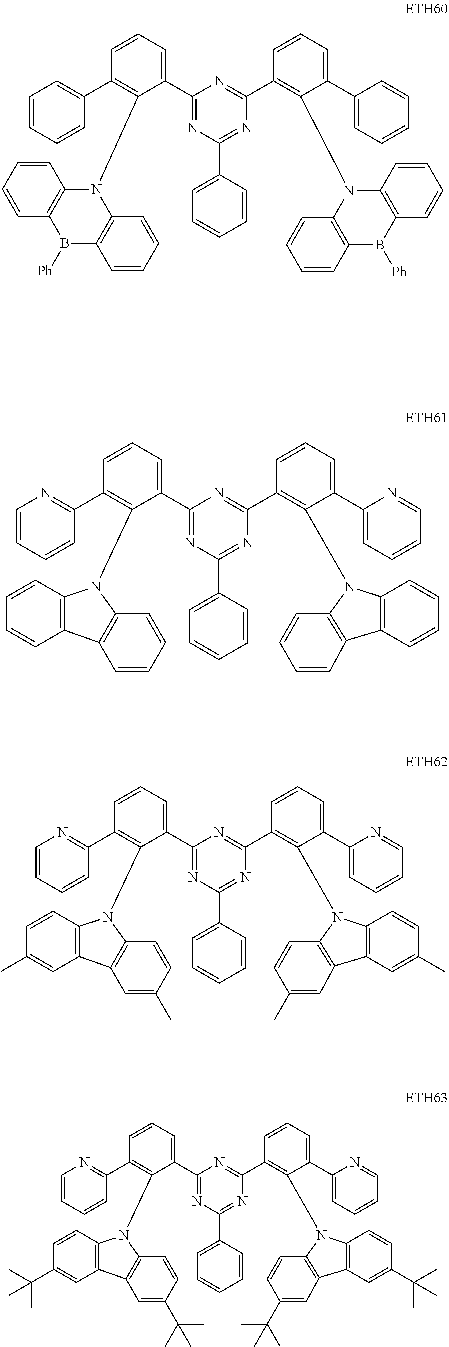

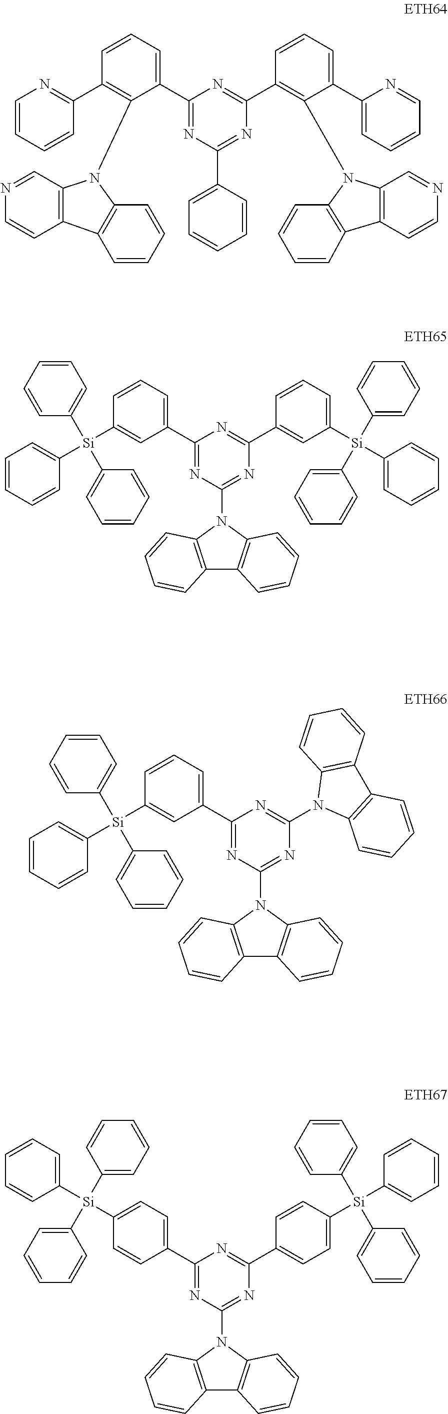 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

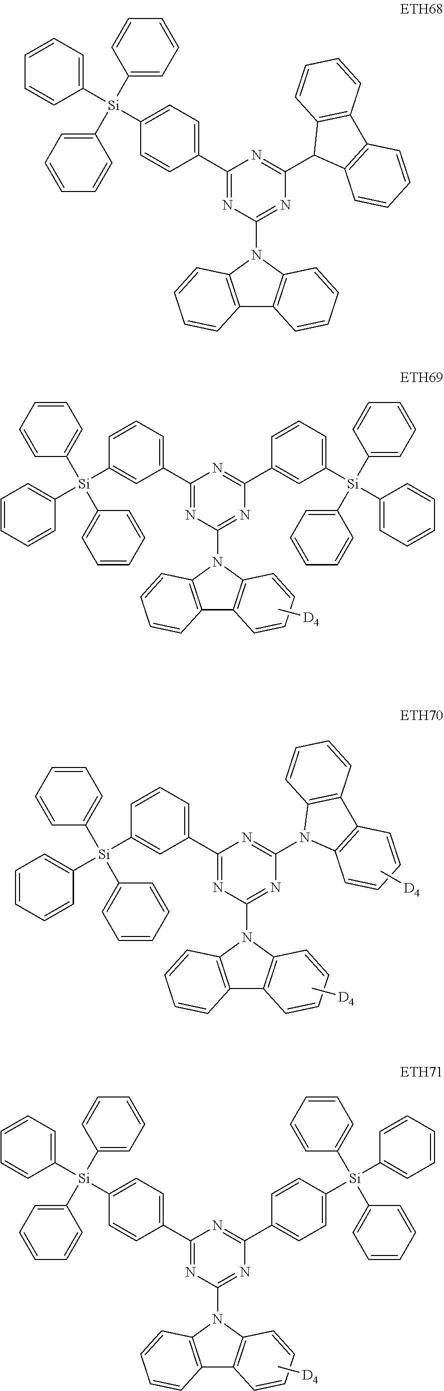

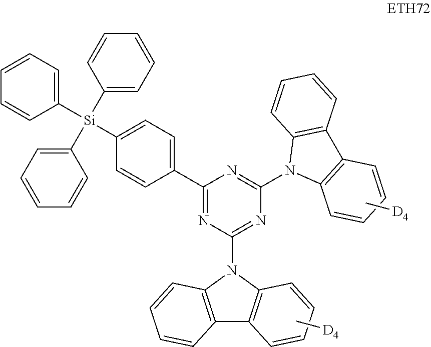

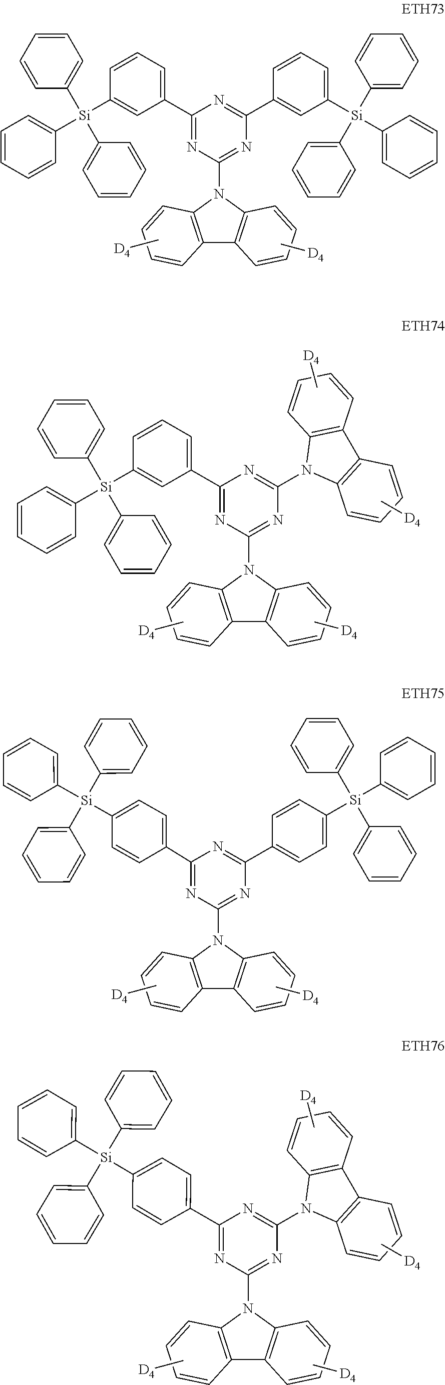

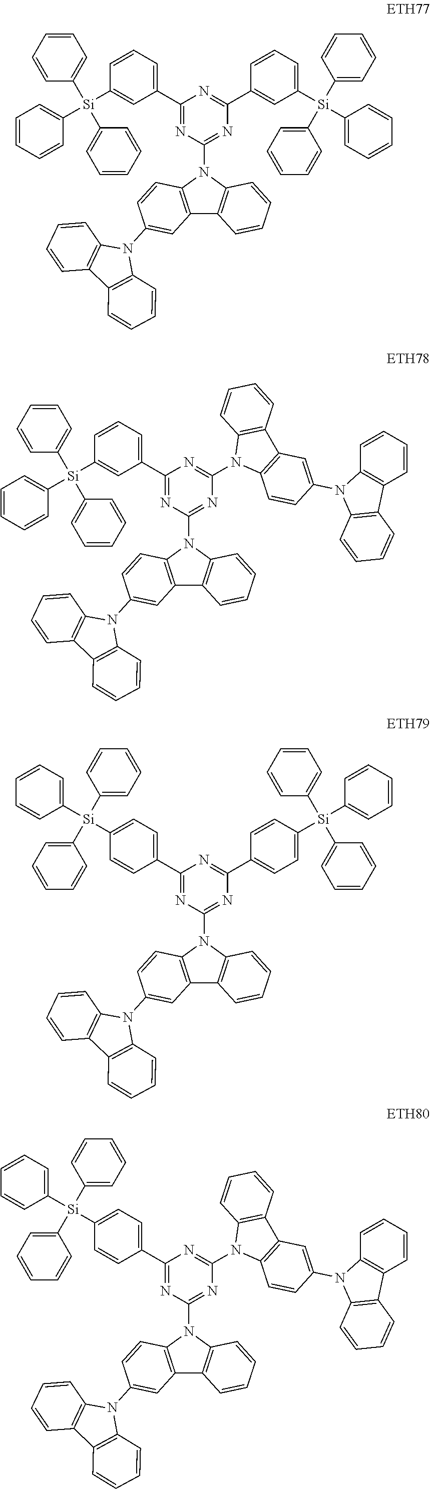

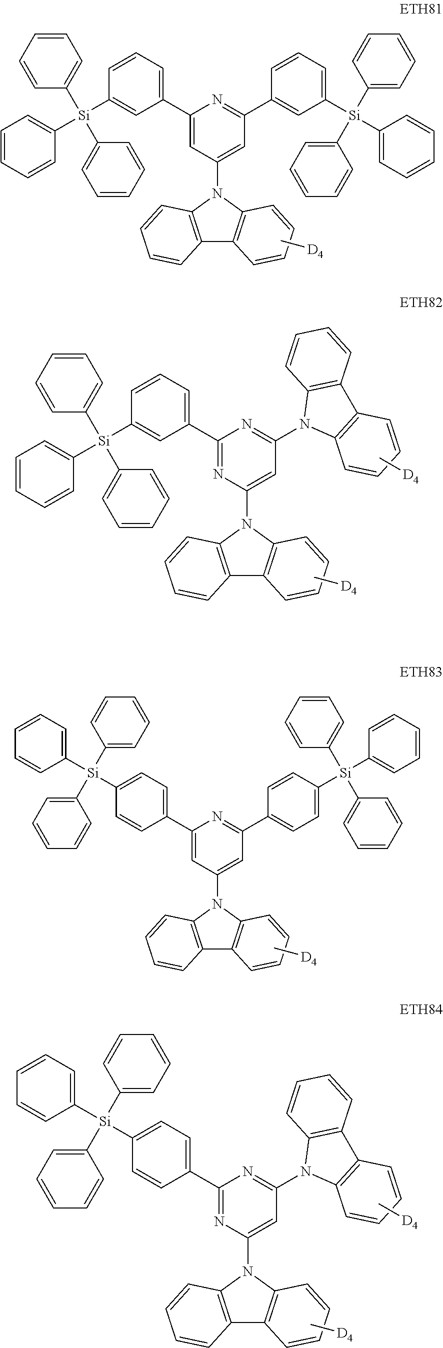

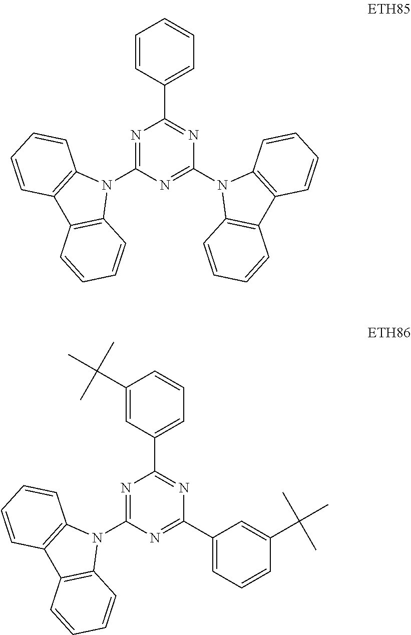 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In the example compounds presented in Compound Group 3, “D” indicates a deuterium atom, and “Ph” indicates an unsubstituted phenyl group.

The emission layer EML may include the second compound and the third compound in addition to the first compound, and the second compound and the third compound may form an exciplex. In the emission layer EML, the hole transporting host and the electron transporting host may form an exciplex. In this case, the triplet energy of the exciplex formed by the hole transporting host and the electron transporting host corresponds to a difference between Lowest Unoccupied Molecular Orbital (LUMO) energy level of the electron transporting host and Highest Occupied Molecular Orbital (HOMO) energy level of the hole transporting host.

For example, the triplet energy level (T1) of the exciplex formed by the hole transporting host and the electron transporting host may have an absolute value of about 2.4 eV to about 3.0 eV. In addition, the triplet energy of the exciplex may have a value smaller than the energy gap of each host material. The exciplex may have a triplet energy of 3.0 eV or less, which is an energy gap between the hole transporting host and the electron transporting host.

In an embodiment, the emission layer EML may further include a fourth compound represented by Formula F-1 below.

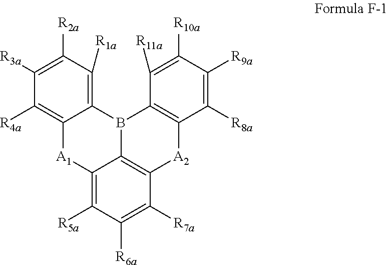

In Formula F-1, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ₐ to R₁₁ₐ are each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-1, A₁ and A₂ may each independently be bonded to substituents of neighboring rings to form a fused ring. For example, when A₁ and A₂ are each independently NRₘ, A₁ may be bonded to R₄ₐ or R₅ₐ to form a ring. In addition, A₂ may be bonded to R₇ₐ or R₈ₐ to form a ring.

For example, the fourth compound represented by Formula F-1 may be included as a dopant in the emission layer EML. In an embodiment, the fourth compound represented by Formula F-1 may be a thermally activated delayed fluorescent dopant.

The fourth compound may be represented by any one among compounds of Compound Group 4 below.

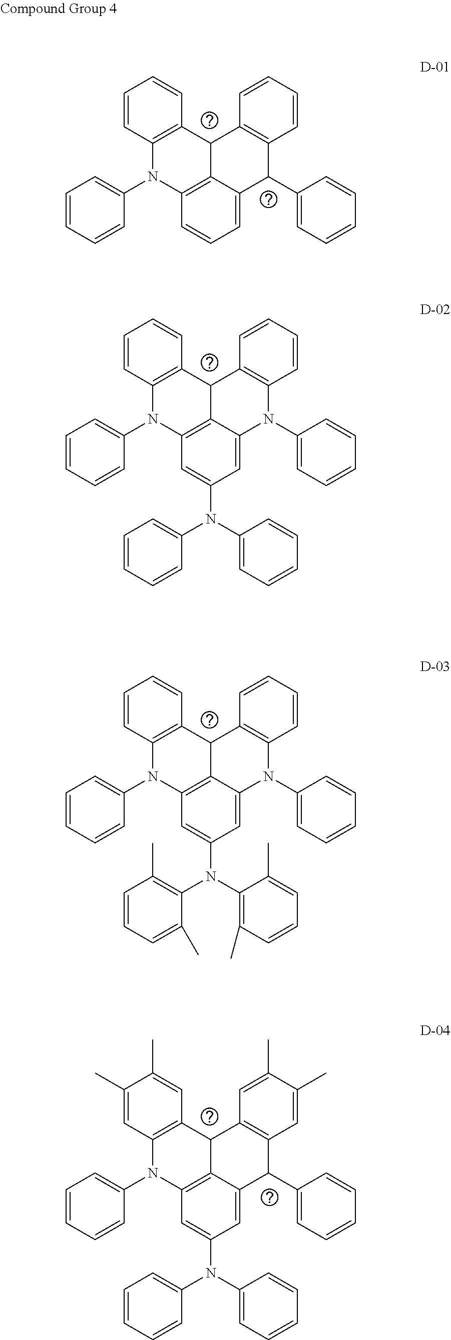 [SMILES: c1ccc(C2c3ccccc3C3c4ccccc4N(c4ccccc4)c4cccc2c43)cc1 ; c1ccc(N(c2ccccc2)c2cc3c4c(c2)N(c2ccccc2)c2ccccc2C4c2ccccc2N3c2ccccc2)cc1 ; Cc1cccc(C)c1N(c1cc2c3c(c1)N(c1ccccc1)c1ccccc1C3c1ccccc1N2c1ccccc1)c1c(C)cccc1C ; Cc1cc2c(cc1C)C1c3cc(C)c(C)cc3N(c3ccccc3)c3cc(N(c4ccccc4)c4ccccc4)cc(c31)C2c1ccccc1]

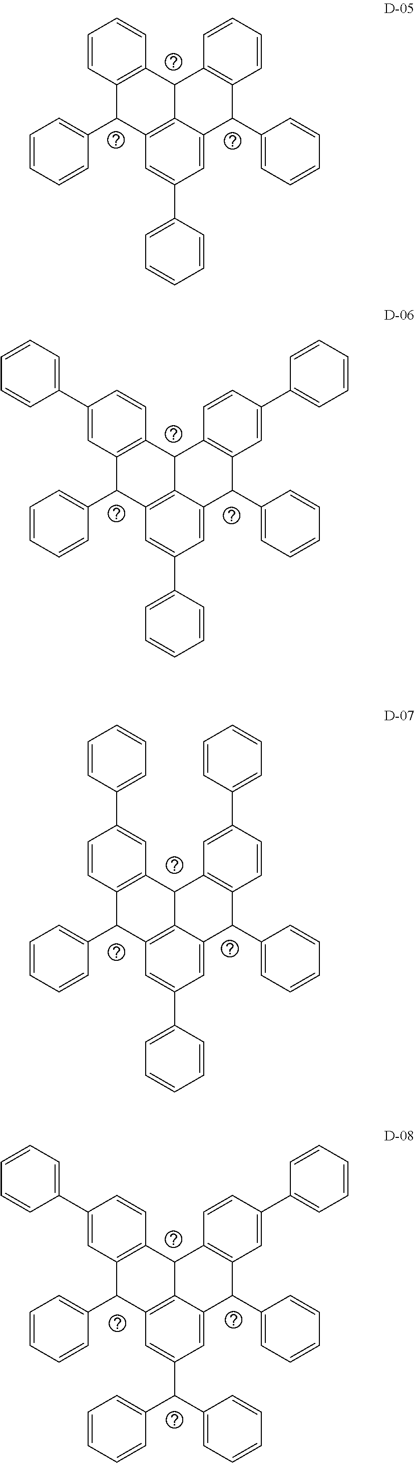

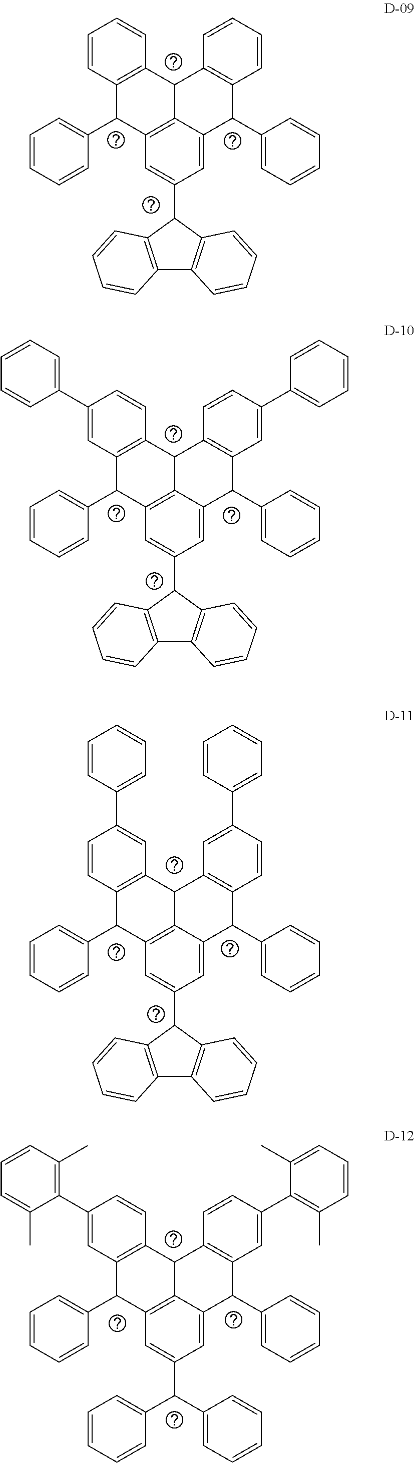

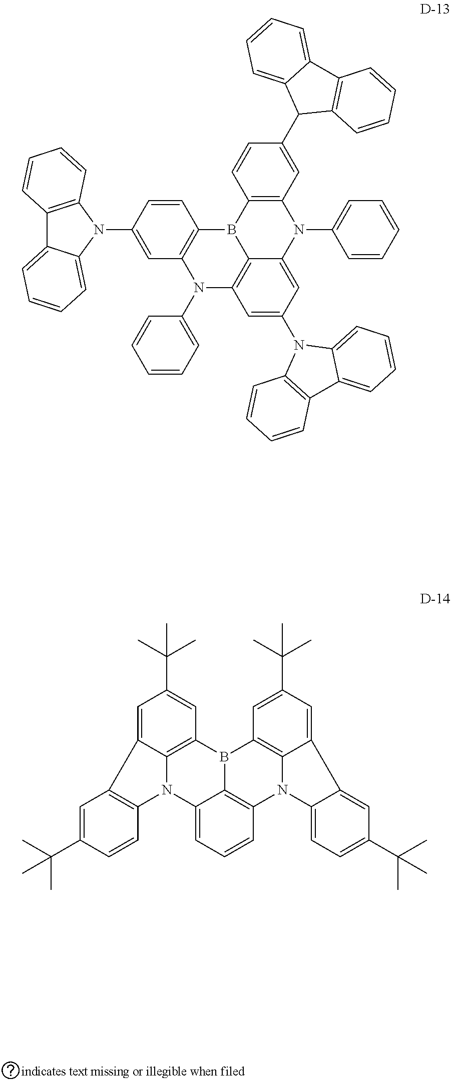 [SMILES: c1ccc(N2c3cc(C4c5ccccc5-c5ccccc54)ccc3B3c4ccc(-n5c6ccccc6c6ccccc65)cc4N(c4ccccc4)c4cc(-n5c6ccccc6c6ccccc65)cc2c43)cc1 ; CC(C)(C)c1ccc2c(c1)c1cc(C(C)(C)C)cc3c1n2-c1cccc2c1B3c1cc(C(C)(C)C)cc3c4cc(C(C)(C)C)ccc4n-2c13]

In some embodiments, when the emission layer EML includes the second to fourth compounds in addition to the first compound, the first compound, which is the organometallic compound of an embodiment, may be used as a phosphorescence sensitizer.

In an embodiment, the emission layer EML may include the first compound, which is the organometallic compound according to an embodiment, and at least one among the second to fourth compounds. For example, the light emitting element ED of an embodiment may include all of a first compound, a second compound, a third compound, and a fourth compound, and the emission layer EML may thus include a combination of two host materials and two dopant materials. In the light emitting element ED of an embodiment, the emission layer EML include the second compound and the third compound that are two different hosts, the fourth compound emitting delayed fluorescence, and the first compound, which is an organometallic complex, and may thus exhibit excellent light emitting efficiency.

For example, in the emission layer EML of an embodiment, the second compound and the third compound form an exciplex, and energy may be transferred from the exciplex to the first compound and the fourth compound to emit light. In an embodiment, the first compound may be a sensitizer. In the light emitting element ED of an embodiment, the first compound included in the emission layer EML may serve as a sensitizer to transfer energy from the host to the fourth compound, which is a thermally activated delayed fluorescent dopant. In some embodiments, the first compound serving as an auxiliary dopant may accelerate the energy transfer to the fourth compound serving as the light emitting dopant, thereby increasing the light emitting ratio of the fourth compound.

In some embodiments, the emission layer EML may include a first compound that is the organometallic compound, and a fourth compound that is the thermally activated delayed fluorescence dopant, or the emission layer EML may include a first compound that is the organometallic compound, and a second compound and a third compound that are host materials.

When the emission layer EML in the light emitting element ED according to an embodiment includes the first compound, the second compound, and the third compound described above, the second compound and the third compound may be in an amount of about 65 wt % to about 95 wt % with respect to a total weight of the first compound, the second compound, and the third compound.

A weight ratio of the second compound and the third compound with respect to the total weight of the second compound and the third compound may be about 3:7 to about 7:3. When the amount of the second compound and the third compound satisfies the above-described ratio, charge balance in the emission layer EML may be improved to increase luminous efficiency and element service life. When the amount of the second compound and the third compound is out of the above-described ratio range, the charge balance in the emission layer EML may be impaired to reduce luminous efficiency and easily deteriorate an element.

The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting element ED of an embodiment shown in FIGS. 3 to 7, the emission layer EML may include the organometallic compound of an embodiment described above as a dopant. In addition, in the light emitting element ED of an embodiment shown in FIGS. 3 to 7, the emission layer EML may include the first compound, which is the organometallic compound of an embodiment, and at least one of the second compound represented by Formula HT-1 or the third compound represented by Formula ET-1. In addition, in the light emitting element ED of an embodiment shown in FIGS. 3 to 7, the emission layer EML may include the first compound, which is the organometallic compound of an embodiment, the second compound represented by Formula HT-1, the third compound represented by Formula ET-1, and the fourth compound represented by Formula F-1.

In the light emitting element ED of an embodiment, the emission layer EML may further include an anthracene derivative, a pyrene derivative, a fluoranthene derivative, a chrysene derivative, a dehydrobenzanthracene derivative, and/or a triphenylene derivative. In some embodiments, the emission layer EML may further include the anthracene derivative and/or the pyrene derivative.

In each light emitting element ED of embodiments illustrated in FIGS. 3 to 7, the emission layer EML may further include a host and a dopant, and for example the emission layer EML may further include a compound represented by Formula E-1 below.

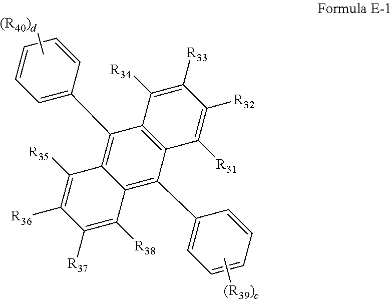

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may be each independently an integer of 0 to 5.

The compound represented by Formula E-1 may be represented by any one among Compound E1 to Compound E19 below.

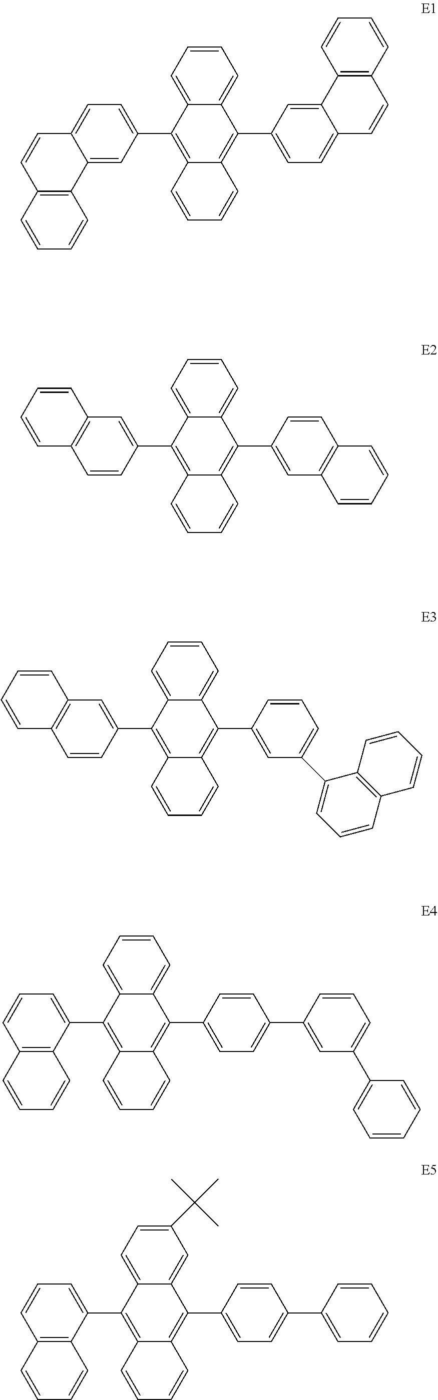

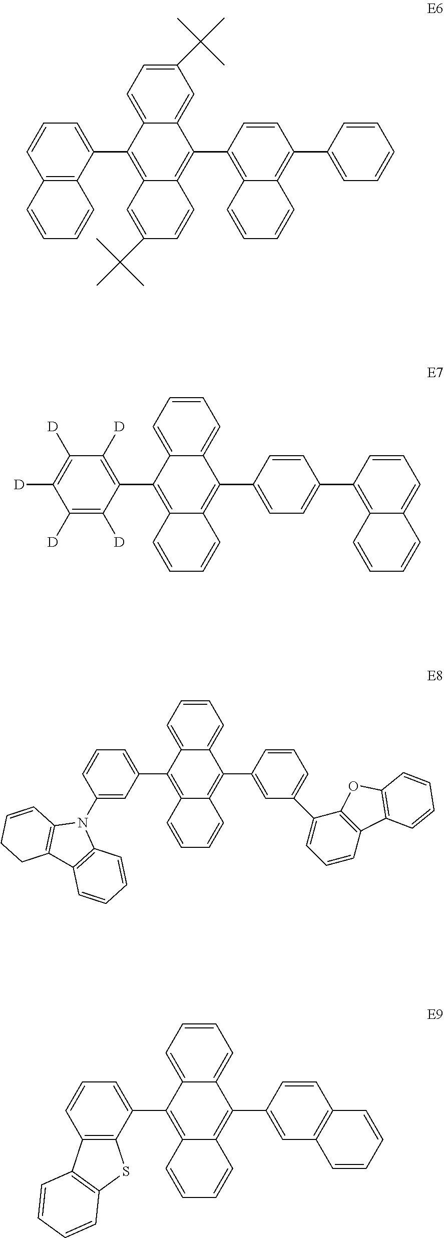

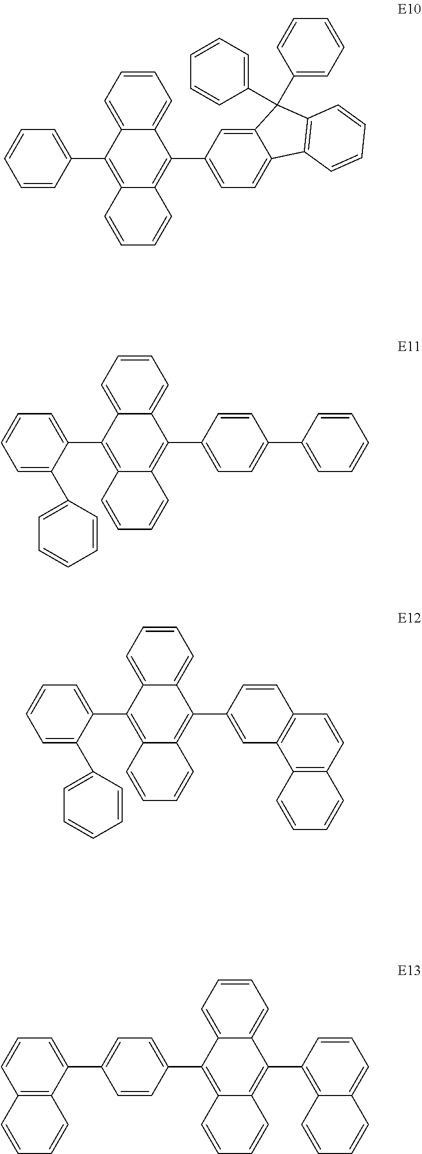

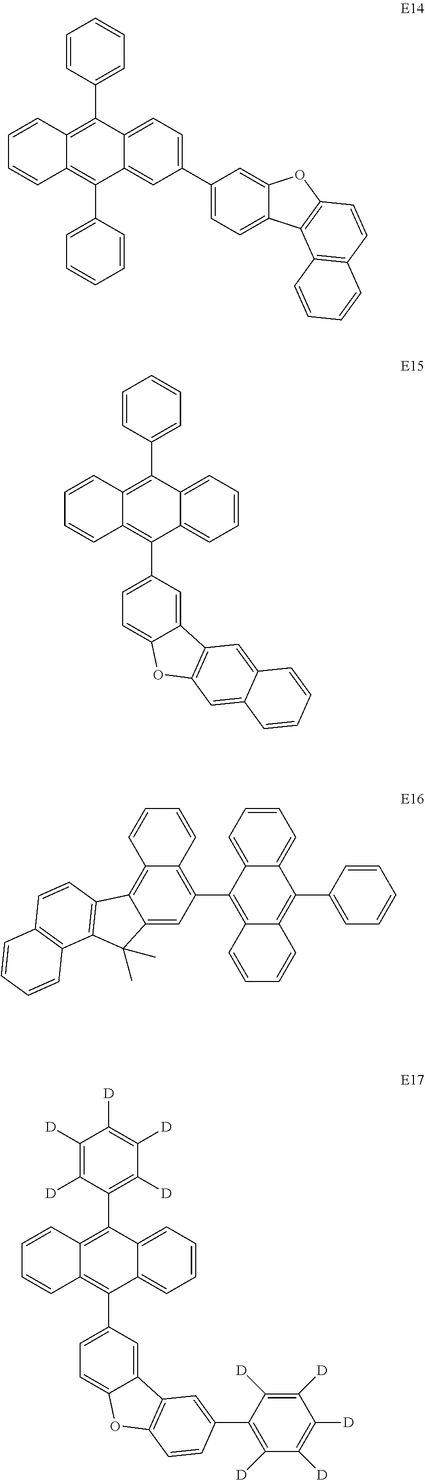

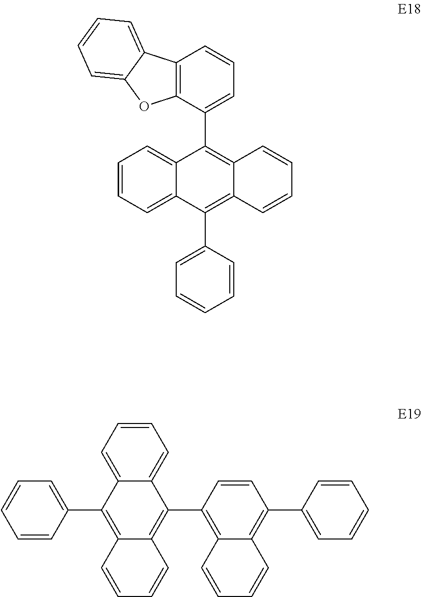

In an embodiment, the emission layer EML may further include a compound represented by Formula E-2a or Formula E-2b below. The compound represented by Formula E-2a or Formula E-2b below may be used as a phosphorescent host material.

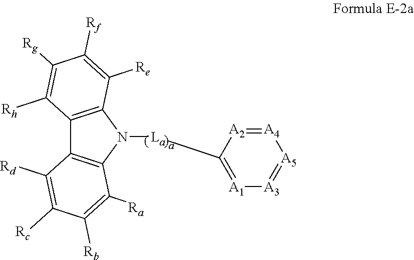

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may be each independently a substituted or unsubstituted arylene group having 6 to 30 ring-forming carbon atoms, or a substituted or unsubstituted heteroarylene group having 2 to 30 ring-forming carbon atoms.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, etc., as a ring-forming atom.

In some embodiments, in Formula E-2a, two or three selected from among A₁ to A₅ may be N, and the rest may be CRᵢ.

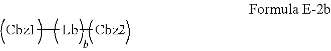

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2 below. However, the compounds listed in Compound Group E-2 below are examples, and the compound represented by Formula E-2a or Formula E-2b is not limited to those represented in Compound Group E-2 below.

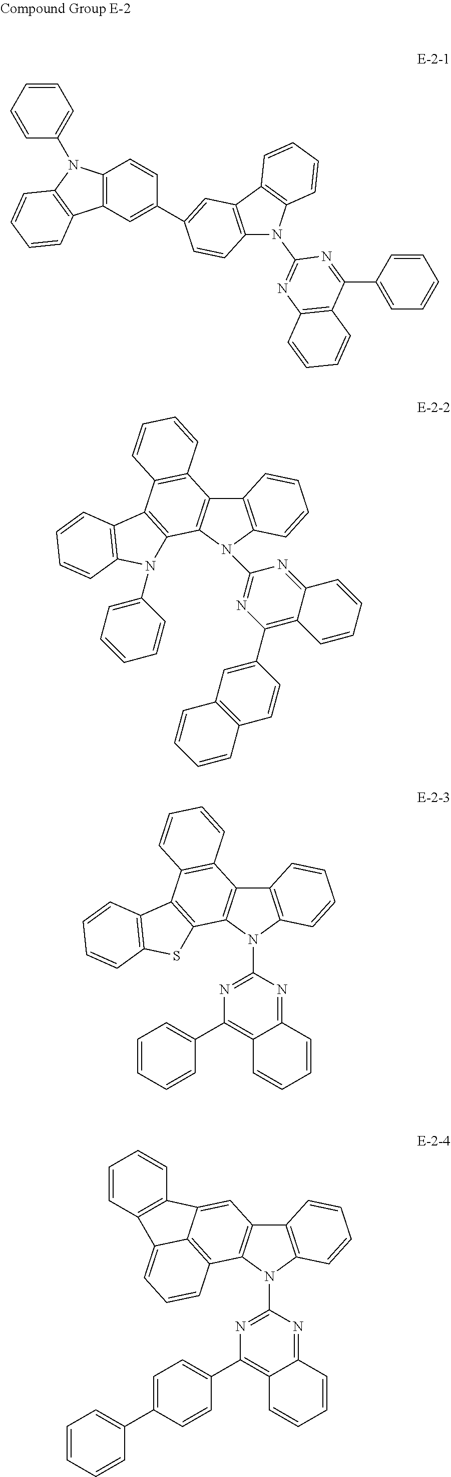

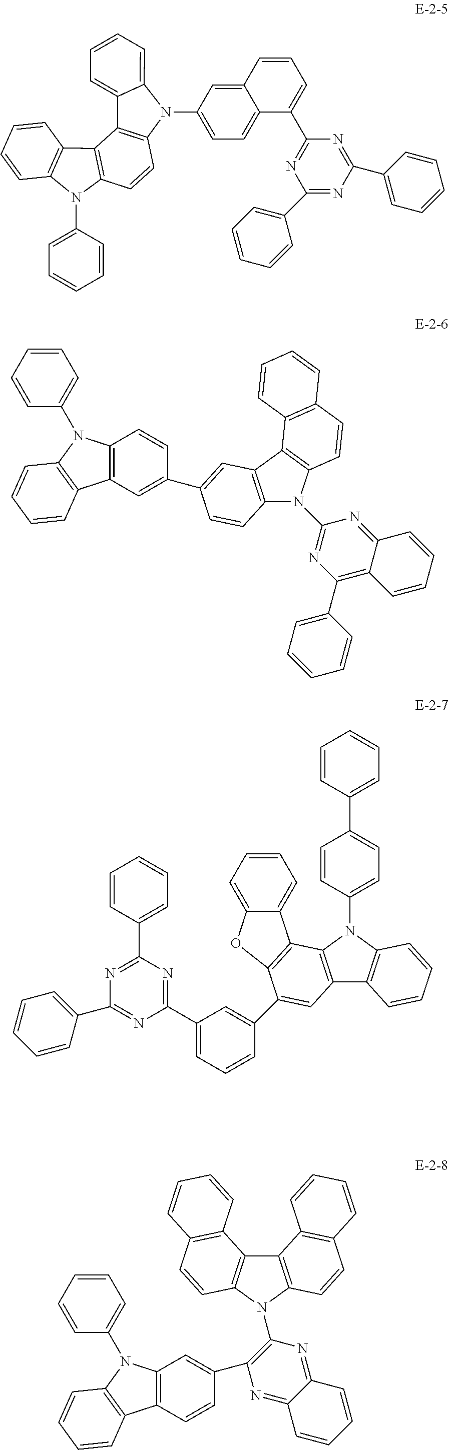 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

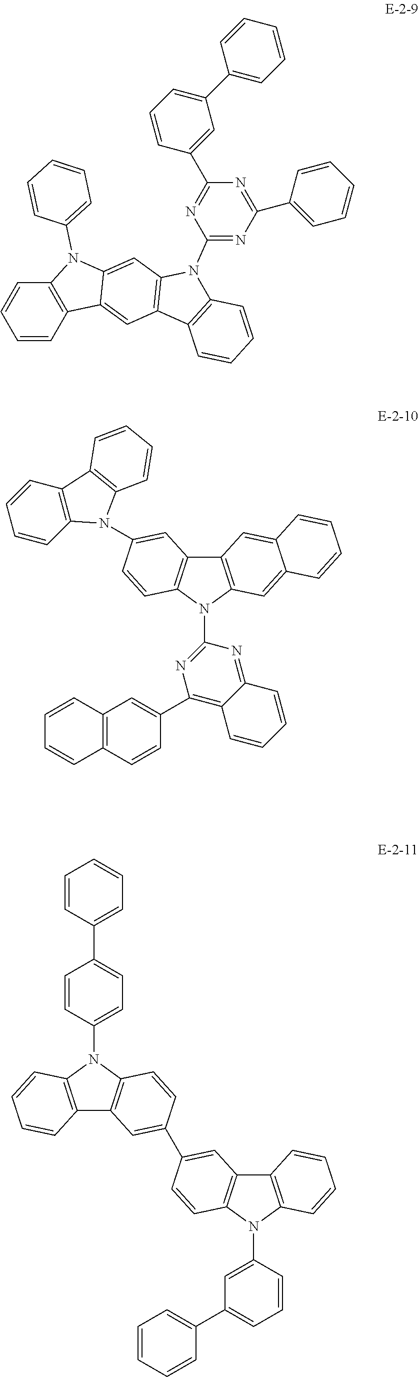 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

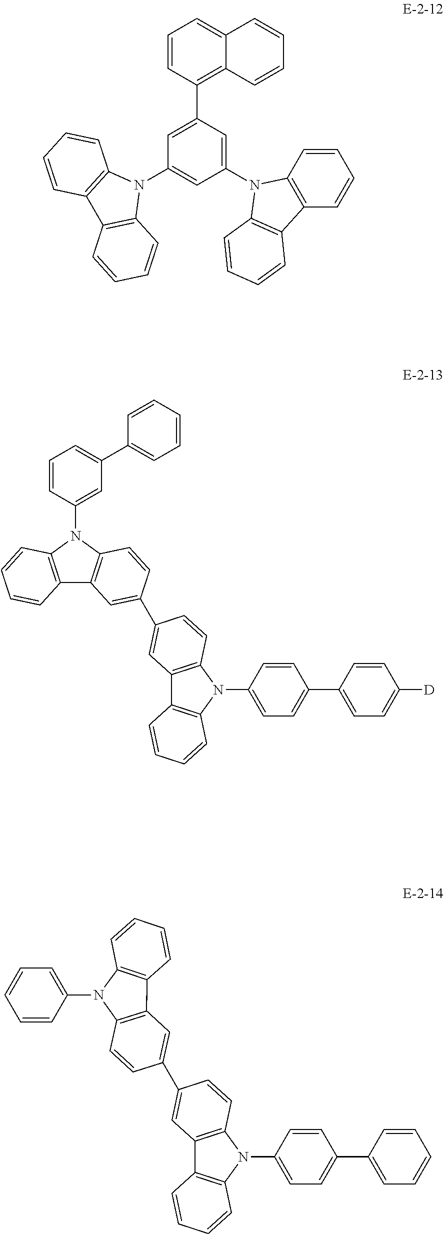 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1]

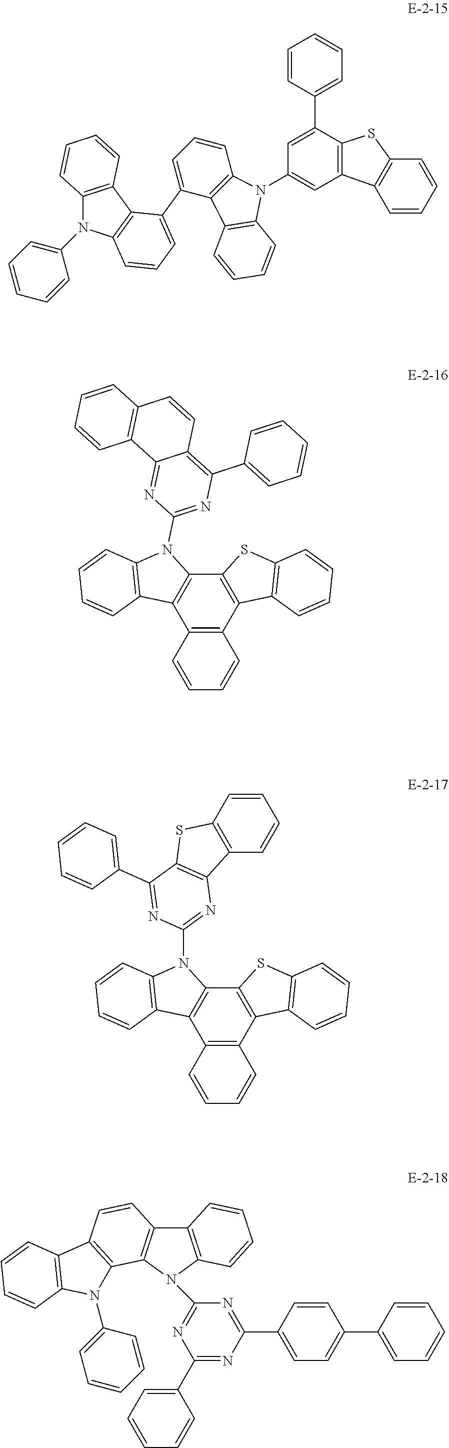 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

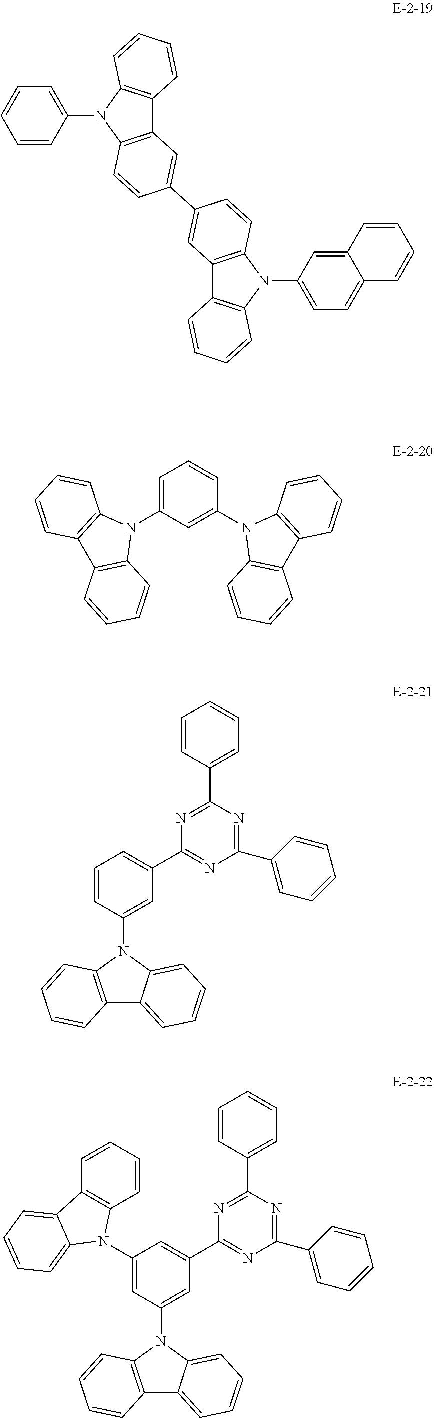 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

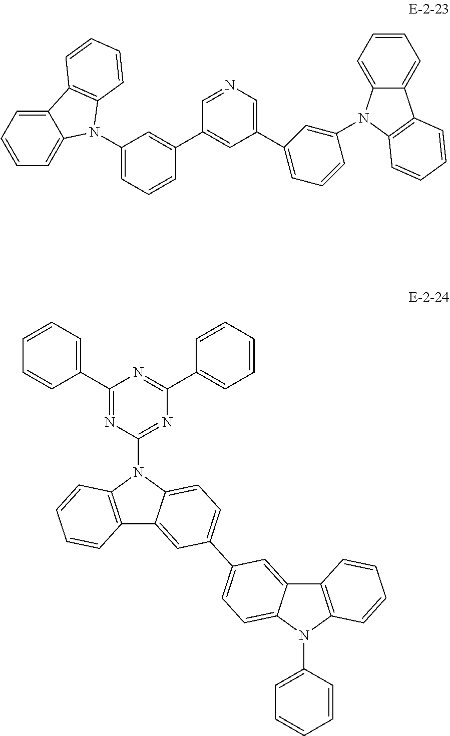 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include the compound represented by Formula M-a below. The compound represented by Formula M-a below may be used as a phosphorescent dopant material.

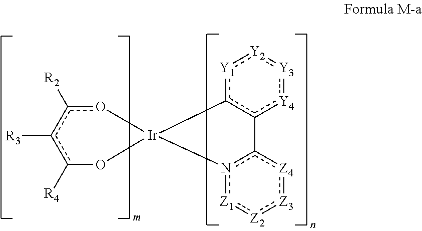

In Formula M-a above, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescent dopant.

The compound represented by Formula M-a may be represented by any one among Compound M-a1 to Compound M-a25 below. However, Compounds M-a1 to M-a25 below are examples, and the compound represented by Formula M-a is not limited to those represented by Compounds M-a1 to M-a25 below.

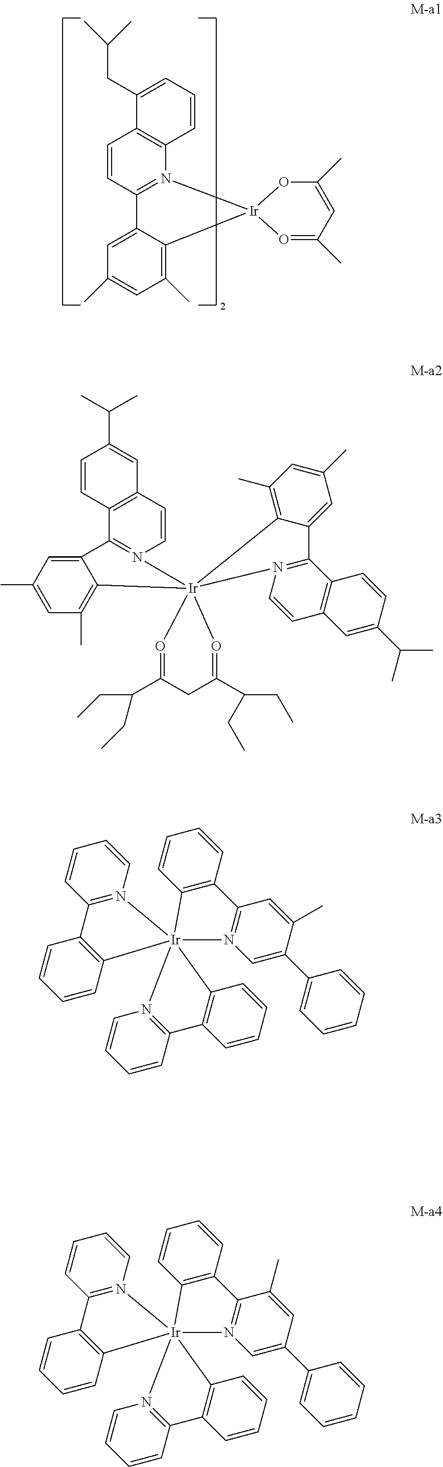

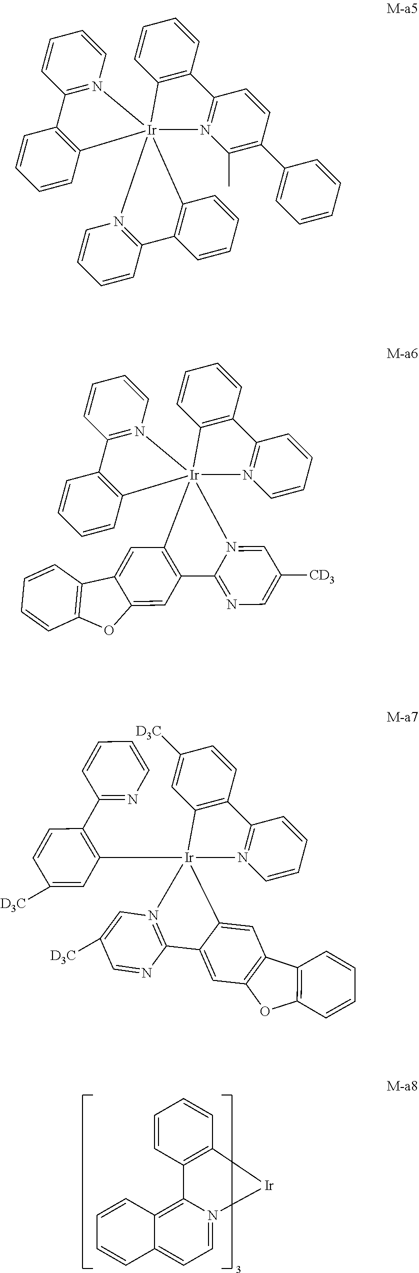

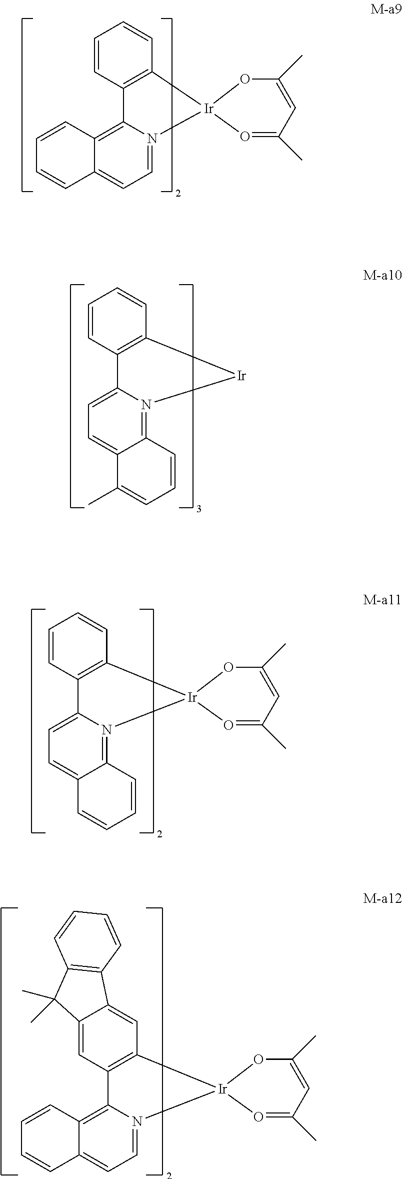

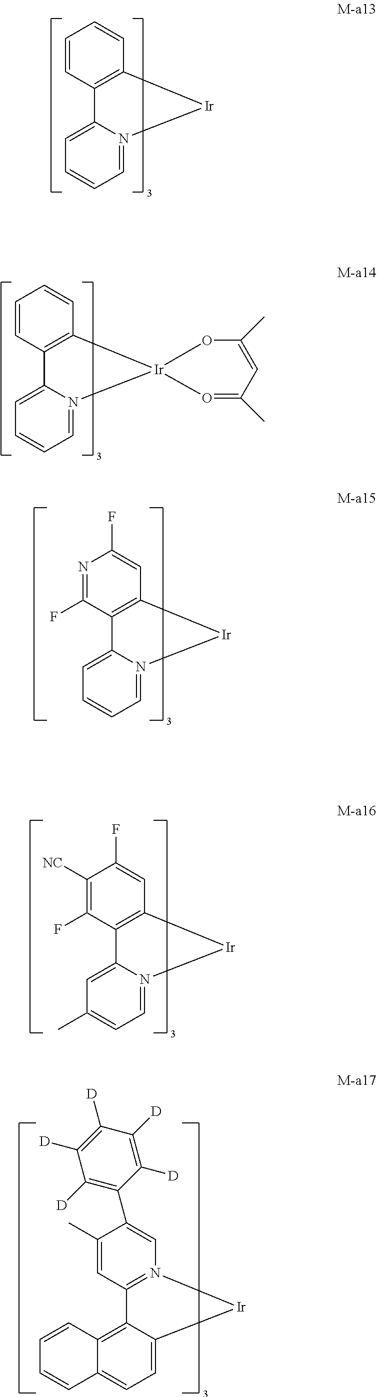

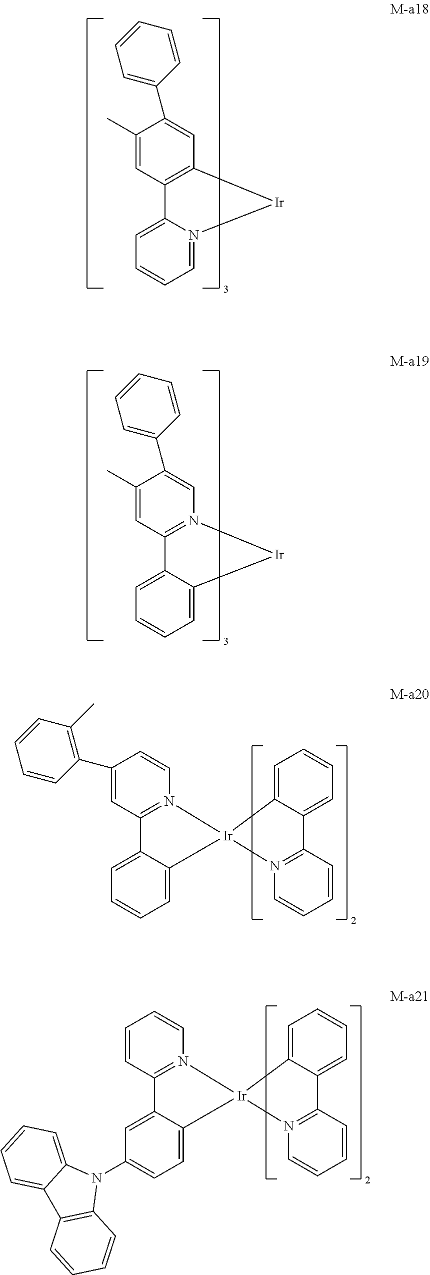

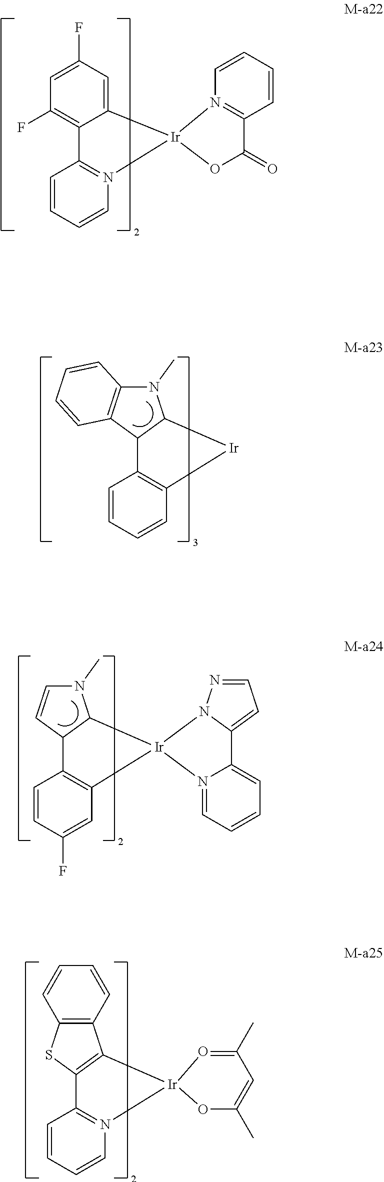

The emission layer EML may further include a compound represented by any one among Formula F-a to Formula F-c below. The compound represented by Formula F-a to Formula F-c below may be used as a fluorescence dopant material.

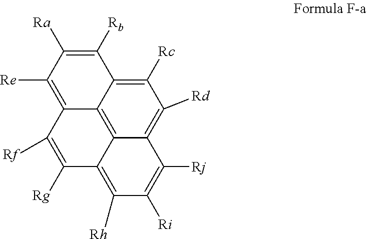

In Formula F-a above, two selected from among Rₐ to Rⱼ may each independently be substituted with *—NAr₁Ar₂. The others, which are not substituted with *—NAr₁Ar₂, among Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

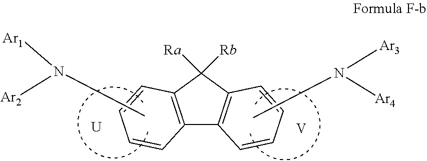

In Formula F-b above, Rₐ and Rb may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may be each independently a substituted or unsubstituted aryl group having 6 to 30 ring-forming carbon atoms, or a substituted or unsubstituted heteroaryl group having 2 to ring-forming carbon atoms.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may be each independently 0 or 1. For example, in Formula F-b, it means that when the number of U or V is 1, one ring constitutes a fused ring at a portion indicated by U or V, and when the number of U or V is 0, a ring indicated by U or V does not exist. Specifically, when the number of U is 0 and the number of V is 1, or when the number of U is 1 and the number of V is 0, the fused ring having a fluorene core in Formula F-b may be a cyclic compound having four rings. In addition, when each number of U and V is 0, the fused ring in Formula F-b may be a cyclic compound having three rings. In addition, when each number of U and V is 1, the fused ring having a fluorene core in Formula F-b may be a cyclic compound having five rings.

In an embodiment, the emission layer EML may further include, as a dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and/or a derivative thereof (e.g., 2,5,8,11-tetra-t-butylperylene (TBP)), pyrene and/or a derivative thereof (e.g., 1,1-dipyrene, 1,4-dipyrenylbenzene, 1,4-bis(N,N-diphenylamino)pyrene), etc.

The emission layer EML may further include any suitable phosphorescence dopant material generally available in the art. For example, a metal complex containing iridium (Ir), platinum (Pt), osmium (Os), aurum (Au), titanium (Ti), zirconium (Zr), hafnium (Hf), europium (Eu), terbium (Tb), or thulium™ may be used as a phosphorescent dopant. In some embodiments, iridium(Ill) bis(4,6-difluorophenylpyridinato-N,C2) (Firpic), bis(2,4-difluorophenylpyridinato)-tetrakis(1-pyrazolyl)borate iridium(III) (Fir6), and/or platinum octaethyl porphyrin (PtOEP) may be used as a phosphorescent dopant. However, embodiments of the present disclosure are not limited thereto.

The emission layer EML may include a quantum dot material. The core of the quantum dots may be selected from a Group II-VI compound, a Group 1-II-VI compound, a Group II-IV-VI compound, a Group I-II-IV-VI compound, a Group II-IV-V compound, a Group Ill-VI compound, a Group 1-Ill-VI compound, a Group Ill-V compound, a Group Ill-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CulnS₂, AgGaS₂, CuGaS₂ CuGaO₂, AgGaO₂, AgAlO₂, and a mixture thereof, and/or a quaternary compound such as AgInGaS₂ and/or CulnGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group Ill-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, or the quaternary compound may be present in a particle with a uniform or non-uniform concentration distribution. In some embodiments, the formulae mean the types (or kinds) of elements included in the compounds, and the elemental ratio in the compound may be different. For example, AgInGaS₂ may mean AgInₓGa₁₋ₓS₂ (where x is a real number of 0 to 1).

In some embodiments, the quantum dot may have a single structure or a double structure of core-shell in which the concentration of each element included in the quantum dot is uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An interface between the core and the shell may have a concentration gradient in which the concentration of an element present in the shell becomes lower along a direction towards the center of the core.

An example of the shell of the quantum dots may include a metal and/or non-metal oxide, a semiconductor compound, or a combination thereof. For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

Each element included in a polynary compound such as the binary compound, and/or the ternary compound may be present in a particle having a uniform or non-uniform concentration distribution. In some embodiments, the formulae mean the types (or kinds) of elements included in the compounds, and the elemental ratio in the compound may be different.

The quantum dot may have a full width of half maximum (FWHM) of an emission wavelength spectrum of about 45 nm or less, preferably about 40 nm or less, and more preferably about 30 nm or less, and color purity or color reproducibility may be improved in the above range. In addition, light emitted through such a quantum dot is emitted in all (e.g., substantially all) directions, and thus a wide viewing angle may be improved.

In addition, although the form of the quantum dot is not particularly limited as long as it is a form generally used in the art, for example, the quantum dot in the form of spherical, pyramidal, multi-arm, and/or cubic nanoparticles, nanotubes, nanowires, nanofibers, nanoplate particles, etc. may be used.

As the size of the quantum dot is adjusted or the elemental ratio in the quantum dot compound is adjusted, it is possible to control the energy band gap, and thus light in various suitable wavelength ranges may be obtained in the quantum dot emission layer. Therefore, the quantum dot as above (using different sizes of quantum dots or different elemental ratios in the quantum dot compound) is used, and thus the light emitting element, which emits light in various suitable wavelengths, may be implemented. In some embodiments, the adjustment of the size of the quantum dot or the elemental ratio in the quantum dot compound may be selected to emit red, green, and/or blue light. In addition, the quantum dots may be configured to emit white light by combining various suitable colors of light.

In each of the light emitting devices ED of embodiments illustrated in FIGS. 3 to 7, the electron transport region ETR is provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but embodiments of the present disclosure are not limited thereto. The electron transport region ETR may have a thickness, for example, from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2 below.

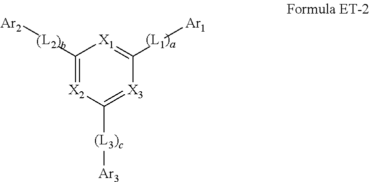

In Formula ET-2, at least one among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may be each independently an integer of 0 to 10. In Formula ET-2, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each independently an integer of 2 or more, L₁ to L₃ may be each independently a substituted or unsubstituted arylene group having 6 to ring-forming carbon atoms, or a substituted or unsubstituted heteroarylene group having 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (Balq), beryllium bis(benzoquinolin-10-olate) (Bebq₂), 9,10-di(naphthalene-2-yl)anthracene (and), 1,3-bis[3,5-di(pyridin-3-yl)phenyl]benzene (BmPyPhB), or a mixture thereof.

The electron transport region ETR may include at least one among Compound ET1 to Compound ET36 below.

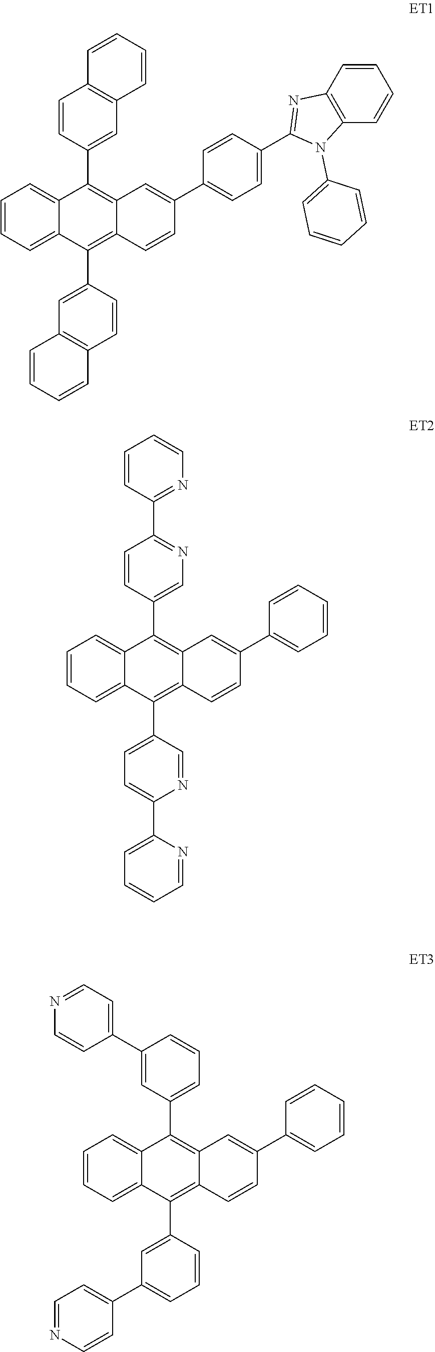 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

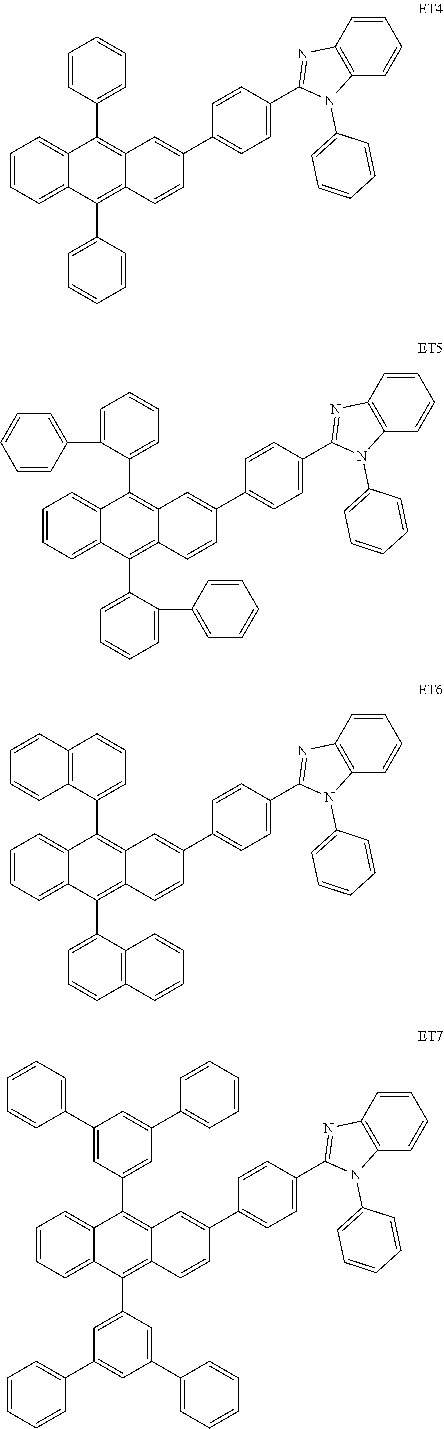 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

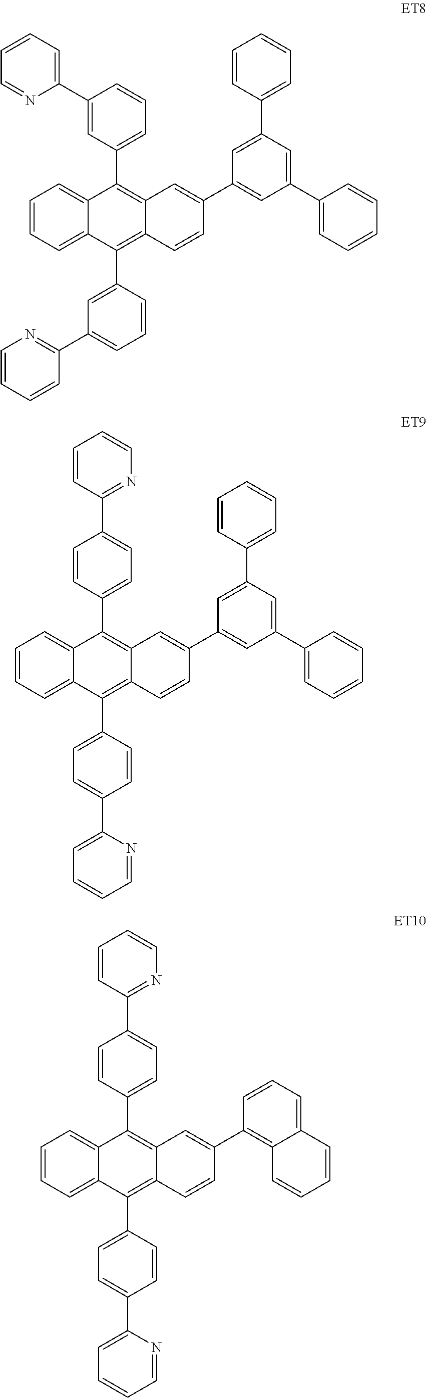

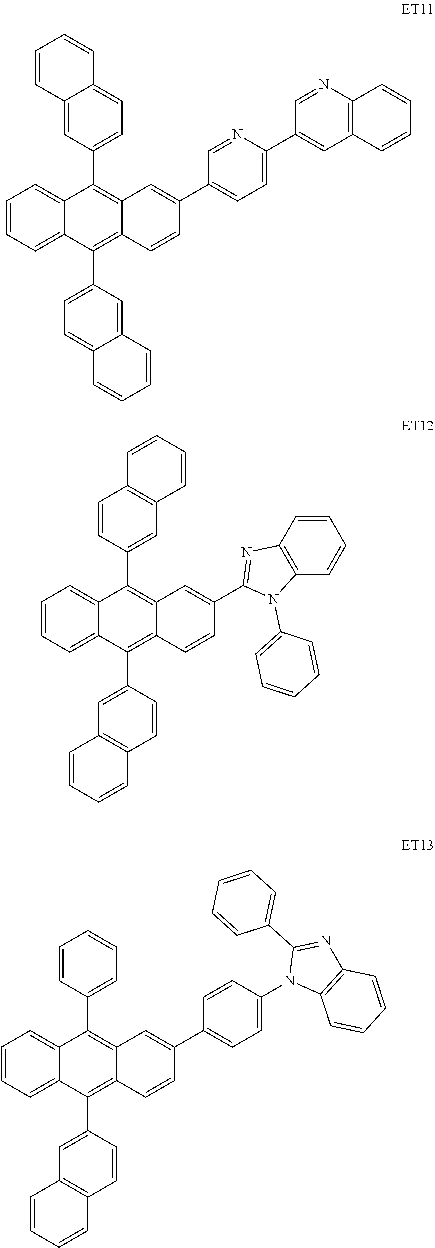 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

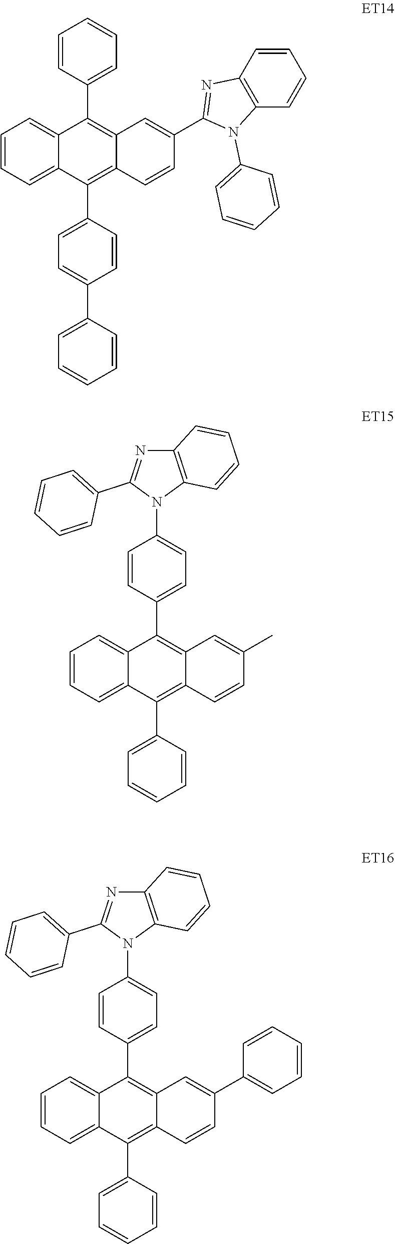 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

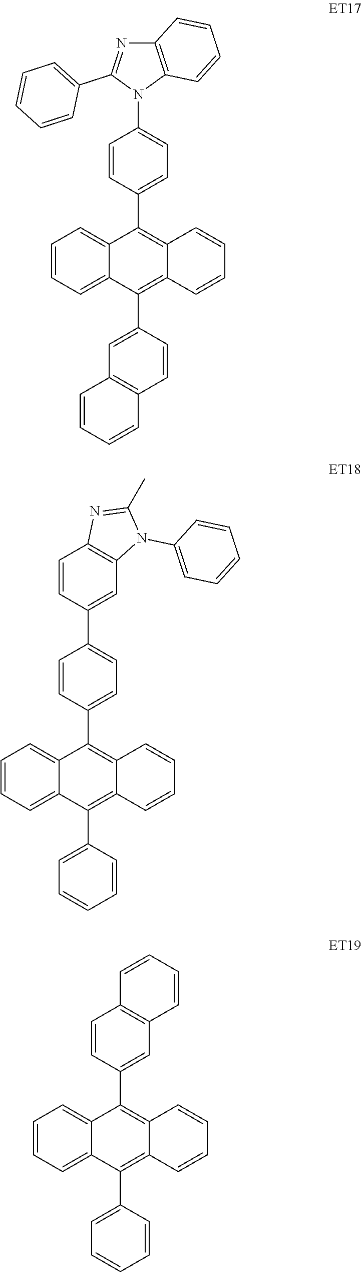

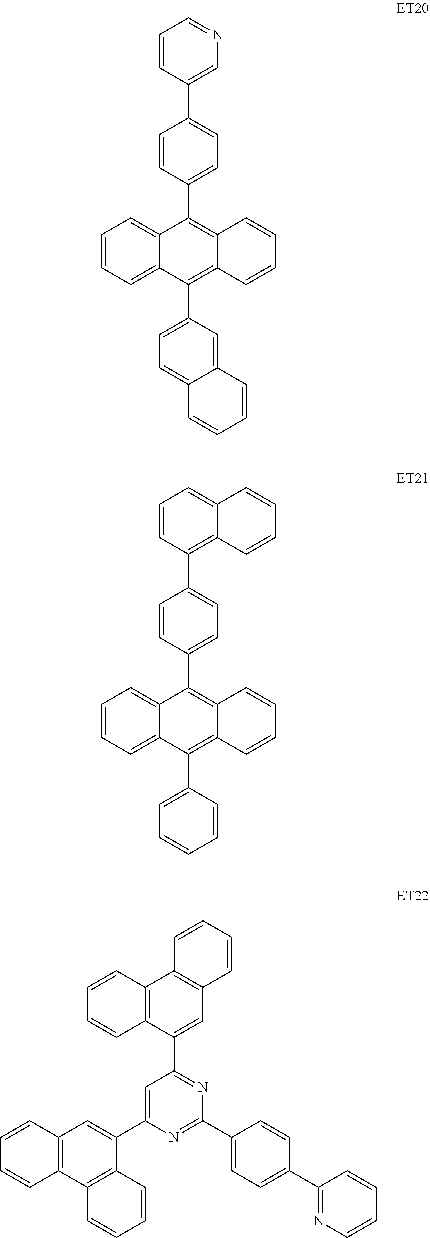

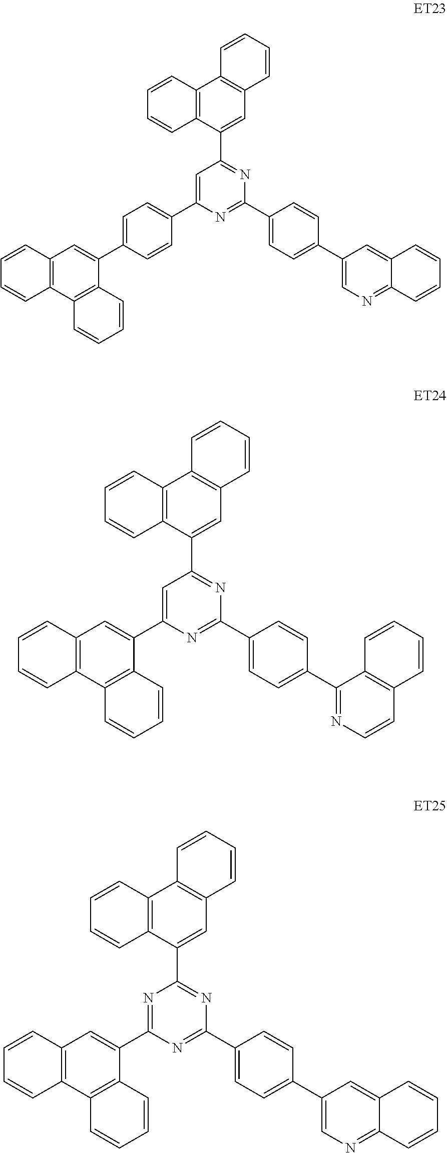 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

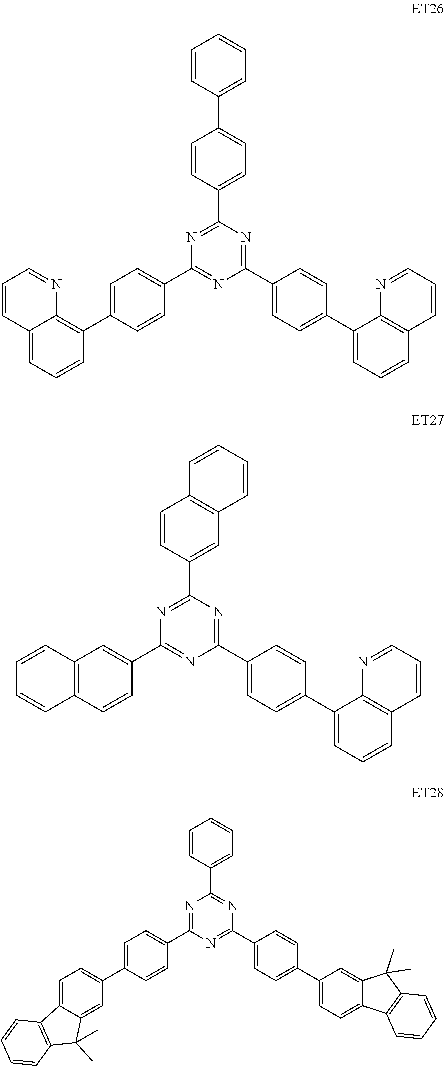 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

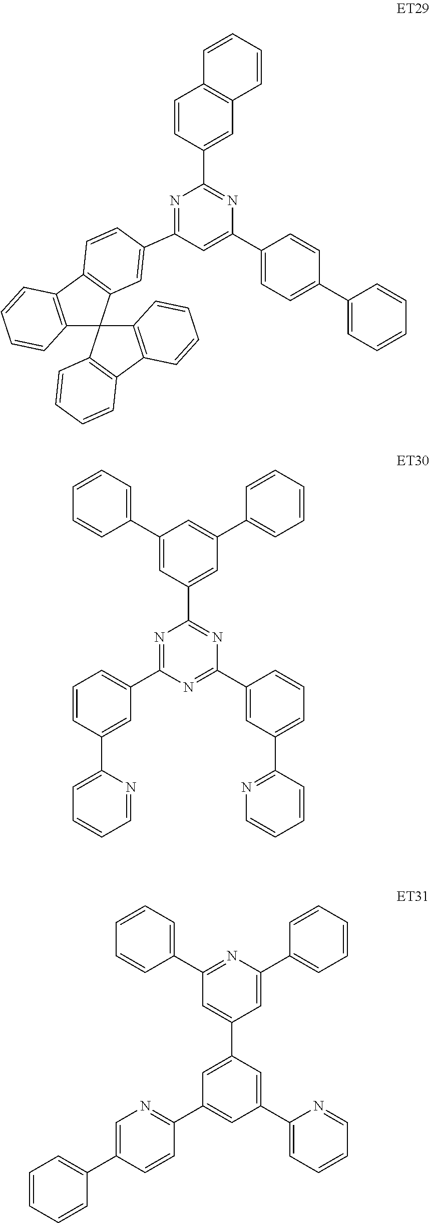 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

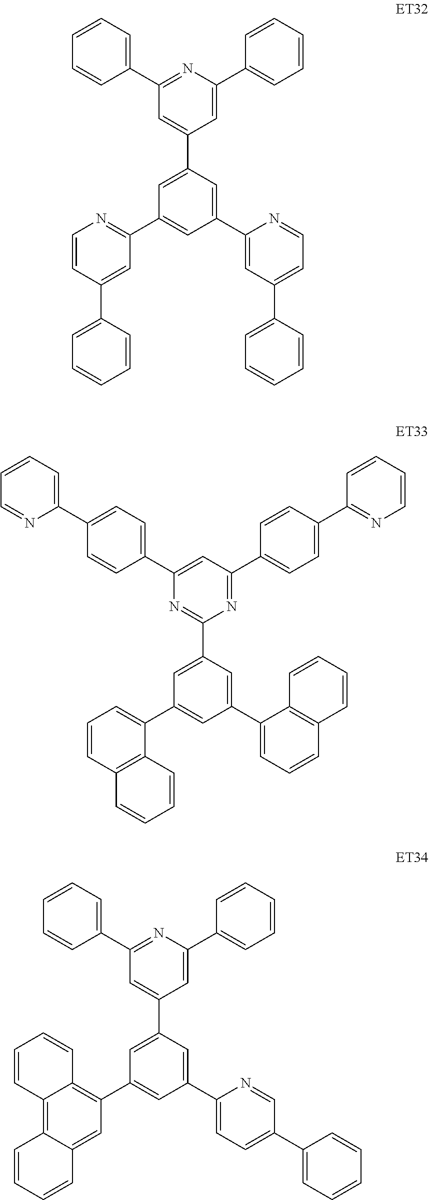 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

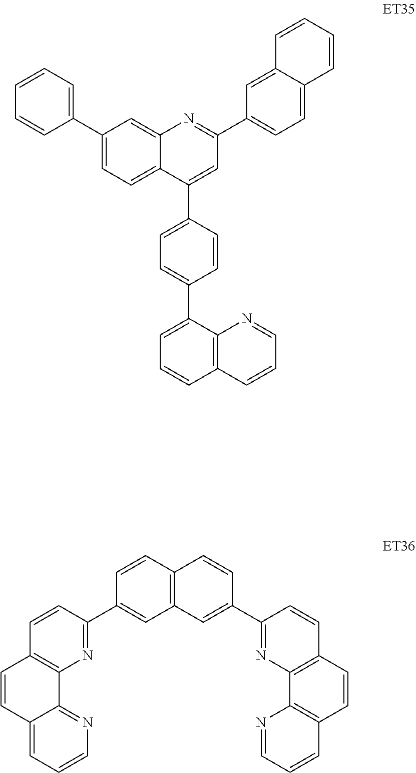 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport region ETR may include a metal halide such as LiF, NaCl, CsF, RbCl, RbI, CuI, and KI, a lanthanide metal such as Yb, and a co-deposited material of the metal halide and the lanthanide metal. For example, the electron transport region ETR may include KI:Yb, RbI:Yb, LiF:Yb, etc., as a co-deposited material. In some embodiments, the electron transport region ETR may be formed using a metal oxide such as Li₂O and/or BaO, and/or 8-hydroxyl-lithium quinolate (Liq), etc., but embodiments of the present disclosure are not limited thereto. The electron transport region ETR may also be formed of a mixture material of an electron transport material and an insulating organometallic salt (e.g., an electrically insulating organometallic salt). The organometallic salt may be a material having an energy band gap of about 4 eV or more. In some embodiments, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments of the present disclosure are not limited thereto.

The electron transport region ETR may include the above-described compounds of the hole transport region in at least one of the electron injection layer EIL, the electron transport layer ETL, or the hole blocking layer HBL

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, suitable or satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, suitable or satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, and/or MgAg). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

In some embodiments, the second electrode EL2 may be connected with an auxiliary electrode. If the second electrode EL2 is connected with the auxiliary electrode, the resistance (e.g., the electrical resistance) of the second electrode EL2 may be decreased.

In some embodiments, a capping layer CPL may further be on the second electrode EL2 of the light emitting device ED of an embodiment. The capping layer CPL may include a multilayer or a single layer.

In an embodiment, the capping layer CPL may be an organic layer and/or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., and/or an epoxy resin, and/or acrylate such as methacrylate. However, embodiments of the present disclosure are not limited thereto, and the capping layer CPL may include at least one among Compounds P1 to P5 below.

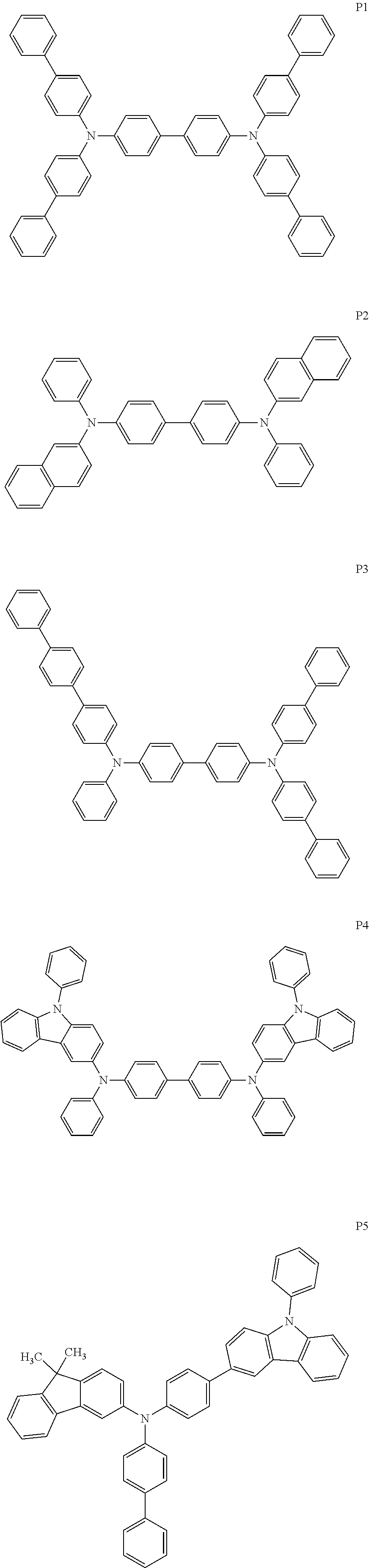 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. In some embodiments, the refractive index of the capping layer CPL may be about 1.6 or more with respect to light in a wavelength range of about 550 nm to about 660 nm.

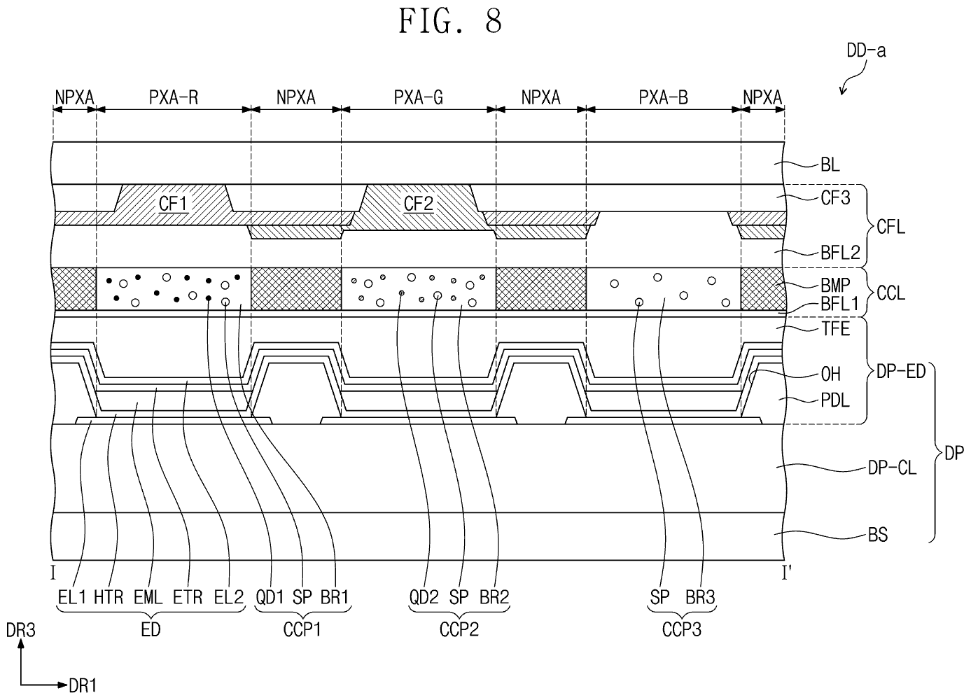

Each of FIGS. 8 to 11 is a cross-sectional view of a display device according to an embodiment of the present disclosure. Hereinafter, in describing the display devices of embodiments with reference to FIGS. 8 to 11, the duplicated features which have been described with respect to FIGS. 1 to 7 may not described again, but their differences will be mainly described.

Referring to FIG. 8, the display device DD-a according to an embodiment may include a display panel DP including a display element layer DP-ED, a light control layer CCL disposed on the display panel DP, and a color filter layer CFL. In an embodiment illustrated in FIG. 8, the display panel DP may include a base layer BS, a circuit layer DP-CL on the base layer BS, and the display element layer DP-ED, and the display element layer DP-ED may include a light emitting element ED.

The light emitting element ED may include a first electrode EL1, a hole transport region HTR on the first electrode EL1, an emission layer EML disposed on the hole transport region HTR, an electron transport region ETR on the emission layer EML, and a second electrode EL2 on the electron transport region ETR. In some embodiments, the structures of the light emitting elements of FIGS. 3 to 7 as described above may be equally applied to the structure of the light emitting element ED illustrated in FIG. 8. The light emitting element ED shown in FIG. 8 may include the organometallic compound of an embodiment. Accordingly, the light emitting element ED may exhibit improved luminous efficiency and low driving voltage characteristics. In addition, the light emitting element ED may emit deep blue light and exhibit excellent color conversion efficiency.

Referring to FIG. 8, the emission layer EML may be in an opening OH defined in a pixel defining layer PDL. For example, the emission layer EML which is divided by the pixel defining layer PDL and provided corresponding to each light emitting regions PXA-R, PXA-G, and PXA-B may emit light in the same wavelength range. In the display device DD-a of an embodiment, the emission layer EML may emit blue light. In some embodiments, the emission layer EML may be provided as a common layer in the entire light emitting regions PXA-R, PXA-G, and PXA-B.

The light control layer CCL may be on the display panel DP. The light control layer CCL may include a light conversion body. The light conversion body may be a quantum dot, a phosphor, and/or the like. The light conversion body may emit provided light by converting the wavelength thereof. In some embodiments, the light control layer CCL may include a layer containing the quantum dot and/or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 8, divided patterns BMP may be between the light control parts CCP1, CCP2 and CCP3 which are spaced apart from each other, but embodiments of the present disclosure are not limited thereto. FIG. 8 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts a first color light provided from the light emitting element ED into a second color light, a second light control part CCP2 containing a second quantum dot QD2 which converts the first color light into a third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described above may be applied with respect to the quantum dots QD1 and QD2.

In addition, the light control layer CCL may further include a scatterer SP (e.g., a light scatterer SP). The first light control part CCP1 may include the first quantum dot QD1 and the scatterer SP, the second light control part CCP2 may include the second quantum dot QD2 and the scatterer SP, and the third light control part CCP3 may not include any quantum dot but include the scatterer SP.

The scatterer SP may be inorganic particles. For example, the scatterer SP may include at least one of TiO₂, ZnO, Al₂O₃, SiO₂, and/or hollow sphere silica. The scatterer SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the exposure of the light control parts CCP1, CCP2 and CCP3 to moisture/oxygen. In some embodiments, the barrier layer BFL1 may cover the light control parts CCP1, CCP2, and CCP3. In addition, the barrier layer BFL2 may be between the light control parts CCP1, CCP2, and CCP3 and the color filter layer CFL

The barrier layers BFL1 and BFL2 may include at least one inorganic layer. In some embodiments, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be on the light control layer CCL. For example, the color filter layer CFL may be directly on the light control layer CCL. In this case, the barrier layer BFL2 may be omitted.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye.

Embodiments of the present disclosure are not limited thereto, however, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but be provided as one filter.

In some embodiments, the color filter layer CFL may further include alight shielding part. The light shielding part may be a black matrix. The light shielding part may include an organic light shielding material or an inorganic light shielding material containing a black pigment and/or dye. The light shielding part may prevent or reduce light leakage, and may separate boundaries between the adjacent filters CF1, CF2, and CF3. Also, in an embodiment, the light shielding part may be formed of a blue filter.

The first to third filters CF1, CF2, and CF3 may be provided corresponding to the red light emitting region PXA-R, the green light emitting region PXA-G, and the blue light emitting region PXA-B, respectively.

A base substrate BL may be on the color filter layer CFL. The base substrate BL may be a member which provides a base surface in which the color filter layer CFL, the light control layer CCL, and the like are provided. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may be omitted.

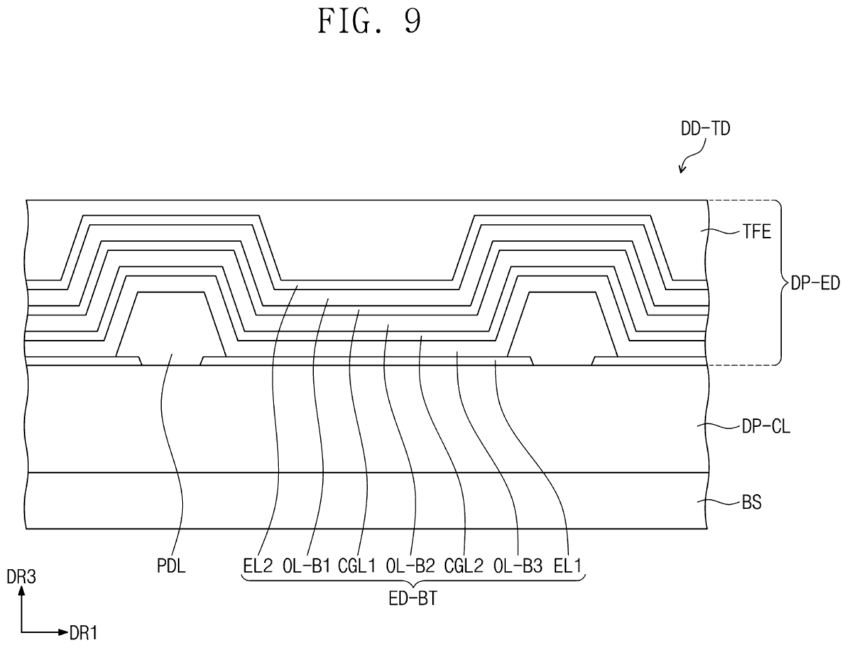

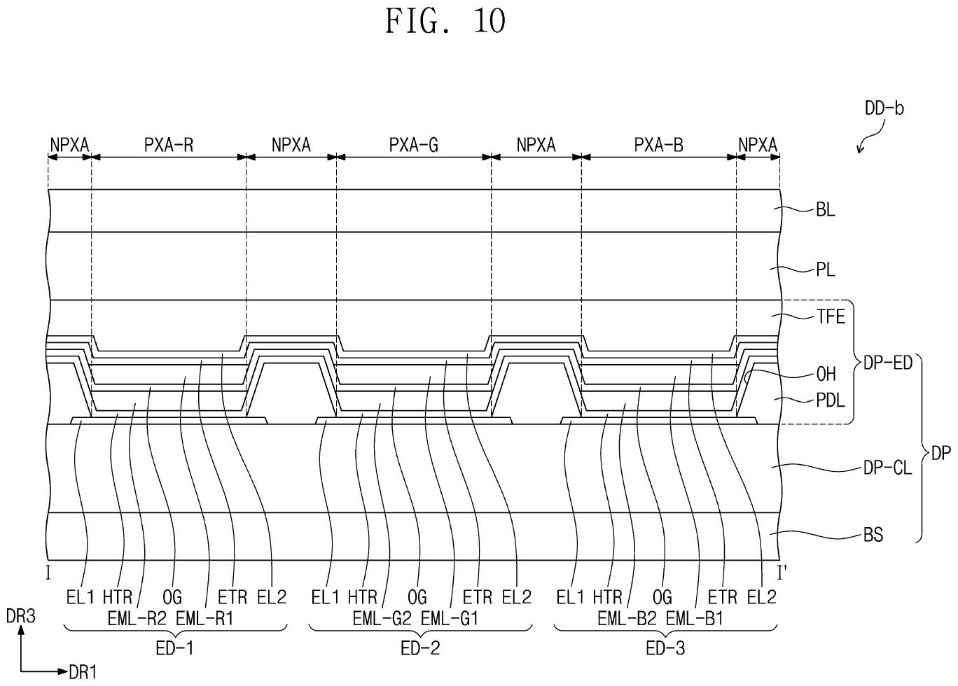

FIG. 9 is a cross-sectional view showing a portion of a display device according to an embodiment. In a display device DD-TD of an embodiment, a light emitting element ED-BT may include a plurality of light emitting structures OL-B1, OL-B2, and OL-B3. At least one of the plurality of light emitting structures OL-B1, OL-B2, and OL-B3 may include the organometallic compound of an embodiment. Accordingly, the light emitting element ED-BT may exhibit improved luminous efficiency and low driving voltage characteristics. In addition, the light emitting element ED-BT may emit deep blue light and exhibit excellent color conversion efficiency.

The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 8) and a hole transport region HTR and an electron transport region ETR disposed with the emission layer EML (FIG. 8) therebetween. In some embodiments, the light emitting element ED-BT included in the display device DD-TD of an embodiment may be a light emitting element having a tandem structure and including a plurality of emission layers.

In an embodiment illustrated in FIG. 9, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may emit white light.

A charge generating layer CGL may be between the neighboring light-emitting structures OL-B1, OL-B2 and OL-B3. The charge generating layer CGL may include a p-type charge generating layer and/or an n-type charge generating layer.

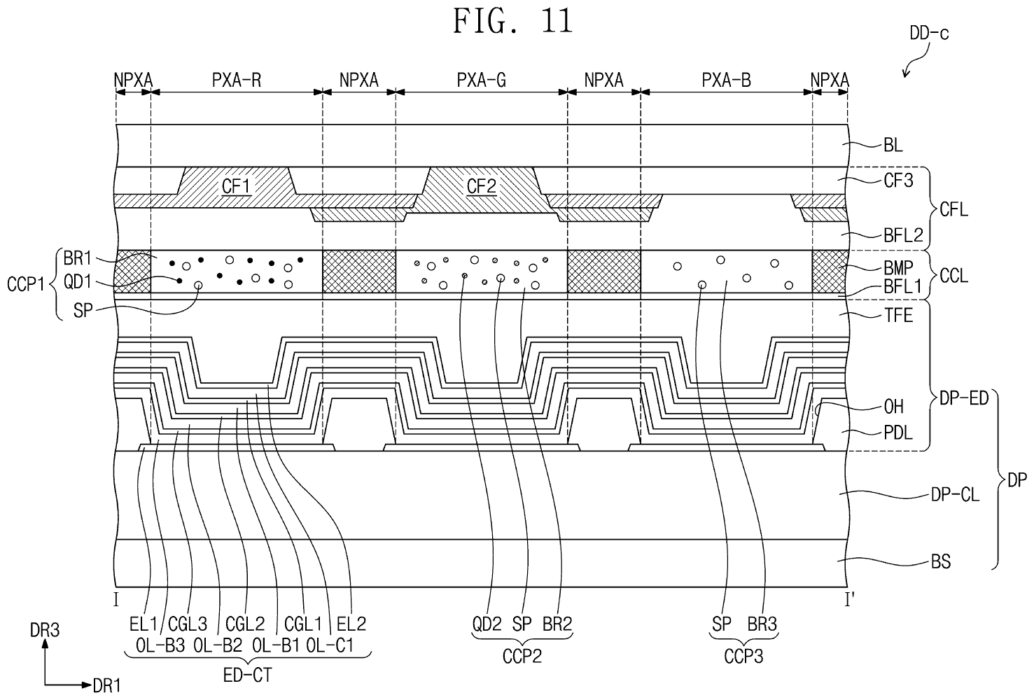

Referring to FIG. 10, a display device DD-b according to an embodiment may include light emitting elements ED-1, ED-2, and ED-3 in which two emission layers are stacked. At least one of the light emitting elements ED-1, ED-2, and ED-3 may include the organometallic compound of an embodiment. Accordingly, the light emitting elements ED-1, ED-2, and ED-3 may exhibit improved luminous efficiency and low driving voltage characteristics. In addition, the light emitting elements ED-1, ED-2, and ED-3 may emit deep blue light and exhibit excellent color conversion efficiency.

Compared with the display device DD of an embodiment illustrated in FIG. 2, an embodiment illustrated in FIG. 10 has a difference in that the first to third light emitting elements ED-1, ED-2, and ED-3 each include two emission layers stacked in the thickness direction. In each of the first to third light emitting elements ED-1, ED-2, and ED-3, the two emission layers may emit light in the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. In some embodiments, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, embodiments of the present disclosure are not limited thereto, and the emission auxiliary part OG may be provided by being patterned within the openings OH defined in the pixel defining layer PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be between the emission auxiliary part OG and the hole transport region HTR.

In some embodiments, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be on the display element layer DP-ED. The optical auxiliary layer PL may include a polarizing layer. The optical auxiliary layer PL may be on the display panel DP and control reflected light in the display panel DP due to external light. In some embodiments, the optical auxiliary layer PL in the display device according to an embodiment may be omitted.

Unlike FIGS. 9 and 10, the display device DD-c of FIG. 11 is illustrated to include four light emitting structures OL-B1, OL-B2, OL-B3, and OL-C1. The light emitting element ED-BT may include the first electrode EL1 and the second electrode EL2 facing each other, and the first to fourth light emitting structures L-B1, OL-B2, OL-B3, and OL-C1 sequentially stacked in a thickness direction between the first electrode EL1 and the second electrode EL2. At least one of the first to fourth light emitting structures OL-B1, OL-B2, OL-B3, and OL-C1 may include the organometallic compound of an embodiment. Accordingly, the light emitting element ED-CT may exhibit improved luminous efficiency and low driving voltage characteristics. In addition, the light emitting element ED-CT may emit deep blue light and exhibit excellent color conversion efficiency.

Charge generation layers CGL1, CGL2, and CGL3 may be between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, embodiments of the present disclosure are not limited thereto, and the first to fourth light emitting structures OL-B1, OL-B2, OL-B3, and OL-C1 may emit light beams in different wavelength regions. The charge generation layers CGL1, CGL2, and CGL3 disposed between adjacent light emitting structures OL-B1, OL-B2, OL-B3, and OL-C1 may include a p-type charge generation layer and/or an n-type charge generation layer.

In an embodiment, the electronic apparatus may include a display device including a plurality of light emitting elements, and a control part which controls the display device. The electronic apparatus of an embodiment may be a device that is activated according to an electrical signal. The electronic apparatus may include display devices of various embodiments. For example, the electronic apparatus may include not only large-sized electronic apparatuses such as a television set, a monitor, and/or an outdoor billboard but also include small- and medium-sized electronic apparatuses such as a personal computer, a laptop computer, a personal digital terminal, a display device for a vehicle, a game console, a portable electronic device, and/or a camera.

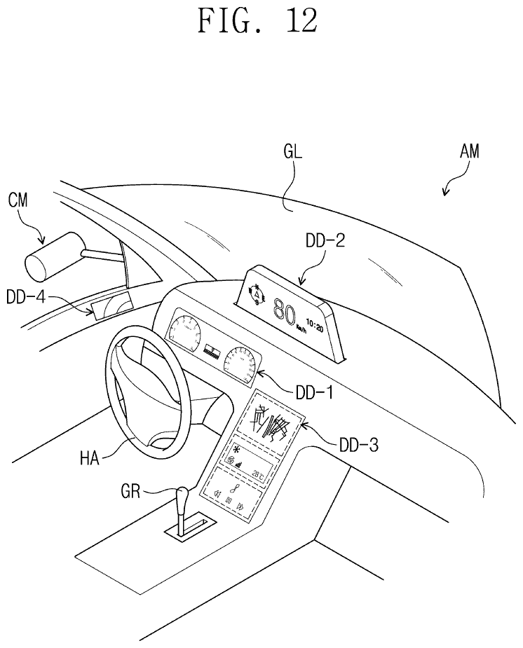

FIG. 12 is a view illustrating a vehicle AM in which first to fourth display devices DD-1, DD-2, DD-3, and DD-4 are provided. At least one among the first to fourth display devices DD-1, DD-2, DD-3, and DD-4 may include the same configuration as the display devices DD, DD-TD, DD-a, DD-b, and DD-c as described with reference to FIGS. 1, and 2, and 8 to 11.

FIG. 12 illustrates a vehicle AM, but this is an example, and the first to fourth display devices DD-1, DD-2, DD-3, and DD-4 may be in another transportation means such as bicycles, motorcycles, trains, ships, and/or airplanes. In addition, at least one among the first to fourth display devices DD-1, DD-2, DD-3, and DD-4 including the same configuration as the display devices DD, DD-TD, DD-a, DD-b, and DD-c of an embodiment may be employed in a personal computer, a laptop computer, a personal digital terminal, a game console, a portable electronic device, a television, a monitor, an outdoor billboard, and/or the like. In addition, these are merely provided as embodiments, and thus may be employed in other suitable electronic apparatuses unless departing from the spirit and scope of the present disclosure.

At least one of the first to fourth display devices DD-1, DD-2, DD-3, or DD-4 may include the light emitting element ED described with reference to FIGS. 3 to 7. At least one of the first to fourth display devices DD-1, DD-2, DD-3, and DD-4 may include the organometallic compound of an embodiment. Accordingly, the first to fourth display devices DD-1, DD-2, DD-3, and DD-4 may have improved display quality.

Referring to FIG. 12, the vehicle AM may include a steering wheel HA and a gear GR for driving the vehicle AM. In addition, the vehicle AM may include a front window GL provided so as to face the driver.

The first display device DD-1 may be in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, etc. A first scale and a second scale may be indicated as a digital image.

The second display device DD-2 may be in a second region facing the driver's seat and overlapping the front window GL. The driver's seat may be a seat in which the steering wheel HA is provided. For example, the second display device DD-2 may be a head up display (HUD) which displays second information of the vehicle AM. The second display device DD-2 may be optically transparent. The second information may include digital numbers which indicate a driving speed, and may further include information such as the current time. In some embodiments, the second information of the second display device DD-2 may be projected to the front window GL to be displayed.

The third display device DD-3 may be in a third region adjacent to the gear GR. For example, the third display device DD-3 may be between the driver's seat and the passenger seat and may be a center information display (CID) for a vehicle for displaying third information. The passenger seat may be a seat spaced apart from the driver's seat with the gear GR therebetween. The third information may include information about traffic (e.g., navigation information), playing music and/or radio and/or a video (or an image), temperatures inside the vehicle AM, etc.

The fourth display device DD-4 may be spaced apart from the steering wheel HA and the gear GR, and may be in a fourth region adjacent to the side of the vehicle AM. For example, the fourth display device DD-4 may be a digital side-view mirror which displays fourth information. The fourth display device DD-4 may display an image outside the vehicle AM taken by a camera module CM outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may include different information. However, embodiments of the present disclosure are not limited thereto, and a part of the first to fourth information may include the same information as one another.

Hereinafter, with reference to Examples and Comparative Examples, an organometallic compound and a light emitting element of an embodiment of the present disclosure will be further described. In addition, Examples shown below are illustrated only for the understanding of the subject matter of the present disclosure, and the scope of the present disclosure is not limited thereto.

### EXAMPLES

### 1. Synthesis of Organometallic Compounds of Examples

A process of synthesizing organometallic compounds according to an embodiment of the present disclosure will be described in more detail by presenting a process of synthesizing Compounds 9, 29, 31, 38, 43, 45, 53, 60, 73, and 81 as an example. In addition, a process of synthesizing organometallic compounds, which will be described hereinafter, is provided as an example, and thus a process of synthesizing compounds according to an embodiment of the present disclosure is not limited to Examples below.

### (1) Synthesis of Compound 9

Organometallic Compound 9 according to an embodiment may be synthesized by, for example, a process of Reaction Formula 1 below.

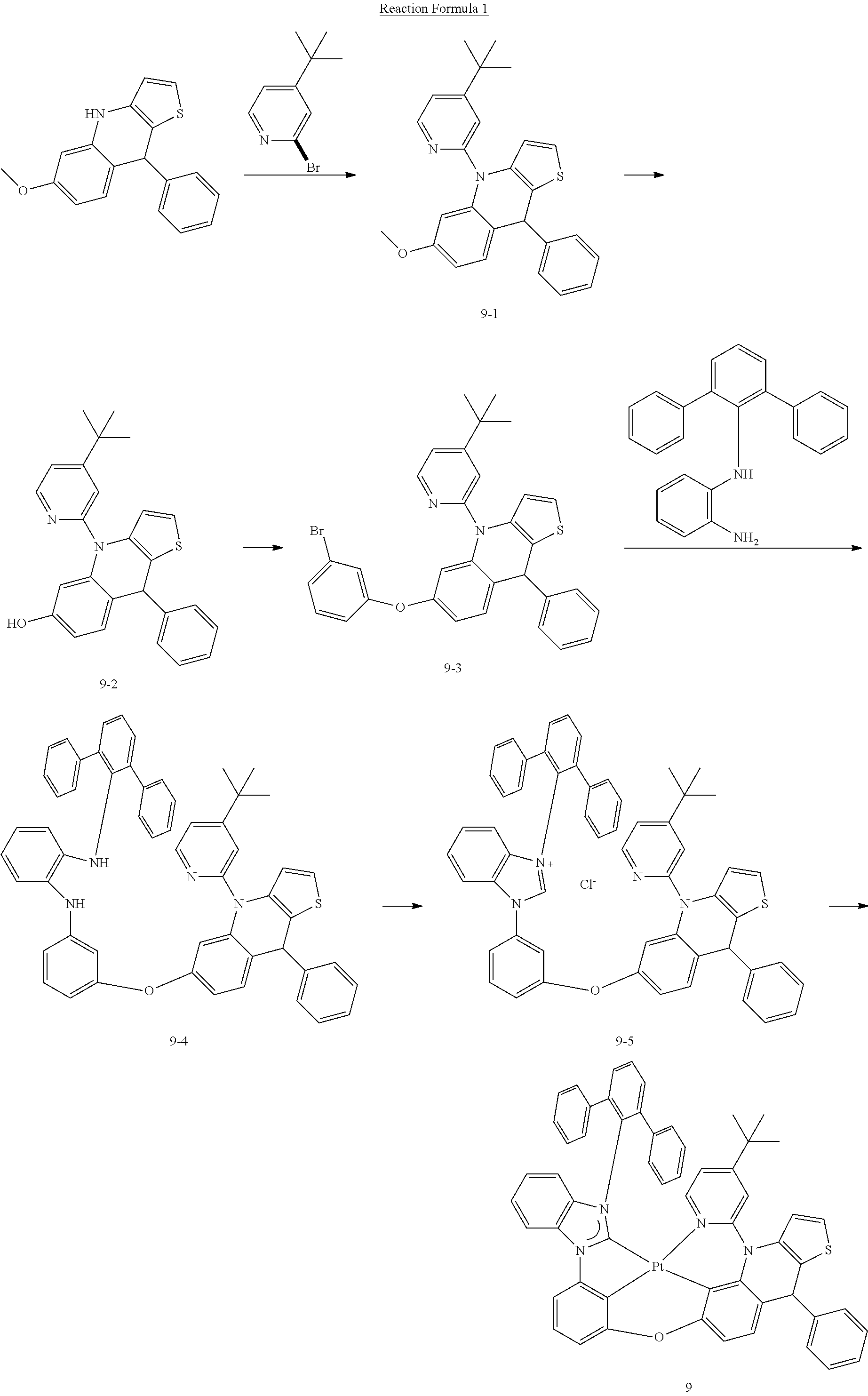

### Synthesis of Intermediate 9-1

6-methoxy-9-phenyl-4,9-dihydrothieno[3,2,b]quinoline (5.3 g, 18 mmol), 2-bromo-4(tert-butyl)pyridine (5.8 g, 27 mmol), tripotassium (8.3 g, 36 mmol), CuI (0.66 g, 3.6 mmol), and picolinic acid (0.4 g, 3.6 mmol) were put into a reaction vessel and suspended in dimethyl sulfoxide (100 mL). The resultant reaction mixture was heated and stirred at 160° C. for 24 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.8 g, 13.7 mmol).

### Synthesis of Intermediate 9-2

Intermediate 9-1 (5.8 g, 13.7 mmol) was suspended in an excess of hydrobromic acid solution. The resultant reaction mixture was heated and stirred at 110° C. for 24 hours. After completion of the reaction, the mixture was cooled to room temperature, and neutralized by adding an appropriate amount of sodium hydrogen carbonate. Distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (4.6 g, 11.1 mmol).

### Synthesis of Intermediate 9-3

Intermediate 9-2 (4.6 g, 11.1 mmol), 1-bromo-3-fluorobenzene (2.9 g, 16.7 mmol), and tripotassium (5.2 g, 22.2 mmol) were put into a reaction vessel and suspended in dimethyl sulfoxide (100 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.2 g, 9.2 mmol).

### Synthesis of Intermediate 9-4

Intermediate 9-3 (5.2 g, 9.2 mmol), N1-([1,1′:3′,1″-terphenyl]-2′-nyl)benzene-1,2-diamine (3.1 g, 9.2 mmol), SPhos (0.70 mmol), Pd₂(dba)₃ (0.46 mmol), and sodium t-butoxide (18 mmol) were suspended in a toluene solvent (100 ml), and then the mixture was heated to 110° C. and stirred for 5 hours. After completion of the reaction, the solvent was removed under reduced pressure, and the mixture was extracted with methylene chloride and distilled water. The extracted organic layer was washed with a saturated aqueous sodium chloride solution and dried over sodium sulfate. The residue left after removing the solvent was separated using column chromatography to obtain a target compound (6.8 g, 8.3 mmol).

### Synthesis of Intermediate 9-5

Intermediate 9-4 (6.8 g, 8.3 mmol) was dissolved in triethyl orthoformate (415 mmol), and HCl (10 mmol) was added dropwise thereto. Thereafter, the mixture was heated to 80° C. and stirred for 20 hours. After completion of the reaction, the solvent was removed under reduced pressure, and the mixture was extracted with methylene chloride and distilled water. The extracted organic layer was washed with a saturated aqueous sodium chloride solution and dried over sodium sulfate. The residue left after removing the solvent was separated using column chromatography to obtain a target compound (6.9 g, 7.9 mmol).

### Synthesis of Compound 9

Intermediate 9-5 (6.9 g, 7.9 mmol), potassium tetrachloroplatinate (3.6 g, 8.7 mmol), and 2,6-lutidine (3.4 g, 32 mmol) were suspended in 1,2-dichlorobenzene (150 ml). The resultant reaction mixture was heated and stirred at 120° C. for 18 hours. After completion of the reaction, the resultant was cooled to room temperature, and then the residue left after removing the solvent was separated using column chromatography to obtain a target compound (3.3 g, 3.2 mmol).

### (2) Synthesis of Compound 29

Organometallic Compound 29 according to an embodiment may be synthesized by, for example, a process of Reaction Formula 2 below.

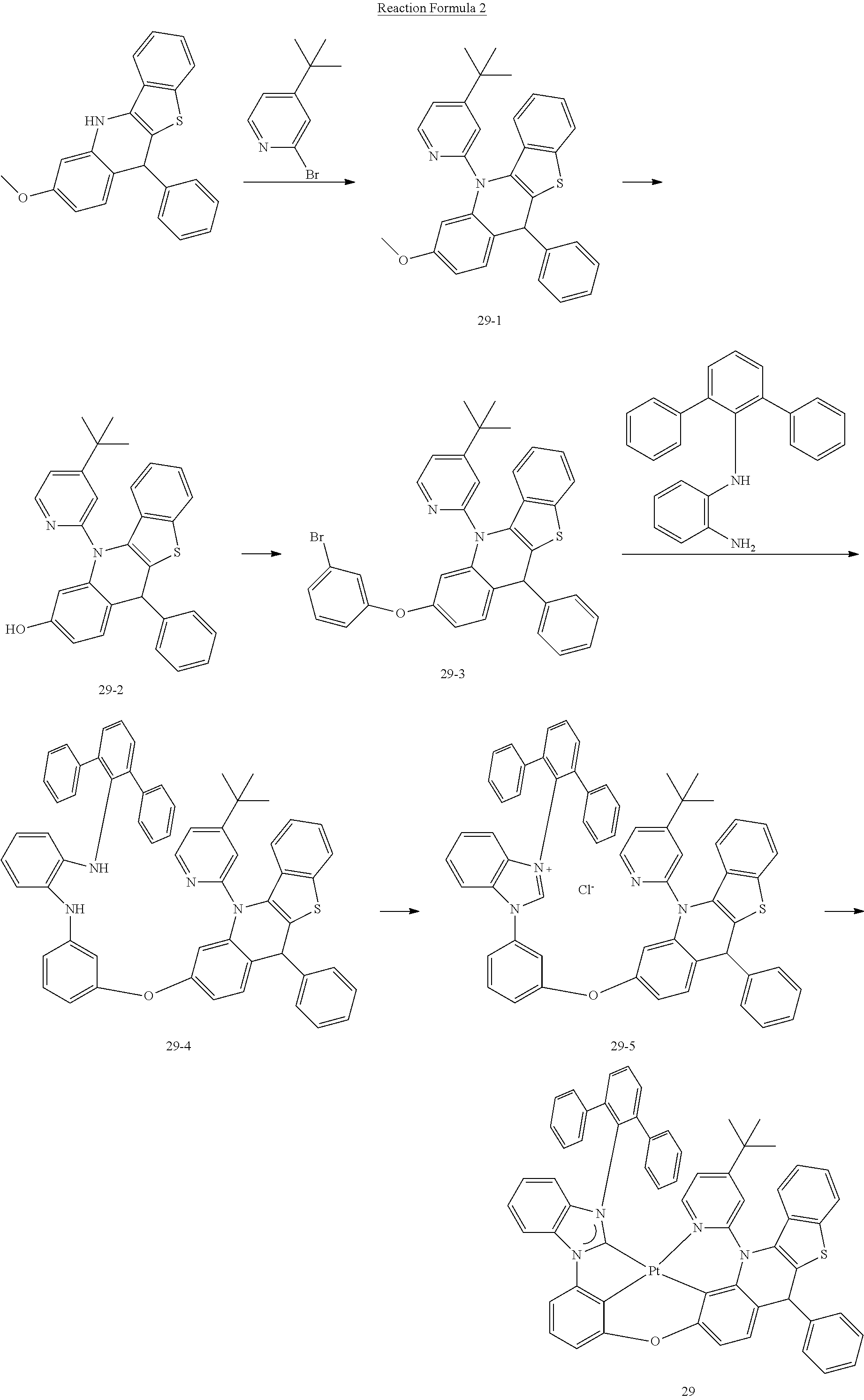

### Synthesis of Intermediate 29-1

3-methoxy-11-phenyl-5,11-dihydrobenzo[4,5]thieno[3,2,b]quinoline (6.2 g, 18 mmol), 2-bromo-4(tert-butyl)pyridine (5.8 g, 27 mmol), tripotassium (8.3 g, 36 mmol), CuI (0.66 g, 3.6 mmol), and picolinic acid (0.4 g, 3.6 mmol) were put into a reaction vessel and suspended in dimethyl sulfoxide (100 mL). The resultant reaction mixture was heated and stirred at 160° C. for 24 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (6.8 g, 14.2 mmol).

### Synthesis of Intermediate 29-2

Intermediate 29-1 (6.8 g, 14.2 mmol) was suspended in an excess of hydrobromic acid solution. The resultant reaction mixture was heated and stirred at 110° C. for 24 hours. After completion of the reaction, the mixture was cooled to room temperature, and neutralized by adding an appropriate amount of sodium hydrogen carbonate. Distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.2 g, 11.3 mmol).

### Synthesis of Intermediate 29-3

Intermediate 29-2 (5.2 g, 11.3 mmol), 1-bromo-3-fluorobenzene (3.0 g, 17 mmol), and tripotassium (5.3 g, 22.6 mmol) were put into a reaction vessel and suspended in dimethyl sulfoxide (100 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.7 g, 9.3 mmol).

### Synthesis of Intermediate 29-4

Intermediate 29-3 (5.7 g, 9.3 mmol), N1-([1,1′:3′,1″-terphenyl]-2′-nyl)benzene-1,2-diamine (3.1 g, 9.3 mmol), SPhos (0.70 mmol), Pd₂(dba)₃ (0.46 mmol), and sodium t-butoxide (18 mmol) were suspended in a toluene solvent (100 ml), and then the mixture was heated to 110° C. and stirred for 4 hours. After completion of the reaction, the solvent was removed under reduced pressure, and the mixture was extracted with methylene chloride and distilled water. The extracted organic layer was washed with a saturated aqueous sodium chloride solution and dried over sodium sulfate. The residue left after removing the solvent was separated using column chromatography to obtain a target compound (7.3 g, 8.4 mmol).

### Synthesis of Intermediate 29-5

Intermediate 29-4 (7.3 g, 8.4 mmol) was dissolved in triethyl orthoformate (420 mmol), and HCl (10 mmol) was added dropwise thereto. Thereafter, the resultant reaction mixture was stirred for 20 hours at a temperature raised to 80° C. After completion of the reaction, the solvent was removed under reduced pressure, and the mixture was extracted with methylene chloride and distilled water. The extracted organic layer was washed with a saturated aqueous sodium chloride solution and dried over sodium sulfate. The residue left after removing the solvent was separated using column chromatography to obtain a target compound (7.2 g, 7.8 mmol).

### Synthesis of Compound 29

Intermediate 29-5 (7.2 g, 7.8 mmol), potassium tetrachloroplatinate (3.6 g, 8.6 mmol), and 2,6-lutidine (3.4 g, 32 mmol) were suspended in 1,2-dichlorobenzene (150 ml). The resultant reaction mixture was heated and stirred at 120° C. for 18 hours. After completion of the reaction, the resultant was cooled to room temperature, and then the residue left after removing the solvent was separated using column chromatography to obtain a target compound (3.3 g, 3.1 mmol).

### (3) Synthesis of Compound 31

Organometallic Compound 31 according to an embodiment may be synthesized by, for example, a process of Reaction Formula 3 below.

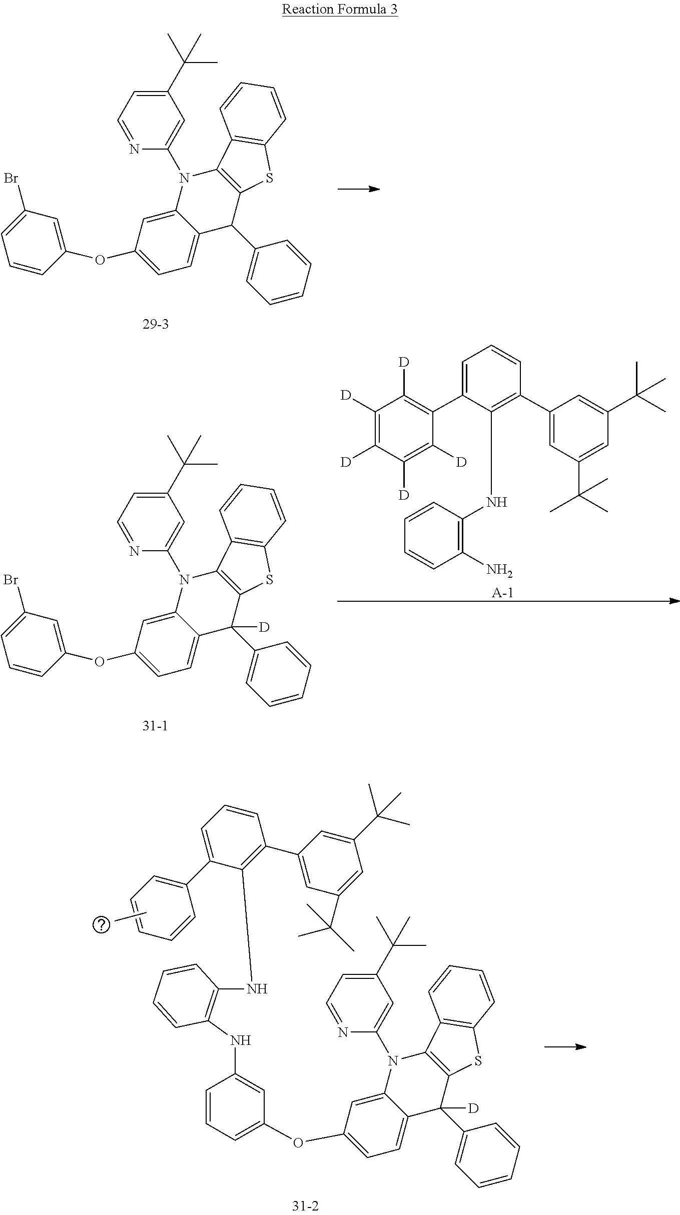

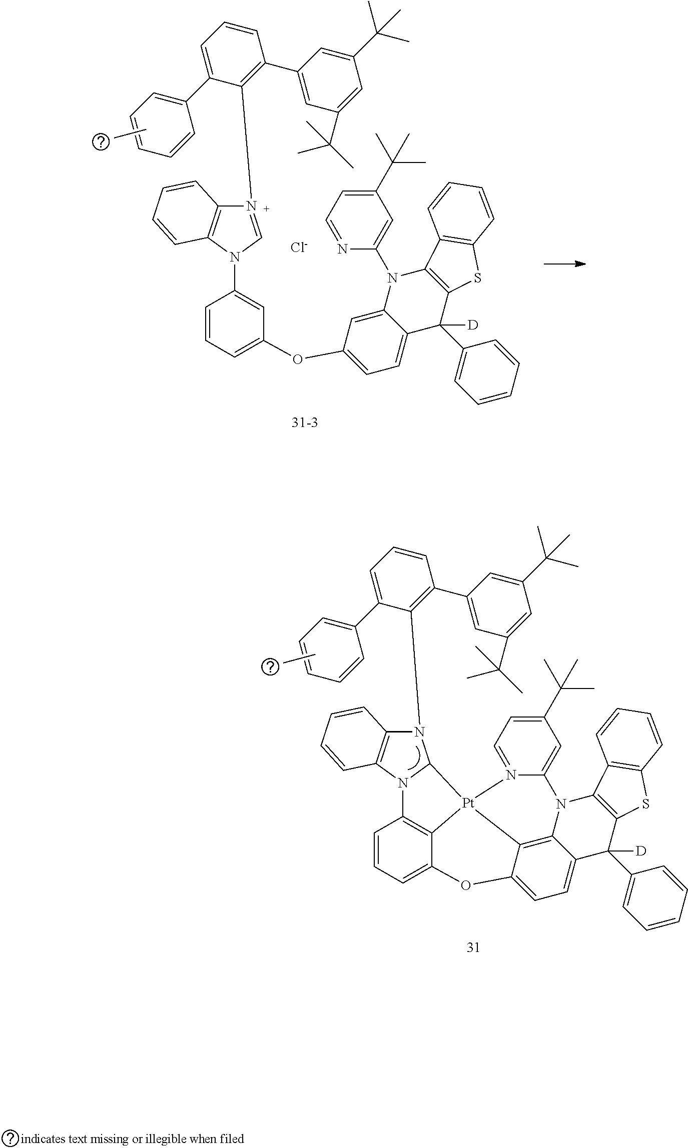

### Synthesis of Intermediate 31-1

Intermediate 29-3 (6.2 g, 10 mmol) and potassium tertbutoxide (0.23 g, 2.0 mmol) were put into a reaction vessel and suspended in dimethyl sulfoxide-D6 (200 mL). The resultant reaction mixture was heated and stirred at 80° C. for 6 hours. After completion of the reaction, the mixture was cooled to room temperature, distilled water (200 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.3 g, 8.6 mmol).

### Synthesis of Intermediate 31-2

Intermediate 31-1 (5.3 g, 8.6 mmol), Intermediate A-1 (3.9 g, 8.6 mmol), SPhos (0.65 mmol), Pd₂(dba)₃ (0.43 mmol), and sodium t-butoxide (16.7 mmol) were suspended in a toluene solvent (100 ml), and then the resultant reaction mixture was heated to 110° C. and stirred for 4 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (7.7 g, 7.8 mmol).

### Synthesis of Intermediate 31-3

Intermediate 31-2 (7.7 g, 7.8 mmol) was dissolved in triethyl orthoformate (390 mmol), and HCl (9.4 mmol) was added dropwise thereto. Thereafter, the resultant reaction mixture was stirred for 20 hours at a temperature raised to 80° C. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (7.4 g, 7.1 mmol).

### Synthesis of Compound 31

Intermediate 31-3 (7.4 g, 7.1 mmol), potassium tetrachloroplatinate (3.3 g, 7.8 mmol), and 2,6-lutidine (3.1 g, 29 mmol) were suspended in 1,2-dichlorobenzene (130 ml). The resultant reaction mixture was heated and stirred at 120° C. for 18 hours. After completion of the reaction, the resultant was cooled to room temperature, and then the residue left after removing the solvent was separated using column chromatography to obtain a target compound (3.5 g, 2.9 mmol).

### (4) Synthesis of Compound 38

Organometallic Compound 38 according to an embodiment may be synthesized by, for example, a process of Reaction Formula 4 below.

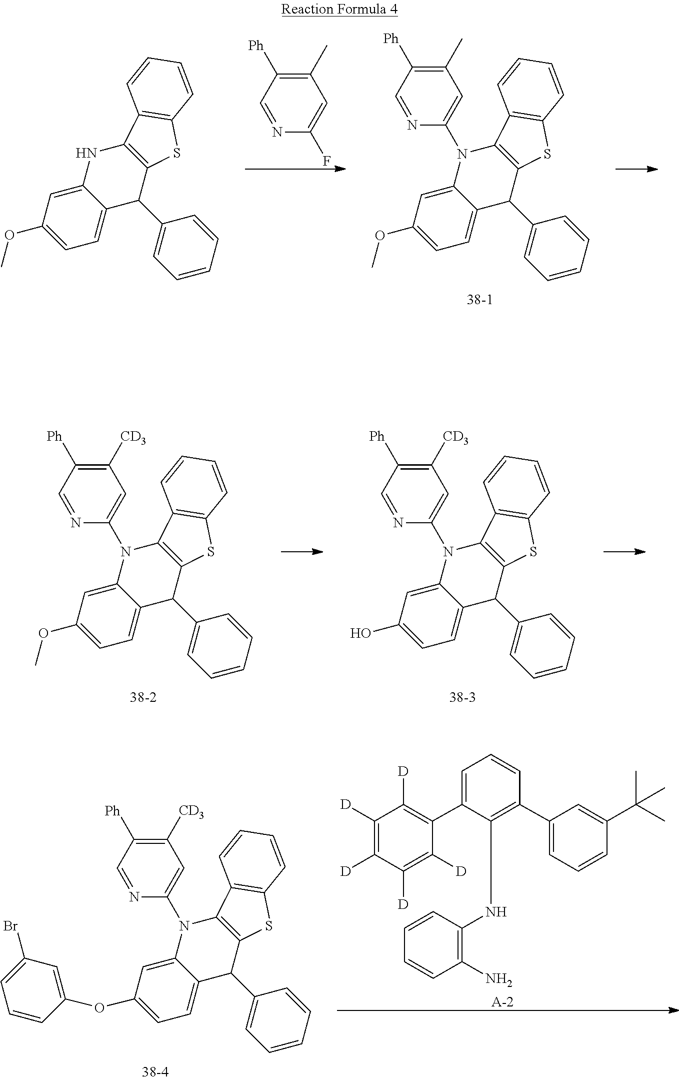

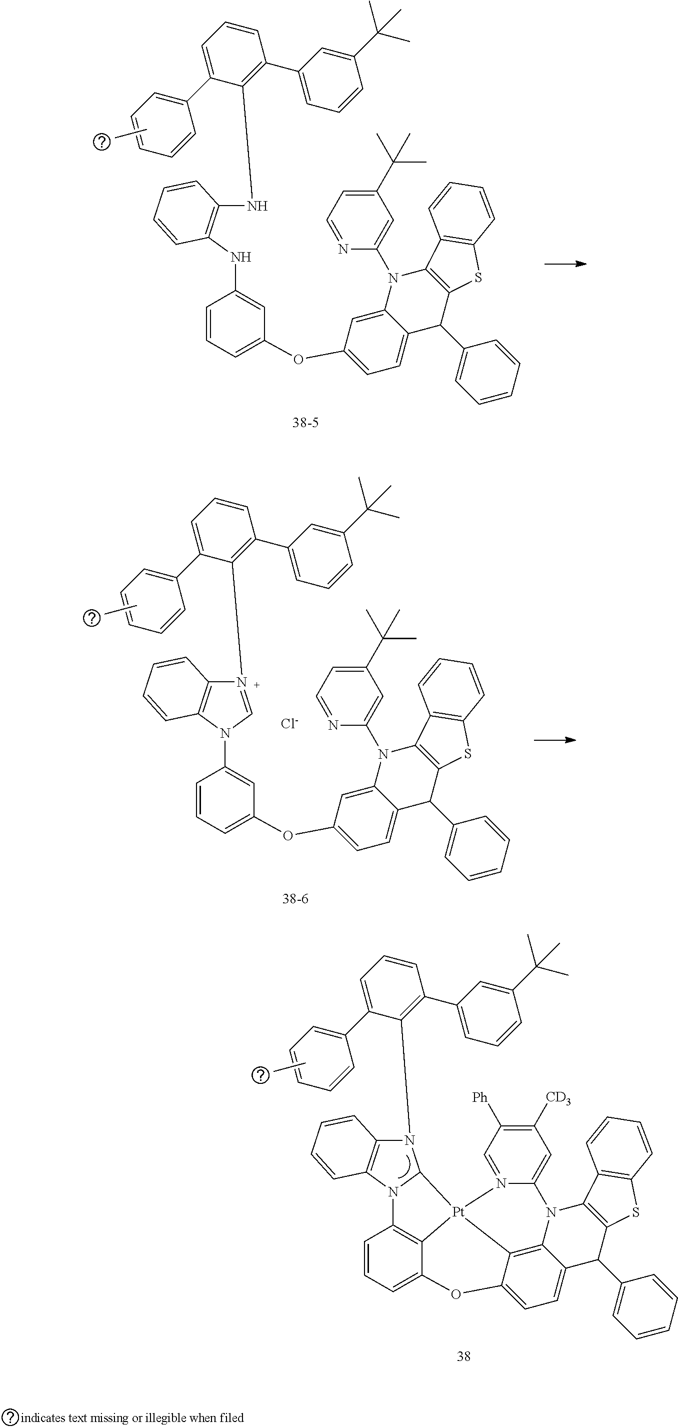

### Synthesis of Intermediate 38-1

3-methoxy-11-phenyl-5,11-dihydrobenzo[4,5]thieno[3,2,b]quinoline (6.2 g, 18 mmol), 2-fluoro-4-methyl-5-phenylpyridine (3.4 g, 18 mmol), and tripotassium (8.3 g, 36 mmol) were put into a reaction vessel and suspended in dimethyl sulfoxide (180 mL). The resultant reaction mixture was heated and stirred at 160° C. for 12 hours. After completion of the reaction, the mixture was cooled to room temperature, distilled water (200 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (7.7 g, 15.1 mmol).

### Synthesis of Intermediate 38-2

Intermediate 38-1 (7.7 g, 15.1 mmol) and potassium tertbutoxide (0.35 g, 3.0 mmol) were put into a reaction vessel and suspended in dimethyl sulfoxide-D6 (300 mL). The resultant reaction mixture was heated and stirred at 80° C. for 6 hours. After completion of the reaction, the mixture was cooled to room temperature, distilled water (200 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (6.8 g, 13.2 mmol).

### Synthesis of Intermediate 38-3

Intermediate 38-2 (6.8 g, 13.2 mmol) was put into a reaction vessel and suspended in dichloromethane (130 mL). The resultant reaction mixture was stirred at 0° C., and then boron tribromide was slowly added dropwise. The resultant reaction mixture was brought to room temperature and stirred for 2 hours, and then distilled water (200 mL) was added thereto and the mixture was extracted with dichloromethane. The extracted organic layer was washed with a saturated aqueous sodium chloride solution and dried over sodium sulfate. The residue left after removing the solvent was separated using column chromatography to obtain a target compound (4.4 g, 8.9 mmol).

### Synthesis of Intermediate 38-4

Intermediate 38-3 (4.4 g, 8.9 mmol), 1-bromo-3-fluorobenzene (2.4 g, 13 mmol), and tripotassium (4.2 g, 17.8 mmol) were put into a reaction vessel and suspended in dimethyl sulfoxide (90 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (4.4 g, 6.8 mmol).

### Synthesis of Intermediate 38-5

Intermediate 38-4 (4.4 g, 6.8 mmol), Intermediate A-2 (2.9 g, 6.8 mmol), SPhos (0.51 mmol), Pd₂(dba)₃ (0.34 mmol), and sodium t-butoxide (13 mmol) were suspended in a toluene solvent (70 ml), and then the resultant mixture was heated to 110° C. and stirred for 4 hours. After completion of the reaction, the solvent was removed under reduced pressure, and the mixture was extracted with methylene chloride and distilled water. The extracted organic layer was washed with a saturated aqueous sodium chloride solution and dried over sodium sulfate. The residue left after removing the solvent was separated using column chromatography to obtain a target compound (5.7 g, 6.1 mmol).

### Synthesis of Intermediate 38-6

Intermediate 38-5 (5.7 g, 6.1 mmol) was dissolved in triethyl orthoformate (305 mmol), and HCl (7.3 mmol) was added dropwise thereto. The resultant reaction mixture was heated to 80° C. and stirred for 20 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (5.5 g, 5.6 mmol).

### Synthesis of Compound 38

Intermediate 38-6 (5.5 g, 5.6 mmol), potassium tetrachloroplatinate (2.6 g, 6.2 mmol), and 2,6-lutidine (2.4 g, 23 mmol) were suspended in 1,2-dichlorobenzene (100 ml). The resultant reaction mixture was heated and stirred at 120° C. for 18 hours.

After completion of the reaction, the resultant was cooled to room temperature, and then the residue left after removing the solvent was separated using column chromatography to obtain a target compound (2.8 g, 2.4 mmol).

### (5) Synthesis of Compound 43

Organometallic Compound 43 according to an embodiment may be synthesized by, for example, a process of Reaction Formula 5 below.

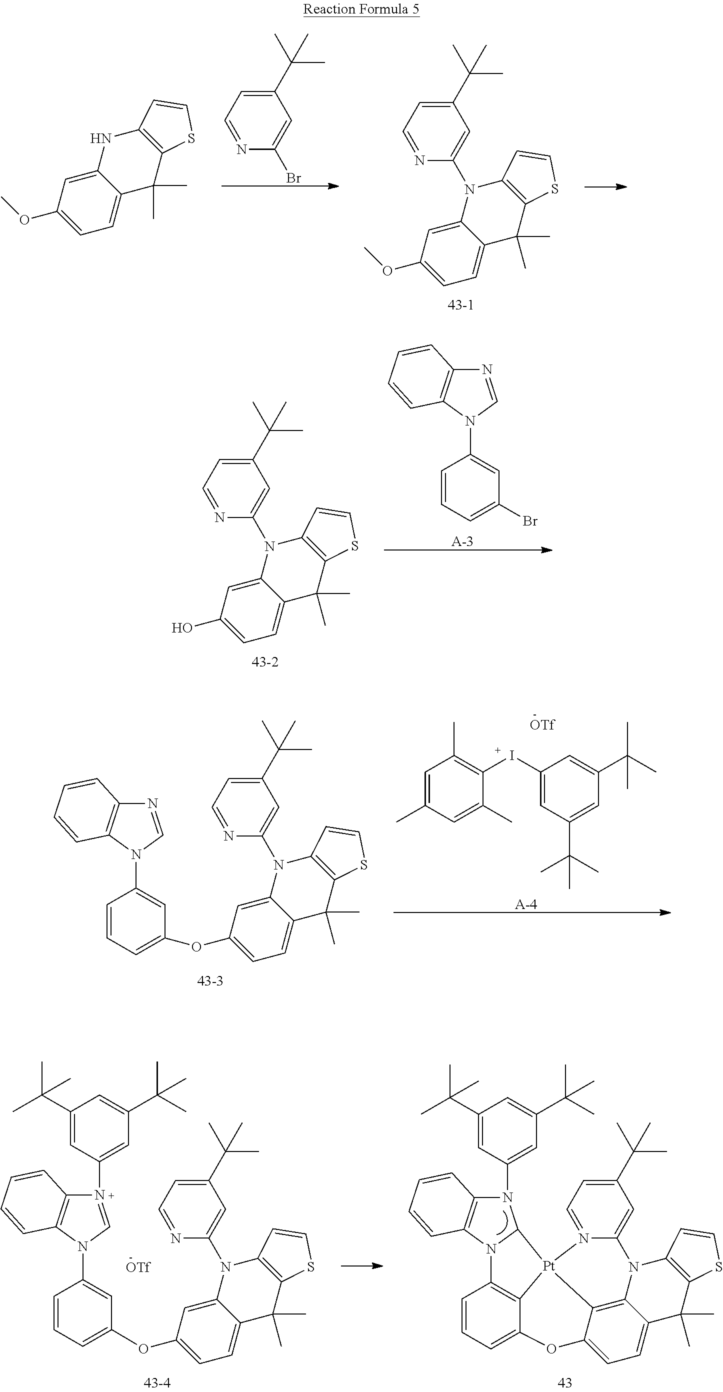

### Synthesis of Intermediate 43-1

6-methoxy-9,9-dimethyl-4,9-dihydrothieno[3,2,b]quinoline (4.4 g, 18 mmol), 2-bromo-4(tert-butyl)pyridine (5.8 g, 27 mmol), tripotassium (8.3 g, 36 mmol), CuI (0.66 g, 3.6 mmol), and picolinic acid (0.4 g, 3.6 mmol) were put into a reaction vessel and suspended in dimethyl sulfoxide (100 mL). The resultant reaction mixture was heated and stirred at 160° C. for 24 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.2 g, 13.8 mmol).

### Synthesis of Intermediate 43-2

Intermediate 43-1 (5.2 g, 13.8 mmol) was suspended in an excess of hydrobromic acid solution. The resultant reaction mixture was heated and stirred at 110° C. for 24 hours. After completion of the reaction, the mixture was cooled to room temperature, and neutralized by adding an appropriate amount of sodium hydrogen carbonate. Distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (4.3 g, 11.8 mmol).

### Synthesis of Intermediate 43-3

Intermediate 43-2 (4.3 g, 11.8 mmol), Intermediate A-3 (4.8 g, 17.7 mmol), tripotassium (5.5 g, 23.6 mmol), CuI (0.43 g, 0.14 mmol), and picolinic acid (0.02 g, 0.24 mmol) were put into a reaction vessel and suspended in dimethyl sulfoxide (80 mL). The resultant reaction mixture was heated and stirred at 160° C. for 20 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (4.7 g, 8.4 mmol).

### Synthesis of Intermediate 43-4

Intermediate 43-3 (4.7 g, 8.4 mmol), Intermediate A-4 (7.4 g, 12.6 mmol), and Cu(OAc)₂ (0.15 g, 0.84 mmol) were added to dimethylsulfoxide, and the resultant reaction mixture was heated and stirred at 150° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (4.6 g, 5.2 mmol).

### Synthesis of Compound 43

Intermediate 43-4 (4.6 g, 5.2 mmol), potassium tetrachloroplatinate (2.4 g, 5.8 mmol), and 2,6-lutidine (2.2 g, 21 mmol) were suspended in 1,2-dichlorobenzene (100 ml). The resultant reaction mixture was heated and stirred at 120° C. for 18 hours. After completion of the reaction, the resultant was cooled to room temperature, and then the residue left after removing the solvent was separated using column chromatography to obtain a target compound (2.2 g, 2.3 mmol).

### (6) Synthesis of Compound 45

Organometallic Compound 45 according to an embodiment may be synthesized by, for example, a process of Reaction Formula 6 below.

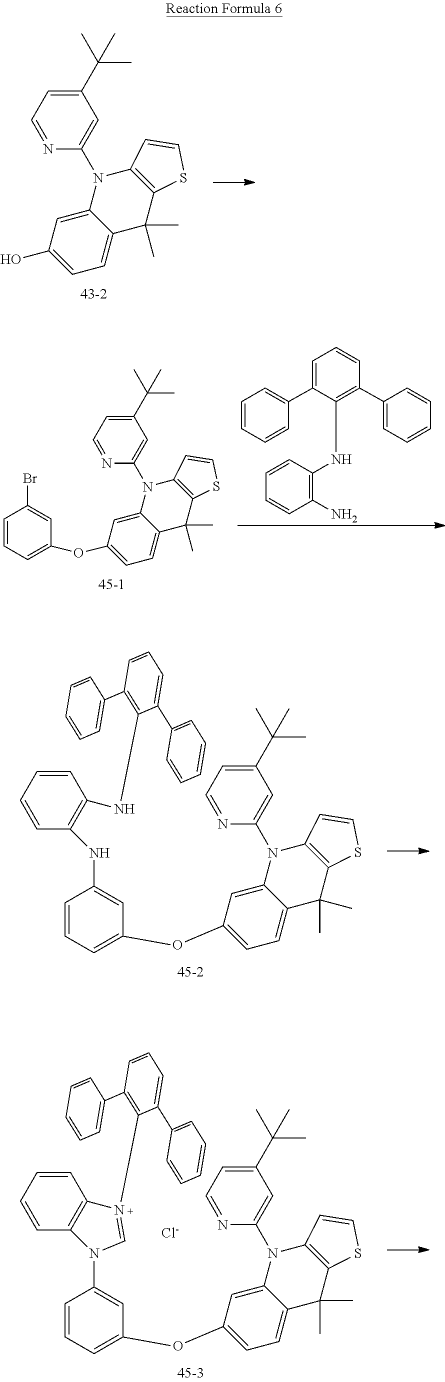

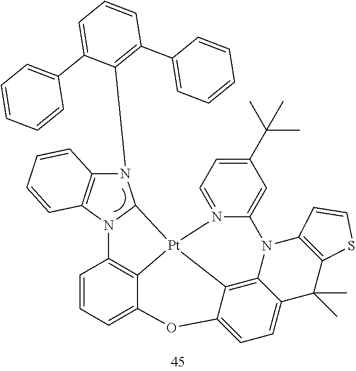

### Synthesis of Intermediate 45-1

Intermediate 43-2 (4.1 g, 11.3 mmol), 1-bromo-3-fluorobenzene (3.0 g, 17 mmol), and tripotassium (5.3 g, 22.6 mmol) were put into a reaction vessel and suspended in dimethyl sulfoxide (100 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (4.7 g, 9.0 mmol).

### Synthesis of Intermediate 45-2

Intermediate 45-1 (4.7 g, 9.0 mmol), N1-([1,1′:3′,1″-terphenyl]-2′-nyl)benzene-1,2-diamine (3.0 g, 9.0 mmol), SPhos (0.68 mmol), Pd₂(dba)₃ (0.45 mmol), and sodium t-butoxide (18 mmol) were suspended in a toluene solvent (100 ml), and then the resultant reaction mixture was heated to 110° C. and stirred for 4 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (6.0 g, 7.8 mmol).

### Synthesis of Intermediate 45-3

Intermediate 45-2 (6.0 g, 7.8 mmol) was dissolved in triethyl orthoformate (390 mmol), and HCl (9.4 mmol) was added dropwise thereto. Thereafter, the resultant reaction mixture was heated to 80° C. and stirred for 20 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (5.8 g, 7.0 mmol).

### Synthesis of Compound 45

Intermediate 45-3 (5.8 g, 7.0 mmol), potassium tetrachloroplatinate (3.2 g, 7.7 mmol), and 2,6-lutidine (3.0 g, 28.7 mmol) were suspended in 1,2-dichlorobenzene (140 ml). The resultant reaction mixture was heated and stirred at 120° C. for 18 hours. After completion of the reaction, the resultant was cooled to room temperature, and then the residue left after removing the solvent was separated using column chromatography to obtain a target compound (2.8 g, 2.9 mmol).

### (7) Synthesis of Compound 53

Organometallic Compound 53 according to an embodiment may be synthesized by, for example, a process of Reaction Formula 7 below.

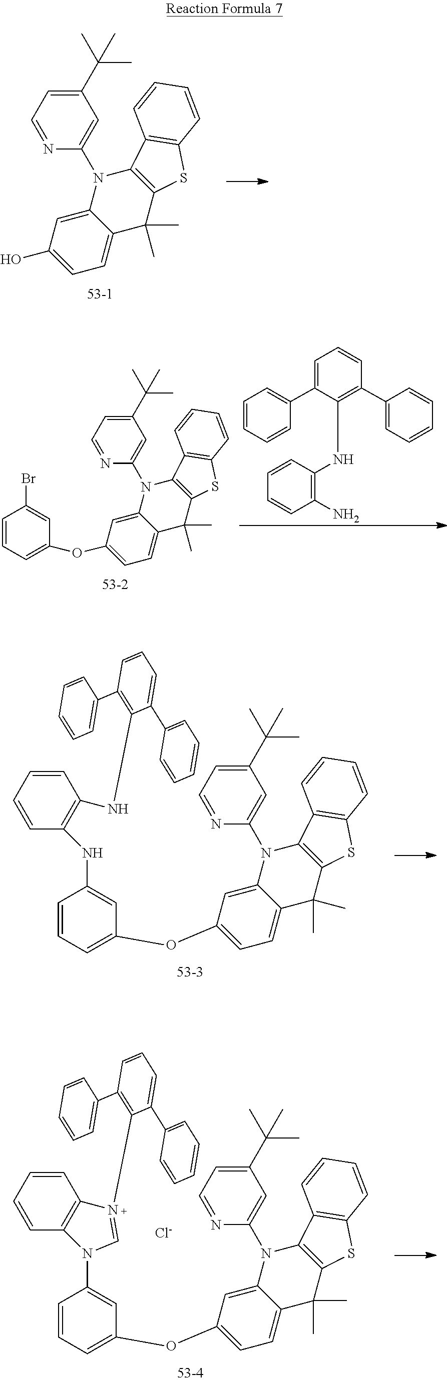

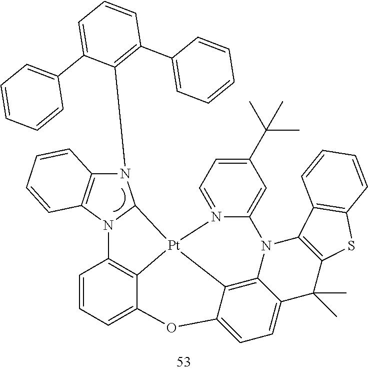

### Synthesis of Intermediate 53-2

Intermediate 53-1 (4.7 g, 11.3 mmol), 1-bromo-3-fluorobenzene (3.0 g, 17 mmol), and tripotassium (5.3 g, 22.6 mmol) were put into a reaction vessel and suspended in dimethyl sulfoxide (100 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.2 g, 9.2 mmol).

### Synthesis of Intermediate 53-3

Intermediate 53-2 (5.2 g, 9.2 mmol), N1-([1,1′:3′,1″-terphenyl]-2′-nyl)benzene-1,2-diamine (3.1 g, 9.2 mmol), SPhos (0.69 mmol), Pd₂(dba)₃ (0.46 mmol), and sodium t-butoxide (18 mmol) were suspended in a toluene solvent (100 ml), and then the resultant reaction mixture was heated to 110° C. and stirred for 4 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (6.5 g, 7.9 mmol).

### Synthesis of Intermediate 53-4

Intermediate 53-3 (6.5 g, 7.9 mmol) was dissolved in triethyl orthoformate (395 mmol), and HCl (9.4 mmol) was added dropwise thereto. The resultant reaction mixture was stirred for 20 hours at a temperature raised to 80° C. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (5.9 g, 6.8 mmol).

### Synthesis of Compound 53

Intermediate 53-4 (5.9 g, 6.8 mmol), potassium tetrachloroplatinate (3.1 g, 7.5 mmol), and 2,6-lutidine (2.9 g, 27.9 mmol) were suspended in 1,2-dichlorobenzene (140 ml). The resultant reaction mixture was heated and stirred at 120° C. for 18 hours. After completion of the reaction, the resultant was cooled to room temperature, and then the residue left after removing the solvent was separated using column chromatography to obtain a target compound (2.9 g, 2.8 mmol).

### (8) Synthesis of Compound 60

Organometallic Compound 60 according to an embodiment may be synthesized by, for example, a process of Reaction Formula 8 below.

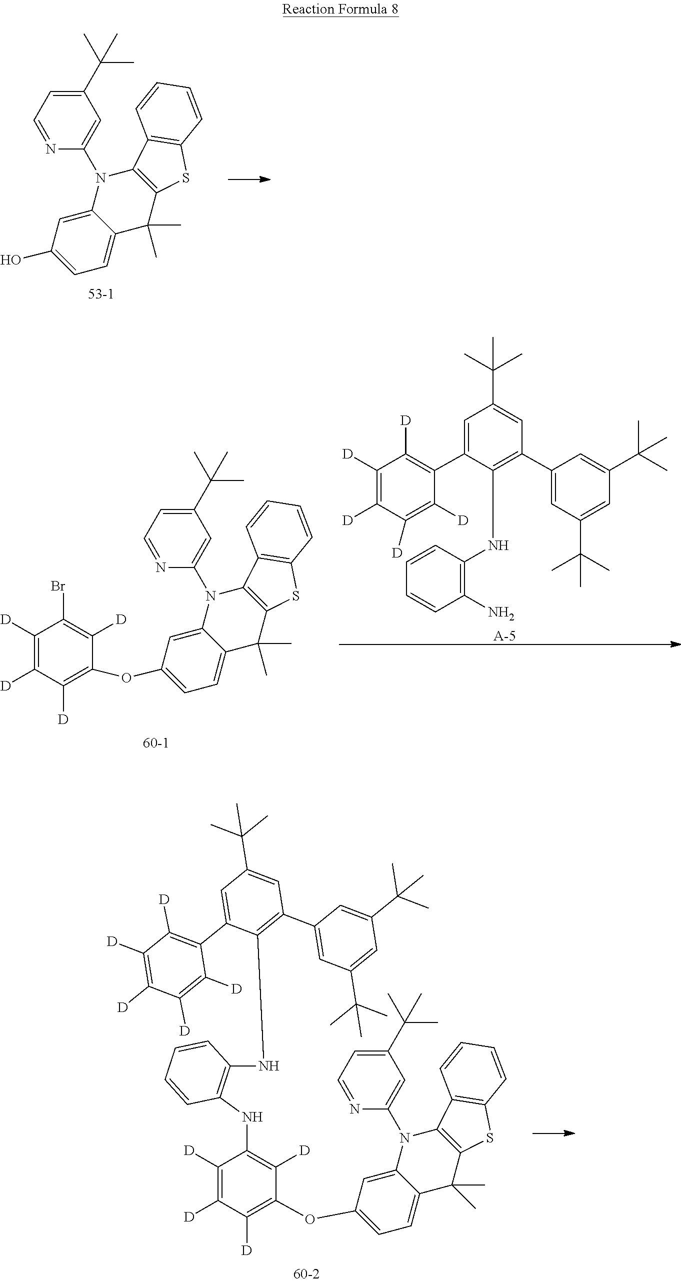

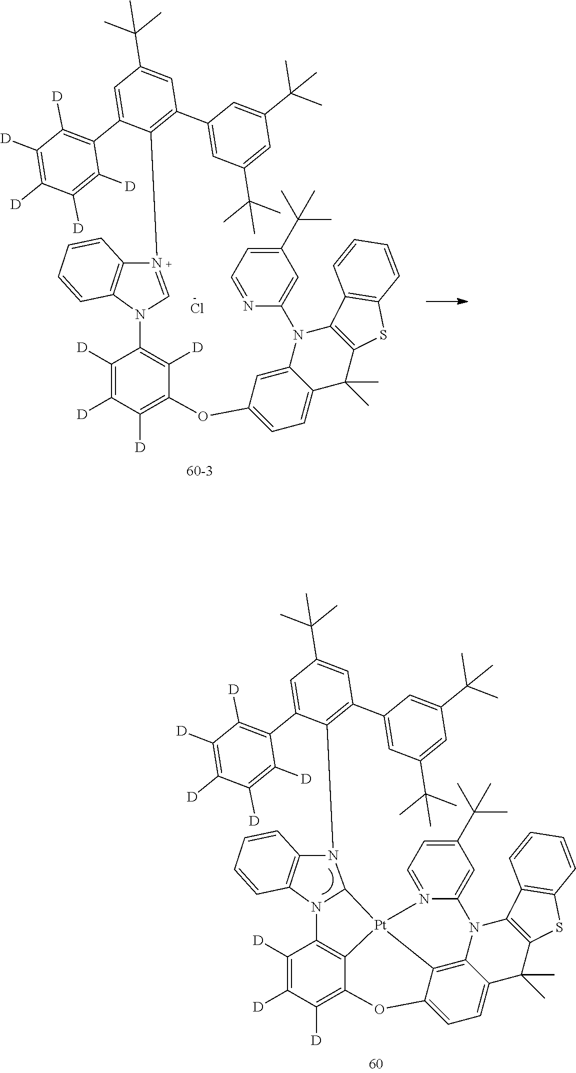

### Synthesis of Intermediate 60-1

Intermediate 53-1 (4.7 g, 11.3 mmol), 1-bromo-3-fluorobenzene-2,4,5,6-di4 (3.0 g, 17 mmol), and tripotassium (5.3 g, 22.6 mmol) were put into a reaction vessel and suspended in dimethyl sulfoxide (100 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.2 g, 9.0 mmol).

### Synthesis of Intermediate 60-2

Intermediate 60-1 (5.2 g, 9.0 mmol), Intermediate A-5 (4.6 g, 9.0 mmol), SPhos (0.68 mmol), Pd₂(dba)₃ (0.45 mmol), and sodium t-butoxide (18 mmol) were suspended in a toluene solvent (100 ml), and then the resultant reaction mixture was heated to 110° C. and stirred for 4 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (8.0 g, 8.0 mmol).

### Synthesis of Intermediate 60-3

Intermediate 60-2 (8.0 g, 8.0 mmol) was dissolved in triethyl orthoformate (400 mmol), and HCl (9.5 mmol) was added dropwise thereto. Thereafter, the resultant reaction mixture was heated to 80° C. and stirred for 20 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (7.6 g, 7.2 mmol).

### Synthesis of Compound 60

Intermediate 60-3 (7.6 g, 7.2 mmol), potassium tetrachloroplatinate (3.3 g, 7.9 mmol), and 2,6-lutidine (3.1 g, 29.5 mmol) were suspended in 1,2-dichlorobenzene (140 ml). The resultant reaction mixture was heated and stirred at 120° C. for 18 hours. After completion of the reaction, the resultant was cooled to room temperature, and then the residue left after removing the solvent was separated using column chromatography to obtain a target compound (3.7 g, 3.1 mmol).

### (9) Synthesis of Compound 73

Organometallic Compound 73 according to an embodiment may be synthesized by, for example, a process of Reaction Formula 9 below.

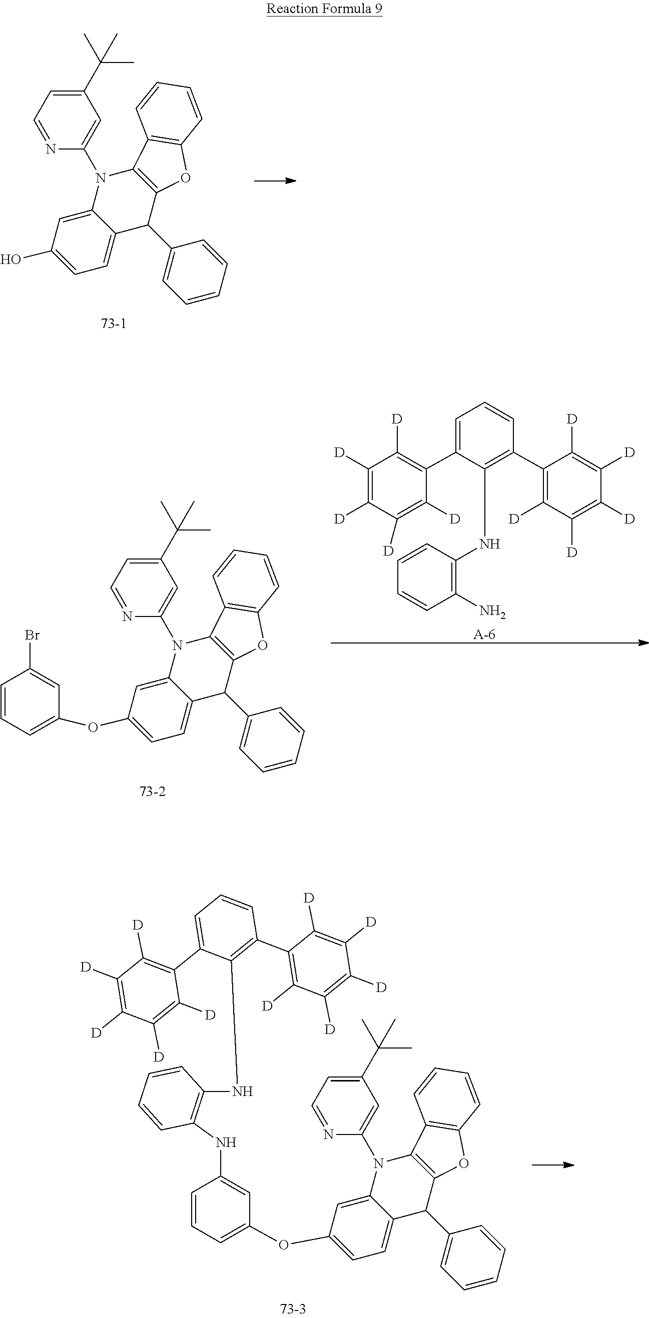

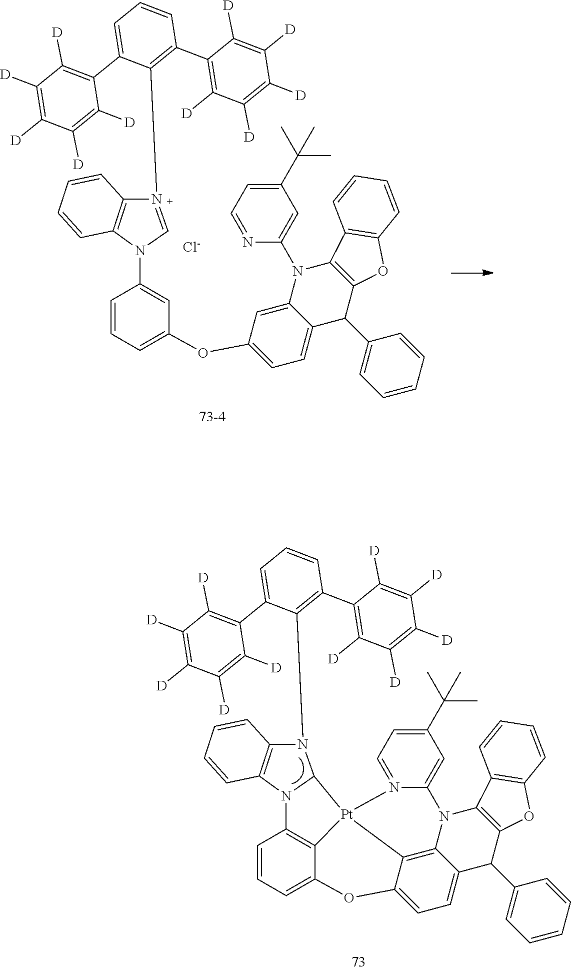

### Synthesis of Intermediate 73-2

Intermediate 73-1 (5.0 g, 11.3 mmol), 1-bromo-3-fluorobenzene (3.0 g, 17 mmol), and tripotassium (5.3 g, 22.6 mmol) were put into a reaction vessel and suspended in dimethyl sulfoxide (100 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (5.1 g, 8.5 mmol).

### Synthesis of Intermediate 73-3

Intermediate 73-2 (5.1 g, 8.5 mmol), Intermediate A-6 (2.9 g, 8.5 mmol), SPhos (0.64 mmol), Pd₂(dba)₃ (0.42 mmol), and sodium t-butoxide (17 mmol) were suspended in a toluene solvent (100 ml), and then the resultant reaction mixture was heated to 110° C. and stirred for 4 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (6.6 g, 7.6 mmol).

### Synthesis of Intermediate 73-4

Intermediate 73-3 (6.6 g, 7.6 mmol) was dissolved in triethyl orthoformate (380 mmol), and HCl (9.0 mmol) was added dropwise thereto. Thereafter, the resultant reaction mixture was heated to 80° C. and stirred for 20 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (6.4 g, 7.0 mmol).

### Synthesis of Compound 73

Intermediate 73-4 (6.4 g, 7.0 mmol), potassium tetrachloroplatinate (3.2 g, 7.7 mmol), and 2,6-lutidine (3.0 g, 28.7 mmol) were suspended in 1,2-dichlorobenzene (140 ml). Thereafter, the resultant reaction mixture was heated and stirred at 120° C. for 18 hours. After completion of the reaction, the resultant was cooled to room temperature, and then the residue left after removing the solvent was separated using column chromatography to obtain a target compound (3.2 g, 3.0 mmol).

### (10) Synthesis of Compound 81

Organometallic Compound 81 according to an embodiment may be synthesized by, for example, a process of Reaction Formula 10 below.

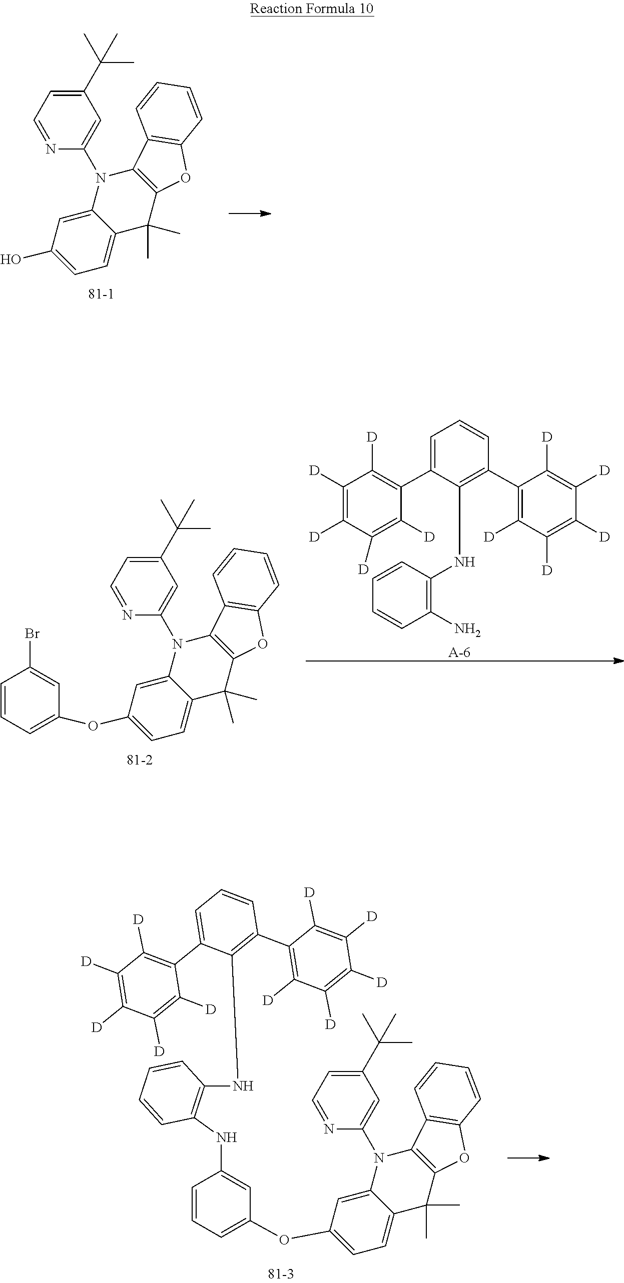

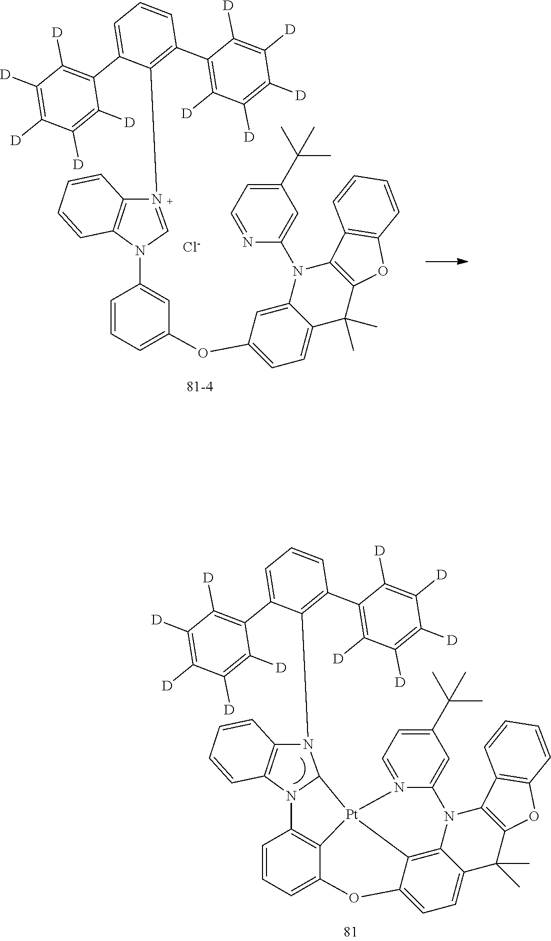

### Synthesis of Intermediate 81-2

Intermediate 81-1 (4.5 g, 11.3 mmol), 1-bromo-3-fluorobenzene (3.0 g, 17 mmol), and tripotassium (5.3 g, 22.6 mmol) were put into a reaction vessel and suspended in dimethyl sulfoxide (100 mL). The resultant reaction mixture was heated and stirred at 160° C. for 12 hours. After completion of the reaction, the mixture was cooled to room temperature, distilled water (100 mL) was added thereto, and then the resultant mixture was extracted with ethyl acetate. The extracted organic layer was washed with a saturated aqueous sodium chloride solution and dried over sodium sulfate. The residue left after removing the solvent was separated using column chromatography to obtain a target compound (4.5 g, 8.2 mmol).

### Synthesis of Intermediate 81-3

Intermediate 81-2 (4.5 g, 8.2 mmol), Intermediate A-6 (2.8 g, 8.2 mmol), SPhos (0.62 mmol), Pd₂(dba)₃ (0.41 mmol), and sodium t-butoxide (16.4 mmol) were suspended in a toluene solvent (100 ml), and then the resultant reaction mixture was heated to 110° C. and stirred for 4 hours. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (5.8 g, 7.1 mmol).

### Synthesis of Intermediate 81-4

Intermediate 81-3 (5.8 g, 7.1 mmol) was dissolved in triethyl orthoformate (350 mmol), and HCl (8.4 mmol) was added dropwise thereto. Thereafter, the resultant reaction mixture was stirred for 20 hours at a temperature raised to 80° C. After completion of the reaction, the solvent was removed under reduced pressure, and the resultant mixture was extracted with methylene chloride and distilled water. The extracted organic layer was washed with a saturated aqueous sodium chloride solution and dried over sodium sulfate. The residue left after removing the solvent was separated using column chromatography to obtain a target compound (5.6 g, 6.5 mmol).

### Synthesis of Compound 81

Intermediate 81-4 (5.6 g, 6.5 mmol), potassium tetrachloroplatinate (3.0 g, 7.2 mmol), and 2,6-lutidine (2.8 g, 26.4 mmol) were suspended in 1,2-dichlorobenzene (130 ml). The resultant reaction mixture was heated and stirred at 120° C. for 18 hours. After completion of the reaction, the resultant was cooled to room temperature, and then the residue left after removing the solvent was separated using column chromatography to obtain a target compound (2.7 g, 2.6 mmol).

### 2. Determination of Organometallic Compound

The ¹H-NMR and MS/FAB analysis results of the compounds synthesized as synthesis examples of the organometallic compounds described above are shown in Table 1 below. Methods for synthesizing compounds other than those synthesized in the synthesis examples described with reference to Reaction Formulas 1 to 10 may be easily modified and applied by referring to the above-described synthesis routes and raw materials.

TABLE 1

| Compound | | MS/FAB | |
|---|---|---|---|
| No. | ¹H-NMR (CDCI₃, 500 MHz) | calc. | Found |
| 9 | δ 8.20(d, 2H), 8.12(d, 1H), 7.95(d, 1H), 7.43- | 1025.2727 | 1025.2730 |
| | 7.30(m, 9H), 7.21-7.08(m, 12H), 6.95-6.90(m, | | |
| | 3H), 6.67-6.65(m, 3H), 6.52(d, 1H), 5.34(s, | | |
| | 1H), 1.30(s, 9H) | | |
| 29 | δ 8.20(d, 2H), 8.15-8.13(m, 2H), 7.93(d, 1H), | 1075.2884 | 1075.2889 |
| | 7.49-7.30(m, 11H), 7.21-7.08(m, 11H), 6.95- | | |
| | 6.90(m, 3H), 6.67-6.65(m, 3H), 6.53(d, 1H), | | |
| | 5.34(s, 1H), 1.30(s, 9H) | | |
| 31 | δ 8.20(d, 2H), 8.15-8.13(m, 2H), 7.93(d, 1H), | 1193.4512 | 1193.4507 |
| | 7.68(d, 2H), 7.49-7.39(m, 4H), 7.29-7.14(m, | | |
| | 9H), 6.95-6.90(m, 3H), 6.67-6.65(m, 3H), | | |
| | 6.52(d, 1H), 1.29(s, 9H), 1.25(s, 18H) | | |
| 38 | δ 8.45(d, 1H), 8.20(d, 2H), 8.07(d, 1H), 7.93- | 1173.3855 | 1173.3849 |
| | 7.92(m, 2H), 7.51-7.10(m, 20H), 6.95-6.90(m, | | |
| | 3H), 6.71-6.65(m, 3H), 5.34(s, 1H), 1.41(s, | | |
| | 9H) | | |
| 43 | δ 8.12(d, 1H), 7.98(d, 1H), 7.21-7.14(m, 8H), | 937.3353 | 937.3358 |
| | 6.95-6.90(m, 3H), 6.67-6.65(m, 3H), 6.52(d, | | |
| | 1H), 1.72(s, 6H), 1.39(s, 18H), 1.31(s, 9H) | | |
| 45 | δ 8.20(d, 2H), 8.12(d, 1H), 7.98(d, 1H), 7.43- | 977.2727 | 977.2730 |
| | 7.35(m, 7H), 7.19-7.08(m, 9H), 6.95-6.90(m, | | |
| | 3H), 6.67-6.65(m, 3H), 6.52(d, 1H), 1.72(s, | | |
| | 6H), 1.31(s, 9H) | | |
| 53 | δ 8.20(d, 2H), 8.15-8.13(m, 2H), 7.93(d, 1H), | 1027.2884 | 1027.2881 |
| | 7.49-7.36(m, 9H), 7.17-7.08(m, 8H), 6.95- | | |
| | 6.90(m, 3H), 6.67-6.65(m, 3H), 6.53(d, 1H), | | |
| | 1.72(s, 6H), 1.31(s, 9H) | | |
| 60 | δ 8.12-8.07(m, 2H), 7.99(d, 2H), 7.93(d, 1H), | 1203.5264 | 1203.5258 |
| | 7.68(d, 2H), 7.49-7.39(m, 3H), 7.14-7.10(m, | | |
| | 3H), 6.95-6.94(m, 2H), 6.67-6.65(m, 2H), | | |
| | 6.07(d, 1H), 1.72(s, 6H), 1.32(s, 9H), 1.30(s, | | |
| | 18H), 1.29(s, 9H) | | |
| 73 | δ 8.20(d, 2H), 8.12(d, 1H), 7.84(d, 1H), | 1069.3740 | 1069.3745 |
| | 7.59(d, 1H), 7.39-7.30(m, 5H), 7.21-7.14(m, | | |
| | 7H), 6.95-6.90(m, 3H), 6.67-6.65(m, 3H), | | |
| | 6.52(d, 1H), 5.57(s, 1H), 1.31(s, 9H) | | |
| 81 | δ 8.20(d, 2H), 8.12(d, 1H), 7.84(d, 1H), | 1021.3740 | 1021.3735 |
| | 7.59(d, 1H), 7.39-7.31(m, 3H), 7.17-7.10(m, | | |
| | 4H), 6.95-6.90(m, 3H), 6.67-6.65(m, 3H), | | |
| | 6.52(d, 1H), 1.72(s, 6H), 1.30(s, 9H) | | |

### 3. Evaluation of Organometallic Compound

Table 2 below shows organometallic compounds used in Examples and Comparative Examples.

TABLE 2

| Item | Compound |
|---|---|
| Ex- am- ple 1 | 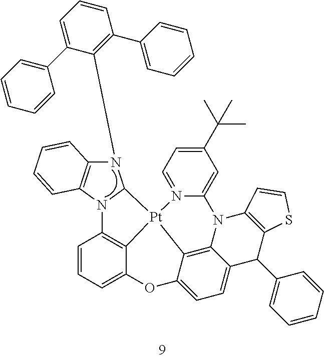 |
| Ex- am- ple 2 | 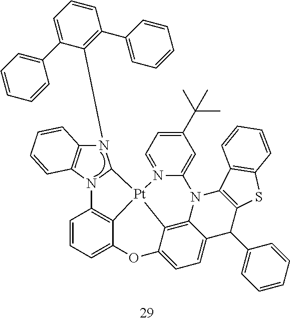 |
| Ex- am- ple 3 | 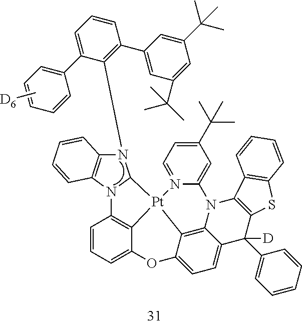 |
| Ex- am- ple 4 | 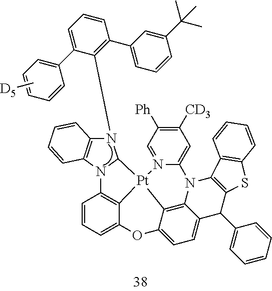 |
| Ex- am- ple 5 | 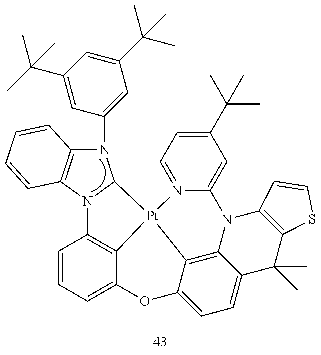 |
| Ex- am- ple 6 | 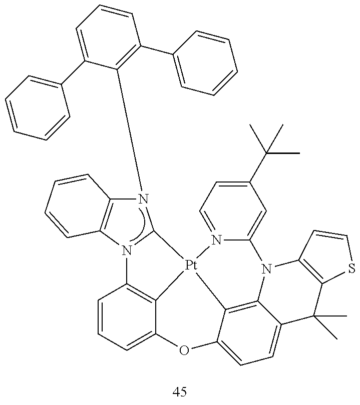 |
| Ex- am- ple 7 | 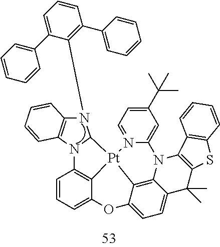 |
| Ex- am- ple 8 | 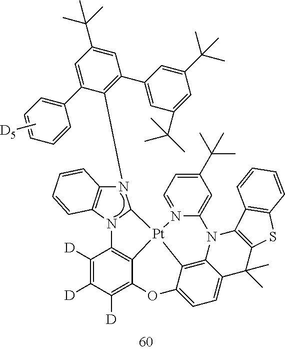 |
| Ex- am- ple 9 | 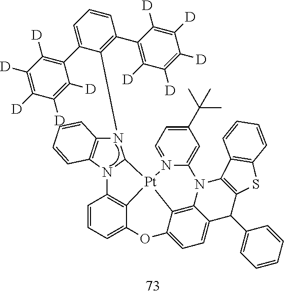 |
| Ex- am- ple 10 | 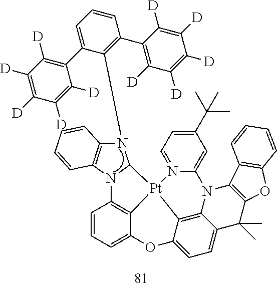 |
| Com- para- tive Ex- am- ple 1 | 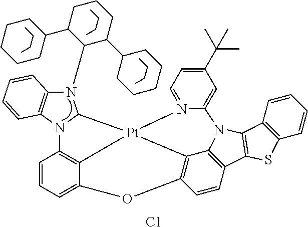 |
| Com- para- tive Ex- am- ple 2 | 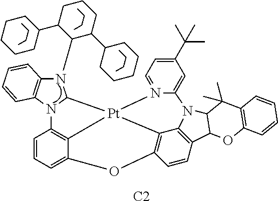 |
| Com- para- tive Ex- am- ple 3 | 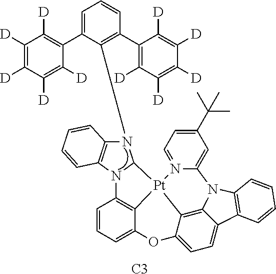 |
| Com- para- tive Ex- am- ple 4 | 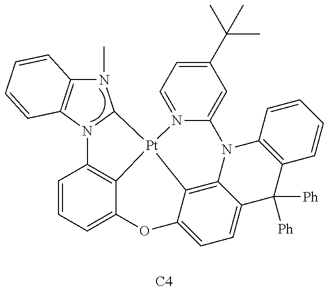 |

Table 3 below shows the results of evaluating the material properties of the organometallic compounds used in Examples and Comparative Examples. The HOMO energy level (eV), LUMO energy level (eV), actual maximum emission wavelength (λₘₐₓ^{exp}), and presence ratio (%) of triplet metal-to-ligand charge transfer state (³MLCT) of the above compounds 9, 29, 31, 38, 43, 45, 53, 60, 73, and 81 and Comparative compounds C1, C2, C3, and C4 were evaluated using a density functional theory (DFT) method of the Gaussian09 program with structure optimization at the B3LYP/6-311 g(d,p)/LANL2DZ level (e.g., using the B3LYP hybrid functional and 6-311 g(d,p) and LANL2DZ mixed basis set).

TABLE 3

| | HOMO | LUMO | | |
|---|---|---|---|---|
| Item | (eV) | (eV) | λₘₐₓ^{exp}(nm) | ³MLCT(%) |
| Example 1 | −5.04 | −1.43 | 449 | 11.95 |
| Example 2 | −5.05 | −1.44 | 450 | 12.29 |
| Example 3 | −5.05 | −1.40 | 449 | 12.37 |
| Example 4 | −5.04 | −1.39 | 448 | 12.01 |
| Example 5 | −5.02 | −1.42 | 452 | 11.76 |
| Example 6 | −5.01 | −1.40 | 448 | 11.82 |
| Example 7 | −5.02 | −1.41 | 451 | 11.13 |
| Example 8 | −5.03 | −1.40 | 450 | 12.08 |
| Example 9 | −5.07 | −1.46 | 448 | 13.55 |
| Example 10 | −5.03 | −1.44 | 448 | 12.82 |
| Comparative | −4.83 | −1.5 | 533 | 7.89 |
| Example 1 | | | | |
| Comparative | −4.81 | −1.43 | 523 | 6.88 |
| Example 2 | | | | |
| Comparative | −4.88 | −1.50 | 457 | 12.90 |
| Example 3 | | | | |
| Comparative | −4.97 | −1.48 | 454 | 11.76 |
| Example 4 | | | | |

Referring to the results in Table 3, the Example compounds showed a smaller HOMO energy level value than the Comparative Example compounds. In addition, the Example compounds showed a relatively shorter central emission wavelength than the Comparative Example compounds. That is, it was determined that the Example compounds emit deep blue light, which is blue light in the short wavelength range, compared to the Comparative Example compounds. In addition, it was assumed that the Example compounds may exhibit a relatively higher luminous efficiency than the compounds of Comparative Examples 1 and 2 based on the fact that the Example compounds have a higher ³MLCT ratio than the compounds of Comparative Examples 1 and 2.

Meanwhile, the compounds of Comparative Examples 3 and 4 have a high ³MLCT ratio similar to that of the Example compounds, but the Example compounds have a smaller HOMO energy level (deep energy level) than Comparative Examples 3 and 4, and may thus have low driving voltage characteristics.

### 4. Preparation and Evaluation of Light Emitting Element

### (1) Preparation of Light Emitting Element

Light emitting elements containing organometallic compounds according to an embodiment or the Comparative Example compounds were prepared through a process below. The organometallic compounds of an example were each used as a dopant material for an emission layer to manufacture light emitting elements of Examples 1 to 10. Light emitting elements of Comparative Examples 3 and 4 were prepared using Comparative Example compounds C3 and C4 as dopant materials for emission layers.

As a first electrode, a glass substrate having an ITO electrode (Corning, 15 Ω/cm², 1200 Å) formed thereon was cut to a size of about 50 mm×50 mm×0.7 mm, subjected to ultrasonic cleaning using isopropyl alcohol and pure water each for 5 minutes and ultraviolet irradiation for 30 minutes, and then exposed to ozone for cleaning to be mounted on a vacuum deposition apparatus.

The first electrode was vacuum deposited with T-TNATA to form a hole injection layer having a thickness of 600 Å, and the hole injection layer was vacuum deposited with 4,4′-bis[N-(1-naphthyl)-N-phenyl aminobiphenyl] (hereinafter referred to as NPB) to form a hole transport layer having a thickness of 300 Å.

The hole transport was vacuum deposited layer with the Example compounds or the Comparative Example compounds (first compound), compound ETH2 (second compound), and compound HT33 (third compound) to form an emission layer having a thickness of 400 Å. In this case, the Examples or the Comparative Example compounds were in an amount of 10 wt % with respect to a total weight (100 wt %) of the emission layer, and the compound ETH2 and the compound HT33 were regulated to have a weight ratio of 3:7.

The emission layer was vacuum deposited with ETH2 to form a hole blocking layer having a thickness of 50 Å. Then, the hole blocking layer was vacuum deposited with CNNPTRZ and LiQ (lithium quinolate) at a weight ratio of 1:1 to form an electron transport layer having a thickness of 300 Å. Thereafter, the top of the electron transport layer was vacuum deposited with Yb to form an electron injection layer having a thickness of 10 Å, and the electron injection layer was vacuum deposited with Mg to form a second electrode having a thickness of 800 Å to prepare a light emitting element.

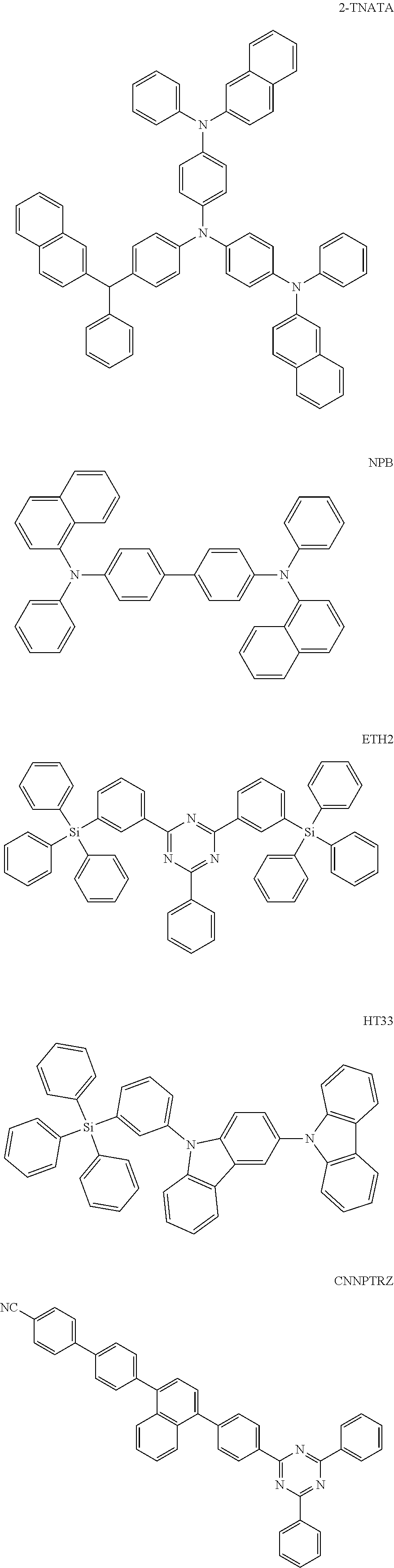 [SMILES: c1ccc(C(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc([Si](c2ccccc2)(c2ccccc2)c2cccc(-n3c4ccccc4c4cc(-n5c6ccccc6c6ccccc65)ccc43)c2)cc1 ; N#Cc1ccc(-c2ccc(-c3ccc(-c4ccc(-c5nc(-c6ccccc6)nc(-c6ccccc6)n5)cc4)c4ccccc34)cc2)cc1]

### (2) Evaluation of Light Emitting Element

Table 4 below shows evaluation results of the light emitting elements of the Examples and the Comparative Examples. In the light emitting elements of the Examples and the Comparative Examples, the driving voltage (V) at luminance of 1000 cd/cm², CIE color coordinate, luminous efficiency, color conversion efficiency based on CIE color coordinate y, and maximum emission wavelength indicating a maximum value at an emission peak were presented. The color conversion efficiency value in Table 4 corresponds to the luminous efficiency shown in Table 4 divided by the CIE color coordinate y.

TABLE 4

| | | | | Color | Maximum |
|---|---|---|---|---|---|
| | Driving | | Luminous | conversion | emission |
| | voltage | | efficiency | efficiency | wavelength |
| Item | (V) | CIE(x, y) | (cd/A) | (cd/A) | (nm) |
| Example 1 | 4.2 | 0.141, | 21.4 | 122.3 | 460 |
| | | 0.175 | | | |
| Example 2 | 4.2 | 0.140, | 21.2 | 124.0 | 461 |
| | | 0.171 | | | |
| Example 3 | 4.1 | 0.140, | 22.9 | 135.5 | 460 |
| | | 0.169 | | | |
| Example 4 | 4.3 | 0.139, | 20.8 | 126.8 | 459 |
| | | 0.164 | | | |
| Example 5 | 4.2 | 0.140, | 21.1 | 115.3 | 462 |
| | | 0.183 | | | |
| Example 6 | 4.3 | 0.140, | 21.4 | 132.9 | 458 |
| | | 0.161 | | | |
| Example 7 | 4.2 | 0.140, | 21.7 | 131.5 | 459 |
| | | 0.165 | | | |
| Example 8 | 4.1 | 0.142, | 23.6 | 138.8 | 460 |
| | | 0.170 | | | |
| Example 9 | 4.1 | 0.139, | 21.5 | 131.9 | 459 |
| | | 0.163 | | | |
| Example 10 | 4.1 | 0.138, | 21.9 | 135.2 | 459 |
| | | 0.162 | | | |
| Comparative | 4.8 | 0.136, | 22.3 | 112.3 | 463 |
| Example 3 | | 0.199 | | | |
| Comparative | 4.7 | 0.143, | 21.5 | 102.4 | 468 |
| Example 4 | | 0.210 | | | |

Referring to the results in Table 4, it is seen that the light emitting elements of the Examples exhibit lower driving voltage than the Comparative Examples. In addition, the light emitting elements of the Examples showed different CIE color coordinates (x,y) compared to the light emitting elements of the Comparative Examples including the Comparative Example compounds having heteropolycyclic rings different from the Example compounds. That is, it was determined that the Examples show luminous properties shifted to the blue region compared to the Comparative Examples. In addition, it is seen that the Examples show higher color conversion efficiency than the Comparative Examples based on the blue-shifted color coordinate value y.

In addition, it is seen that the Examples show shorter wavelength emission characteristics than the Comparative Examples. In particular, it was determined that Comparative Example 4 using Comparative Example compound C4, which does not have a bulky substituent such as an aromatic ring, emits longer wavelength light than the Examples. This indicates that in the case of not having a bulky substituent such as an aromatic ring, exciplex formation with a host is facilitated, and accordingly, the emission wavelength from the light emitting element is shifted toward a longer wavelength due to the modification of the emission spectrum.

In the light emitting element of an embodiment, the emission layer may include the organometallic compound of an embodiment. The organometallic compound of an embodiment includes a set or specific heteropolycyclic ring among the ligands bonded to the central metal atom, may thus exhibit deep blue luminous properties.

The organometallic compound of an embodiment includes a set or specific heteropolycyclic ring as a ligand and thus has increased ³MLCT properties and a low HOMO energy level, and accordingly, may exhibit excellent light efficiency, low driving voltage, and also maintain deep blue luminous properties.

In addition, the organometallic compound of an embodiment may be used as a phosphorescent material, and a light emitting element including the organometallic compound of an embodiment may exhibit high efficiency and low driving voltage.

A light emitting element of an embodiment includes an organometallic compound of an embodiment, and may thus exhibit low driving voltage and high efficiency.

An organometallic compound of an embodiment may contribute to implementing a deep blue color and increasing light efficiency of a light emitting element.

A display device of an embodiment may exhibit high display quality.

Although the subject matter of the present disclosure has been described with reference to example, embodiments of the present disclosure, it will be understood that the presented disclosure should not be limited to these example embodiments but various changes and modifications may be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode and comprising a first compound represented by Formula 1: 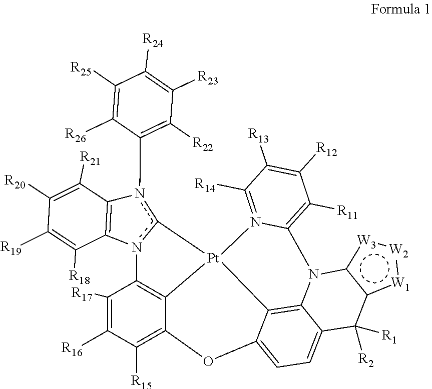
wherein in Formula 1,
at least one of W₁ to W₃ is O or S and the others are CRa,
Ra is a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms, or bonded to an adjacent group to form a ring, and
R₁, R₂, and R₁₁ to R₂₆ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms.

2. The light emitting element of claim 1, further comprising at least one of a second compound represented by Formula HT-1 or a third compound represented by Formula ET-1: 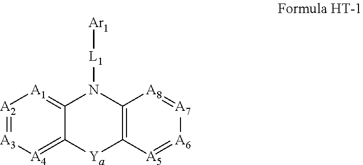
wherein in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms, or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, 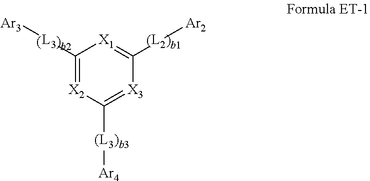
wherein in Formula ET-1,
at least one of X₁ to X₃ is N and the others are CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms.

3. The light emitting element of claim 2, wherein the emission layer further comprises a fourth compound represented by Formula F-1: 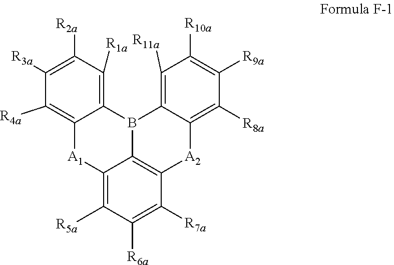
wherein in Formula F-1,
A₁ and A₂ are each independently O, S, Se, or NRₘ,
Rₘ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R₁ₐ to R₁₁ₐ are each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

4. The light emitting element of claim 3, wherein the emission layer comprises the first compound, the second compound, the third compound, and the fourth compound.

5. The light emitting element of claim 1, wherein the emission layer comprises a host and a phosphorescent dopant, and the phosphorescent dopant is the first compound.

6. The light emitting element of claim 1, wherein the emission layer emits blue light having a maximum central wavelength of about 470 nm or less.

7. The light emitting element of claim 1, wherein Formula 1 is represented by Formula 1-1: 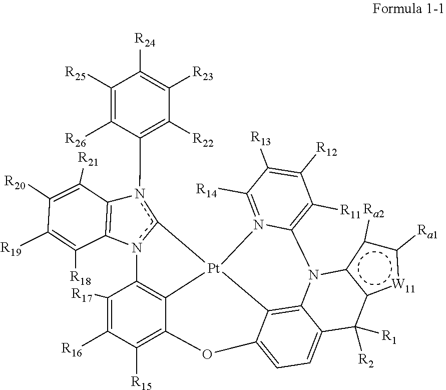
wherein in Formula 1-1,
W₁₁ is O or S,
Rₐ₁ and Rₐ₂ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms, and
R₁, R₂, and R₁₁ to R₂₆ are the same as defined with respect to Formula 1.

8. The light emitting element of claim 7, wherein Rₐ₁ and Rₐ₂ are hydrogen atoms.

9. The light emitting element of claim 1, wherein Formula 1 is represented by Formula 1-2: 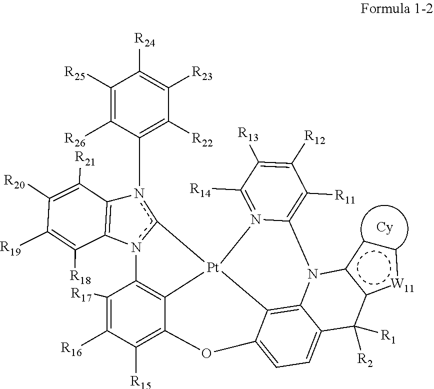
wherein in Formula 1-2,
W₁₁ is O or S,
Cy is a substituted or unsubstituted hydrocarbon ring having 5 to 30 ring-forming carbon atoms, or a substituted or unsubstituted heterocycle having 3 to 30 ring-forming carbon atoms, and
R₁, R₂, and R₁₁ to R₂₆ are the same as defined with respect to Formula 1.

10. The light emitting element of claim 9, wherein Cy is a substituted or unsubstituted benzene ring.

11. The light emitting element of claim 1, wherein the first compound is represented by any one among the compounds of Compound Group 1: 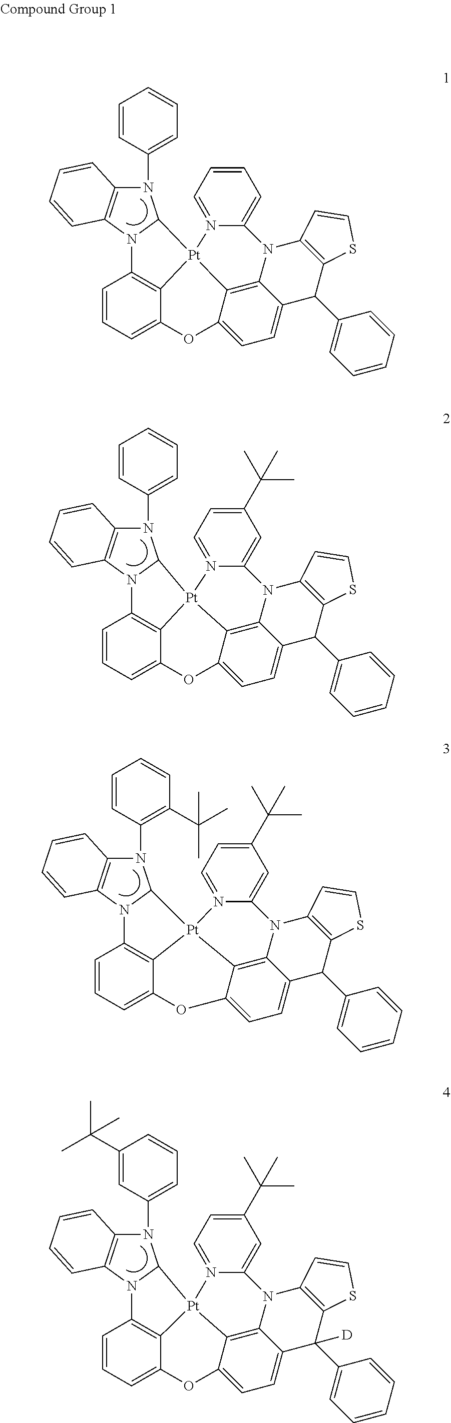 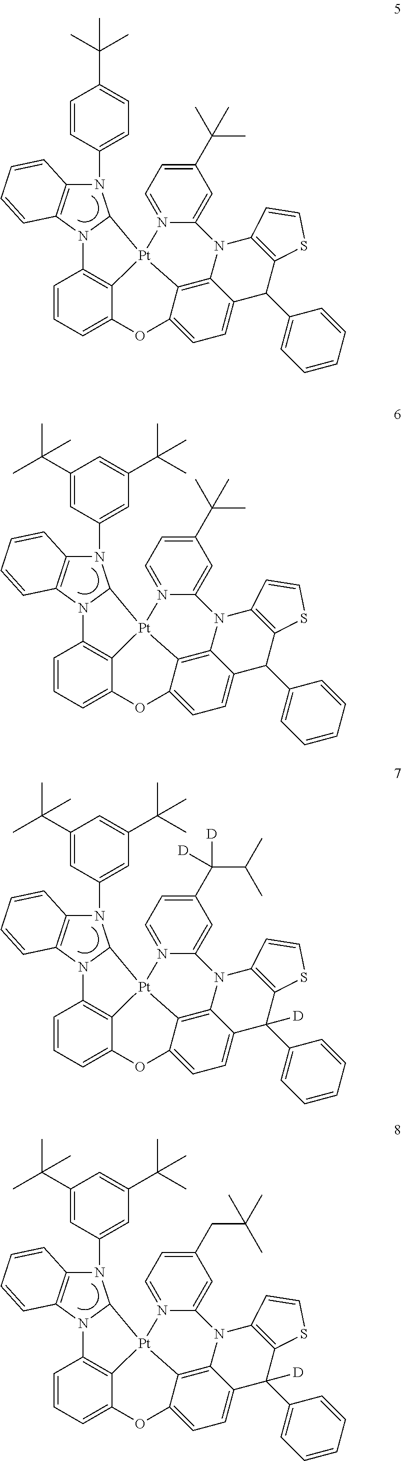 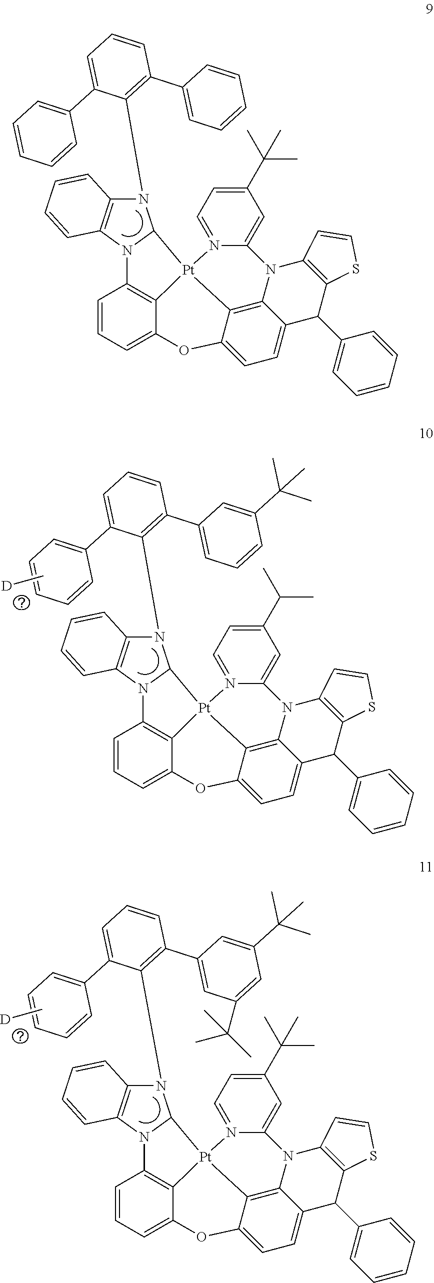 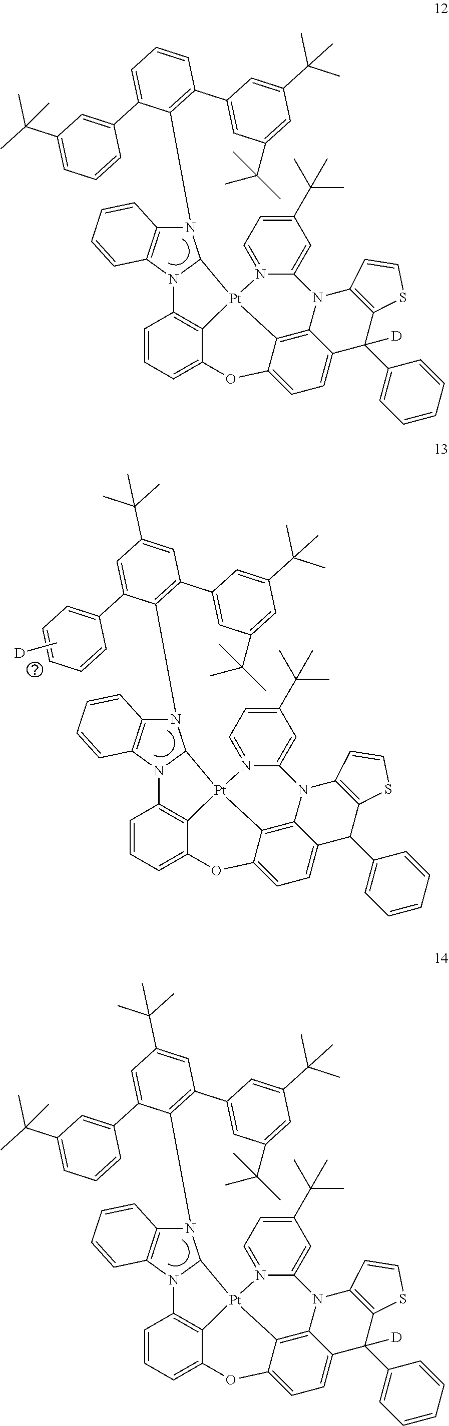 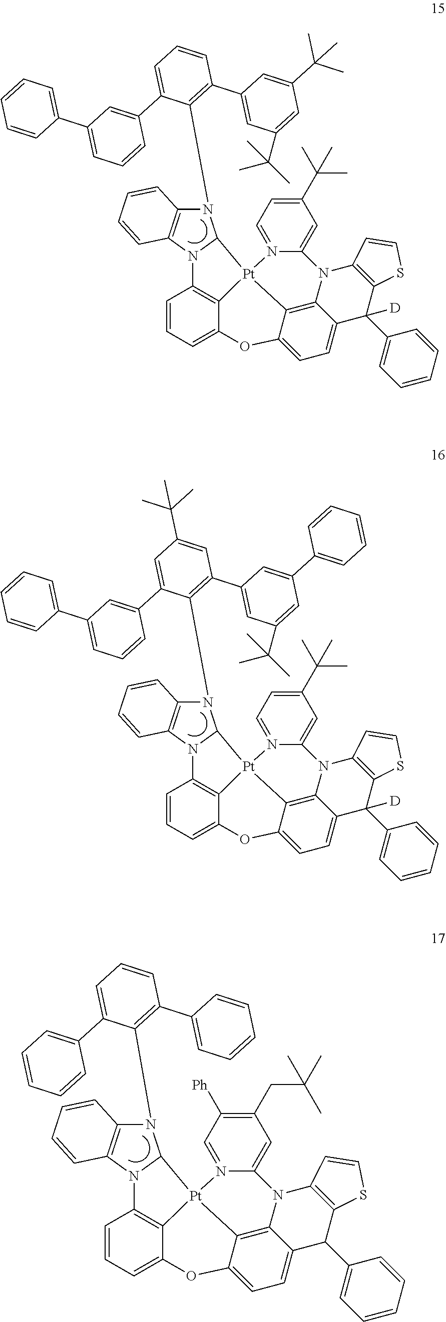 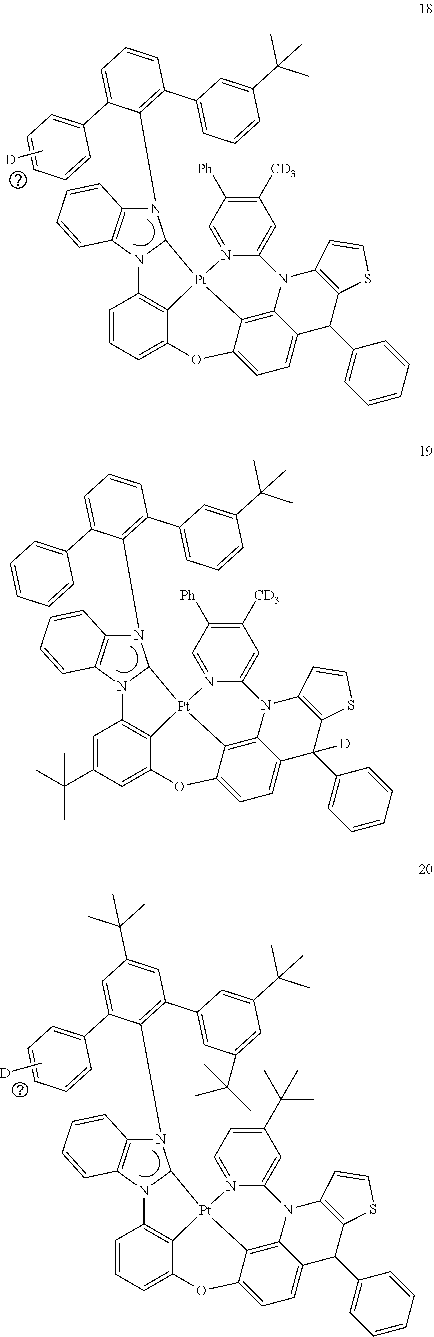 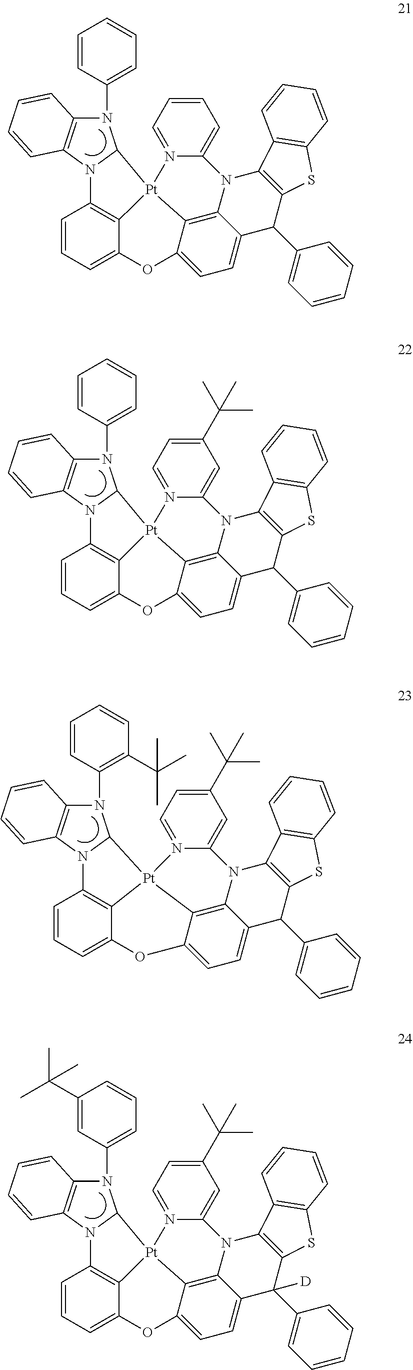 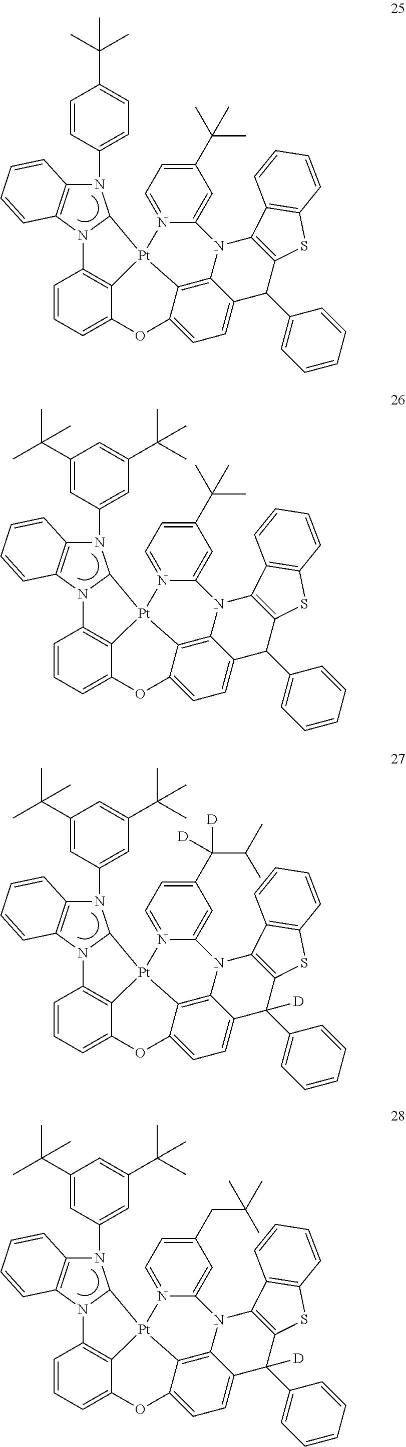 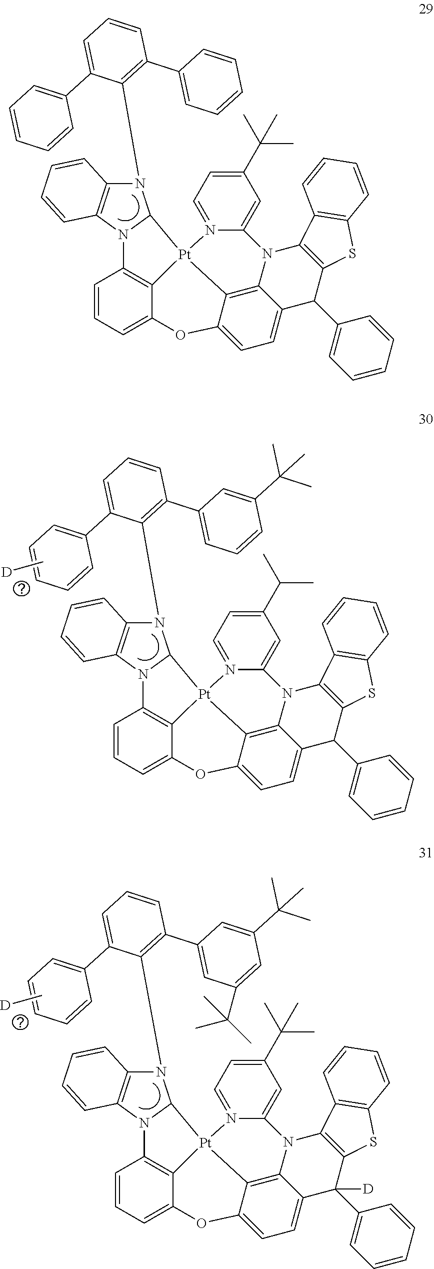 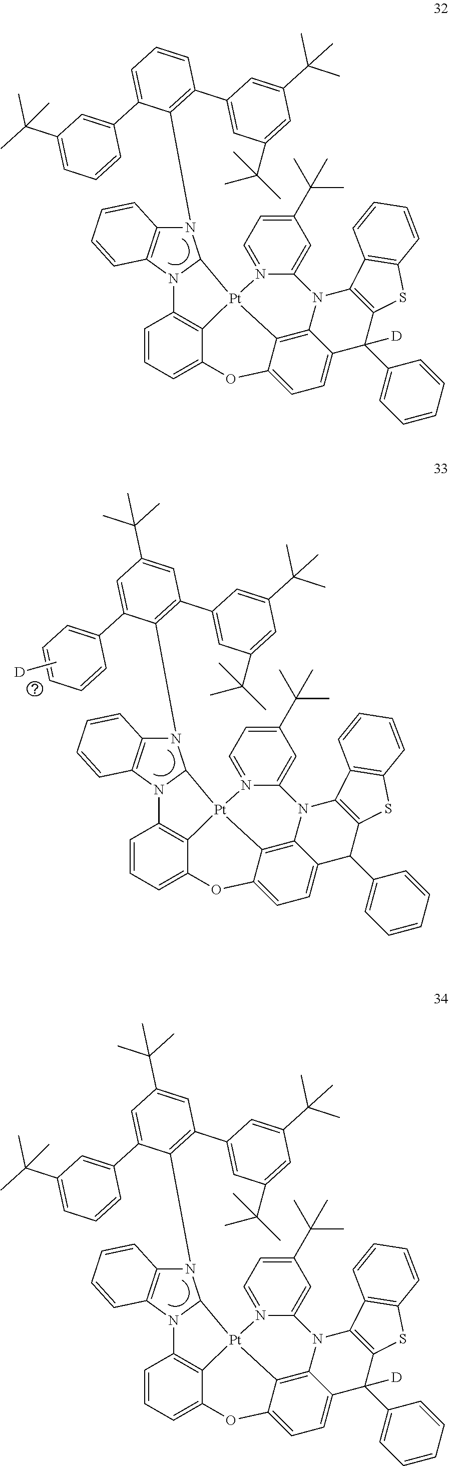 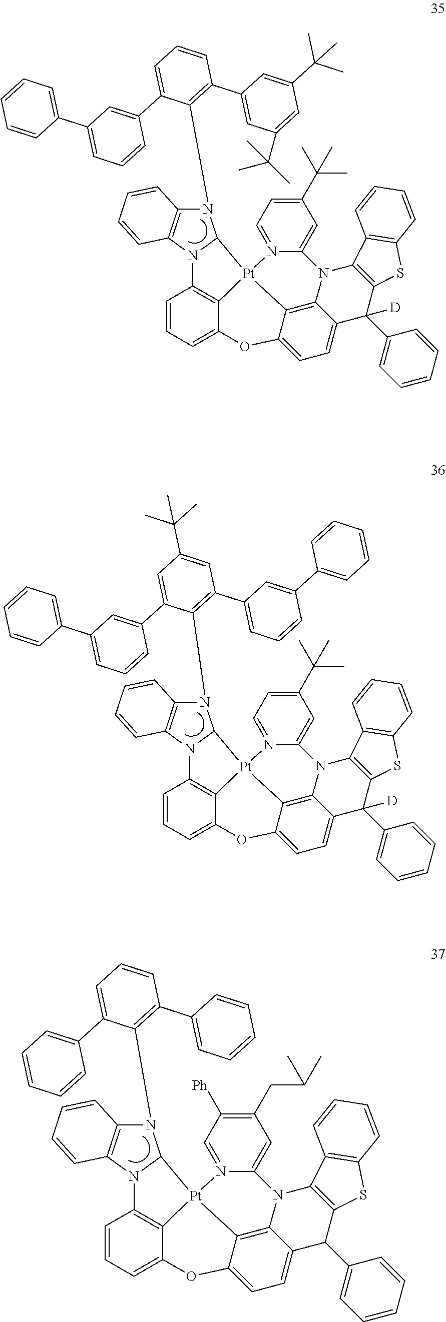 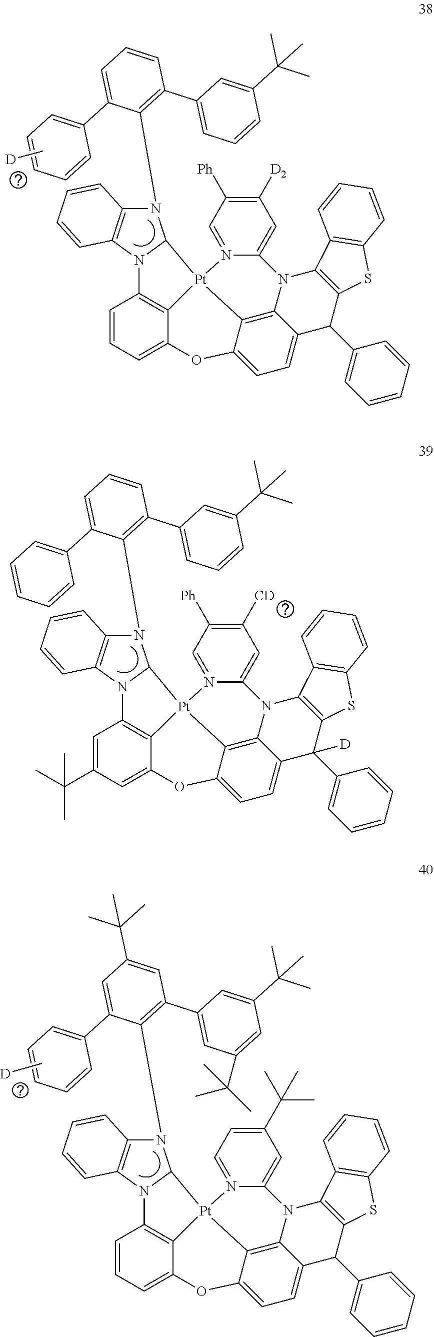 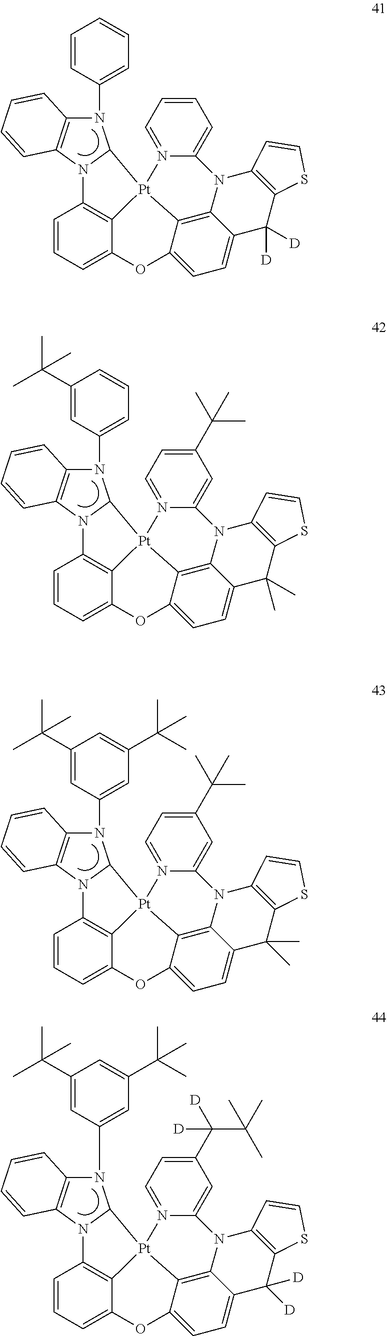 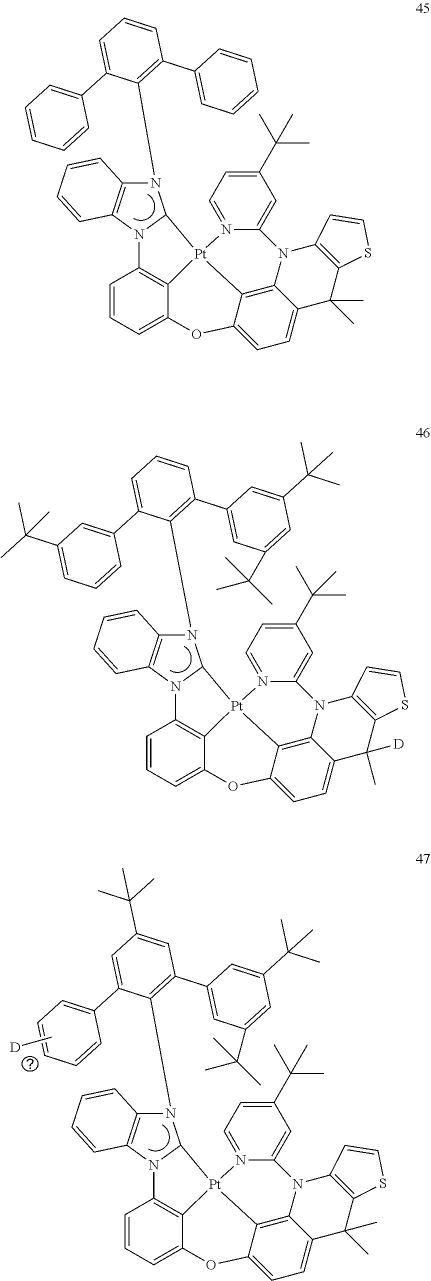 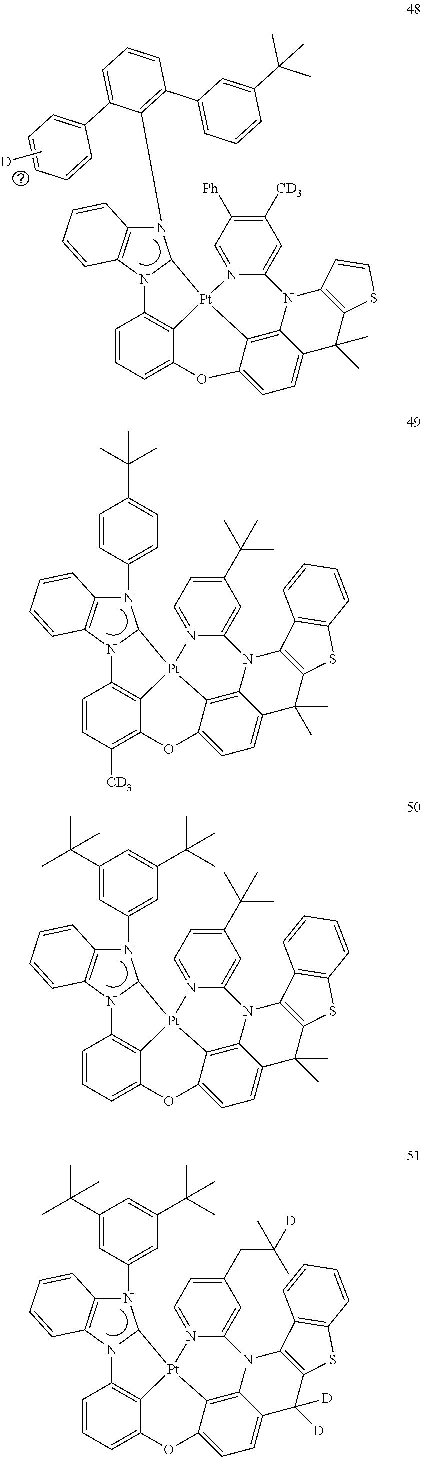 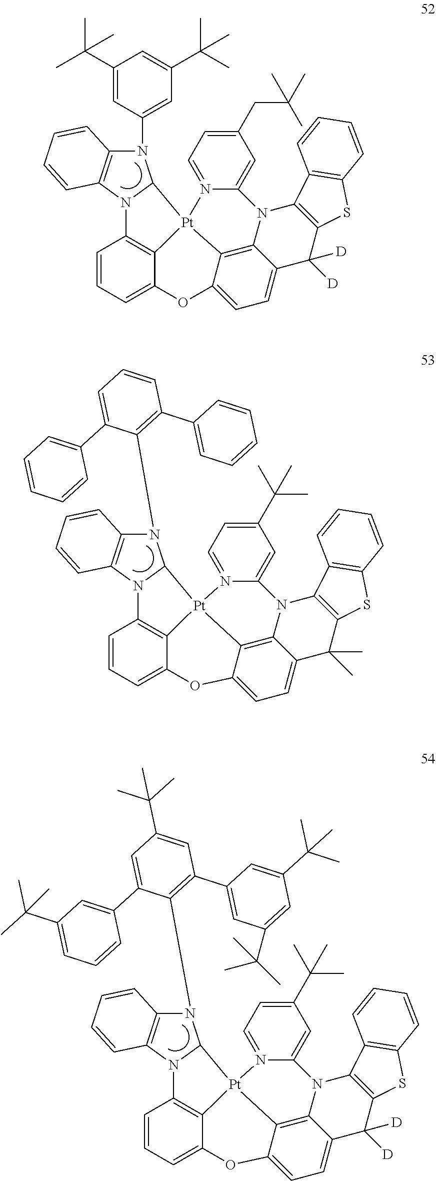 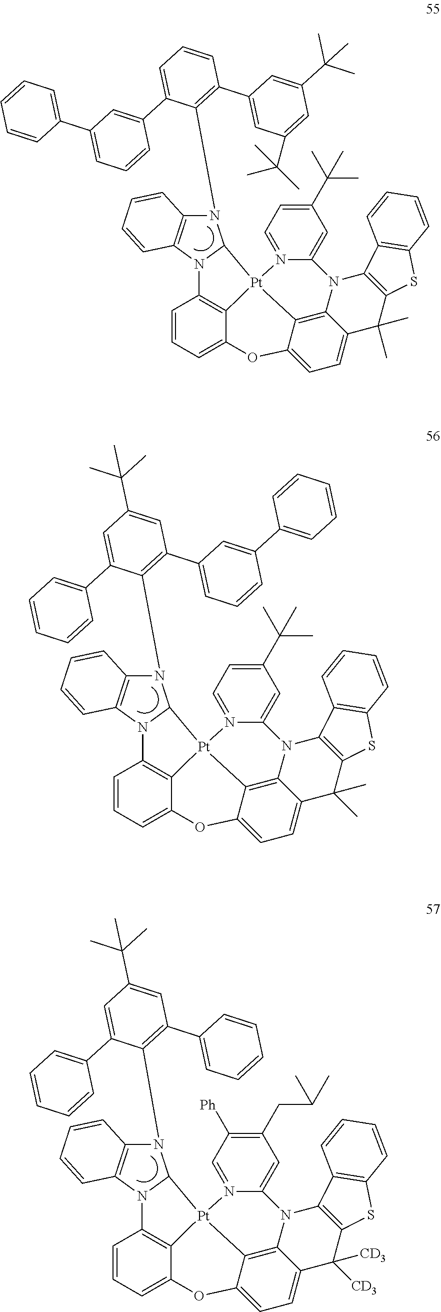 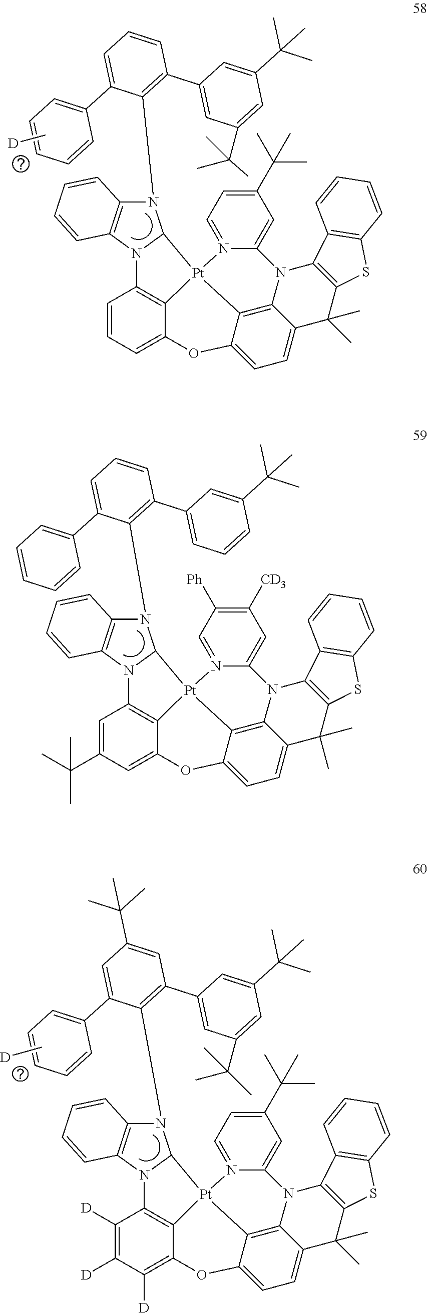 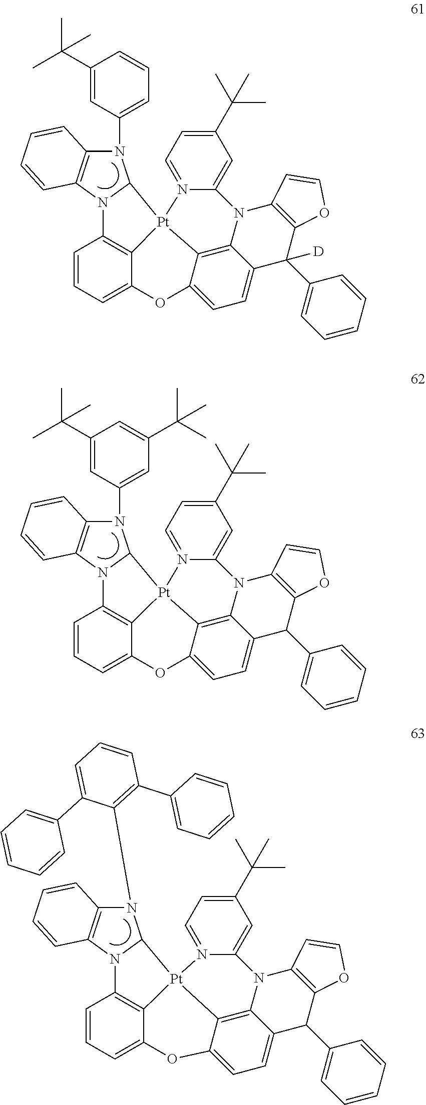 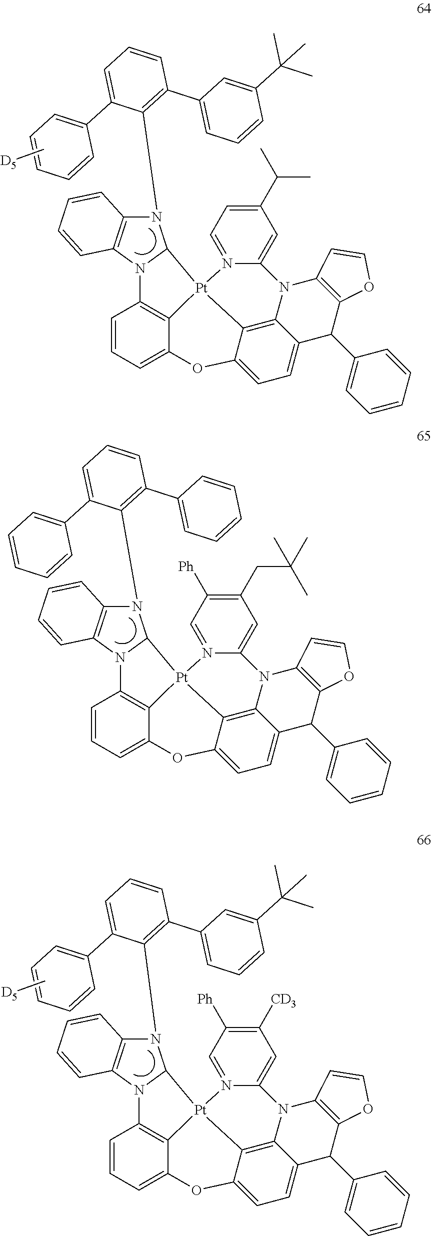 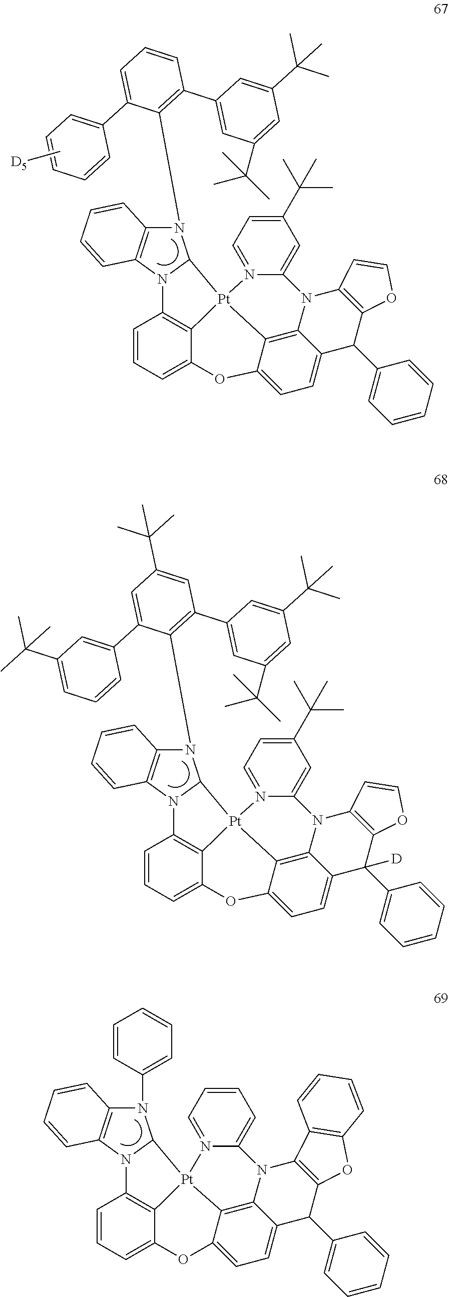 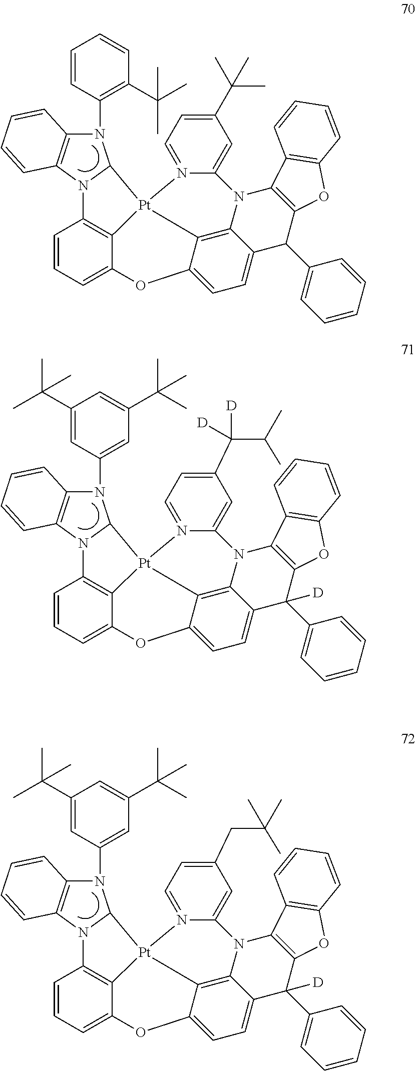 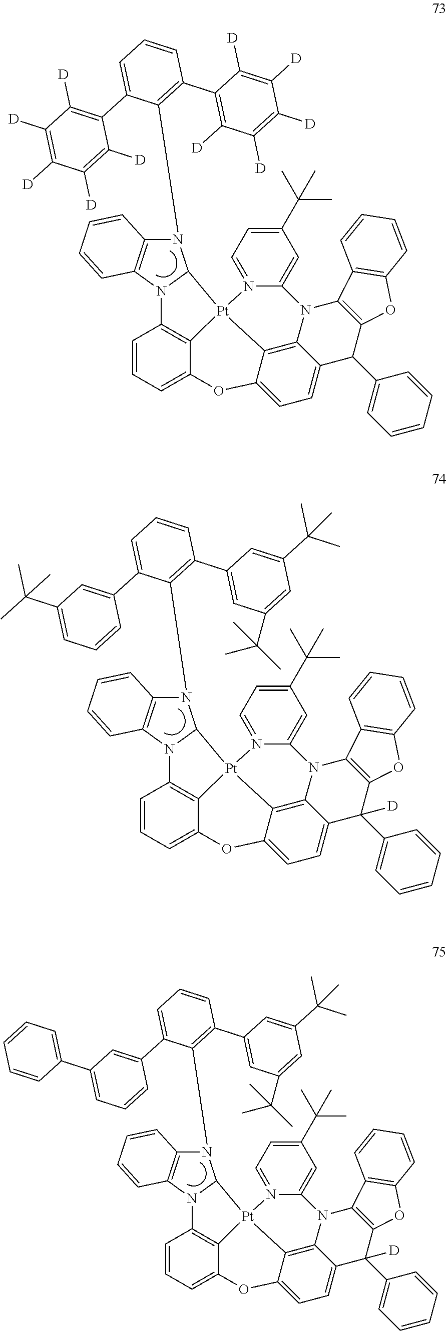 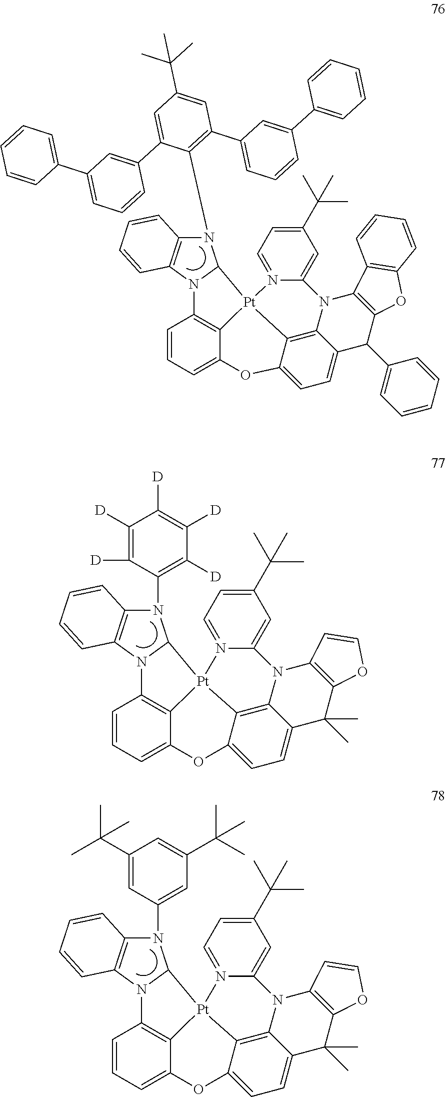 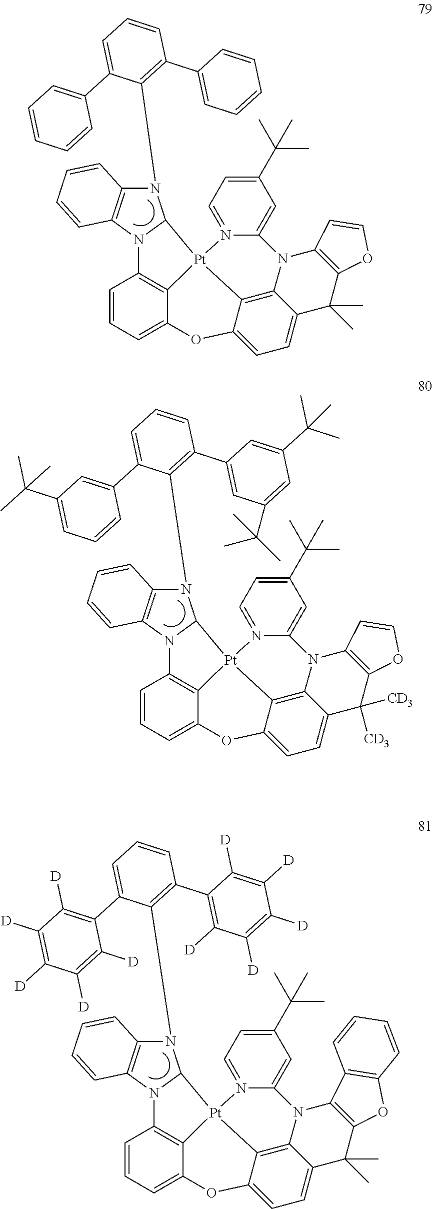 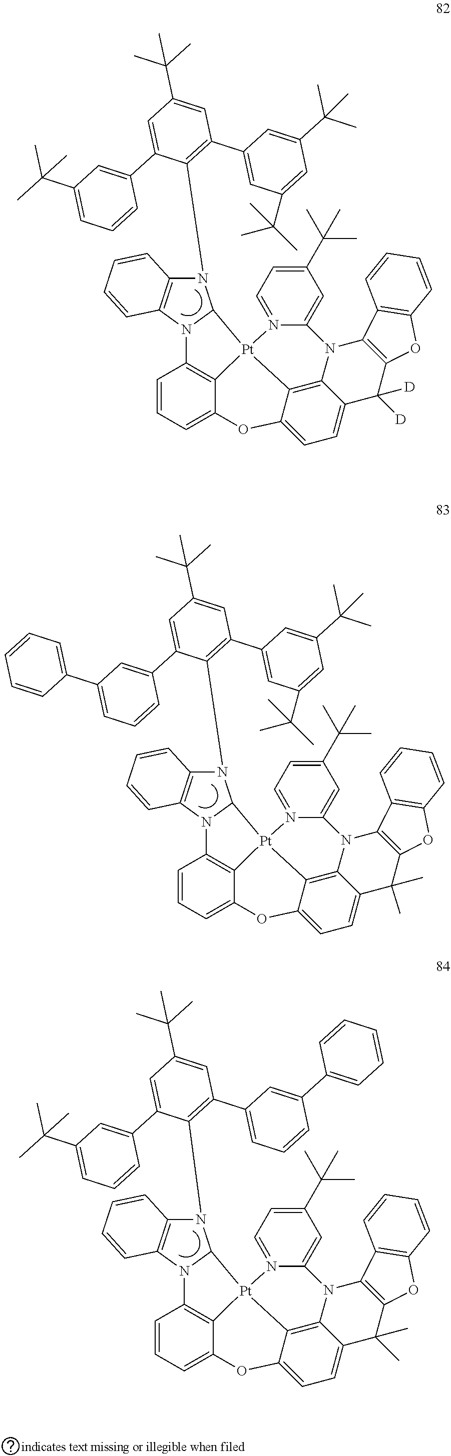
wherein in Compound Group 1, D is a deuterium atom, and Ph is an unsubstituted phenyl group.

12. An organometallic compound represented by Formula 1: 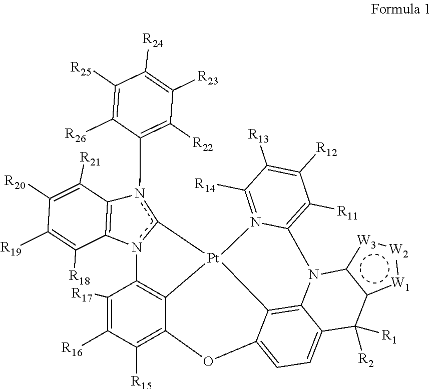
wherein in Formula 1,
at least one of W₁ to W₃ is O or S and the others are CRa,
Ra is a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms, or bonded to an adjacent group to form a ring, and
R₁, R₂, and R₁₁ to R₂₆ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms.

13. The organometallic compound of claim 12, wherein Formula 1 is represented by Formula 1-1: 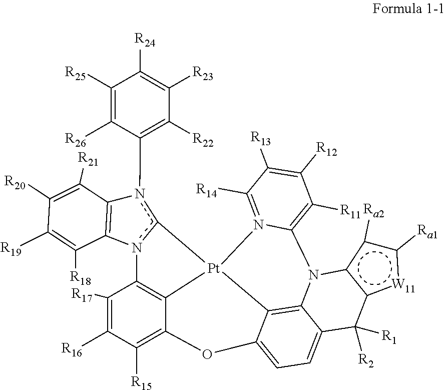
wherein in Formula 1-1,
W₁₁ is O or S,
Rₐ₁ and Rₐ₂ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms, and
R₁, R₂, and R₁₁ to R₂₆ are the same as defined with respect to Formula 1.

14. The organometallic compound of claim 13, wherein Rₐ₁ and Rₐ₂ are hydrogen atoms.

15. The organometallic compound of claim 12, wherein Formula 1 is represented by Formula 1-2: 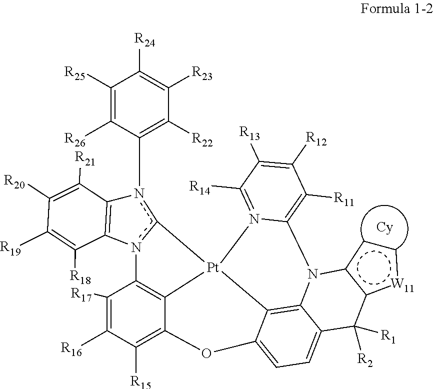
wherein in Formula 1-2,
W₁₁ is O or S,
Cy is a substituted or unsubstituted hydrocarbon ring having 5 to 30 ring-forming carbon atoms, or a substituted or unsubstituted heterocycle having 3 to 30 ring-forming carbon atoms, and
R₁, R₂, and R₁₁ to R₂₆ are the same as defined with respect to Formula 1.

16. The organometallic compound of claim 15, wherein Cy is a substituted or unsubstituted benzene ring.

17. The organometallic compound of claim 12, wherein the compound of Formula 1 emits light of phosphorescence.

18. The organometallic compound of claim 12, wherein Formula 1 is represented by any one among the compounds of Compound Group 1: 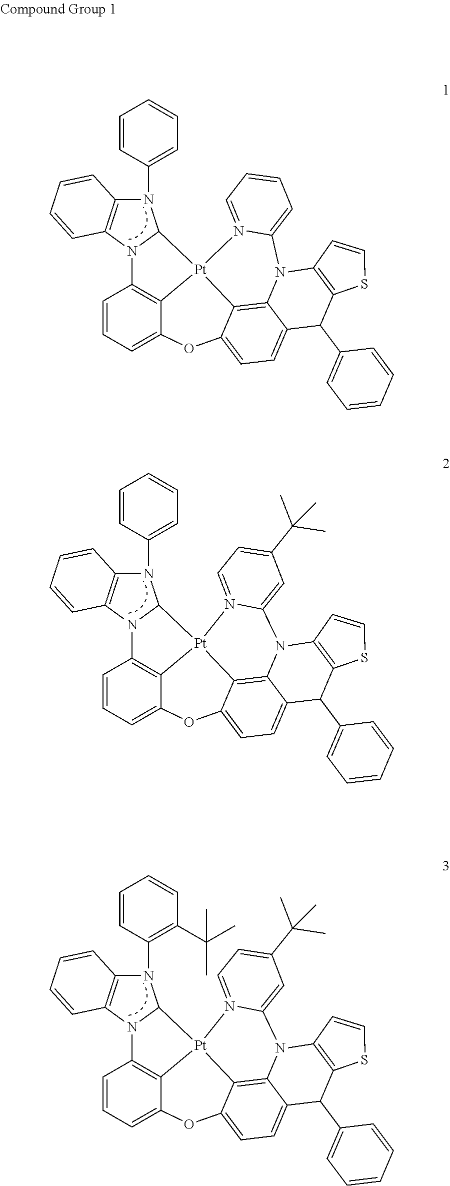 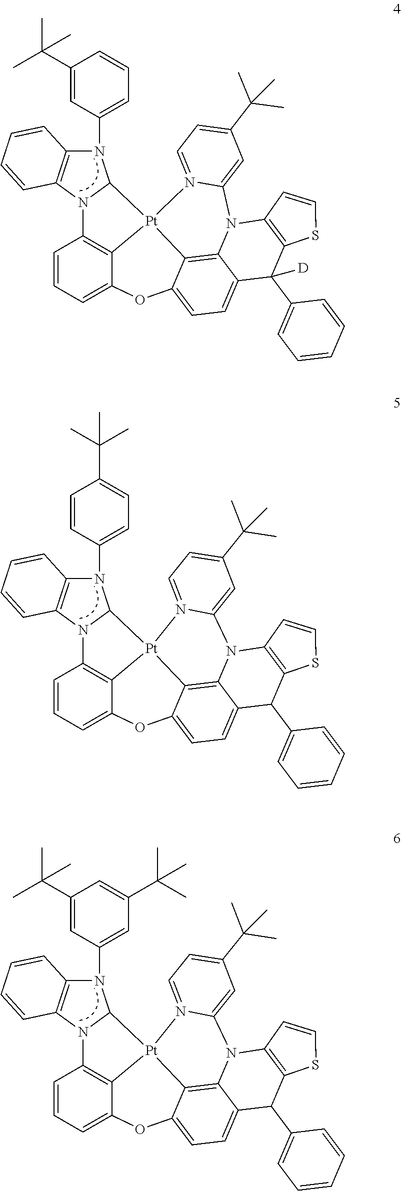 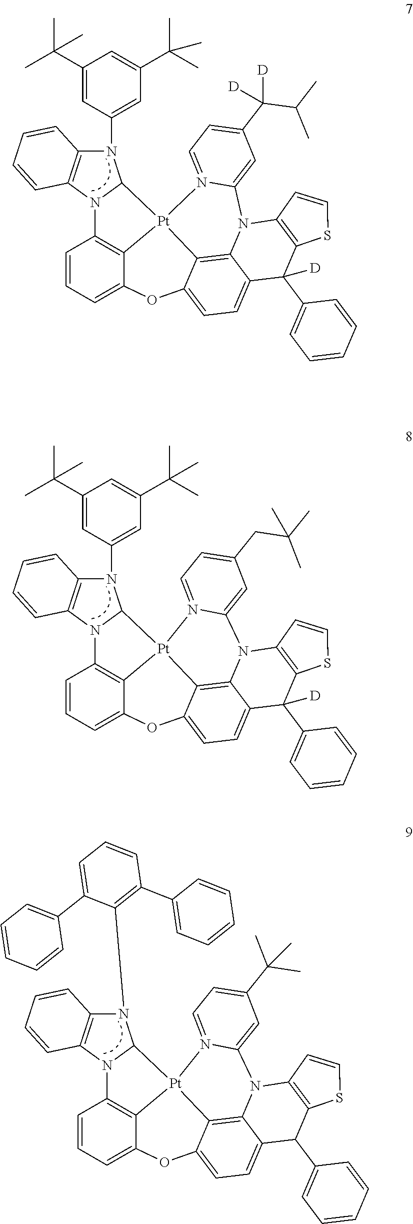 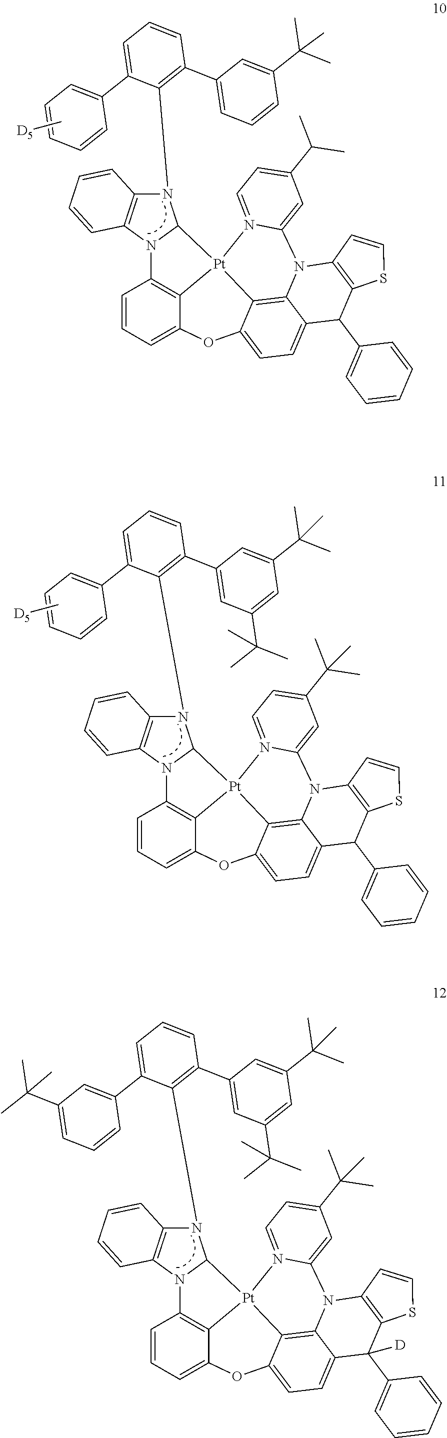 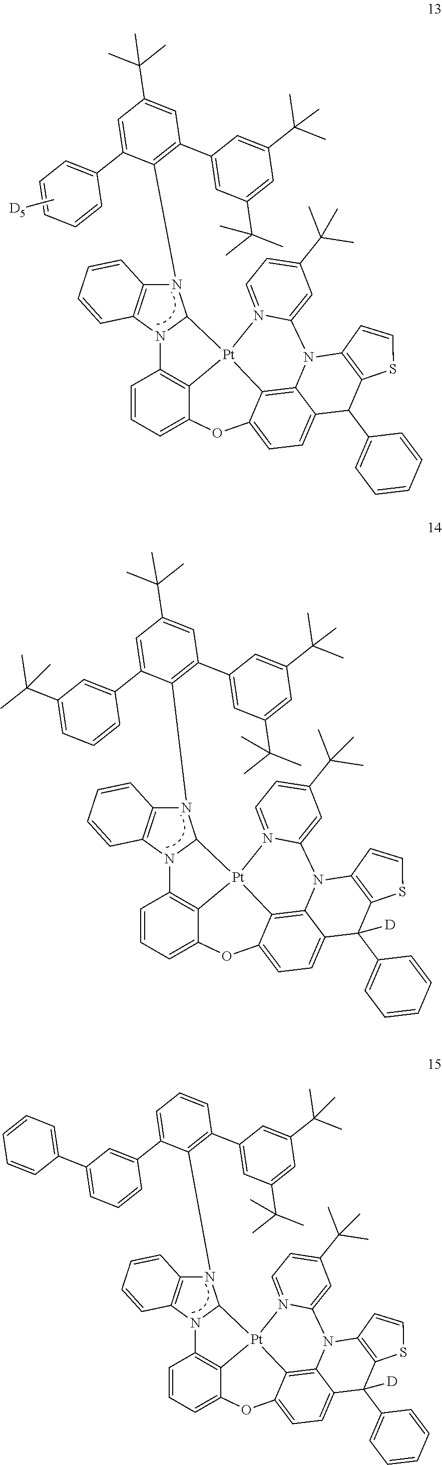 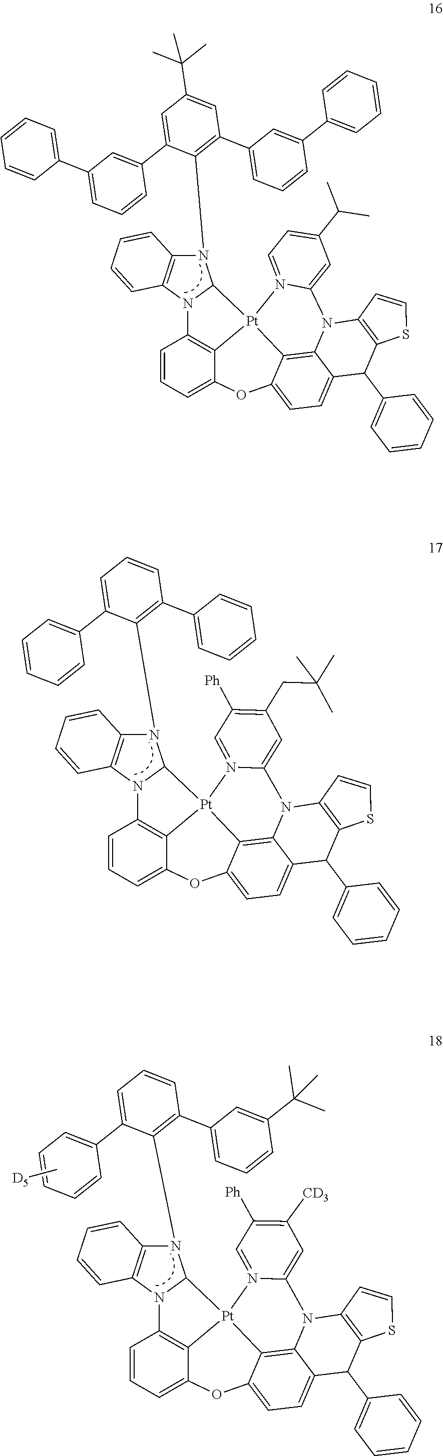 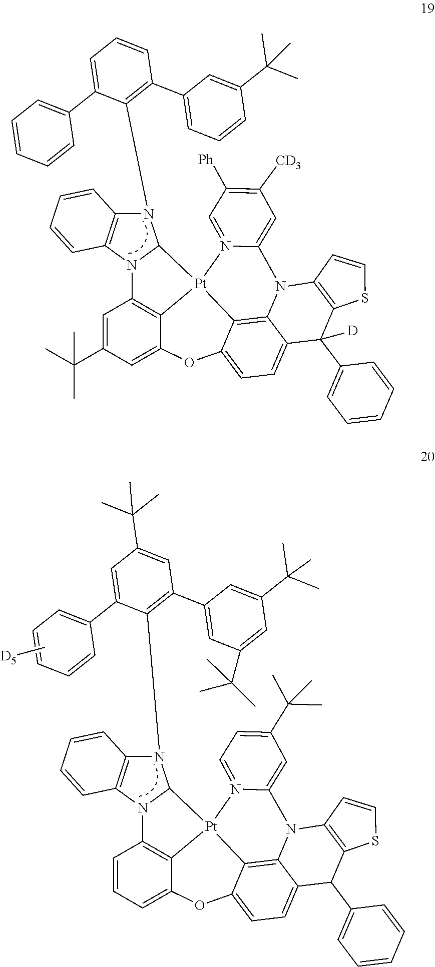 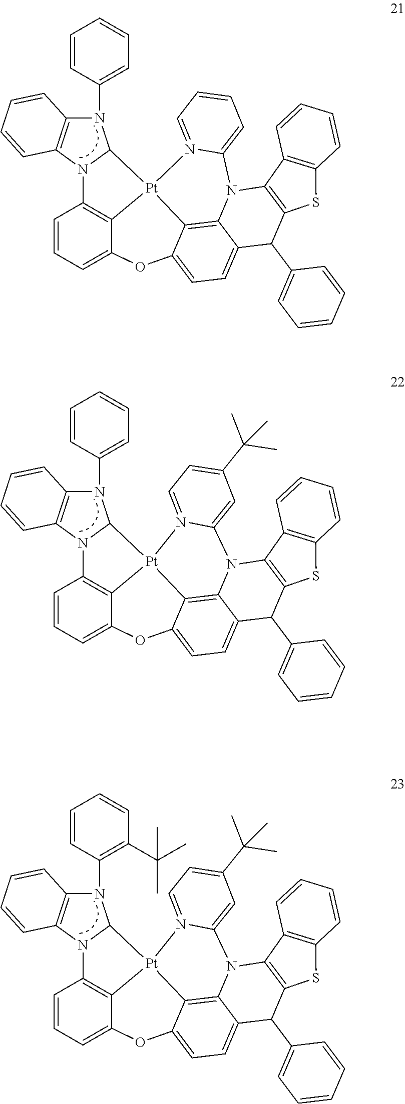 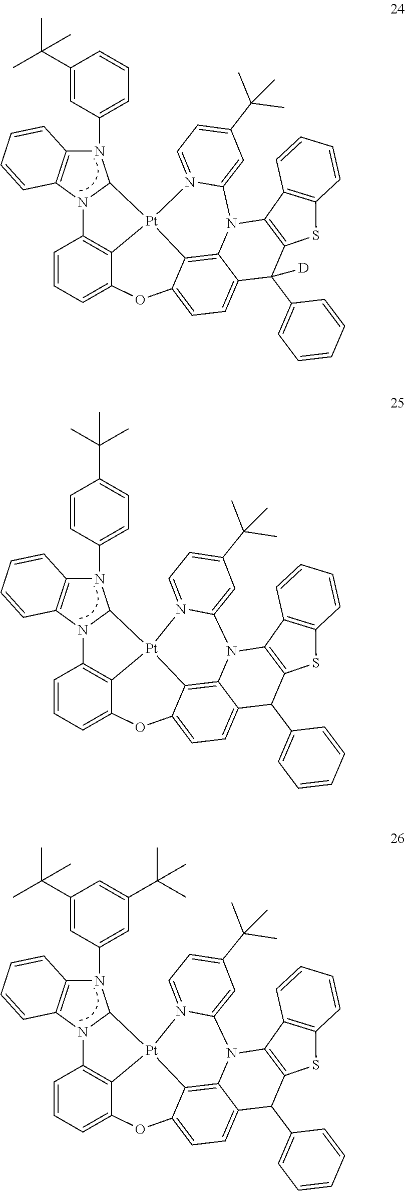 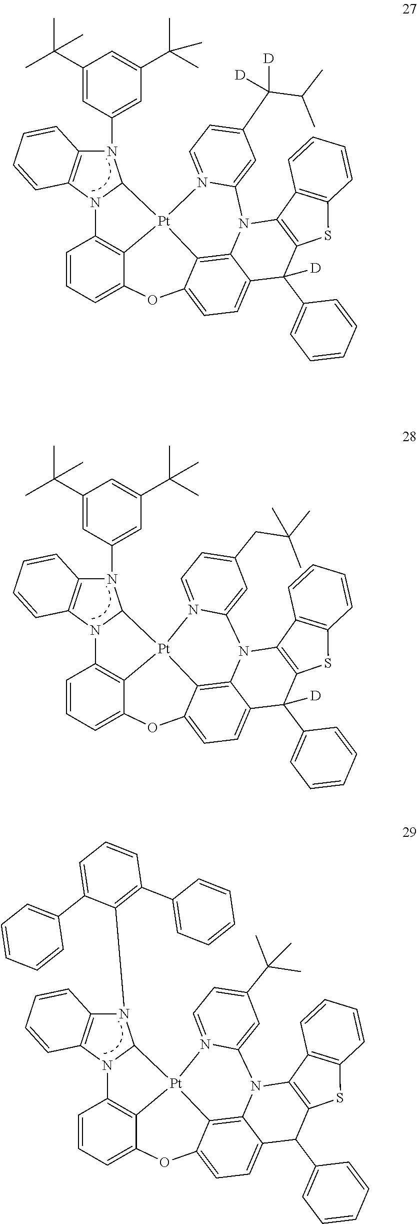 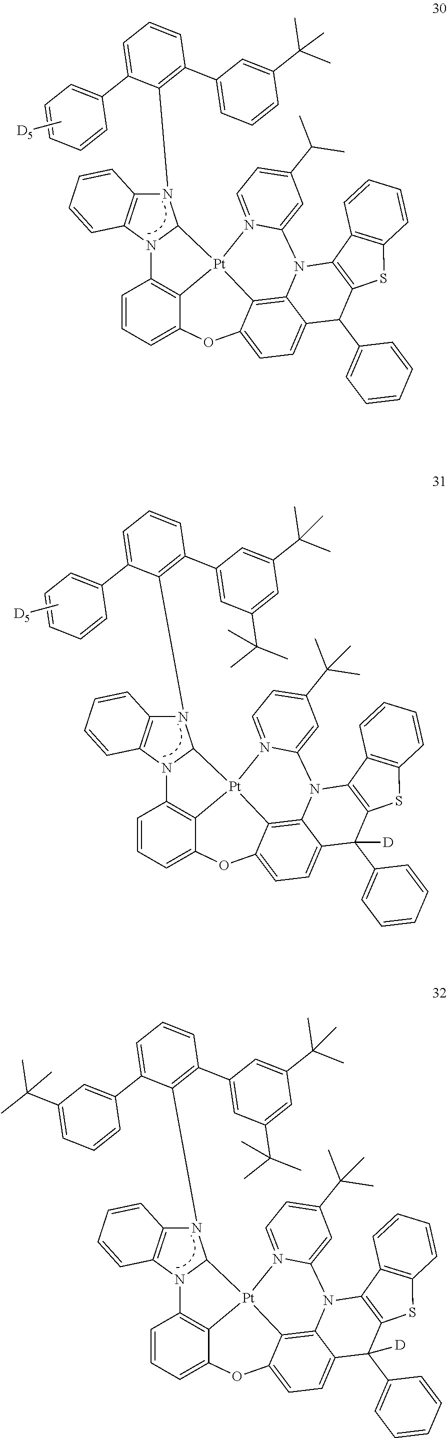 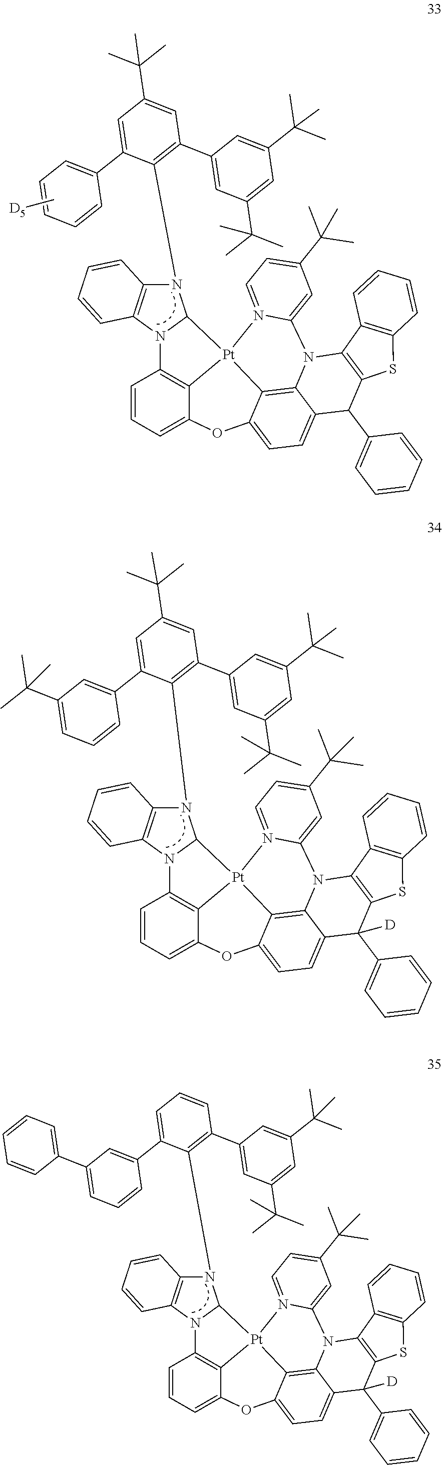 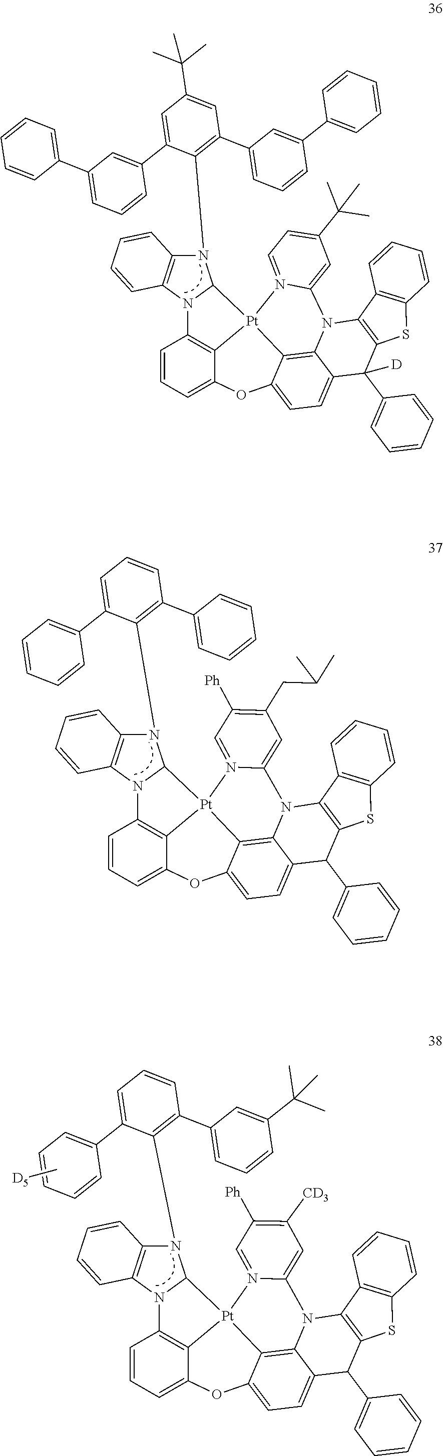 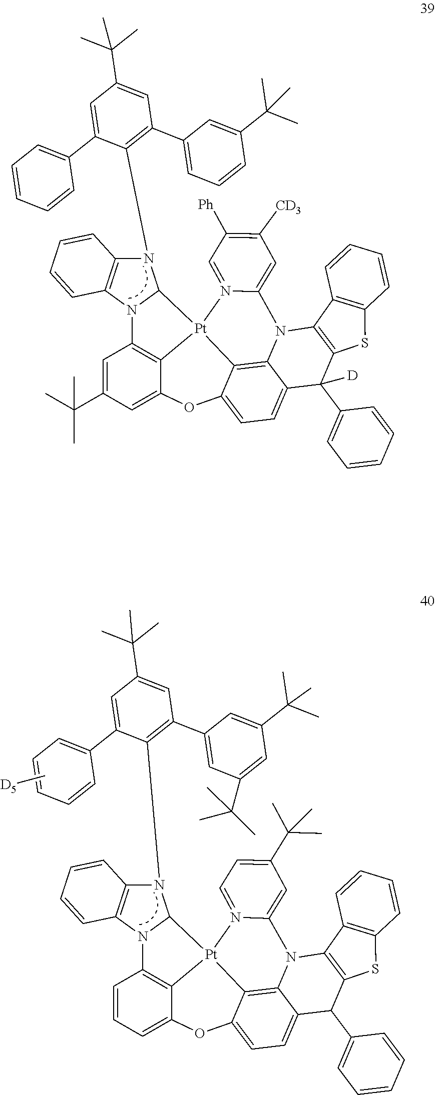 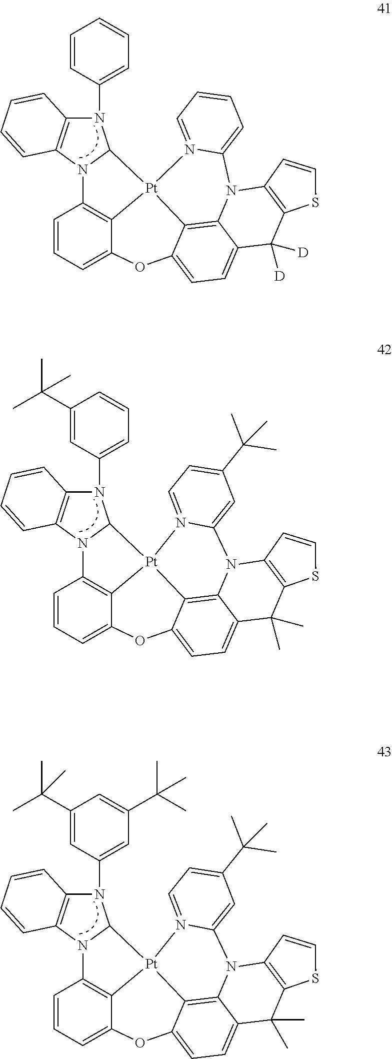 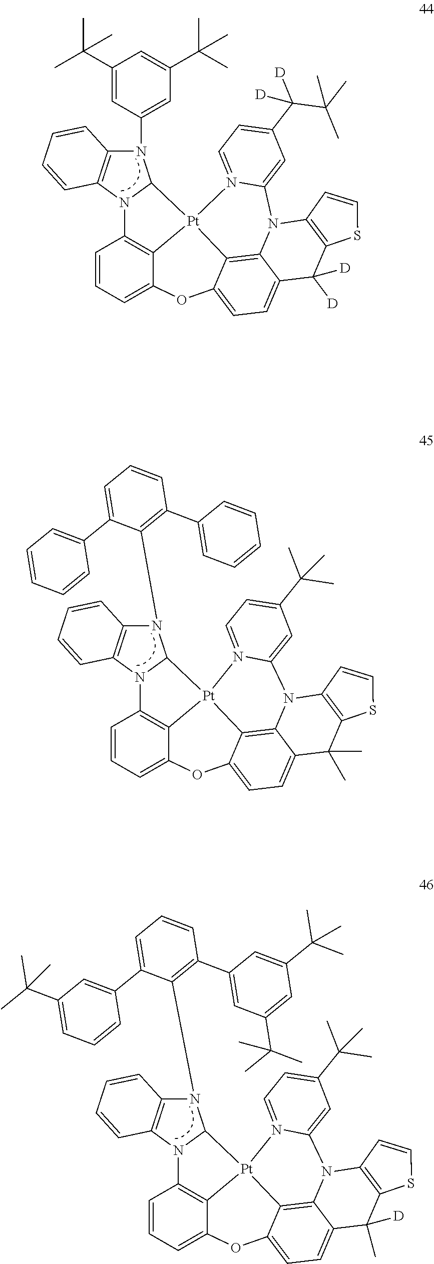 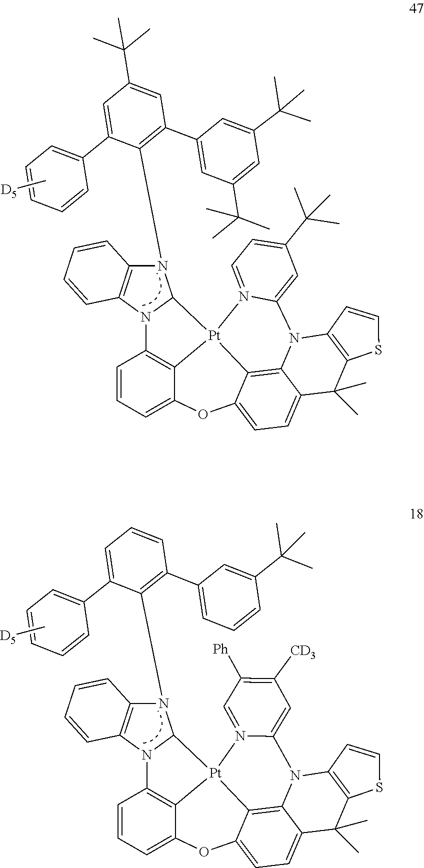 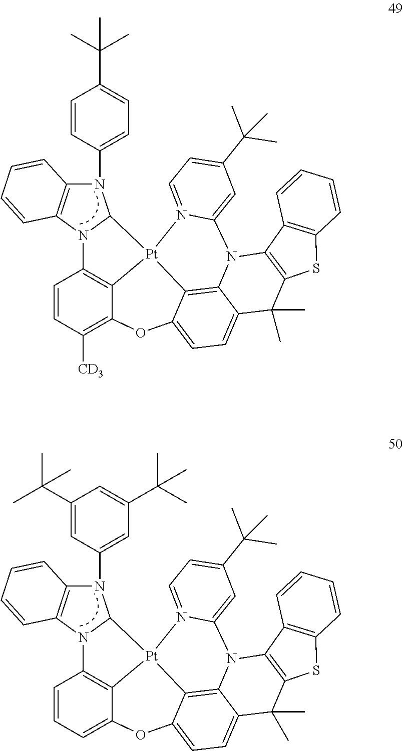 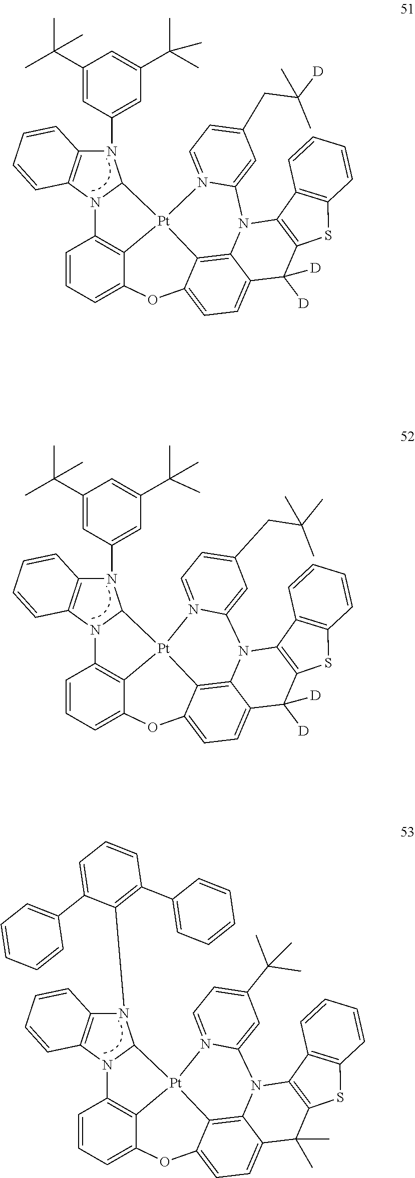 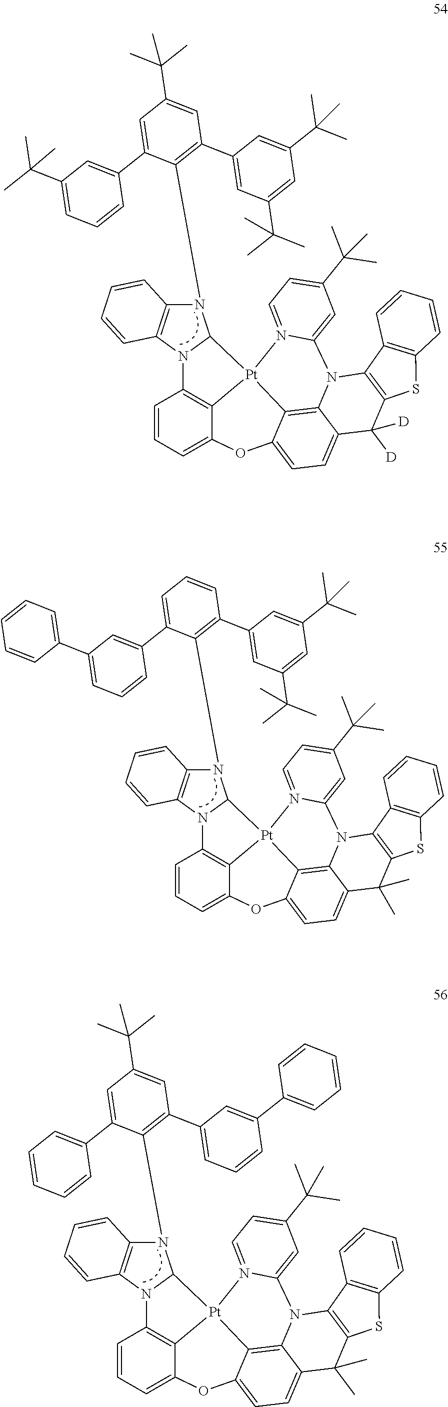 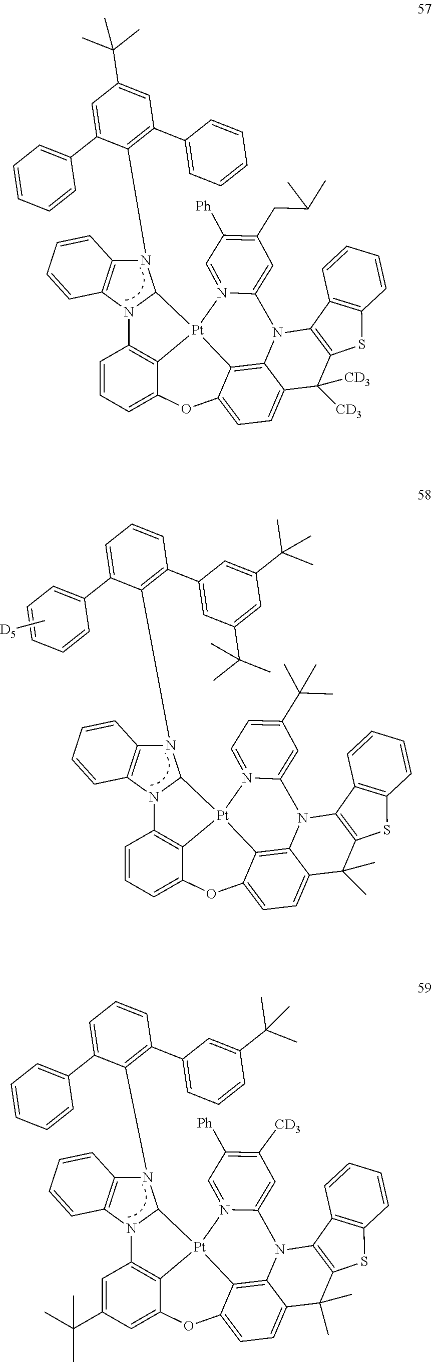 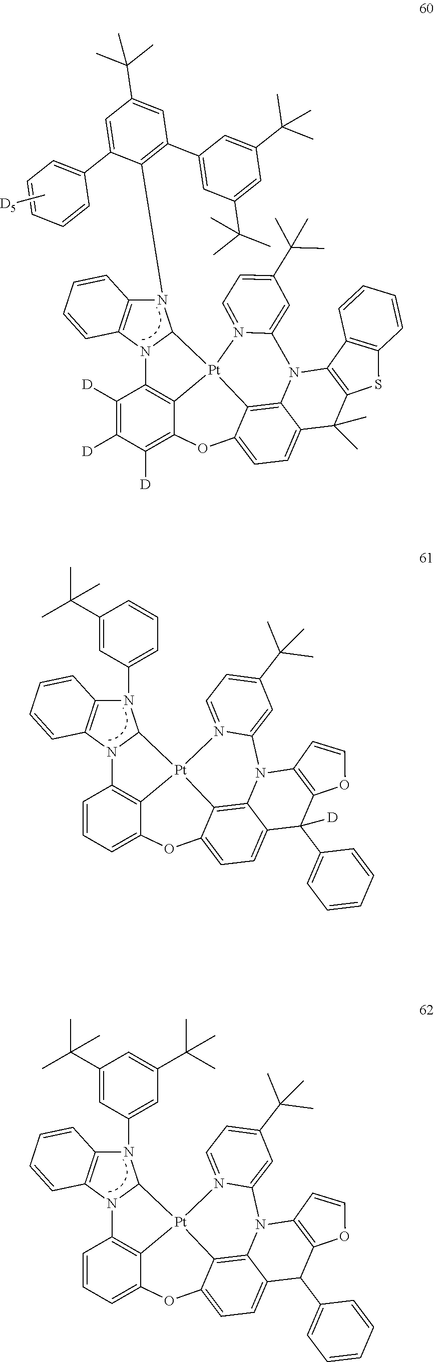 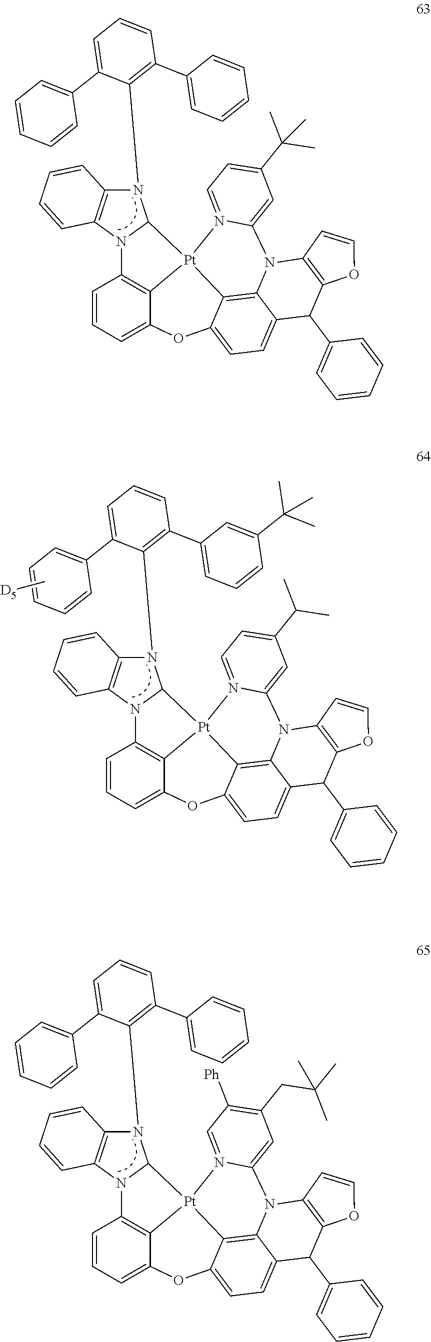 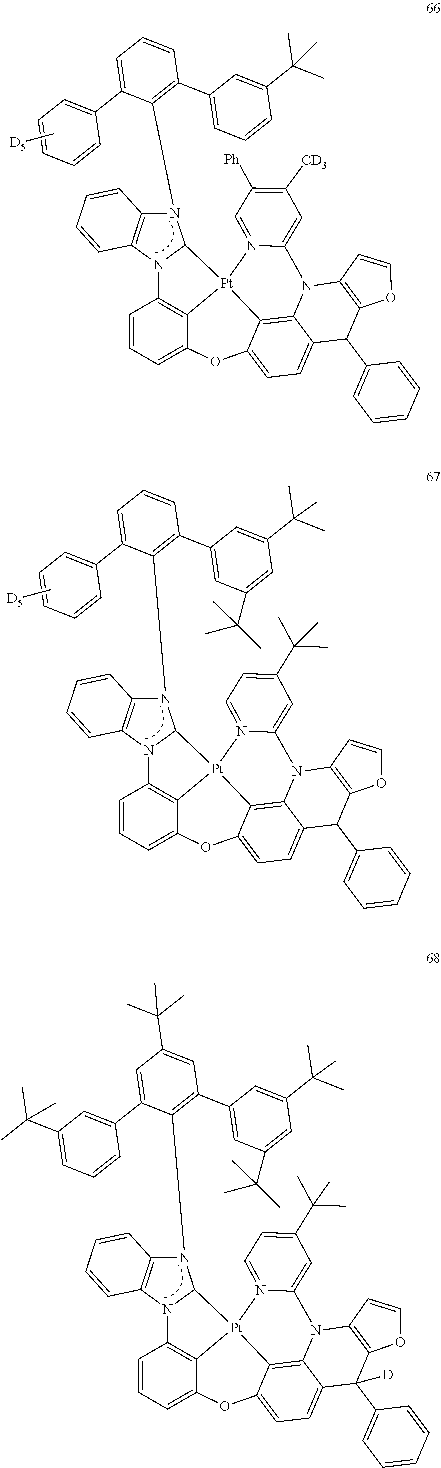 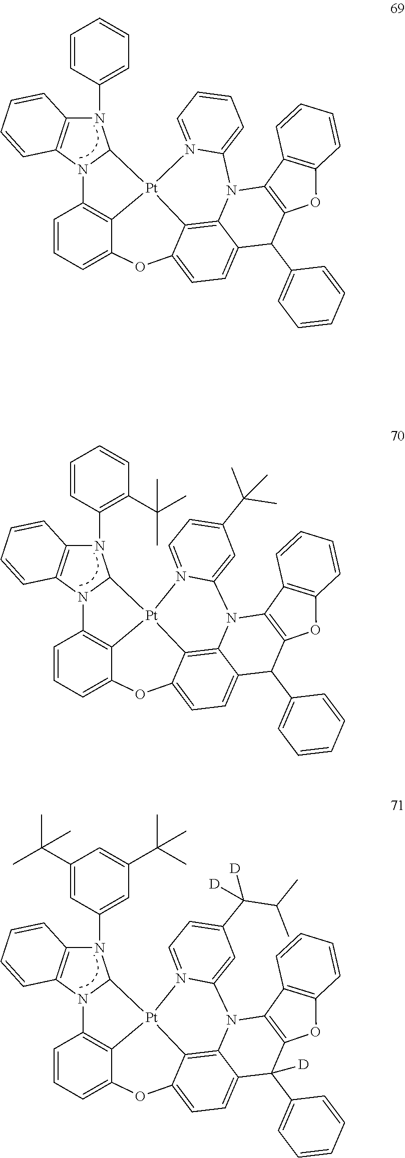 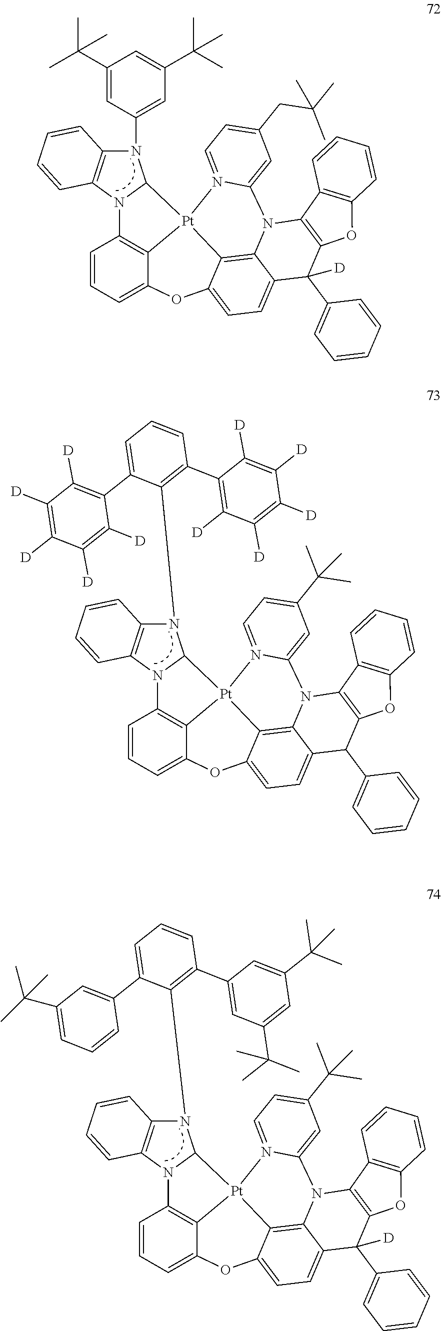 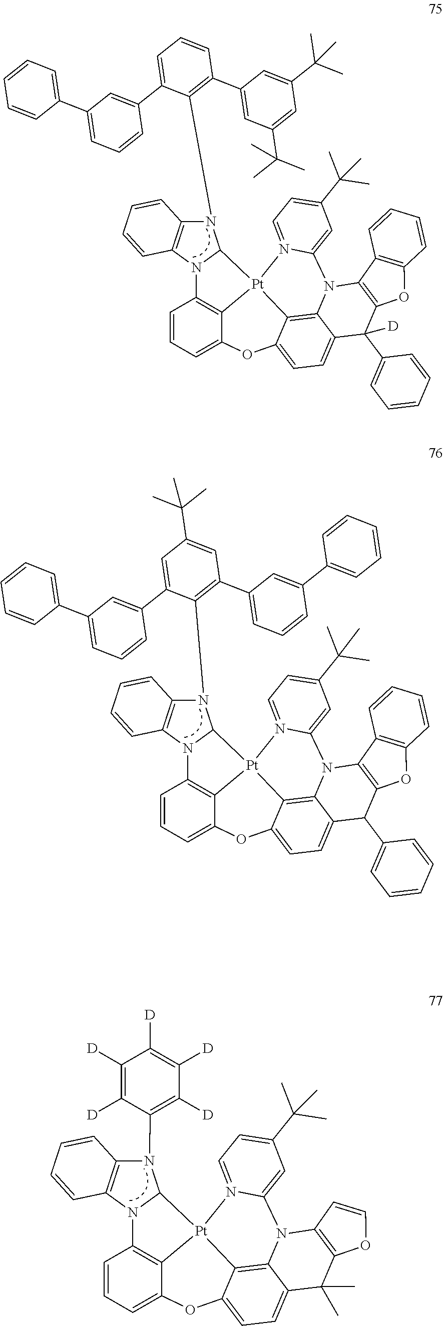 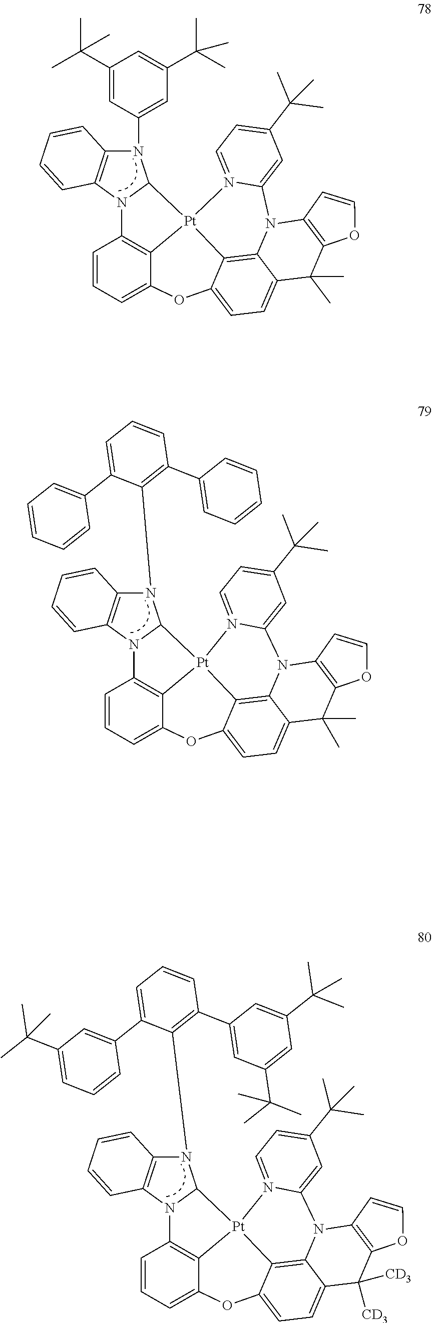 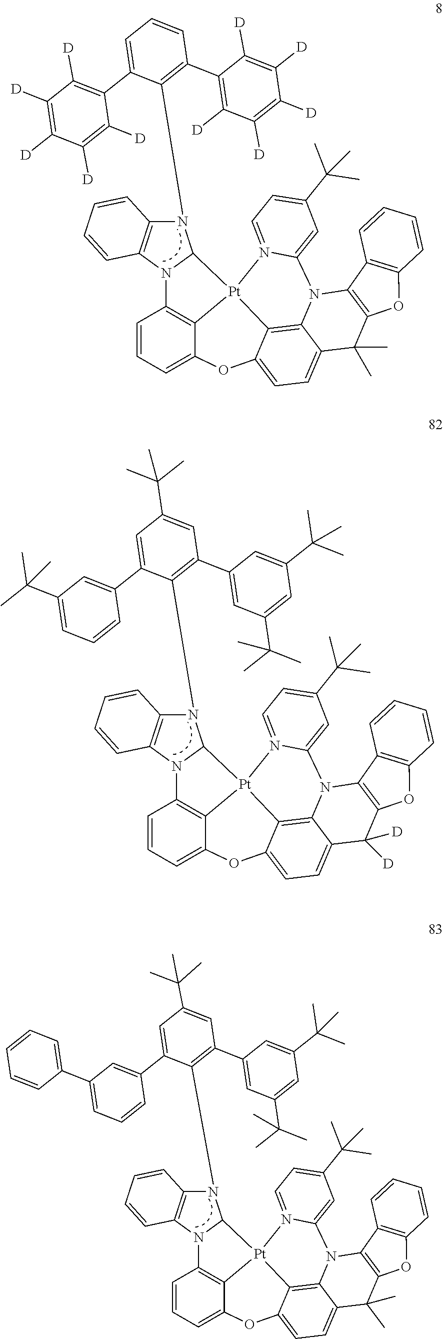 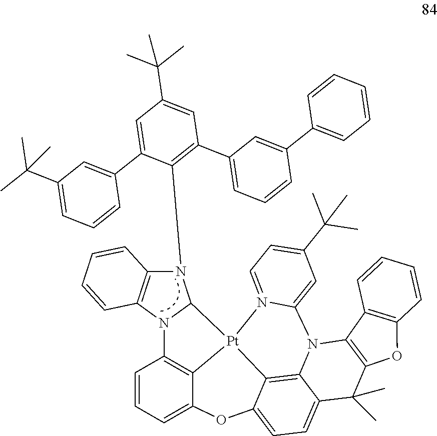
wherein in Compound Group 1, D is deuterium atom, and Ph is an unsubstituted phenyl group.

19. A display device comprising:
a base layer;
a circuit layer on the base layer; and
a display element layer on the circuit layer and including a light emitting element,
wherein the light emitting element comprises a first electrode, a second electrode facing the first electrode, and an emission layer between the first electrode and the second electrode and containing an organometallic compound represented by Formula 1: 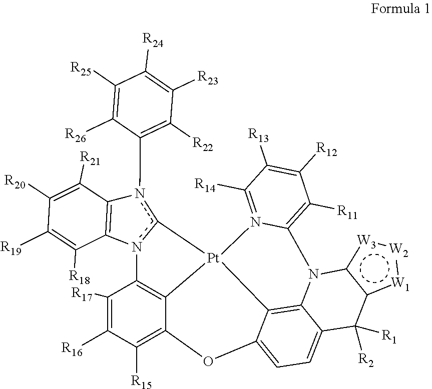
wherein in Formula 1,
at least one of W₁ to W₃ is O or S and the others are CRa,
Ra is a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms, or bonded to an adjacent group to form a ring, and
R₁, R₂, and R₁₁ to R₂₆ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted oxy group, a substituted or unsubstituted thio group, a substituted or unsubstituted aryl group having 6 to 30 ring-forming carbon atoms, or a substituted or unsubstituted heteroaryl group having 3 to 30 ring-forming carbon atoms.

20. The display device of claim 19, wherein the light emitting element emits blue light.

21. The display device of claim 19, further comprising a light control layer containing quantum dots.
